(19) United States
(12) Patent Application Publication
(10) Pub. No.: US 2021/0399227 A1
(43) Pub. Date: Dec. 23, 2021

(54) ORGANIC ELECTROLUMINESCENCE DEVICE AND FUSED POLYCYCLIC COMPOUND FOR ORGANIC ELECTROLUMINESCENCE DEVICE

(71) Applicant: Samsung Display Co., Ltd., Yongin-si (KR)

(72) Inventors: Mun-Ki SIM, Seoul (KR); Soo-Byung KO, Yongin-si (KR); Sun Young PAK, Suwon-si (KR); Junha PARK, Gwacheon-si (KR); Jang Yeol BAEK, Yongin-si (KR); Chanseok OH, Seoul (KR)

(21) Appl. No.: 17/223,937

(22) Filed: Apr. 6, 2021

(30) Foreign Application Priority Data
Jun. 18, 2020 (KR) 10-2020-0074363

(51) Int. Cl. H01L 51/00

(52) U.S. Cl. CPC H01L 51/0069; H01L 51/0094; H01L 51/0059; H01L 51/0072

(57) ABSTRACT

Provided is an organic electroluminescence device, which includes a first electrode and a second electrode which face each other, and a plurality of organic layers between the first electrode and the second electrode, wherein at least one selected from among the organic layers includes a fused polycyclic compound represented by Formula 1 below, thereby exhibiting improved luminous efficiency.

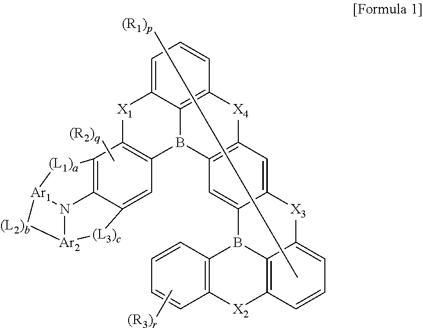

### CROSS-REFERENCE TO RELATED APPLICATION

This application claims priority to and the benefit of Korean Patent Application No. 10-2020-0074363, filed on Jun. 18, 2020, the entire contents of which are hereby incorporated by reference.

### BACKGROUND

### 1. Field

Embodiments of the present disclosure relate to an organic electroluminescence device and a fused polycyclic compound used for the same, and for example, to a fused polycyclic compound used as a luminescent material and an organic electroluminescence device including the same.

### 2. Description of the Related Art

Recently, the development of an organic electroluminescence display as an image display device is being actively conducted. Unlike liquid crystal display devices and the like, the organic electroluminescence display is a so-called self-luminescent display device in which holes and electrons injected from a first electrode and a second electrode recombine in an emission layer, and thus a luminescent material including an organic compound in the emission layer emits light to implement a display.

In the application of an organic electroluminescence device to a display device, there is a demand for an organic electroluminescence device having a low driving voltage, high luminous efficiency, and a long service life, and the development of materials, for an organic electroluminescence device, capable of stably attaining such characteristics is being continuously pursued.

In recent years, particularly in order to implement a highly efficient organic electroluminescence device, technologies pertaining to phosphorescence emission using triplet state energy or delayed fluorescence using triplet-triplet annihilation (TTA) in which singlet excitons are generated by collision of triplet excitons are being developed, and thermally activated delayed fluorescence (TADF) materials using delayed fluorescence phenomenon are being developed.

### SUMMARY

Embodiments of the present disclosure provide an organic electroluminescence device having improved luminous efficiency.

Embodiments of the present disclosure also provide a fused polycyclic compound which can improve luminous efficiency of an organic electroluminescence device.

An embodiment of the present disclosure provides an organic electroluminescence device including: a first electrode; a second electrode facing the first electrode; and a plurality of organic layers between the first electrode and the second electrode, wherein at least one organic layer selected from among the organic layers includes a fused polycyclic compound represented by Formula 1 below, and at least any one of a compound represented by Formula A and a compound represented by Formula B below:

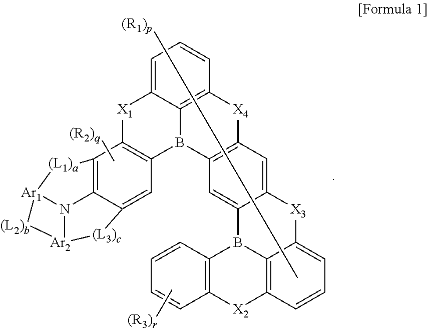

In Formula 1 above, X₁, X₂, X₃, and X₄ are each independently NAr₃, O, or S, Ar₁ to Ar₃ are each independently a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or are bonded to an adjacent group to form a ring, R₁ to R₃ are each independently a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, p is an integer in a range of 0 to 8, q is 0 or 1, r is an integer in a range of 0 to 4, L₁ to L₃ are each independently a direct linkage, *—O—*, *—S—*, *—Si(R₁₁R₁₂)—*, *—CR₁₃R₁₄—*, or *—(CR₁₅)(CR₁₆)—*, R₁₁ to R₁₆ are each independently a deuterium atom, a halogen atom, a cyano group, or a substituted or unsubstituted alkyl group having 1 to 20 carbon atoms, and a, b, and c are each independently 0 or 1,

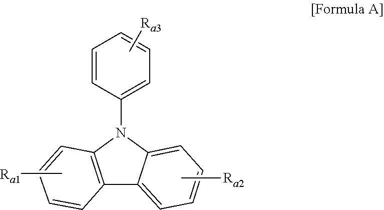

wherein, in Formula A above, Rₐ₁ to Rₐ₃ are each independently a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and

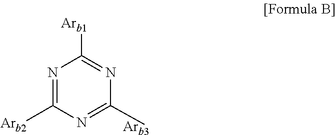

wherein, in Formula B above, Ar_{b1} to Ar_{b3} are each independently a substituted or unsubstituted aryl group having 6 to 30 ring-forming carbon atoms, or a substituted or unsubstituted heteroaryl group having 2 to 30 ring-forming carbon atoms.

In an embodiment, the fused polycyclic compound represented by Formula 1 above may be represented by any one selected from among Formula 1-1 to Formula 1-3 below:

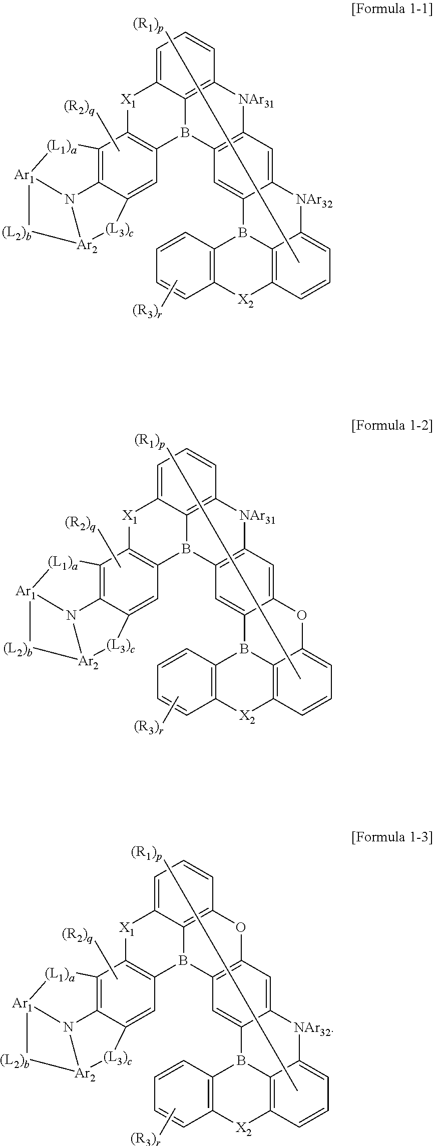

In Formula 1-1 to Formula 1-3 above,

Ar₃₁ and Ar₃₂ may each independently be a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or may be bonded to an adjacent group to form a ring, and X₁, X₂, Ar₁, Ar₂, L₁ to L₃, R₁ to R₃, a, b, c, p, q, and r above may be the same as defined in Formula 1.

In an embodiment, the fused polycyclic compound represented by Formula 1 above may be represented by Formula 2-1 or Formula 2-2 below:

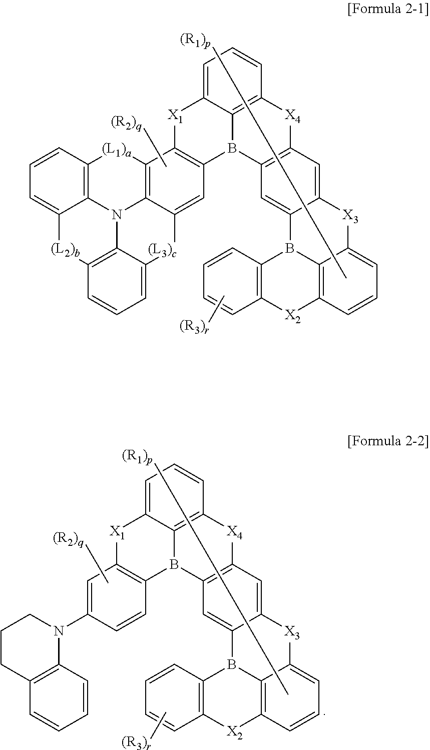

In Formula 2-1 and Formula 2-2 above, X₁ to X₄, L₁ to L₃, R₁ to R₃, a, b, c, p, q, and r above may be the same as defined in Formula 1.

In an embodiment, the fused polycyclic compound represented by Formula 1 above may be represented by Formula 3 below:

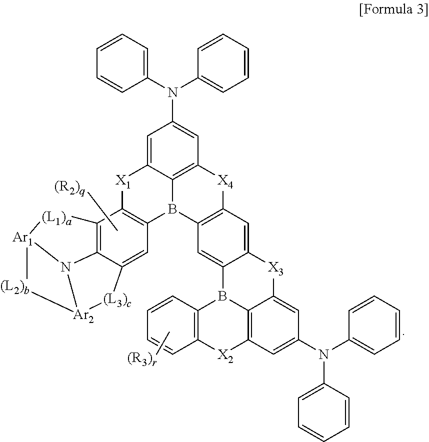

In Formula 3 above, X₁ to X₄, Ar₁, Ar₂, L₁ to L₃, R₂, R₃, a, b, c, q, and r above may be the same as defined in Formula 1.

In an embodiment, X₁ to X₄ above may each independently be NAr₃ or O.

In an embodiment, R₂ and R₃ above may each independently be a hydrogen atom or a deuterium atom.

In an embodiment, the organic layers may include a hole transport region, an emission layer, and an electron transport region which are sequentially on the first electrode, and the emission layer may include the fused polycyclic compound.

In an embodiment, the emission layer may emit a delayed fluorescence.

In an embodiment, at least one organic layer selected from among the organic layers may include the fused polycyclic compound represented by Formula 1 above, the compound represented by Formula A above, and the compound represented by Formula B above.

In an embodiment, the emission layer may emit light in a blue wavelength region.

In an embodiment, a difference (ΔE_{ST}) value between a lowest triplet exciton energy level (T1 energy level) and a lowest singlet exciton energy level (S1 energy level) of the fused polycyclic compound may be about 0.13 eV or less.

### BRIEF DESCRIPTION OF THE DRAWINGS

The accompanying drawings are included to provide a further understanding of the subject matter of the present disclosure, and are incorporated in and constitute a part of this specification. The drawings illustrate exemplary embodiments of the present disclosure and, together with the description, serve to explain principles of the present disclosure. In the drawings:

FIG. 1 is a cross-sectional view schematically illustrating an organic electroluminescence device according to an embodiment of the present disclosure;

FIG. 2 is a cross-sectional view schematically illustrating an organic electroluminescence device according to an embodiment of the present disclosure.

FIG. 3 is a cross-sectional view schematically illustrating an organic electroluminescence device according to an embodiment of the present disclosure; and

FIG. 4 is a cross-sectional view schematically illustrating an organic electroluminescence device according to an embodiment of the present disclosure.

### DETAILED DESCRIPTION

The subject matter of the present disclosure may have various modifications and may be embodied in different forms, and example embodiments will be explained in more detail with reference to the accompanying drawings. The subject matter of the present disclosure may, however, be embodied in different forms and should not be construed as limited to the embodiments set forth herein. Rather, all modifications, equivalents, and substituents which are included in the spirit and technical scope of the present disclosure should be included in the present disclosure.

In the present description, when an element (or a region, a layer, a portion, etc.) is referred to as being “on,” “connected to,” or “coupled to” another element, it means that the element may be directly on/connected to/coupled to the other element, or that a third element may be therebetween.

Like reference numerals refer to like elements throughout. Also, in the drawings, the thickness, the ratio, and the dimensions of elements are exaggerated for an effective description of technical contents.

The term “and/or” includes all combinations of one or more of which associated configurations may define.

It will be understood that, although the terms “first,” “second,” etc. may be used herein to describe various elements, these elements should not be limited by these terms. These terms are only used to distinguish one element from another. For example, a first element could be termed a second element, and, similarly, a second element could be termed a first element, without departing from the scope of example embodiments of the present disclosure. The terms of a singular form may include plural forms unless the context clearly indicates otherwise.

In addition, terms such as “below,” “lower,” “above,” “upper,” and the like are used to describe the relationship of the configurations shown in the drawings. The terms are used as a relative concept and are described with reference to the direction indicated in the drawings.

Unless otherwise defined, all terms (including technical and scientific terms) used herein have the same meaning as commonly understood by one of ordinary skill in the art to which the present disclosure pertains. It is also to be understood that terms defined in commonly used dictionaries should be interpreted as having meanings consistent with the meanings in the context of the related art, and are expressly defined herein unless they are interpreted in an ideal or overly formal sense.

It should be understood that the terms “comprise,” or “have” are intended to specify the presence of stated features, integers, acts, operations, elements, components, or combinations thereof in the disclosure, but do not preclude the presence or addition of one or more other features, integers, acts, operations, elements, components, or combinations thereof.

Hereinafter, an organic electroluminescence device according to an embodiment of the present disclosure and a fused polycyclic compound of an embodiment included therein will be described with reference to the accompanying drawings.

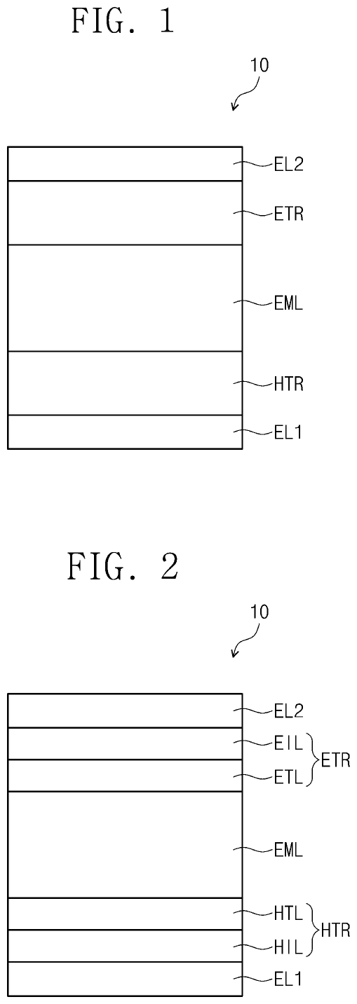

FIGS. 1 to 4 are cross-sectional views schematically illustrating organic electroluminescence devices according to embodiments of the present disclosure. Referring to FIGS. 1 to 4, in each of organic electroluminescence devices 10 according to embodiments of the present disclosure, a first electrode EU and a second electrode EL2 face each other, and a plurality of organic layers may be between the first electrode EL1 and the second electrode EL2. The plurality of organic layers may include a hole transport region HTR, an emission layer EML, an electron transport region ETR. For example, each of the organic electroluminescence devices 10 according to embodiments may include the first electrode EL1 the hole transport region HTR, the emission layer EML, the electron transport region ETR, and the second electrode EL2 that are sequentially stacked.

The organic electroluminescence device 10 of an embodiment may include a fused polycyclic compound according to an embodiment described below in at least one organic layer selected from among the plurality of organic layers between the first electrode EL1 and the second electrode EL2. For example, the organic electroluminescence device 10 of an embodiment may include a fused polycyclic compound according to an embodiment described below in the emission layer EML between the first electrode EL1 and the second electrode EL2. However, embodiments of the present disclosure are not limited thereto, and the organic electroluminescence device 10 of an embodiment may include a fused polycyclic compound according to an embodiment described below in at least one organic layer included in the hole transport region HTR and the electron transport region ETR which are the plurality of organic layers between the first electrode EL1 and the second electrode EL2, as well as in the emission layer EML.

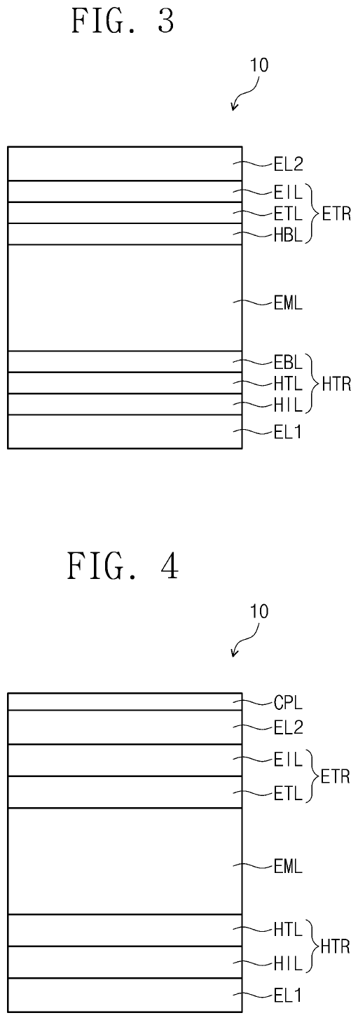

Compared to FIG. 1, FIG. 2 illustrates a cross-sectional view of an organic electroluminescence device 10 of an embodiment, in which a hole transport region HTR includes a hole injection layer HIL and a hole transport layer HTL, and an electron transport region ETR includes an electron injection layer EIL and an electron transport layer ETL. In addition, compared to FIG. 1, FIG. 3 illustrates a cross-sectional view of an organic electroluminescence device 10 of an embodiment, in which a hole transport region HTR includes a hole injection layer HIL, a hole transport layer HTL, and an electron blocking layer EBL, and an electron transport region ETR includes an electron injection layer EIL, an electron transport layer ETL, and a hole blocking layer HBL.

Hereinafter, in the description of the organic electroluminescence device 10 of an embodiment, it is described that the organic electroluminescence device 10 includes a fused polycyclic compound according to an embodiment described below in the emission layer EML, but embodiments of the present disclosure are not limited thereto, and the fused polycyclic compound according to an embodiment described below may be included in the hole transport region HTR and/or the electron transport region ETR.

The first electrode EL1 has conductivity (e.g., electrical conductivity). The first electrode EL1 may be formed of a metal alloy and/or a conductive compound. The first electrode EL1 may be an anode. In addition, the first electrode EU may be a pixel electrode. The first electrode EU may be a transmissive electrode, a transflective electrode, or a reflective electrode. When the first electrode EL1 is the transmissive electrode, the first electrode EL1 may include a transparent metal oxide, such as, indium tin oxide (ITO), indium zinc oxide (IZO), zinc oxide (ZnO), and/or indium tin zinc oxide (ITZO). When the first electrode EL1 is the transflective electrode or the reflective electrode, the first electrode EU may include Ag, Mg, Cu, Al, Pt, Pd, Au, Ni, Nd, Ir, Cr, Li, Ca, LiF/Ca, LiF/Al, Mo, Ti, a compound thereof, or a mixture thereof (e.g., a mixture of Ag and Mg). In some embodiments, the first electrode EL1 may have a multilayer structure including a reflective layer or a transflective layer formed of the above-described materials, and a transparent conductive layer formed of ITO, IZO, ZnO, ITZO, etc. For example, the first electrode EU may have a three-layer structure of ITO/Ag/ITO, but embodiments of the present disclosure are not limited thereto. The thickness of the first electrode EU may be in a range from about 1,000 Å to about 10,000 Å, for example, in a range from about 1,000 Å to about 3,000 Å.

The hole transport region HTR is on the first electrode EL1. The hole transport region HTR may include at least one selected from a hole injection layer HIL, a hole transport layer HTL, a hole buffer layer, and an electron blocking layer EBL. The thickness of the hole transport region HTR may be, for example, in a range from about 50 Å to about 1,500 Å.

The hole transport region HTR may have a single layer formed of a single material, a single layer formed of a plurality of different materials, or a multilayer structure including a plurality of layers formed of a plurality of different materials.

For example, the hole transport region HTR may have a single layer structure of a hole injection layer HIL or a hole transport layer HTL, and may have a single layer structure formed of a hole injection material and a hole transport material. In addition, the hole transport region HTR may have a single layer structure formed of a plurality of different materials, or a structure in which a hole injection layer HIL/hole transport layer HTL, a hole injection layer HIL/hole transport layer HTL/hole buffer layer, a hole injection layer HIL/hole buffer layer, a hole transport layer HTL/hole buffer layer, or a hole injection layer HIL/hole transport layer HTL/electron blocking layer EBL are stacked in order from the first electrode EL1, but an embodiment is not limited thereto.

The hole transport region HTR may be formed using various suitable methods such as a vacuum deposition method, a spin coating method, a cast method, a Langmuir-Blodgett (LB) method, an inkjet printing method, a laser printing method, and/or a laser induced thermal imaging (LITI) method.

The hole injection layer HIL may include, for example, a phthalocyanine compound such as copper phthalocyanine; N,N′-diphenyl-N,N′-bis-[4-(phenyl-m-tolyl-amino)-phenyl]-biphenyl-4,4′-diamine (DNTPD), 4,4′,4″-tris(3-methylphenylphenylamino)triphenylamine (m-MTDATA), 4,4′,4″-tris(N,N-diphenylamino)triphenylamine (TDATA), 4,4′,4″-tris{N-(2-naphthyl)-N-phenylamino)-triphenylamine (2-TNATA), poly(3,4-ethylenedioxythiophene)/poly(4-styrenesulfonate) (PEDOT/PSS), polyaniline/dodecylbenzenesulfonic acid (PANI/DBSA), polyaniline/camphor sulfonic acid (PANI/CSA), polyaniline/poly(4-styrenesulfonate) (PANI/PSS), N,N′-di(naphthalene-1-yl)-N,N′-diphenyl-benzidine (NPB), N,N′-di(1-naphthyl)-N,N′-diphenyl-(1,1′-biphenyl)-4,4′-diamine (NPD), triphenylamine-containing polyetherketone (TPAPEK), 4-isopropyl-4′-methyldiphenyliodonium tetrakis(pentafluorophenyl)borate, dipyrazino[2,3-f: 2′,3′-h]quinoxaline-2,3,6,7,10,11-hexacarbonitrile (HAT-CN), etc.

The hole transport layer HTL may further include, for example, carbazole derivatives such as N-phenyl carbazole and polyvinyl carbazole, fluorene derivatives, N,N′-bis(3-methylphenyl)-N,N′-diphenyl-[1,1-biphenyl]-4,4′-diamine (TPD), triphenylamine derivatives such as 4,4′,4″-tris(N-carbazolyl)triphenylamine (TCTA), N,N′-di(naphthalene-1-yl)-N,N′-diphenyl-benzidine (NPB), 4,4′-cyclohexylidene bis[N,N-bis(4-methylphenyl]benzenamine] (TAPC), 4,4′-bis[N,N′-(3-tolyl)amino]-3,3′-dimethylbiphenyl (HMTPD), 1,3-bis(N-carbazolyl)benzene (mCP), 9-(4-tert-butylphenyl)-3,6-bis(triphenylsilyl)-9H-carbazole (CzSi), etc.

The thickness of the hole transport region HTR may be in a range from about 100 Å to about 10,000 Å, for example, in a range from about 100 Å to about 5,000 Å. The thickness of the hole injection layer HIL may be, for example, in a range from about 30 Å to about 1,000 Å, and the thickness of the hole transport layer HTL may be in a range from about 30 Å to about 1,000 Å. For example, the thickness of the electron blocking layer EBL may be in a range from about 10 Å to about 1,000 Å. If the thicknesses of the hole transport region HTR, the hole injection layer HIL, the hole transport layer HTL and the electron blocking layer EBL satisfy the above-described ranges, suitable or satisfactory hole transport properties may be achieved without a substantial increase in driving voltage.

The hole transport region HTR may further include, in addition to the above-described materials, a charge generating material to increase conductivity (e.g., electrical conductivity). The charge generating material may be dispersed uniformly or non-uniformly in the hole transport region HTR. The charge generating material may be, for example, a p-dopant. The p-dopant may be one of quinone derivatives, metal oxides, and/or cyano group-containing compounds, but embodiments of the present disclosure are not limited thereto. For example, non-limiting examples of the p-dopant may include quinone derivatives such as tetracyanoquinodimethane (TCNQ) and 2,3,5,6-tetrafluoro-7,7′,8,8′-tetracyanoquinodimethane (F4-TCNQ), metal oxides such as tungsten oxide and molybdenum oxide, etc., but embodiments of the present disclosure are not limited thereto.

As described above, the hole transport region HTR may further include at least one of a hole buffer layer and/or an electron blocking layer EBL in addition to the hole injection layer HIL and the hole transport layer HTL. The hole buffer layer, may compensate a resonance distance according to the wavelength of light emitted from an emission layer EML and may increase light emission efficiency. Materials which may be included in the hole transport region HTR may be used as materials which may be included in the hole buffer layer. The electron blocking layer EBL is a layer that serves to prevent or reduce injection of electrons from the electron transport region ETR to the hole transport region HTR.

The emission layer EML is provided on the hole transport region HTR. The thickness of the emission layer EML may be, for example, in a range from about 100 Å to about 1,000 Å or in a range from about 100 Å to about 300 Å. The emission layer EML may have a single layer formed of a single material, a single layer formed of a plurality of different materials, or a multilayer structure having a plurality of layers formed of a plurality of different materials.

The emission layer EML in the organic electroluminescence device 10 of an embodiment may include a fused polycyclic compound of an embodiment.

In the present description, the term “substituted or unsubstituted” may indicate that one is substituted or unsubstituted with at least one substituent selected from the group consisting of a deuterium atom, a halogen atom, a cyano group, a nitro group, an amino group, a silyl group, an oxy group, a thio group, a sulfinyl group, a sulfonyl group, a carbonyl group, a boron group, a phosphine oxide group, a phosphine sulfide group, an alkyl group, an alkenyl group, an alkoxy group, a hydrocarbon ring group, an aryl group, and a heterocyclic group. In addition, each of the substituents exemplified above may be substituted or unsubstituted. For example, a biphenyl group may be interpreted as an aryl group or a phenyl group substituted with a phenyl group.

In the present description, the phrase “bonded to an adjacent group to form a ring” may indicate that one is bonded to an adjacent group to form a substituted or unsubstituted hydrocarbon ring, or a substituted or unsubstituted heterocycle. The hydrocarbon ring includes an aliphatic hydrocarbon ring and an aromatic hydrocarbon ring. The heterocycle includes an aliphatic heterocycle and an aromatic heterocycle. The rings formed by being bonded to an adjacent group may be monocyclic or polycyclic. In addition, the rings formed by being bonded to each other may be connected to another ring to form a spiro structure.

In the present description, the term “an adjacent group” may mean a substituent substituted for an atom which is directly connected to an atom substituted with a corresponding substituent, another substituent substituted for an atom which is substituted with a corresponding substituent, or a substituent sterically positioned at the nearest position to a corresponding substituent. For example, two methyl groups in 1,2-dimethylbenzene may be interpreted as “adjacent groups” to each other and two ethyl groups in 1,1-diethylcyclopentane may be interpreted as “adjacent groups” to each other.

In the present description, a direct linkage may be a single bond (e.g., single covalent bond).

In the present description, examples of the halogen atom may include a fluorine atom, a chlorine atom, a bromine atom, and an iodine atom.

In the present description, the alkyl group may be a linear, branched or cyclic type (e.g., a linear alkyl group, a branched alkyl group, or a cyclic alkyl group). The number of carbons in the alkyl group is 1 to 50, 1 to 30, 1 to 20, 1 to 10, or 1 to 6. Examples of the alkyl group may include a methyl group, an ethyl group, an n-propyl group, an isopropyl group, an n-butyl group, an s-butyl group, a t-butyl group, an i-butyl group, a 2-ethylbutyl group, a 3,3-dimethylbutyl group, an n-pentyl group, an i-pentyl group, a neopentyl group, a t-pentyl group, a cyclopentyl group, a 1-methylpentyl group, a 3-methylpentyl group, a 2-ethylpentyl group, a 4-methyl-2-pentyl group, an n-hexyl group, a 1-methylhexyl group, a 2-ethylhexyl group, a 2-butylhexyl group, a cyclohexyl group, a 4-methylcyclohexyl group, a 4-t-butylcyclohexyl group, an n-heptyl group, a 1-methylheptyl group, a 2,2-dimethylheptyl group, a 2-ethylheptyl group, a 2-butylheptyl group, an n-octyl group, a t-octyl group, a 2-ethyloctyl group, a 2-butyloctyl group, a 2-hexyloctyl group, a 3,7-dimethyloctyl group, a cyclooctyl group, an n-nonyl group, an n-decyl group, an adamantyl group, a 2-ethyldecyl group, a 2-butyldecyl group, a 2-hexyldecyl group, a 2-octyldecyl group, an n-undecyl group, an n-dodecyl group, a 2-ethyldodecyl group, a 2-butyldodecyl group, a 2-hexyldocecyl group, a 2-octyldodecyl group, an n-tridecyl group, an n-tetradecyl group, an n-pentadecyl group, an n-hexadecyl group, a 2-ethylhexadecyl group, a 2-butylhexadecyl group, a 2-hexylhexadecyl group, a 2-octylhexadecyl group, an n-heptadecyl group, an n-octadecyl group, an n-nonadecyl group, an n-eicosyl group, a 2-ethyleicosyl group, a 2-butyleicosyl group, a 2-hexyleicosyl group, a 2-octyleicosyl group, an n-heneicosyl group, an n-docosyl group, an n-tricosyl group, an n-tetracosyl group, an n-pentacosyl group, an n-hexacosyl group, an n-heptacosyl group, an n-octacosyl group, an n-nonacosyl group, an n-triacontyl group, etc., but embodiments of the present disclosure are not limited thereto.

In the present description, the hydrocarbon ring includes an aliphatic hydrocarbon ring and an aromatic hydrocarbon ring. The heterocycle includes an aliphatic heterocycle and an aromatic heterocycle. The hydrocarbon ring and the heterocycle may be monocyclic or polycyclic.

In the present description, a hydrocarbon ring group may be an any functional group or substituent derived from an aliphatic hydrocarbon ring, or an any functional group or substituent derived from an aromatic hydrocarbon ring. The carbon number for forming a ring in the hydrocarbon ring group may be 5 to 60.

In the present description, the hetero ring group may be an optional functional group or substituent derived from a hetero ring including at least one heteroatom as an atom for forming a ring. The carbon number for forming a ring in the hetero ring group may be 5 to 60.

In the present description, the term “aryl group” means any functional group or substituent derived from an aromatic hydrocarbon ring. The aryl group may be a monocyclic aryl group or a polycyclic aryl group. The number of ring-forming carbon atoms in the aryl group may be 6 to 30, 6 to 20, or 6 to 15. Examples of the aryl group may include a phenyl group, a naphthyl group, a fluorenyl group, an anthracenyl group, a phenanthryl group, a biphenyl group, a terphenyl group, a quaterphenyl group, a quinqphenyl group, a sexiphenyl group, a triphenylenyl group, a pyrenyl group, a benzofluoranthenyl group, a chrysenyl group, etc., but embodiments of the present disclosure are not limited thereto.

In the present description, the fluorenyl group may be substituted, and two substituents may be combined with each other to form a spiro structure. Examples of the substituted fluorenyl group are as follows. However, embodiments of the present disclosure are not limited thereto.

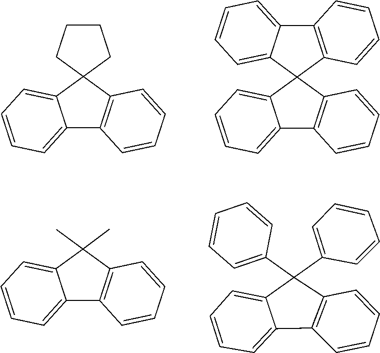

In the present description, the heteroaryl group may include at least one of B, O, N, P, Si, and S as a heteroatom. When the heteroaryl group contains two or more heteroatoms, the two or more heteroatoms may be the same as or different from each other. The heteroaryl group may be a monocyclic heterocyclic group or a polycyclic heterocyclic group. The number of ring-forming carbon atoms in the heteroaryl group may be 2 to 30, 2 to 20, or 2 to 10. Examples of the heteroaryl group may include, but are not limited to, thiophene, furan, pyrrole, imidazole, thiazole, oxazole, oxadiazole, triazole, pyridine, bipyridine, pyrimidine, triazine, triazole, acridine, pyridazine, pyrazine, quinoline, quinazoline, quinoxaline, phenoxazine, phthalazine, pyrido pyrimidine, pyrido pyrazine, pyrazino pyrazine, isoquinoline, indole, carbazole, N-arylcarbazole, N-heteroarylcarbazole, N-alkylcarbazole, benzoxazole, benzoimidazole, benzothiazole, benzocarbazole, benzothiophene, dibenzothiophene, thienothiophene, benzofuran, phenanthroline, thiazole, isooxazole, oxadiazole, thiadiazole, phenothiazine, dibenzosilole, dibenzofuranyl, etc.

In the present description, the silyl group includes an alkyl silyl group and an aryl silyl group. Examples of the silyl group may include, but are not limited to, trimethylsilyl, triethylsilyl, t-butyldimethylsilyl, vinyldimethylsilyl, propyldimethylsilyl, triphenylsilyl, diphenylsilyl, phenylsilyl, etc.

In the present description, the boron group includes an alkyl boron group and an aryl boron group. Examples of the boron group may include, but are not limited to, trimethylboron, triethylboron, t-butyldimethylboron, triphenylboron, diphenylboron, phenylboron, etc.

In the present description, the alkenyl group may be linear or branched. Although the number of carbon atoms is not specifically limited, but may be 2 to 30, 2 to 20, or 2 to 10. Examples of the alkenyl group include a vinyl group, a 1-butenyl group, a 1-pentenyl group, a 1,3-butadienyl aryl group, a styrenyl group, a styryl vinyl group, etc., but embodiments of the present disclosure are not limited thereto.

In the present description, the number of carbon atoms in an amine group is not specifically limited, but may be 1 to 30. The amine group may include an alkyl amine group and an aryl amine group. Examples of the amine group may include, but are not limited to, methylamine group, dimethylamine group, phenylamine group, diphenylamine group, naphthylamine group, 9-methyl-anthracenylamine group, triphenylamine group, etc.

In the present description, the hydrocarbon ring group refers to any functional group or substituent derived from an aliphatic hydrocarbon ring. The hydrocarbon ring group may be a saturated hydrocarbon ring group having 5 to 20 ring-forming carbon atoms.

In the present description, the heterocyclic group may include at least one of B, O, N, P, Si, and S as a hetero atom. When the heterocyclic group contains two or more hetero atoms, the two or more hetero atoms may be the same as or different from each other. The heterocyclic group may be a monocyclic heterocyclic group or a polycyclic heterocyclic group, and includes a heteroaryl group. The number of ring-forming carbon atoms in the heterocyclic group may be 2 to 30, 2 to 20, or 2 to 10.

In the present description, the aryl group of aryl oxy, aryl thio, aryl sulfoxy, aryl amino, aryl boron, aryl silyl is the same as examples of the aryl group described above.

In the present description, the direct linkage may mean a single bond (e.g., a single covalent bond).

In the present description

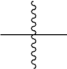

or “-.” means the position to be linked (e.g., linked to an adjacent atom).

The fused polycyclic compound of an embodiment includes: a fused polycyclic heterocycle in which five rings are fused (e.g., combined together) and which contains a first boron atom and a second boron atom; an aromatic ring group having 6 ring-forming carbon atoms substituted to the first boron atom; and a nitrogen atom which is substituted to the aromatic ring group and bonded at the para-position of the first boron atom. For example, the aromatic ring group having 6 ring-forming carbon atoms substituted to the first boron atom may be a phenyl group.

The fused polycyclic compound of an embodiment is represented by Formula 1 below:

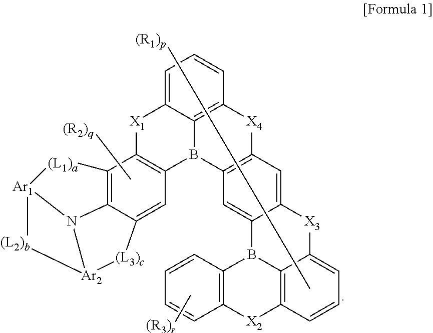

In Formula 1 above, X₁, X₂, X₃, and X₄ may each independently be NAr₃, O, or S. For example, X₁, X₂, X₃, and X₄ may each independently be NAr₃, or O.

In Formula 1, Ar₁ to Ar₃ may each independently be a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or may be bonded to an adjacent group to form a ring. For example, Ar₁ may be a substituted phenyl group or a divalent propane which is bonded to Ar₂ to form a ring.

For example, Ar₂ may be a substituted or unsubstituted phenyl group.

For example, Ar₃ may be a substituted or unsubstituted phenyl group.

In Formula 1, R₁ to R₃ may each independently be a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

For example, R₁ may be a substituted or unsubstituted amine group. In some embodiments, R₁ may be an arylamine group. For example, R₁ may be a biphenyl amine group.

For example, R₂ and R₃ each may be a hydrogen atom or a deuterium atom.

In Formula 1, p is an integer in a range of 0 to 8. For example, p may be 2. In Formula 1, if p is 2 or more, a plurality of R₁'s may be the same as or different from each other.

In Formula 1, q is 0 or 1. For example, in Formula 1, when q is 0, R₂ may not be substituted in the fused polycyclic compound of an embodiment. In Formula 1, the case where q is 1 and R₂ is a hydrogen atom may be the same as the case where q is 0 in Formula 1.

In Formula 1, r is an integer in a range of 0 to 4. For example, r may be 0 or 1. In Formula 1, when r is 0, R₃ may not be substituted in the fused polycyclic compound of an embodiment. In Formula 1, the case where r is 1 and R₃ is a hydrogen atom may be the same as the case where r is 0 in Formula 1.

In Formula 1, L₁ to L₃ are each independently a direct linkage, *—S—*, *—Si(R₁₁R₁₂)—*, *—CR₁₃R₁₄—*, or *—(CR₁₅)(CR₁₆)—*. R₁₁ to R₁₆ may be a deuterium atom, a halogen atom, a cyano group, an alkyl group having 1 to 20 carbon atoms. For example, R₁₁ to R₁₆ each may be a methyl group.

In Formula 1, a, b and c are each independently 0 or 1. In Formula 1, the case where a, b, and c each are 0 may be the same as the case where L₁ to L₃ each are not included in the fused polycyclic compound of an embodiment, respectively.

The fused polycyclic compound of an embodiment includes two boron atoms and a nitrogen atom which is at the para-position to any one of the two boron atoms, and thus donor characteristics may be reinforced and a difference between a lowest singlet exciton energy level (S1 energy level) and a lowest triplet exciton energy level (T1 energy level) may decrease. This allows reverse intersystem crossing (RISC) to easily occur, and thus the fused polycyclic compound of an embodiment may exhibit high external quantum efficiency.

In addition, the electron density in the molecule (the fused polycyclic compound) is increased by the nitrogen atom, and thus the bonding energy between the boron atom and the carbon atom may be increased and the stability of the molecule (the fused polycyclic compound) may be enhanced.

The organic electroluminescence device including the fused polycyclic compound of an embodiment as a luminescent material may have improved TADF characteristics and luminous efficiency of the device.

In an embodiment, the fused polycyclic compound of an embodiment represented by Formula 1 may be represented by any one selected from among Formula 1-1 to Formula 1-3 below:

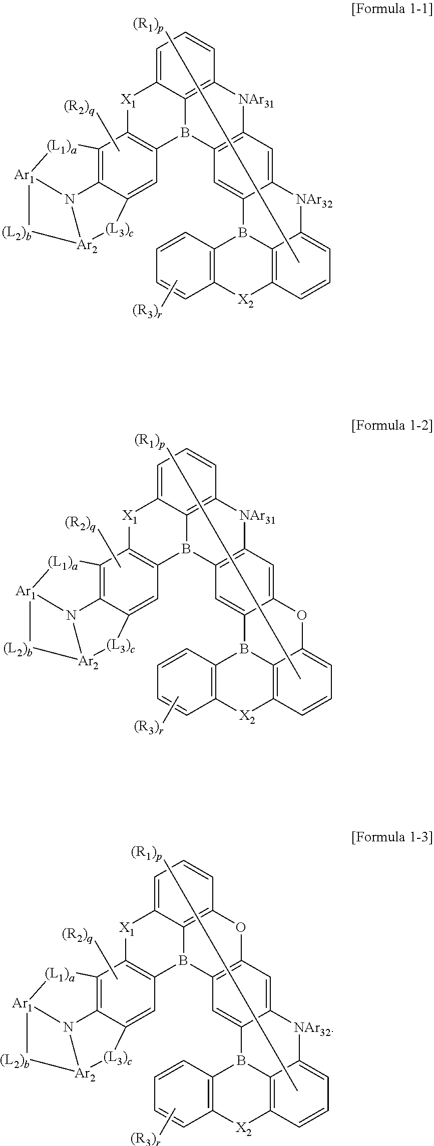

Formula 1-1 to Formula 1-3 above are those in which X₃ and X₄ are specified in Formula 1 above. As shown in Formula 1-1 to Formula 1-3, at least any one of X₃ and X₄ may be NAr₃₁ or NAr₃₂.

In Formula 1-1 to Formula 1-3, Ar₃₁ and Ar₃₂ may each independently be a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or may be bonded to an adjacent group to form a ring. For example, NAr₃₁ and NAr₃₂ each may be a biphenyl amine.

In Formula 1-1 to Formula 1-3, the definitions provided with respect to Formula 1 may be equally applied to X₁, X₂, Ar₁, Ar₂, L₁ to L₃, R₁ to R₃, a, b, c, p, q, and r.

In an embodiment, the fused polycyclic compound represented by Formula 1 above may be represented by Formula 2-1 or Formula 2-2 below:

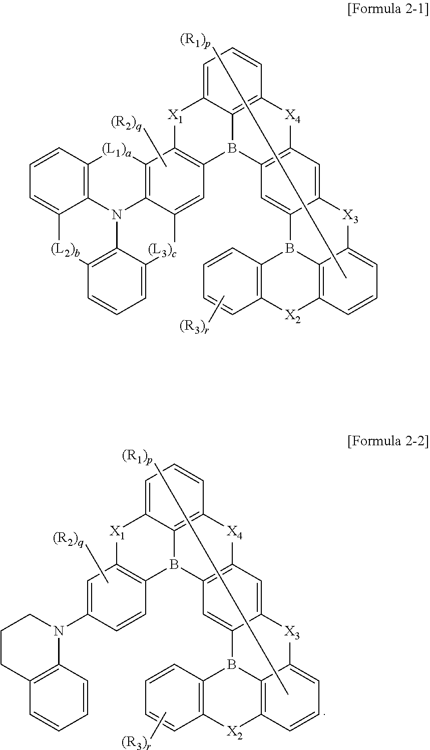

Formula 2-1 and Formula 2-2 are those in which Ar₁, Ar₂, and L₁ to L₃ are specified in Formula 1 above. For example, Formula 2-1 represents the case where Ar₁ and Ar₂ are phenyl groups in Formula 1. Formula 2-2 represents the case where, in Formula 1, Ar₁ is bonded to Ar₂ to form a piperidine, and Ar₂ is a phenyl group. In addition, Formula 2-2 represents the case where a, b, and c are 0.

In Formula 2-1 and Formula 2-2, those described in Formula 1 may be equally applied to X₁ to X₄, R₁ to R₃, L₁ to L₃, a, b, c, p, q, and r.

In an embodiment, the fused polycyclic compound represented by Formula 1 may be represented by Formula 3 below:

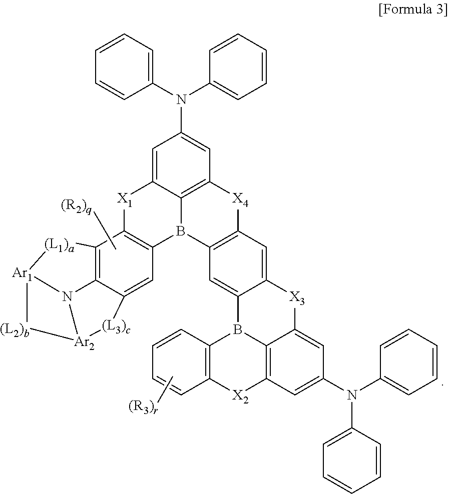

Formula 3 is the one in which R₁ is specified in Formula 1 above. For example, Formula 3 represents the case where, in Formula 1, p is 2 and two R₁'s are both biphenyl amine groups.

In Formula 3, those described in Formula 1 may be equally applied to X₁ to X₄, R₂, R₃, L₁ to L₃, a, b, c, q, and r.

The fused polycyclic compound of an embodiment may be any one selected from among compounds represented by Compound Group 1 below. The electroluminescence device 10 of an embodiment may include at least one fused polycyclic compound selected from among the compounds represented by Compound Group 1 in the emission layer EML.

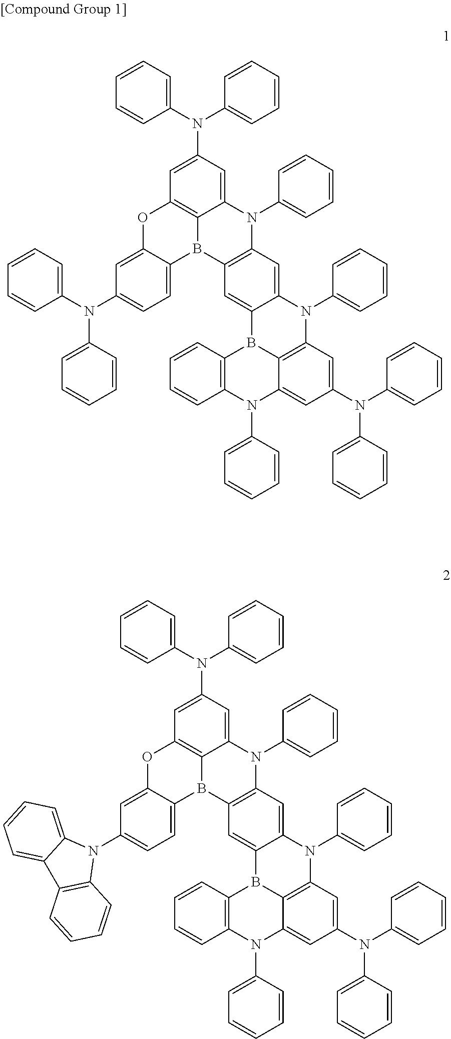 [SMILES: c1ccc(N(c2ccccc2)c2ccc3c(c2)Oc2cc(N(c4ccccc4)c4ccccc4)cc4c2B3c2cc3c(cc2N4c2ccccc2)N(c2ccccc2)c2cc(N(c4ccccc4)c4ccccc4)cc4c2B3c2ccccc2N4c2ccccc2)cc1 ; c1ccc(N(c2ccccc2)c2cc3c4c(c2)N(c2ccccc2)c2cc5c(cc2B4c2ccc(-n4c6ccccc6c6ccccc64)cc2O3)B2c3ccccc3N(c3ccccc3)c3cc(N(c4ccccc4)c4ccccc4)cc(c32)N5c2ccccc2)cc1]

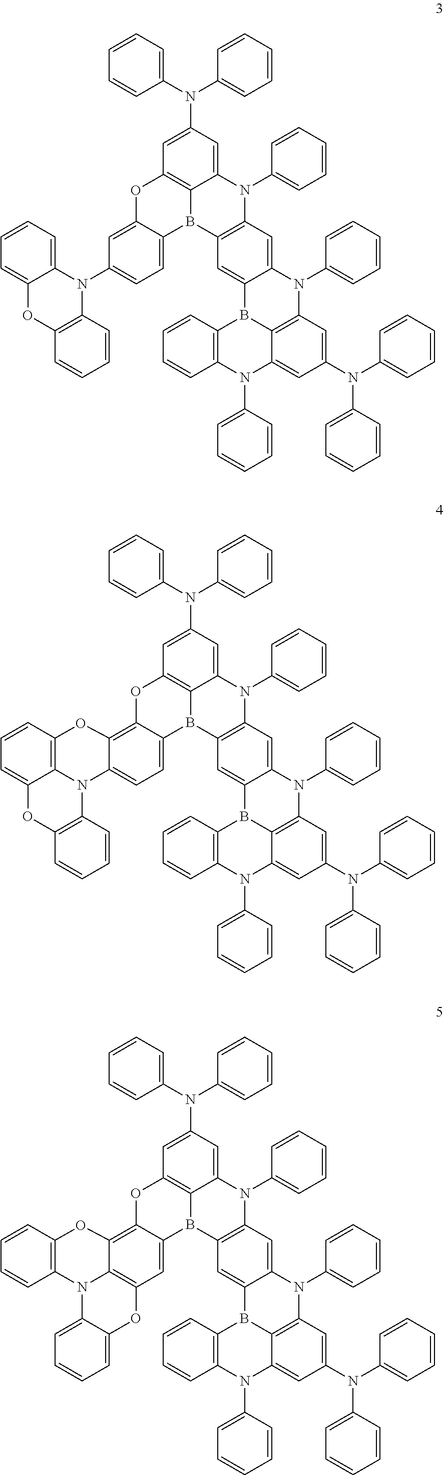 [SMILES: c1ccc(N(c2ccccc2)c2cc3c4c(c2)N(c2ccccc2)c2cc5c(cc2B4c2ccc(N4c6ccccc6Oc6ccccc64)cc2O3)B2c3ccccc3N(c3ccccc3)c3cc(N(c4ccccc4)c4ccccc4)cc(c32)N5c2ccccc2)cc1 ; c1ccc(N(c2ccccc2)c2cc3c4c(c2)N(c2ccccc2)c2cc5c(cc2B4c2ccc4c(c2O3)Oc2cccc3c2N4c2ccccc2O3)B2c3ccccc3N(c3ccccc3)c3cc(N(c4ccccc4)c4ccccc4)cc(c32)N5c2ccccc2)cc1 ; c1ccc(N(c2ccccc2)c2cc3c4c(c2)N(c2ccccc2)c2cc5c(cc2B4c2cc4c6c(c2O3)Oc2ccccc2N6c2ccccc2O4)B2c3ccccc3N(c3ccccc3)c3cc(N(c4ccccc4)c4ccccc4)cc(c32)N5c2ccccc2)cc1]

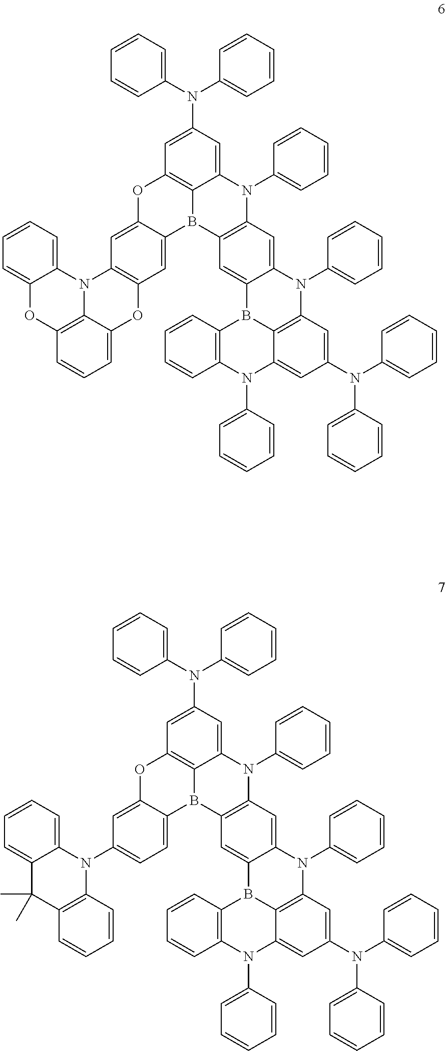 [SMILES: c1ccc(N(c2ccccc2)c2cc3c4c(c2)N(c2ccccc2)c2cc5c(cc2B4c2cc4c(cc2O3)N2c3ccccc3Oc3cccc(c32)O4)B2c3ccccc3N(c3ccccc3)c3cc(N(c4ccccc4)c4ccccc4)cc(c32)N5c2ccccc2)cc1 ; CC1(C)c2ccccc2N(c2ccc3c(c2)Oc2cc(N(c4ccccc4)c4ccccc4)cc4c2B3c2cc3c(cc2N4c2ccccc2)N(c2ccccc2)c2cc(N(c4ccccc4)c4ccccc4)cc4c2B3c2ccccc2N4c2ccccc2)c2ccccc21]

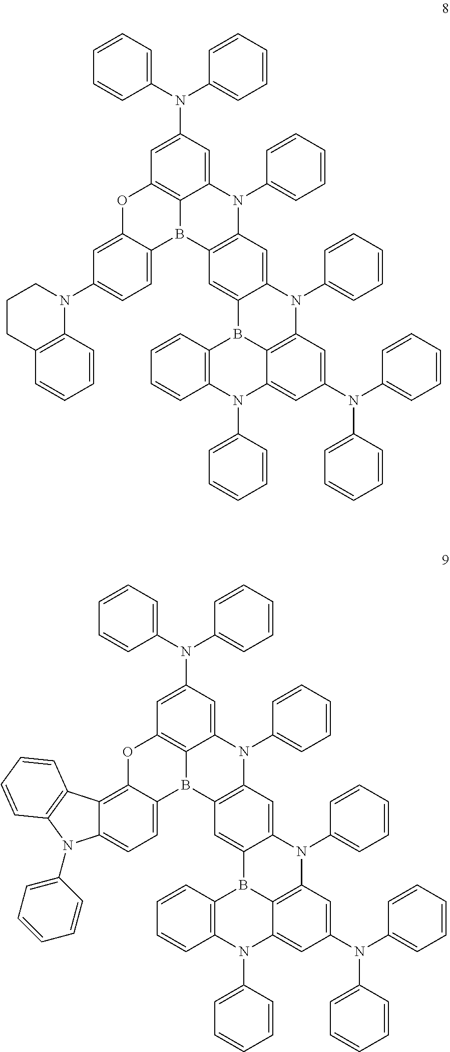 [SMILES: c1ccc(N(c2ccccc2)c2cc3c4c(c2)N(c2ccccc2)c2cc5c(cc2B4c2ccc(N4CCCc6ccccc64)cc2O3)B2c3ccccc3N(c3ccccc3)c3cc(N(c4ccccc4)c4ccccc4)cc(c32)N5c2ccccc2)cc1 ; c1ccc(N(c2ccccc2)c2cc3c4c(c2)N(c2ccccc2)c2cc5c(cc2B4c2ccc4c(c2O3)c2ccccc2n4-c2ccccc2)B2c3ccccc3N(c3ccccc3)c3cc(N(c4ccccc4)c4ccccc4)cc(c32)N5c2ccccc2)cc1]

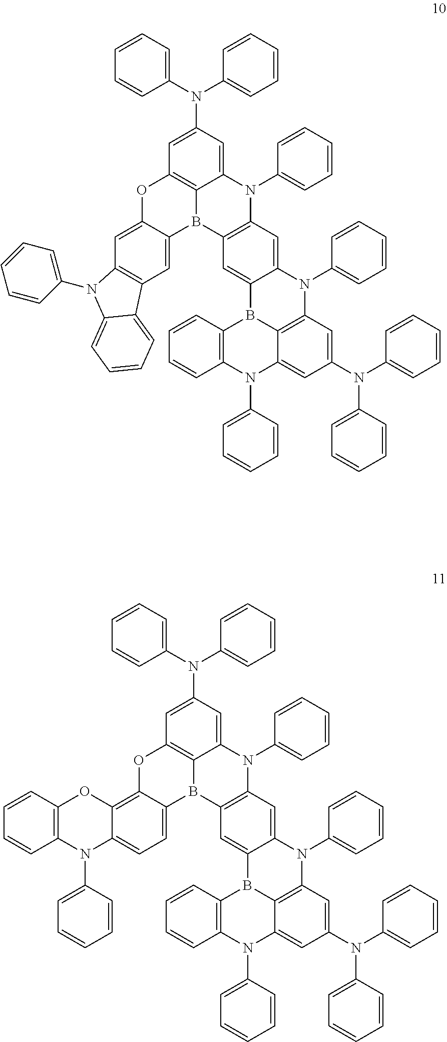 [SMILES: c1ccc(N(c2ccccc2)c2cc3c4c(c2)N(c2ccccc2)c2cc5c(cc2B4c2cc4c6ccccc6n(-c6ccccc6)c4cc2O3)B2c3ccccc3N(c3ccccc3)c3cc(N(c4ccccc4)c4ccccc4)cc(c32)N5c2ccccc2)cc1 ; c1ccc(N(c2ccccc2)c2cc3c4c(c2)N(c2ccccc2)c2cc5c(cc2B4c2ccc4c(c2O3)Oc2ccccc2N4c2ccccc2)B2c3ccccc3N(c3ccccc3)c3cc(N(c4ccccc4)c4ccccc4)cc(c32)N5c2ccccc2)cc1]

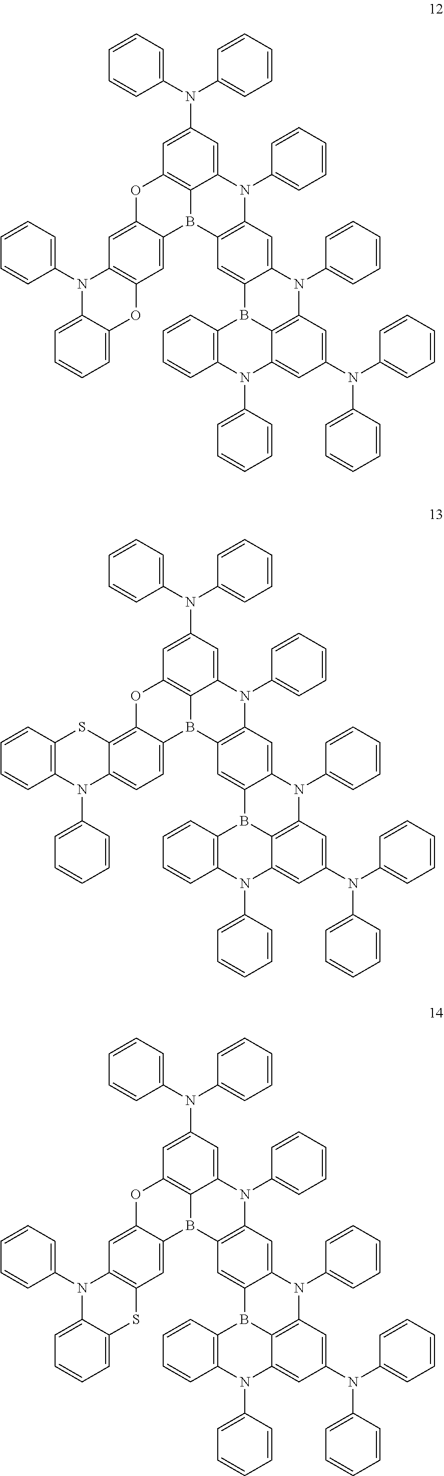 [SMILES: c1ccc(N(c2ccccc2)c2cc3c4c(c2)N(c2ccccc2)c2cc5c(cc2B4c2cc4c(cc2O3)N(c2ccccc2)c2ccccc2O4)B2c3ccccc3N(c3ccccc3)c3cc(N(c4ccccc4)c4ccccc4)cc(c32)N5c2ccccc2)cc1 ; c1ccc(N(c2ccccc2)c2cc3c4c(c2)N(c2ccccc2)c2cc5c(cc2B4c2ccc4c(c2O3)Sc2ccccc2N4c2ccccc2)B2c3ccccc3N(c3ccccc3)c3cc(N(c4ccccc4)c4ccccc4)cc(c32)N5c2ccccc2)cc1 ; c1ccc(N(c2ccccc2)c2cc3c4c(c2)N(c2ccccc2)c2cc5c(cc2B4c2cc4c(cc2O3)N(c2ccccc2)c2ccccc2S4)B2c3ccccc3N(c3ccccc3)c3cc(N(c4ccccc4)c4ccccc4)cc(c32)N5c2ccccc2)cc1]

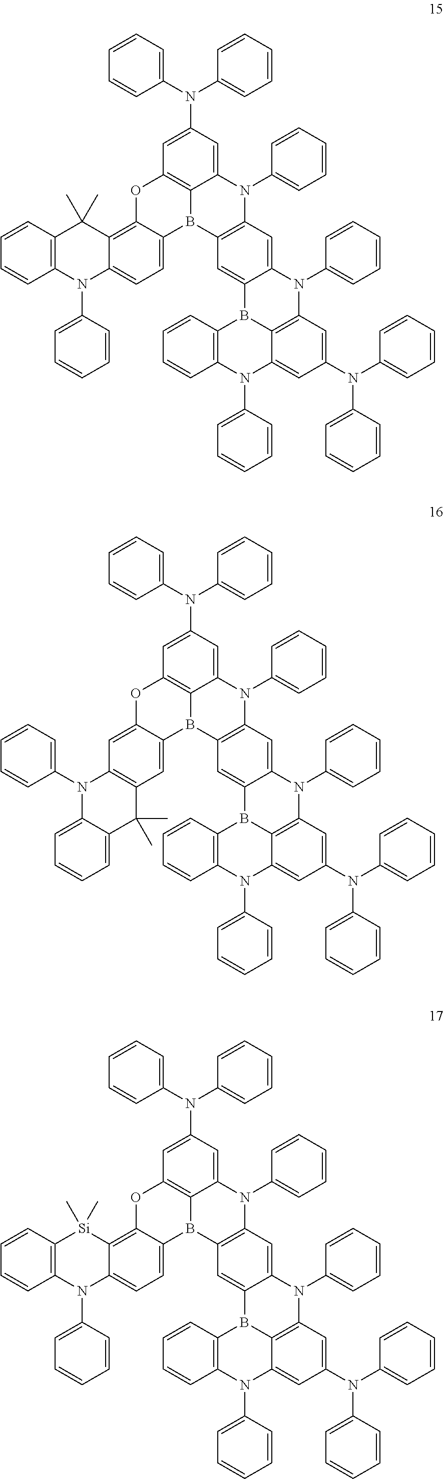 [SMILES: CC1(C)c2ccccc2N(c2ccccc2)c2ccc3c(c21)Oc1cc(N(c2ccccc2)c2ccccc2)cc2c1B3c1cc3c(cc1N2c1ccccc1)N(c1ccccc1)c1cc(N(c2ccccc2)c2ccccc2)cc2c1B3c1ccccc1N2c1ccccc1 ; CC1(C)c2ccccc2N(c2ccccc2)c2cc3c(cc21)B1c2cc4c(cc2N(c2ccccc2)c2cc(N(c5ccccc5)c5ccccc5)cc(c21)O3)N(c1ccccc1)c1cc(N(c2ccccc2)c2ccccc2)cc2c1B4c1ccccc1N2c1ccccc1 ; C[Si]1(C)c2ccccc2N(c2ccccc2)c2ccc3c(c21)Oc1cc(N(c2ccccc2)c2ccccc2)cc2c1B3c1cc3c(cc1N2c1ccccc1)N(c1ccccc1)c1cc(N(c2ccccc2)c2ccccc2)cc2c1B3c1ccccc1N2c1ccccc1]

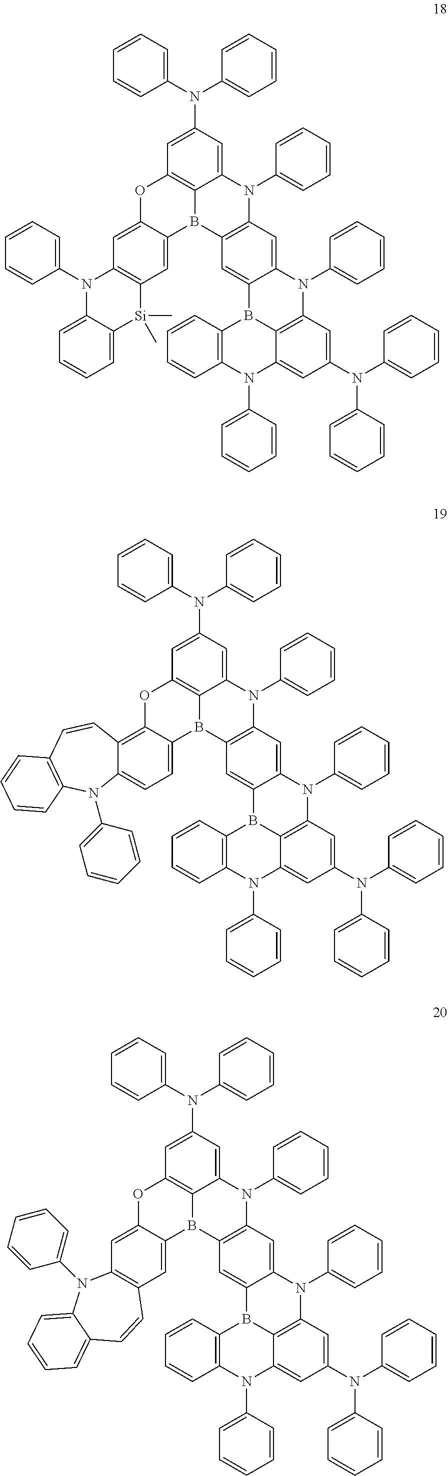 [SMILES: C[Si]1(C)c2ccccc2N(c2ccccc2)c2cc3c(cc21)B1c2cc4c(cc2N(c2ccccc2)c2cc(N(c5ccccc5)c5ccccc5)cc(c21)O3)N(c1ccccc1)c1cc(N(c2ccccc2)c2ccccc2)cc2c1B4c1ccccc1N2c1ccccc1 ; C1=Cc2c(ccc3c2Oc2cc(N(c4ccccc4)c4ccccc4)cc4c2B3c2cc3c(cc2N4c2ccccc2)N(c2ccccc2)c2cc(N(c4ccccc4)c4ccccc4)cc4c2B3c2ccccc2N4c2ccccc2)N(c2ccccc2)c2ccccc21 ; C1=Cc2cc3c(cc2N(c2ccccc2)c2ccccc21)Oc1cc(N(c2ccccc2)c2ccccc2)cc2c1B3c1cc3c(cc1N2c1ccccc1)N(c1ccccc1)c1cc(N(c2ccccc2)c2ccccc2)cc2c1B3c1ccccc1N2c1ccccc1]

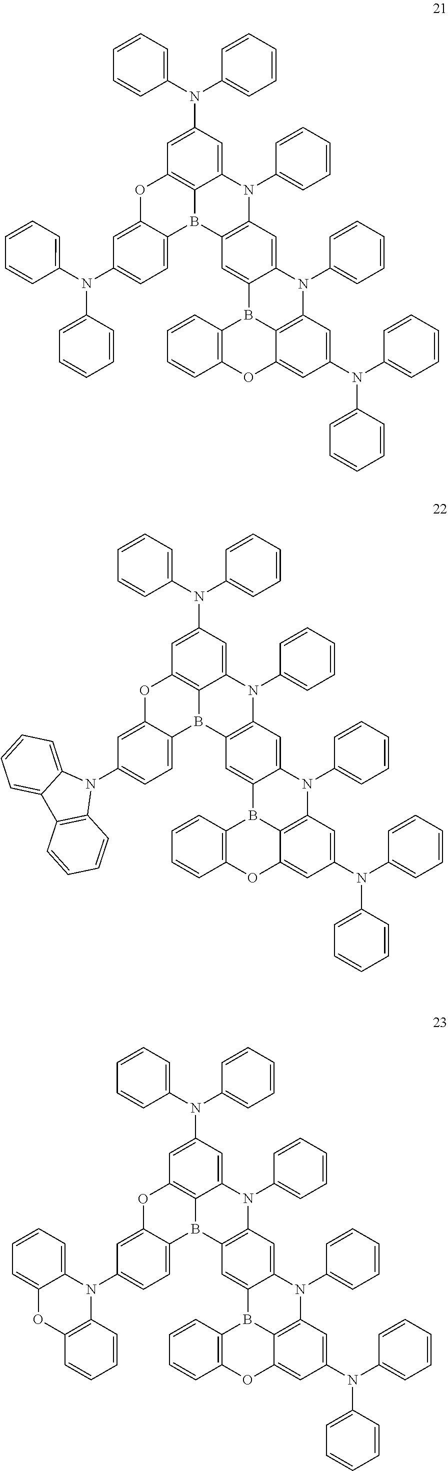 [SMILES: c1ccc(N(c2ccccc2)c2ccc3c(c2)Oc2cc(N(c4ccccc4)c4ccccc4)cc4c2B3c2cc3c(cc2N4c2ccccc2)N(c2ccccc2)c2cc(N(c4ccccc4)c4ccccc4)cc4c2B3c2ccccc2O4)cc1 ; c1ccc(N(c2ccccc2)c2cc3c4c(c2)N(c2ccccc2)c2cc5c(cc2B4c2ccccc2O3)B2c3ccc(-n4c6ccccc6c6ccccc64)cc3Oc3cc(N(c4ccccc4)c4ccccc4)cc(c32)N5c2ccccc2)cc1 ; c1ccc(N(c2ccccc2)c2cc3c4c(c2)N(c2ccccc2)c2cc5c(cc2B4c2ccccc2O3)B2c3ccc(N4c6ccccc6Oc6ccccc64)cc3Oc3cc(N(c4ccccc4)c4ccccc4)cc(c32)N5c2ccccc2)cc1]

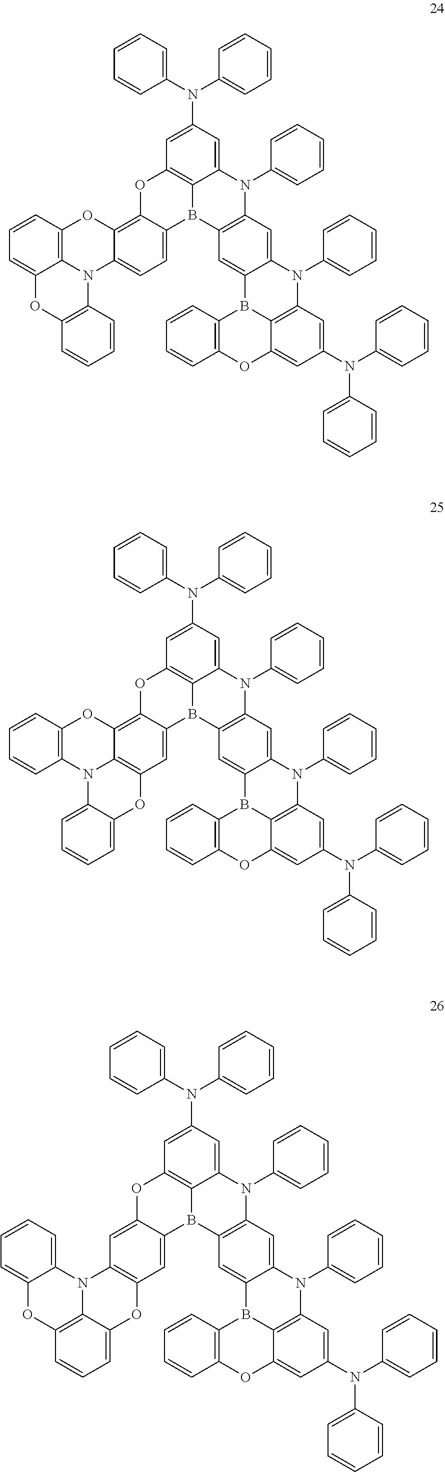 [SMILES: c1ccc(N(c2ccccc2)c2cc3c4c(c2)N(c2ccccc2)c2cc5c(cc2B4c2ccccc2O3)B2c3ccc4c(c3Oc3cc(N(c6ccccc6)c6ccccc6)cc(c32)N5c2ccccc2)Oc2cccc3c2N4c2ccccc2O3)cc1 ; c1ccc(N(c2ccccc2)c2cc3c4c(c2)N(c2ccccc2)c2cc5c(cc2B4c2ccccc2O3)B2c3cc4c6c(c3Oc3cc(N(c7ccccc7)c7ccccc7)cc(c32)N5c2ccccc2)Oc2ccccc2N6c2ccccc2O4)cc1 ; c1ccc(N(c2ccccc2)c2cc3c4c(c2)N(c2ccccc2)c2cc5c(cc2B4c2ccccc2O3)B2c3cc4c(cc3Oc3cc(N(c6ccccc6)c6ccccc6)cc(c32)N5c2ccccc2)N2c3ccccc3Oc3cccc(c32)O4)cc1]

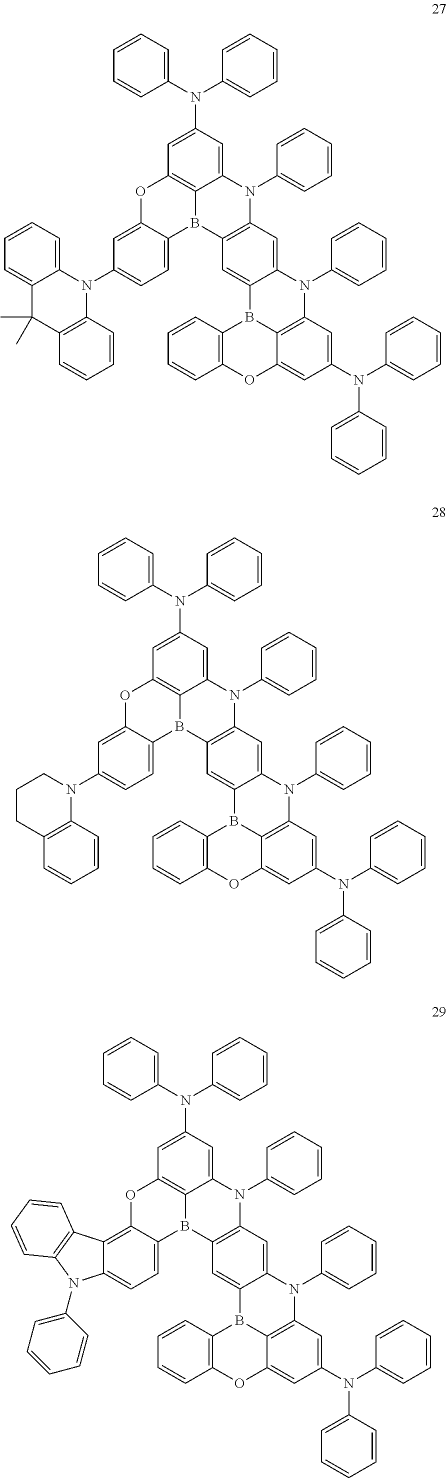 [SMILES: CC1(C)c2ccccc2N(c2ccc3c(c2)Oc2cc(N(c4ccccc4)c4ccccc4)cc4c2B3c2cc3c(cc2N4c2ccccc2)N(c2ccccc2)c2cc(N(c4ccccc4)c4ccccc4)cc4c2B3c2ccccc2O4)c2ccccc21 ; c1ccc(N(c2ccccc2)c2cc3c4c(c2)N(c2ccccc2)c2cc5c(cc2B4c2ccccc2O3)B2c3ccc(N4CCCc6ccccc64)cc3Oc3cc(N(c4ccccc4)c4ccccc4)cc(c32)N5c2ccccc2)cc1 ; c1ccc(N(c2ccccc2)c2cc3c4c(c2)N(c2ccccc2)c2cc5c(cc2B4c2ccccc2O3)B2c3ccc4c(c3Oc3cc(N(c6ccccc6)c6ccccc6)cc(c32)N5c2ccccc2)c2ccccc2n4-c2ccccc2)cc1]

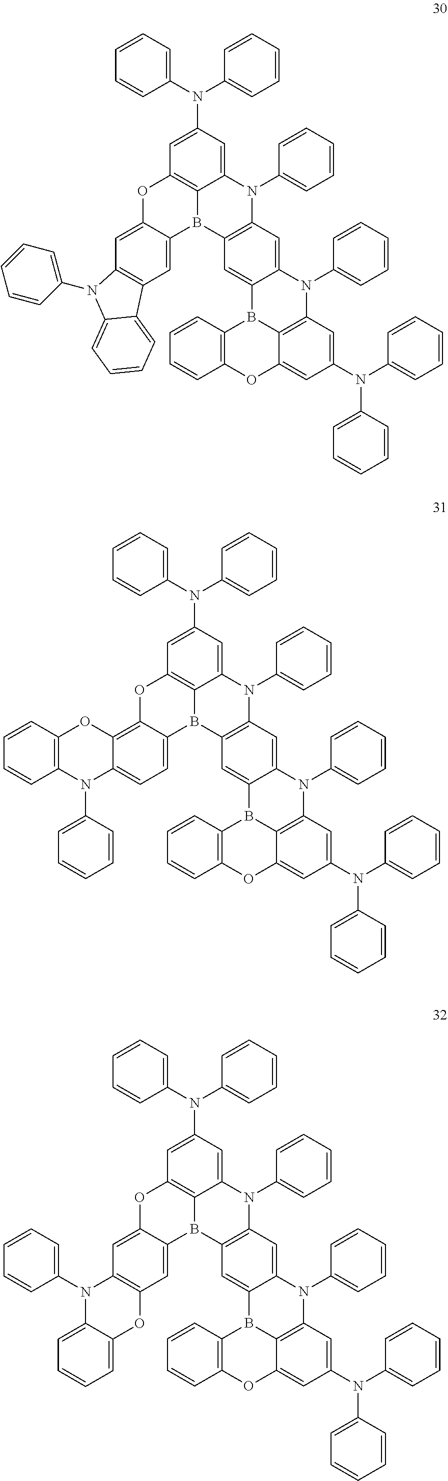 [SMILES: c1ccc(N(c2ccccc2)c2cc3c4c(c2)N(c2ccccc2)c2cc5c(cc2B4c2ccccc2O3)B2c3cc4c6ccccc6n(-c6ccccc6)c4cc3Oc3cc(N(c4ccccc4)c4ccccc4)cc(c32)N5c2ccccc2)cc1 ; c1ccc(N(c2ccccc2)c2cc3c4c(c2)N(c2ccccc2)c2cc5c(cc2B4c2ccccc2O3)B2c3ccc4c(c3Oc3cc(N(c6ccccc6)c6ccccc6)cc(c32)N5c2ccccc2)Oc2ccccc2N4c2ccccc2)cc1 ; c1ccc(N(c2ccccc2)c2cc3c4c(c2)N(c2ccccc2)c2cc5c(cc2B4c2ccccc2O3)B2c3cc4c(cc3Oc3cc(N(c6ccccc6)c6ccccc6)cc(c32)N5c2ccccc2)N(c2ccccc2)c2ccccc2O4)cc1]

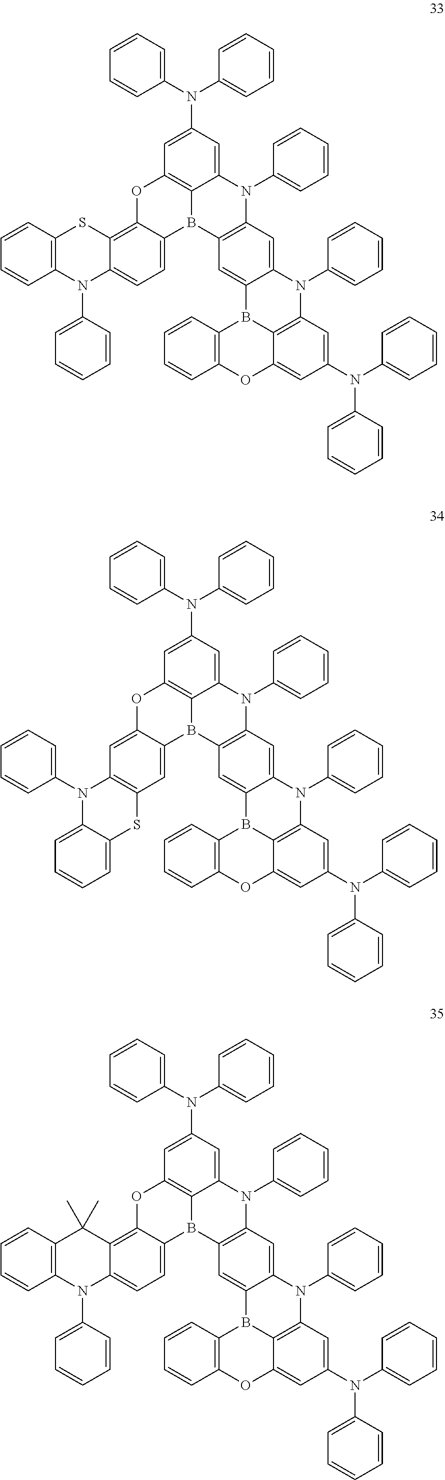 [SMILES: c1ccc(N(c2ccccc2)c2cc3c4c(c2)N(c2ccccc2)c2cc5c(cc2B4c2ccccc2O3)B2c3ccc4c(c3Oc3cc(N(c6ccccc6)c6ccccc6)cc(c32)N5c2ccccc2)Sc2ccccc2N4c2ccccc2)cc1 ; c1ccc(N(c2ccccc2)c2cc3c4c(c2)N(c2ccccc2)c2cc5c(cc2B4c2ccccc2O3)B2c3cc4c(cc3Oc3cc(N(c6ccccc6)c6ccccc6)cc(c32)N5c2ccccc2)N(c2ccccc2)c2ccccc2S4)cc1 ; CC1(C)c2ccccc2N(c2ccccc2)c2ccc3c(c21)Oc1cc(N(c2ccccc2)c2ccccc2)cc2c1B3c1cc3c(cc1N2c1ccccc1)N(c1ccccc1)c1cc(N(c2ccccc2)c2ccccc2)cc2c1B3c1ccccc1O2]

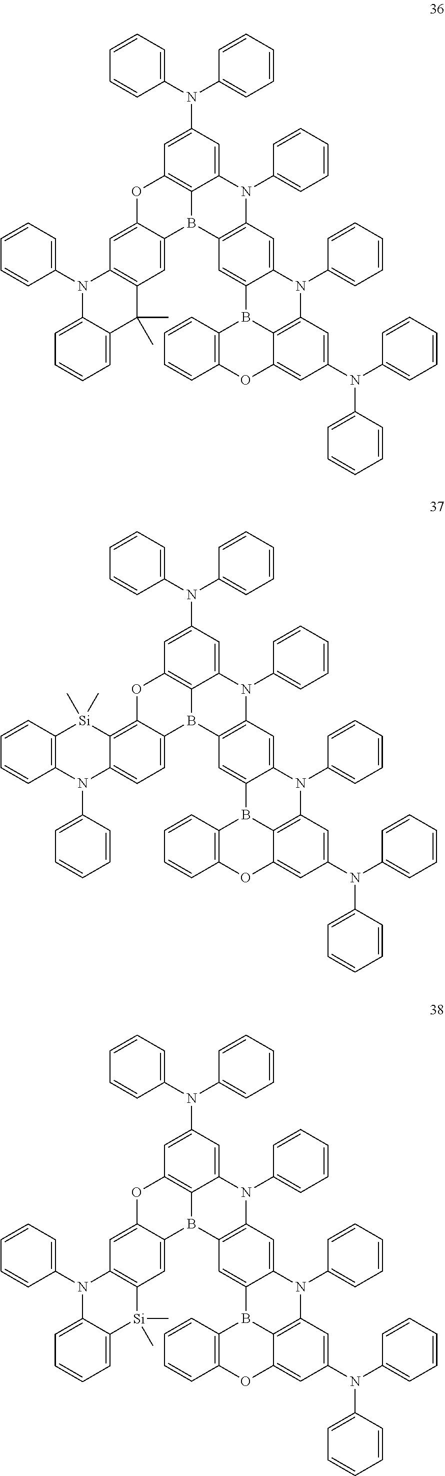 [SMILES: CC1(C)c2ccccc2N(c2ccccc2)c2cc3c(cc21)B1c2cc4c(cc2N(c2ccccc2)c2cc(N(c5ccccc5)c5ccccc5)cc(c21)O3)N(c1ccccc1)c1cc(N(c2ccccc2)c2ccccc2)cc2c1B4c1ccccc1O2 ; C[Si]1(C)c2ccccc2N(c2ccccc2)c2ccc3c(c21)Oc1cc(N(c2ccccc2)c2ccccc2)cc2c1B3c1cc3c(cc1N2c1ccccc1)N(c1ccccc1)c1cc(N(c2ccccc2)c2ccccc2)cc2c1B3c1ccccc1O2 ; C[Si]1(C)c2ccccc2N(c2ccccc2)c2cc3c(cc21)B1c2cc4c(cc2N(c2ccccc2)c2cc(N(c5ccccc5)c5ccccc5)cc(c21)O3)N(c1ccccc1)c1cc(N(c2ccccc2)c2ccccc2)cc2c1B4c1ccccc1O2]

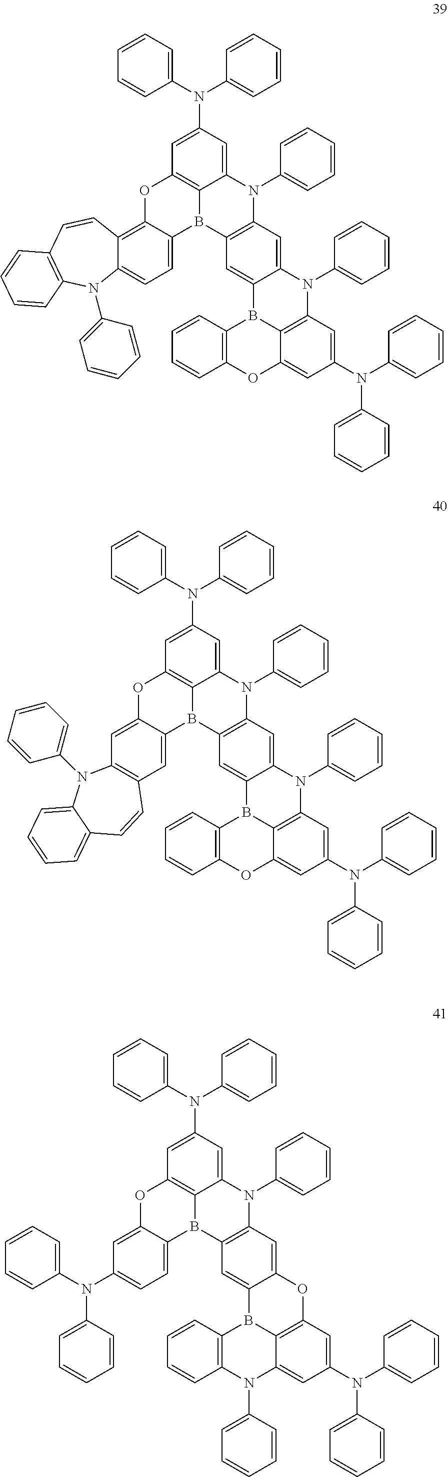 [SMILES: C1=Cc2c(ccc3c2Oc2cc(N(c4ccccc4)c4ccccc4)cc4c2B3c2cc3c(cc2N4c2ccccc2)N(c2ccccc2)c2cc(N(c4ccccc4)c4ccccc4)cc4c2B3c2ccccc2O4)N(c2ccccc2)c2ccccc21 ; C1=Cc2cc3c(cc2N(c2ccccc2)c2ccccc21)Oc1cc(N(c2ccccc2)c2ccccc2)cc2c1B3c1cc3c(cc1N2c1ccccc1)N(c1ccccc1)c1cc(N(c2ccccc2)c2ccccc2)cc2c1B3c1ccccc1O2 ; c1ccc(N(c2ccccc2)c2ccc3c(c2)Oc2cc(N(c4ccccc4)c4ccccc4)cc4c2B3c2cc3c(cc2N4c2ccccc2)Oc2cc(N(c4ccccc4)c4ccccc4)cc4c2B3c2ccccc2N4c2ccccc2)cc1]

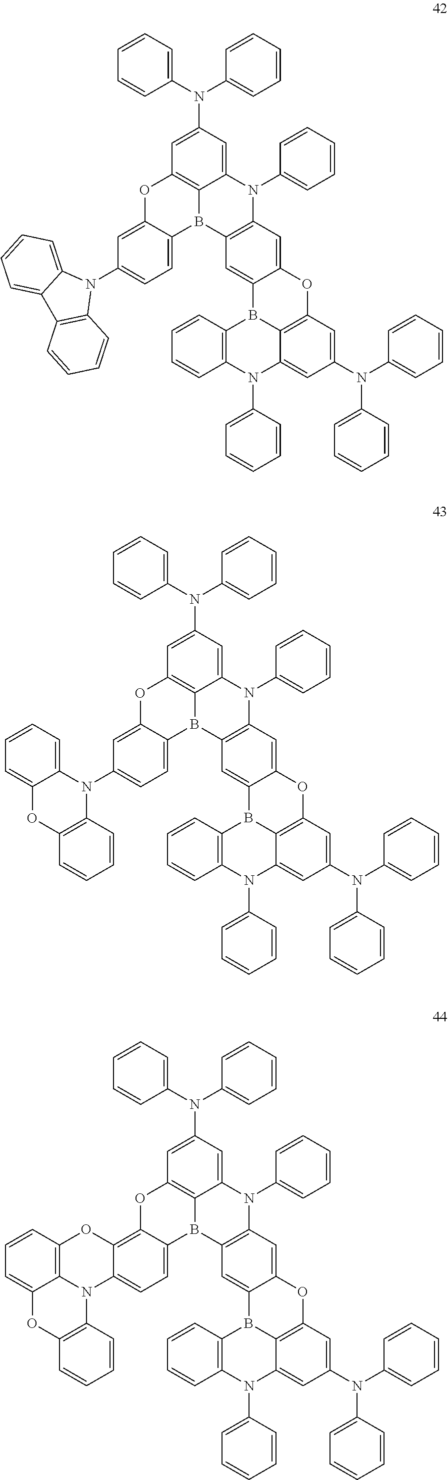 [SMILES: c1ccc(N(c2ccccc2)c2cc3c4c(c2)N(c2ccccc2)c2ccccc2B4c2cc4c(cc2O3)N(c2ccccc2)c2cc(N(c3ccccc3)c3ccccc3)cc3c2B4c2ccc(-n4c5ccccc5c5ccccc54)cc2O3)cc1 ; c1ccc(N(c2ccccc2)c2cc3c4c(c2)N(c2ccccc2)c2ccccc2B4c2cc4c(cc2O3)N(c2ccccc2)c2cc(N(c3ccccc3)c3ccccc3)cc3c2B4c2ccc(N4c5ccccc5Oc5ccccc54)cc2O3)cc1 ; c1ccc(N(c2ccccc2)c2cc3c4c(c2)N(c2ccccc2)c2ccccc2B4c2cc4c(cc2O3)N(c2ccccc2)c2cc(N(c3ccccc3)c3ccccc3)cc3c2B4c2ccc4c(c2O3)Oc2cccc3c2N4c2ccccc2O3)cc1]

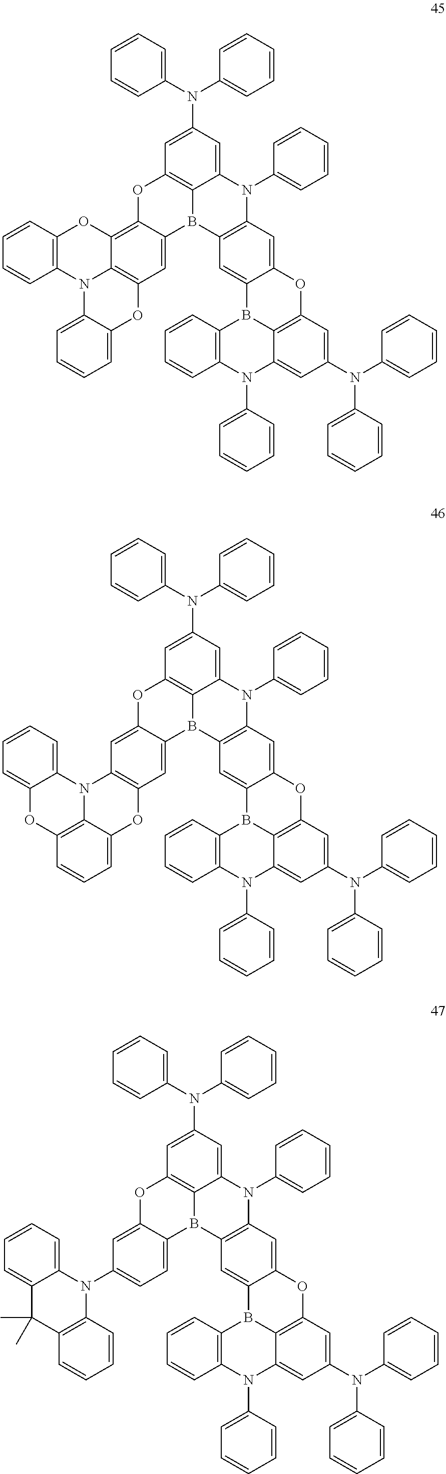 [SMILES: c1ccc(N(c2ccccc2)c2cc3c4c(c2)N(c2ccccc2)c2ccccc2B4c2cc4c(cc2O3)N(c2ccccc2)c2cc(N(c3ccccc3)c3ccccc3)cc3c2B4c2cc4c5c(c2O3)Oc2ccccc2N5c2ccccc2O4)cc1 ; c1ccc(N(c2ccccc2)c2cc3c4c(c2)N(c2ccccc2)c2ccccc2B4c2cc4c(cc2O3)N(c2ccccc2)c2cc(N(c3ccccc3)c3ccccc3)cc3c2B4c2cc4c(cc2O3)N2c3ccccc3Oc3cccc(c32)O4)cc1 ; CC1(C)c2ccccc2N(c2ccc3c(c2)Oc2cc(N(c4ccccc4)c4ccccc4)cc4c2B3c2cc3c(cc2N4c2ccccc2)Oc2cc(N(c4ccccc4)c4ccccc4)cc4c2B3c2ccccc2N4c2ccccc2)c2ccccc21]

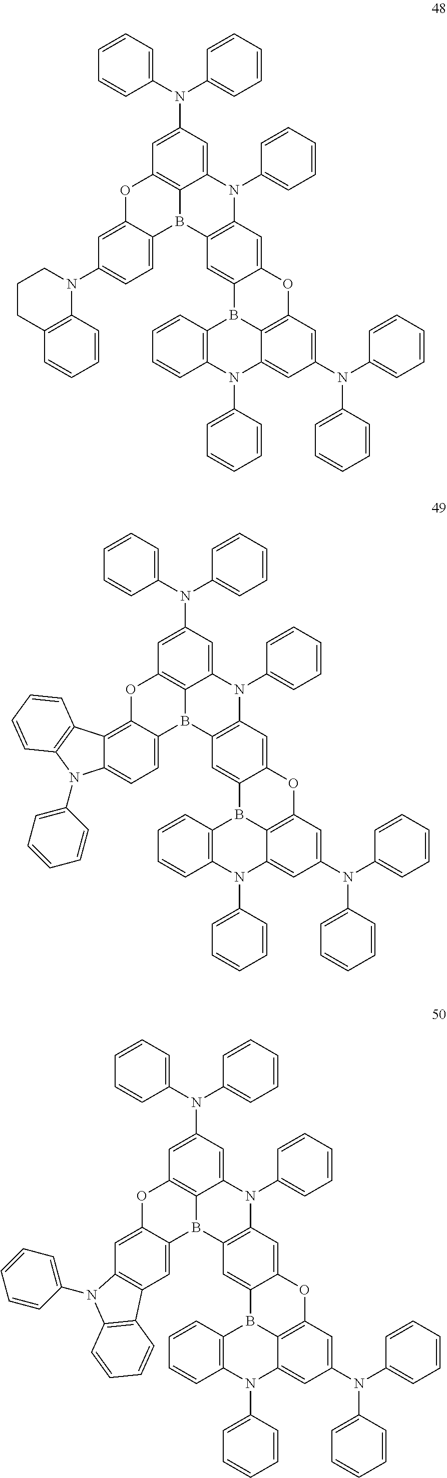 [SMILES: c1ccc(N(c2ccccc2)c2cc3c4c(c2)N(c2ccccc2)c2ccccc2B4c2cc4c(cc2O3)N(c2ccccc2)c2cc(N(c3ccccc3)c3ccccc3)cc3c2B4c2ccc(N4CCCc5ccccc54)cc2O3)cc1 ; c1ccc(N(c2ccccc2)c2cc3c4c(c2)N(c2ccccc2)c2ccccc2B4c2cc4c(cc2O3)N(c2ccccc2)c2cc(N(c3ccccc3)c3ccccc3)cc3c2B4c2ccc4c(c2O3)c2ccccc2n4-c2ccccc2)cc1 ; c1ccc(N(c2ccccc2)c2cc3c4c(c2)N(c2ccccc2)c2ccccc2B4c2cc4c(cc2O3)N(c2ccccc2)c2cc(N(c3ccccc3)c3ccccc3)cc3c2B4c2cc4c5ccccc5n(-c5ccccc5)c4cc2O3)cc1]

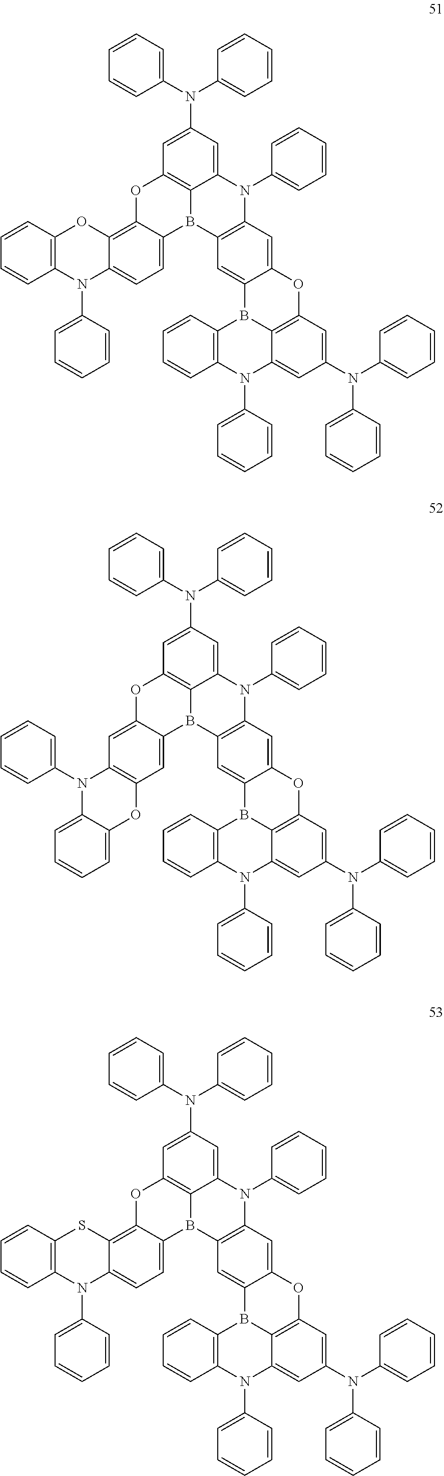 [SMILES: c1ccc(N(c2ccccc2)c2cc3c4c(c2)N(c2ccccc2)c2ccccc2B4c2cc4c(cc2O3)N(c2ccccc2)c2cc(N(c3ccccc3)c3ccccc3)cc3c2B4c2ccc4c(c2O3)Oc2ccccc2N4c2ccccc2)cc1 ; c1ccc(N(c2ccccc2)c2cc3c4c(c2)N(c2ccccc2)c2ccccc2B4c2cc4c(cc2O3)N(c2ccccc2)c2cc(N(c3ccccc3)c3ccccc3)cc3c2B4c2cc4c(cc2O3)N(c2ccccc2)c2ccccc2O4)cc1 ; c1ccc(N(c2ccccc2)c2cc3c4c(c2)N(c2ccccc2)c2ccccc2B4c2cc4c(cc2O3)N(c2ccccc2)c2cc(N(c3ccccc3)c3ccccc3)cc3c2B4c2ccc4c(c2O3)Sc2ccccc2N4c2ccccc2)cc1]

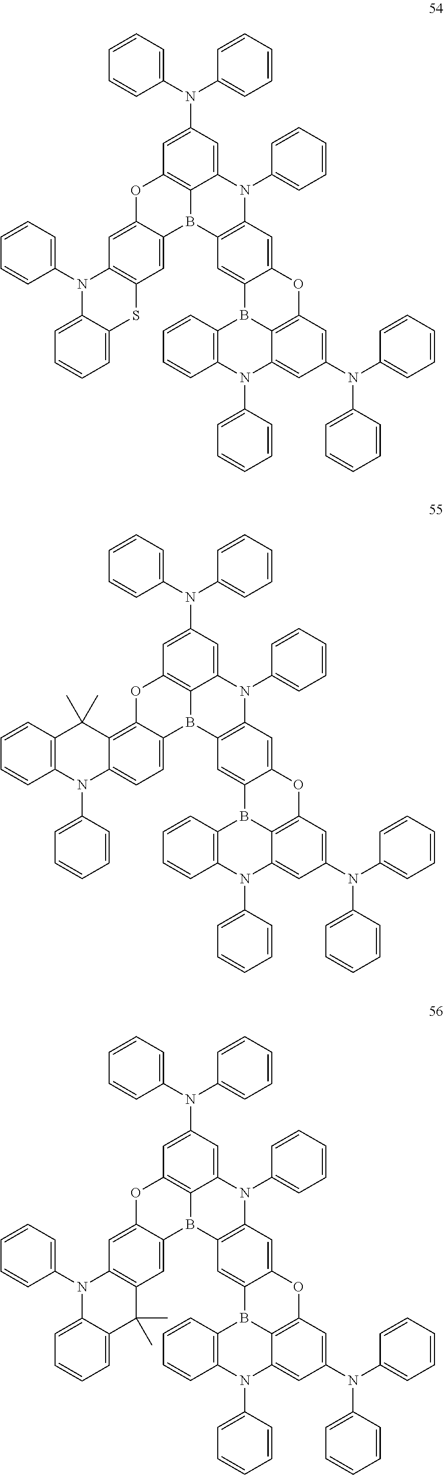 [SMILES: c1ccc(N(c2ccccc2)c2cc3c4c(c2)N(c2ccccc2)c2ccccc2B4c2cc4c(cc2O3)N(c2ccccc2)c2cc(N(c3ccccc3)c3ccccc3)cc3c2B4c2cc4c(cc2O3)N(c2ccccc2)c2ccccc2S4)cc1 ; CC1(C)c2ccccc2N(c2ccccc2)c2ccc3c(c21)Oc1cc(N(c2ccccc2)c2ccccc2)cc2c1B3c1cc3c(cc1N2c1ccccc1)Oc1cc(N(c2ccccc2)c2ccccc2)cc2c1B3c1ccccc1N2c1ccccc1 ; CC1(C)c2ccccc2N(c2ccccc2)c2cc3c(cc21)B1c2cc4c(cc2N(c2ccccc2)c2cc(N(c5ccccc5)c5ccccc5)cc(c21)O3)Oc1cc(N(c2ccccc2)c2ccccc2)cc2c1B4c1ccccc1N2c1ccccc1]

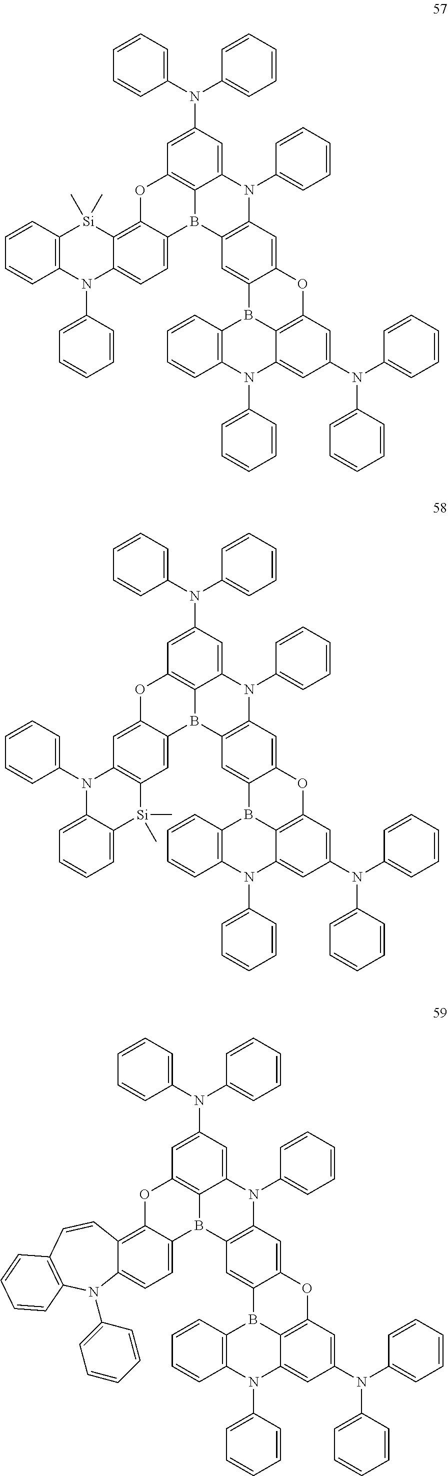 [SMILES: C[Si]1(C)c2ccccc2N(c2ccccc2)c2ccc3c(c21)Oc1cc(N(c2ccccc2)c2ccccc2)cc2c1B3c1cc3c(cc1N2c1ccccc1)Oc1cc(N(c2ccccc2)c2ccccc2)cc2c1B3c1ccccc1N2c1ccccc1 ; C[Si]1(C)c2ccccc2N(c2ccccc2)c2cc3c(cc21)B1c2cc4c(cc2N(c2ccccc2)c2cc(N(c5ccccc5)c5ccccc5)cc(c21)O3)Oc1cc(N(c2ccccc2)c2ccccc2)cc2c1B4c1ccccc1N2c1ccccc1 ; C1=Cc2c(ccc3c2Oc2cc(N(c4ccccc4)c4ccccc4)cc4c2B3c2cc3c(cc2N4c2ccccc2)Oc2cc(N(c4ccccc4)c4ccccc4)cc4c2B3c2ccccc2N4c2ccccc2)N(c2ccccc2)c2ccccc21]

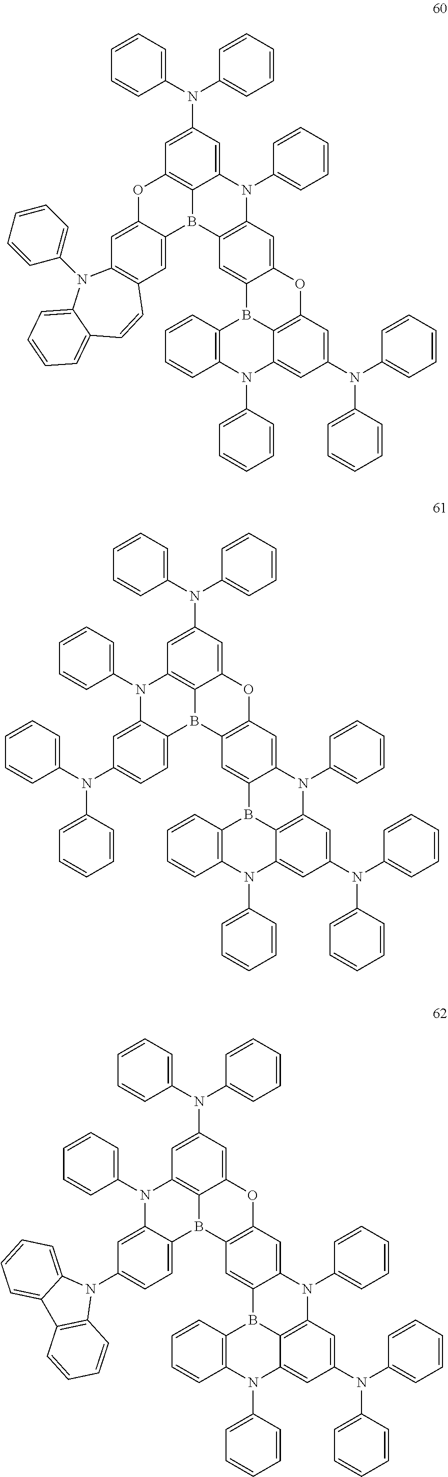 [SMILES: C1=Cc2cc3c(cc2N(c2ccccc2)c2ccccc21)Oc1cc(N(c2ccccc2)c2ccccc2)cc2c1B3c1cc3c(cc1N2c1ccccc1)Oc1cc(N(c2ccccc2)c2ccccc2)cc2c1B3c1ccccc1N2c1ccccc1 ; c1ccc(N(c2ccccc2)c2ccc3c(c2)N(c2ccccc2)c2cc(N(c4ccccc4)c4ccccc4)cc4c2B3c2cc3c(cc2O4)N(c2ccccc2)c2cc(N(c4ccccc4)c4ccccc4)cc4c2B3c2ccccc2N4c2ccccc2)cc1 ; c1ccc(N(c2ccccc2)c2cc3c4c(c2)N(c2ccccc2)c2cc(-n5c6ccccc6c6ccccc65)ccc2B4c2cc4c(cc2O3)N(c2ccccc2)c2cc(N(c3ccccc3)c3ccccc3)cc3c2B4c2ccccc2N3c2ccccc2)cc1]

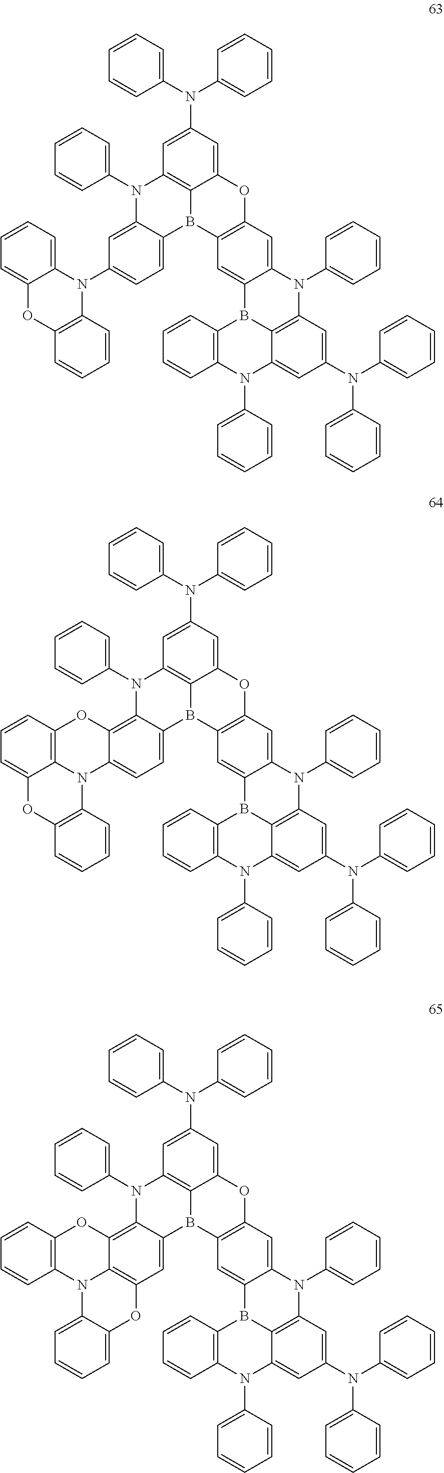 [SMILES: c1ccc(N(c2ccccc2)c2cc3c4c(c2)N(c2ccccc2)c2cc(N5c6ccccc6Oc6ccccc65)ccc2B4c2cc4c(cc2O3)N(c2ccccc2)c2cc(N(c3ccccc3)c3ccccc3)cc3c2B4c2ccccc2N3c2ccccc2)cc1 ; c1ccc(N(c2ccccc2)c2cc3c4c(c2)N(c2ccccc2)c2c(ccc5c2Oc2cccc6c2N5c2ccccc2O6)B4c2cc4c(cc2O3)N(c2ccccc2)c2cc(N(c3ccccc3)c3ccccc3)cc3c2B4c2ccccc2N3c2ccccc2)cc1 ; c1ccc(N(c2ccccc2)c2cc3c4c(c2)N(c2ccccc2)c2c(cc5c6c2Oc2ccccc2N6c2ccccc2O5)B4c2cc4c(cc2O3)N(c2ccccc2)c2cc(N(c3ccccc3)c3ccccc3)cc3c2B4c2ccccc2N3c2ccccc2)cc1]

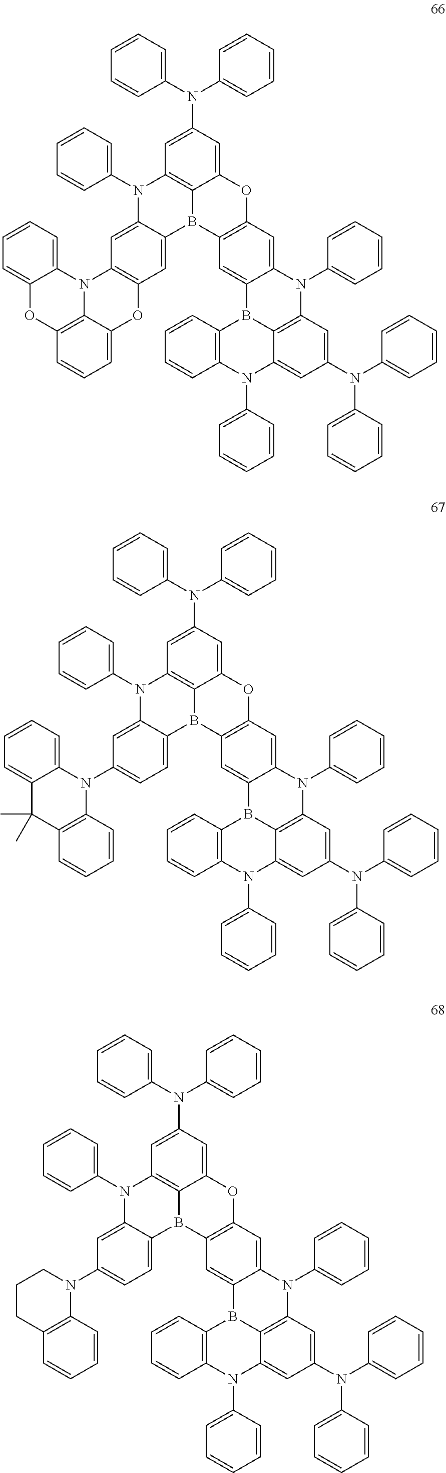 [SMILES: c1ccc(N(c2ccccc2)c2cc3c4c(c2)N(c2ccccc2)c2cc5c(cc2B4c2cc4c(cc2O3)N(c2ccccc2)c2cc(N(c3ccccc3)c3ccccc3)cc3c2B4c2ccccc2N3c2ccccc2)Oc2cccc3c2N5c2ccccc2O3)cc1 ; CC1(C)c2ccccc2N(c2ccc3c(c2)N(c2ccccc2)c2cc(N(c4ccccc4)c4ccccc4)cc4c2B3c2cc3c(cc2O4)N(c2ccccc2)c2cc(N(c4ccccc4)c4ccccc4)cc4c2B3c2ccccc2N4c2ccccc2)c2ccccc21 ; c1ccc(N(c2ccccc2)c2cc3c4c(c2)N(c2ccccc2)c2cc(N5CCCc6ccccc65)ccc2B4c2cc4c(cc2O3)N(c2ccccc2)c2cc(N(c3ccccc3)c3ccccc3)cc3c2B4c2ccccc2N3c2ccccc2)cc1]

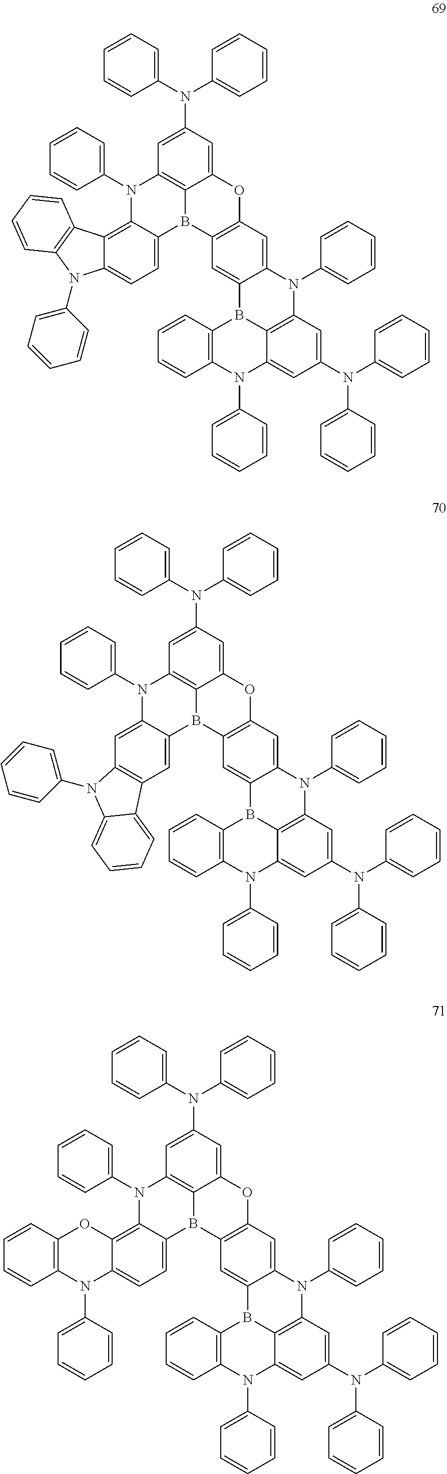 [SMILES: c1ccc(N(c2ccccc2)c2cc3c4c(c2)N(c2ccccc2)c2c(ccc5c2c2ccccc2n5-c2ccccc2)B4c2cc4c(cc2O3)N(c2ccccc2)c2cc(N(c3ccccc3)c3ccccc3)cc3c2B4c2ccccc2N3c2ccccc2)cc1 ; c1ccc(N(c2ccccc2)c2cc3c4c(c2)N(c2ccccc2)c2cc5c(cc2B4c2cc4c(cc2O3)N(c2ccccc2)c2cc(N(c3ccccc3)c3ccccc3)cc3c2B4c2ccccc2N3c2ccccc2)c2ccccc2n5-c2ccccc2)cc1 ; c1ccc(N(c2ccccc2)c2cc3c4c(c2)N(c2ccccc2)c2c(ccc5c2Oc2ccccc2N5c2ccccc2)B4c2cc4c(cc2O3)N(c2ccccc2)c2cc(N(c3ccccc3)c3ccccc3)cc3c2B4c2ccccc2N3c2ccccc2)cc1]

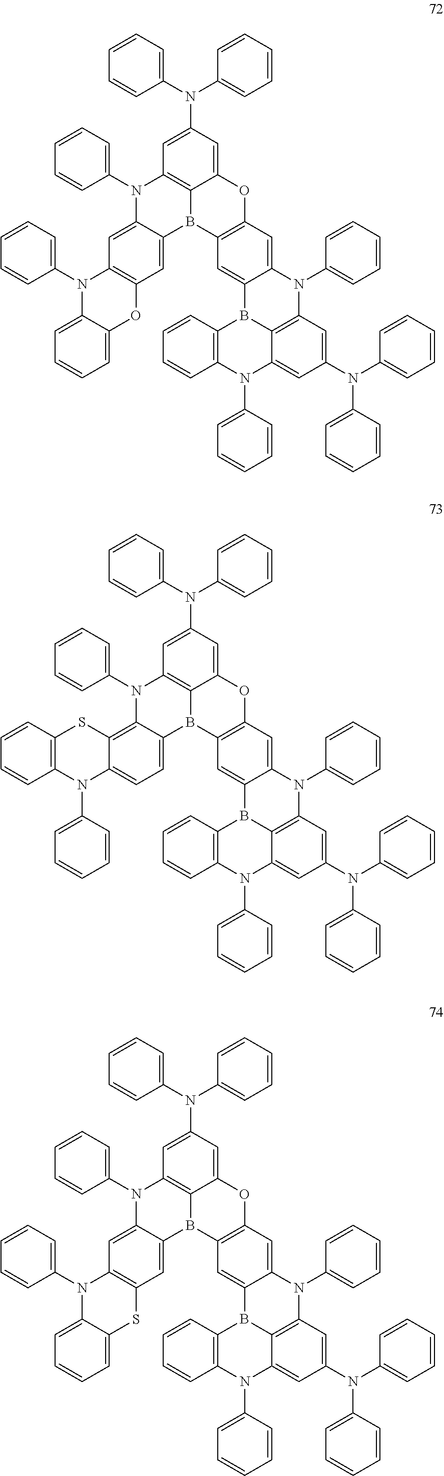 [SMILES: c1ccc(N(c2ccccc2)c2cc3c4c(c2)N(c2ccccc2)c2cc5c(cc2B4c2cc4c(cc2O3)N(c2ccccc2)c2cc(N(c3ccccc3)c3ccccc3)cc3c2B4c2ccccc2N3c2ccccc2)Oc2ccccc2N5c2ccccc2)cc1 ; c1ccc(N(c2ccccc2)c2cc3c4c(c2)N(c2ccccc2)c2c(ccc5c2Sc2ccccc2N5c2ccccc2)B4c2cc4c(cc2O3)N(c2ccccc2)c2cc(N(c3ccccc3)c3ccccc3)cc3c2B4c2ccccc2N3c2ccccc2)cc1 ; c1ccc(N(c2ccccc2)c2cc3c4c(c2)N(c2ccccc2)c2cc5c(cc2B4c2cc4c(cc2O3)N(c2ccccc2)c2cc(N(c3ccccc3)c3ccccc3)cc3c2B4c2ccccc2N3c2ccccc2)Sc2ccccc2N5c2ccccc2)cc1]

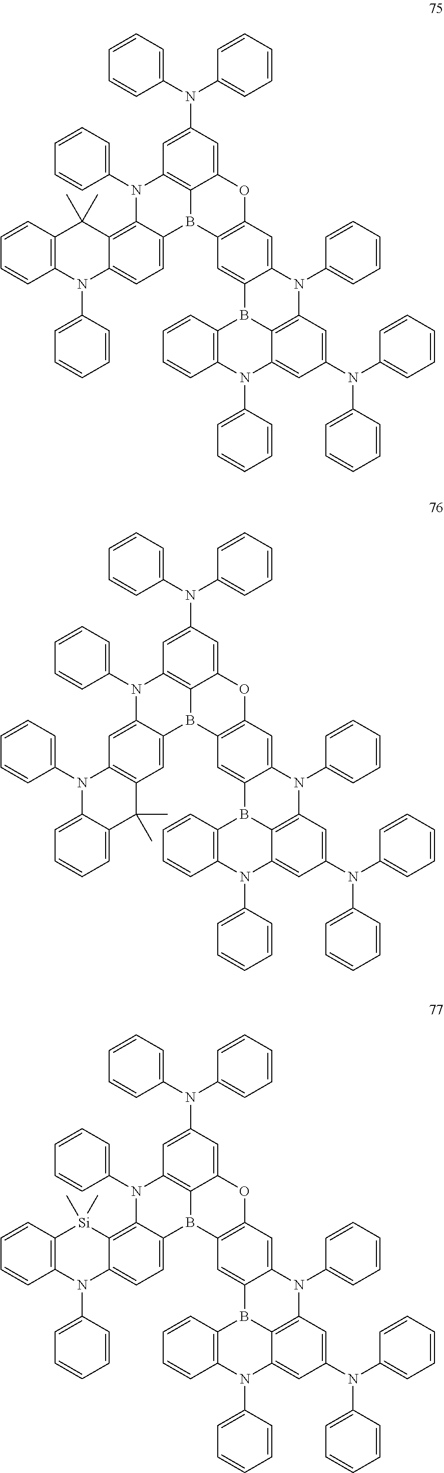 [SMILES: CC1(C)c2ccccc2N(c2ccccc2)c2ccc3c(c21)N(c1ccccc1)c1cc(N(c2ccccc2)c2ccccc2)cc2c1B3c1cc3c(cc1O2)N(c1ccccc1)c1cc(N(c2ccccc2)c2ccccc2)cc2c1B3c1ccccc1N2c1ccccc1 ; CC1(C)c2ccccc2N(c2ccccc2)c2cc3c(cc21)B1c2cc4c(cc2Oc2cc(N(c5ccccc5)c5ccccc5)cc(c21)N3c1ccccc1)N(c1ccccc1)c1cc(N(c2ccccc2)c2ccccc2)cc2c1B4c1ccccc1N2c1ccccc1 ; C[Si]1(C)c2ccccc2N(c2ccccc2)c2ccc3c(c21)N(c1ccccc1)c1cc(N(c2ccccc2)c2ccccc2)cc2c1B3c1cc3c(cc1O2)N(c1ccccc1)c1cc(N(c2ccccc2)c2ccccc2)cc2c1B3c1ccccc1N2c1ccccc1]

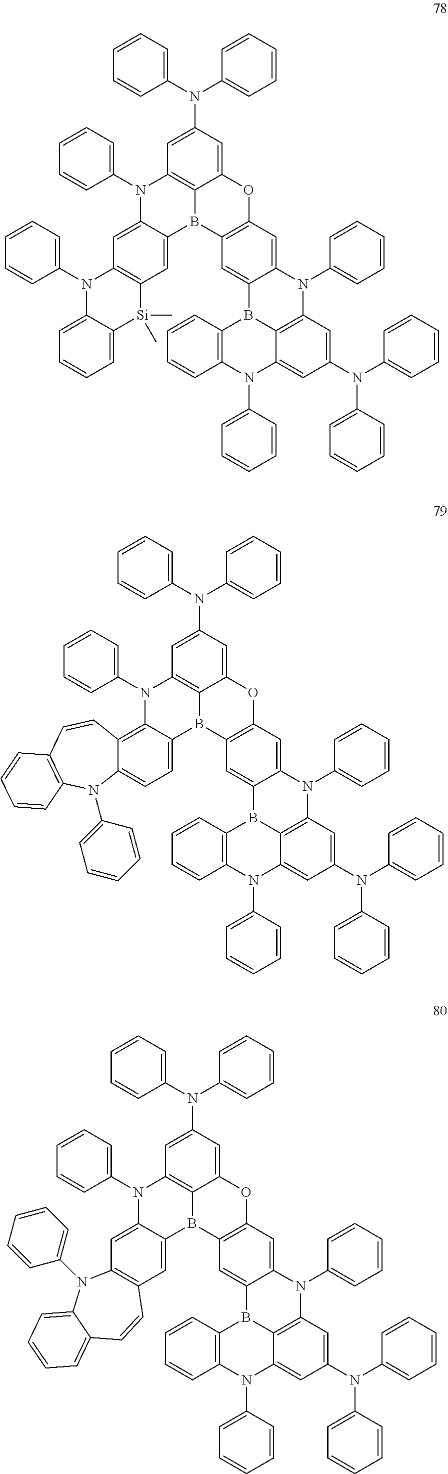 [SMILES: C[Si]1(C)c2ccccc2N(c2ccccc2)c2cc3c(cc21)B1c2cc4c(cc2Oc2cc(N(c5ccccc5)c5ccccc5)cc(c21)N3c1ccccc1)N(c1ccccc1)c1cc(N(c2ccccc2)c2ccccc2)cc2c1B4c1ccccc1N2c1ccccc1 ; C1=Cc2c(ccc3c2N(c2ccccc2)c2cc(N(c4ccccc4)c4ccccc4)cc4c2B3c2cc3c(cc2O4)N(c2ccccc2)c2cc(N(c4ccccc4)c4ccccc4)cc4c2B3c2ccccc2N4c2ccccc2)N(c2ccccc2)c2ccccc21 ; C1=Cc2cc3c(cc2N(c2ccccc2)c2ccccc21)N(c1ccccc1)c1cc(N(c2ccccc2)c2ccccc2)cc2c1B3c1cc3c(cc1O2)N(c1ccccc1)c1cc(N(c2ccccc2)c2ccccc2)cc2c1B3c1ccccc1N2c1ccccc1]

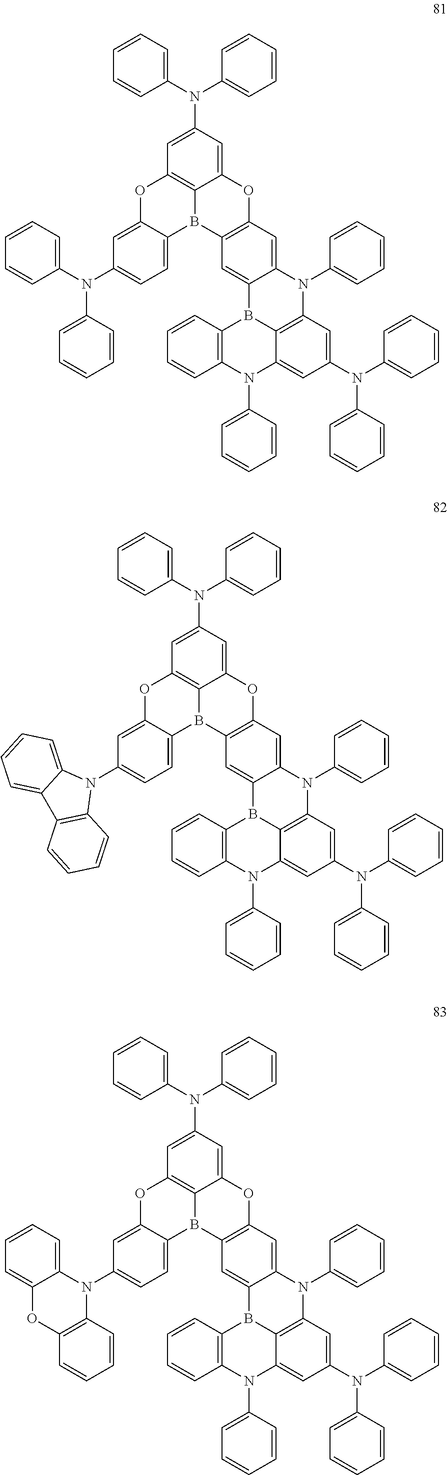 [SMILES: c1ccc(N(c2ccccc2)c2ccc3c(c2)Oc2cc(N(c4ccccc4)c4ccccc4)cc4c2B3c2cc3c(cc2O4)N(c2ccccc2)c2cc(N(c4ccccc4)c4ccccc4)cc4c2B3c2ccccc2N4c2ccccc2)cc1 ; c1ccc(N(c2ccccc2)c2cc3c4c(c2)Oc2cc5c(cc2B4c2ccc(-n4c6ccccc6c6ccccc64)cc2O3)B2c3ccccc3N(c3ccccc3)c3cc(N(c4ccccc4)c4ccccc4)cc(c32)N5c2ccccc2)cc1 ; c1ccc(N(c2ccccc2)c2cc3c4c(c2)Oc2cc5c(cc2B4c2ccc(N4c6ccccc6Oc6ccccc64)cc2O3)B2c3ccccc3N(c3ccccc3)c3cc(N(c4ccccc4)c4ccccc4)cc(c32)N5c2ccccc2)cc1]

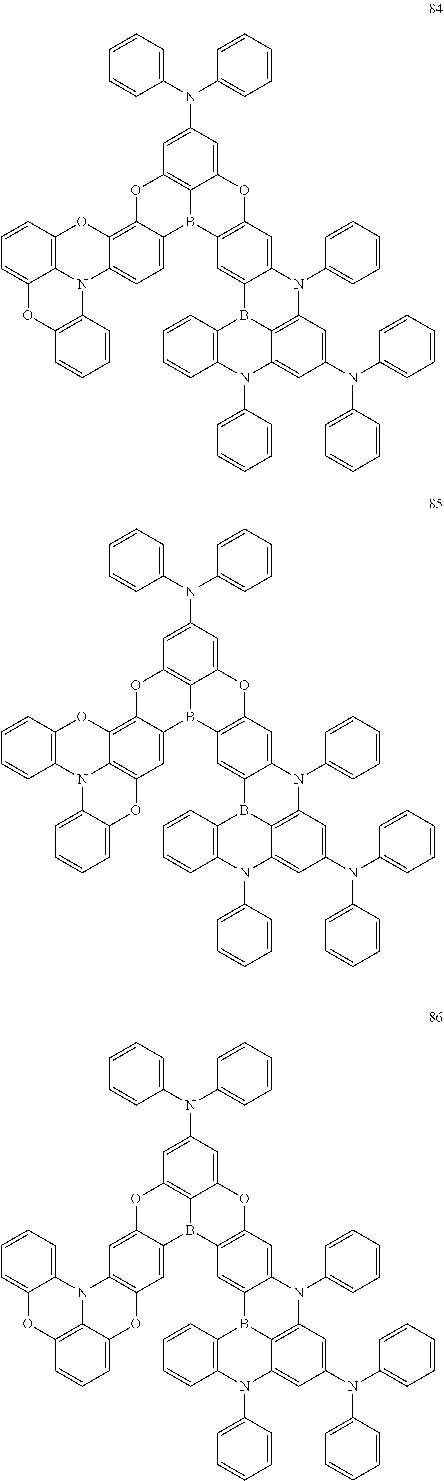 [SMILES: c1ccc(N(c2ccccc2)c2cc3c4c(c2)Oc2c(ccc5c2Oc2cccc6c2N5c2ccccc2O6)B4c2cc4c(cc2O3)N(c2ccccc2)c2cc(N(c3ccccc3)c3ccccc3)cc3c2B4c2ccccc2N3c2ccccc2)cc1 ; c1ccc(N(c2ccccc2)c2cc3c4c(c2)Oc2c(cc5c6c2Oc2ccccc2N6c2ccccc2O5)B4c2cc4c(cc2O3)N(c2ccccc2)c2cc(N(c3ccccc3)c3ccccc3)cc3c2B4c2ccccc2N3c2ccccc2)cc1 ; c1ccc(N(c2ccccc2)c2cc3c4c(c2)Oc2cc5c(cc2B4c2cc4c(cc2O3)N2c3ccccc3Oc3cccc(c32)O4)B2c3ccccc3N(c3ccccc3)c3cc(N(c4ccccc4)c4ccccc4)cc(c32)N5c2ccccc2)cc1]

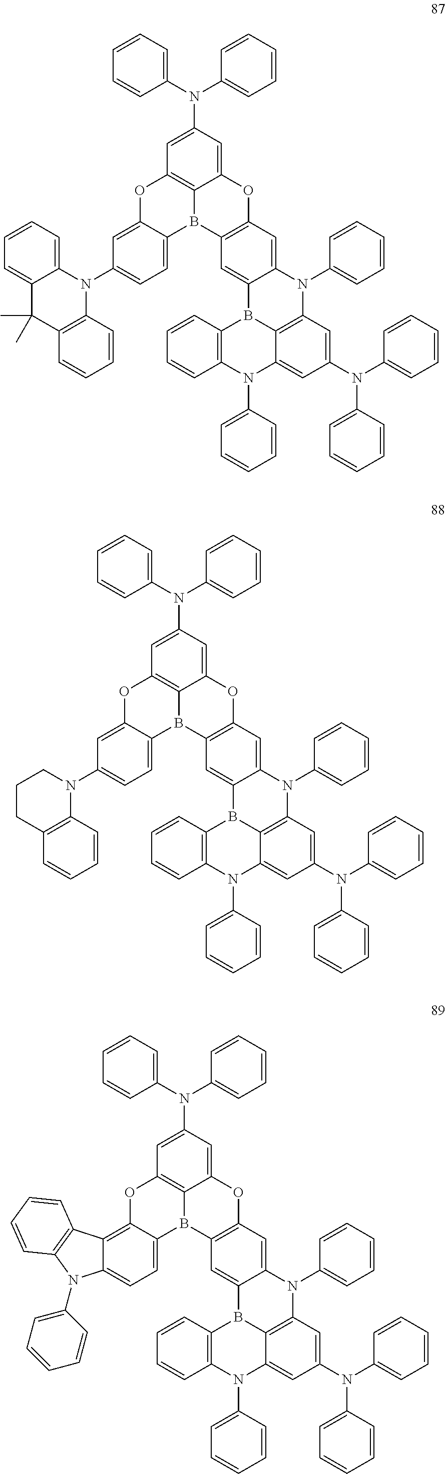 [SMILES: CC1(C)c2ccccc2N(c2ccc3c(c2)Oc2cc(N(c4ccccc4)c4ccccc4)cc4c2B3c2cc3c(cc2O4)N(c2ccccc2)c2cc(N(c4ccccc4)c4ccccc4)cc4c2B3c2ccccc2N4c2ccccc2)c2ccccc21 ; c1ccc(N(c2ccccc2)c2cc3c4c(c2)Oc2cc5c(cc2B4c2ccc(N4CCCc6ccccc64)cc2O3)B2c3ccccc3N(c3ccccc3)c3cc(N(c4ccccc4)c4ccccc4)cc(c32)N5c2ccccc2)cc1 ; c1ccc(N(c2ccccc2)c2cc3c4c(c2)Oc2c(ccc5c2c2ccccc2n5-c2ccccc2)B4c2cc4c(cc2O3)N(c2ccccc2)c2cc(N(c3ccccc3)c3ccccc3)cc3c2B4c2ccccc2N3c2ccccc2)cc1]

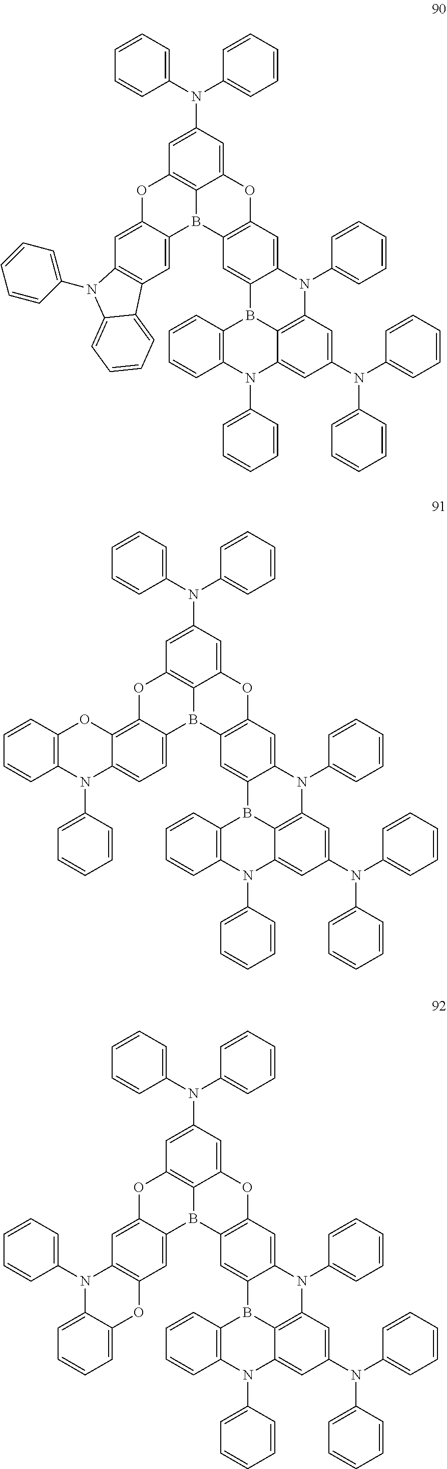 [SMILES: c1ccc(N(c2ccccc2)c2cc3c4c(c2)Oc2cc5c(cc2B4c2cc4c(cc2O3)N(c2ccccc2)c2cc(N(c3ccccc3)c3ccccc3)cc3c2B4c2ccccc2N3c2ccccc2)c2ccccc2n5-c2ccccc2)cc1 ; c1ccc(N(c2ccccc2)c2cc3c4c(c2)Oc2c(ccc5c2Oc2ccccc2N5c2ccccc2)B4c2cc4c(cc2O3)N(c2ccccc2)c2cc(N(c3ccccc3)c3ccccc3)cc3c2B4c2ccccc2N3c2ccccc2)cc1 ; c1ccc(N(c2ccccc2)c2cc3c4c(c2)Oc2cc5c(cc2B4c2cc4c(cc2O3)N(c2ccccc2)c2ccccc2O4)B2c3ccccc3N(c3ccccc3)c3cc(N(c4ccccc4)c4ccccc4)cc(c32)N5c2ccccc2)cc1]

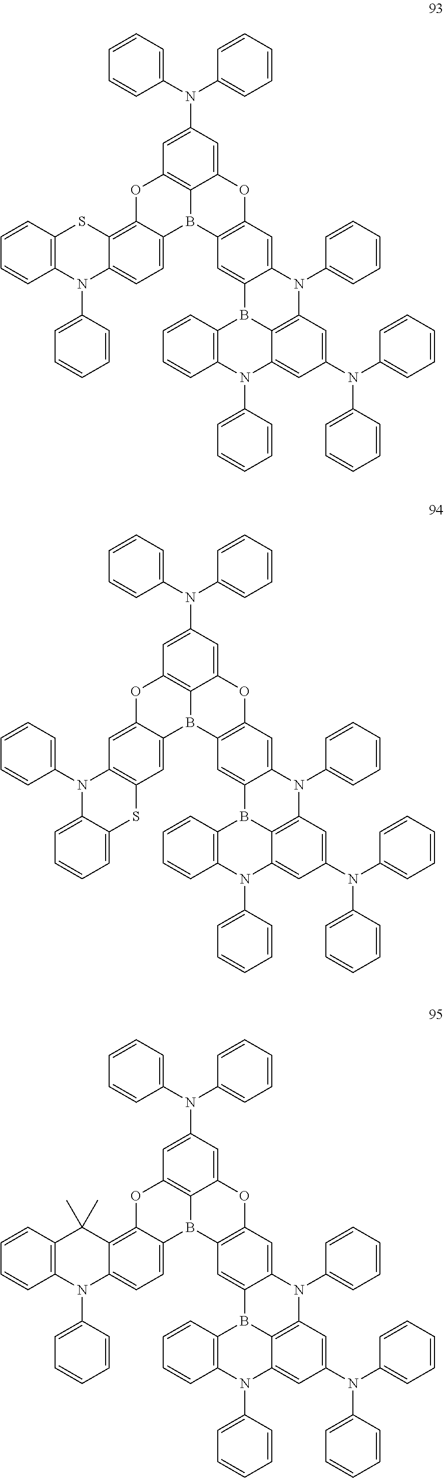 [SMILES: c1ccc(N(c2ccccc2)c2cc3c4c(c2)Oc2c(ccc5c2Sc2ccccc2N5c2ccccc2)B4c2cc4c(cc2O3)N(c2ccccc2)c2cc(N(c3ccccc3)c3ccccc3)cc3c2B4c2ccccc2N3c2ccccc2)cc1 ; c1ccc(N(c2ccccc2)c2cc3c4c(c2)Oc2cc5c(cc2B4c2cc4c(cc2O3)N(c2ccccc2)c2ccccc2S4)B2c3ccccc3N(c3ccccc3)c3cc(N(c4ccccc4)c4ccccc4)cc(c32)N5c2ccccc2)cc1 ; CC1(C)c2ccccc2N(c2ccccc2)c2ccc3c(c21)Oc1cc(N(c2ccccc2)c2ccccc2)cc2c1B3c1cc3c(cc1O2)N(c1ccccc1)c1cc(N(c2ccccc2)c2ccccc2)cc2c1B3c1ccccc1N2c1ccccc1]

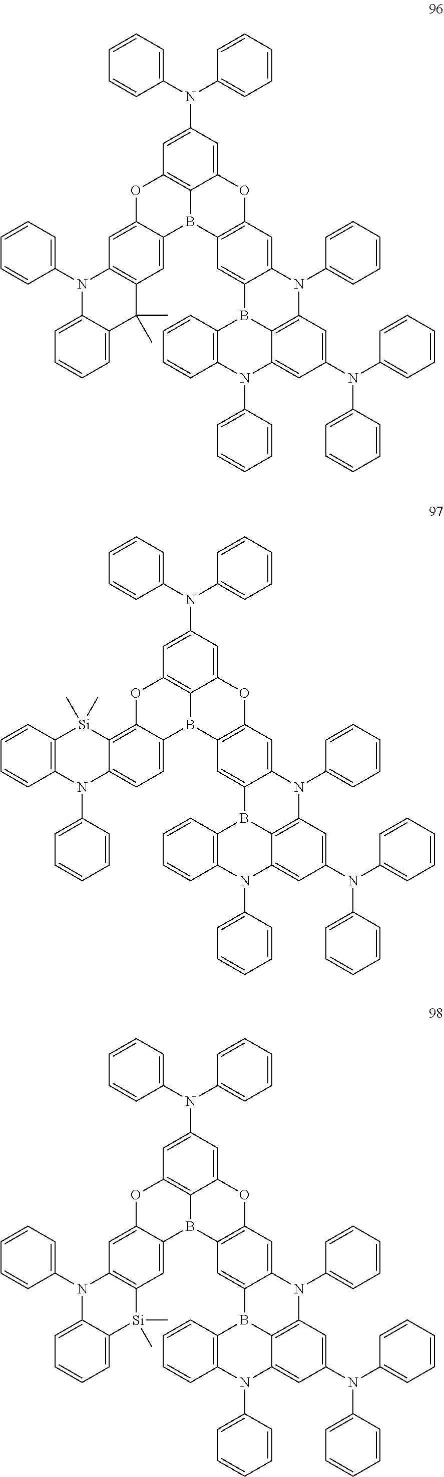

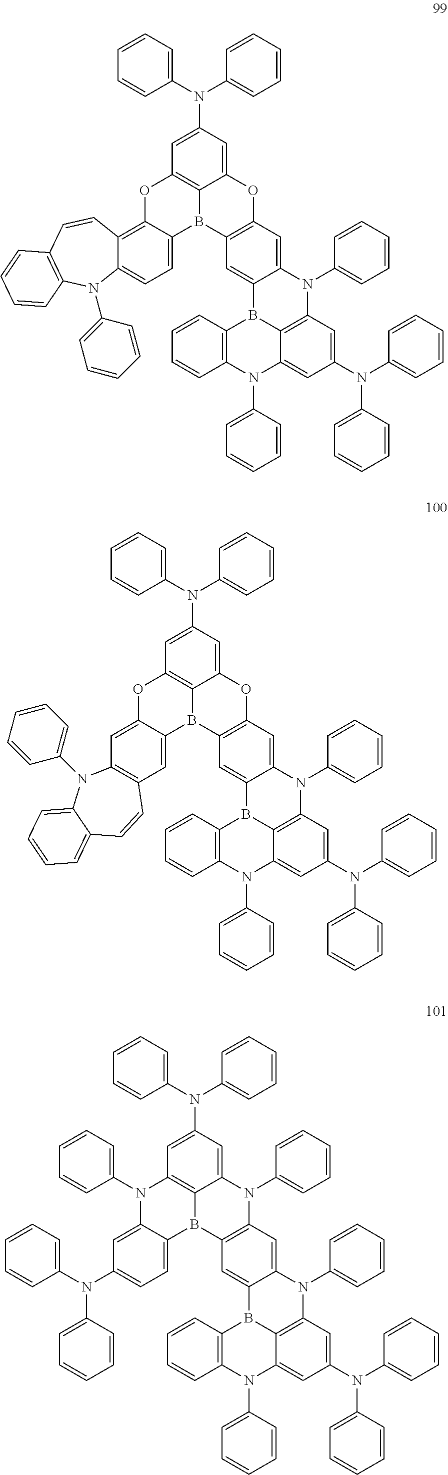 [SMILES: C1=Cc2c(ccc3c2Oc2cc(N(c4ccccc4)c4ccccc4)cc4c2B3c2cc3c(cc2O4)N(c2ccccc2)c2cc(N(c4ccccc4)c4ccccc4)cc4c2B3c2ccccc2N4c2ccccc2)N(c2ccccc2)c2ccccc21 ; C1=Cc2cc3c(cc2N(c2ccccc2)c2ccccc21)Oc1cc(N(c2ccccc2)c2ccccc2)cc2c1B3c1cc3c(cc1O2)N(c1ccccc1)c1cc(N(c2ccccc2)c2ccccc2)cc2c1B3c1ccccc1N2c1ccccc1 ; c1ccc(N(c2ccccc2)c2ccc3c(c2)N(c2ccccc2)c2cc(N(c4ccccc4)c4ccccc4)cc4c2B3c2cc3c(cc2N4c2ccccc2)N(c2ccccc2)c2cc(N(c4ccccc4)c4ccccc4)cc4c2B3c2ccccc2N4c2ccccc2)cc1]

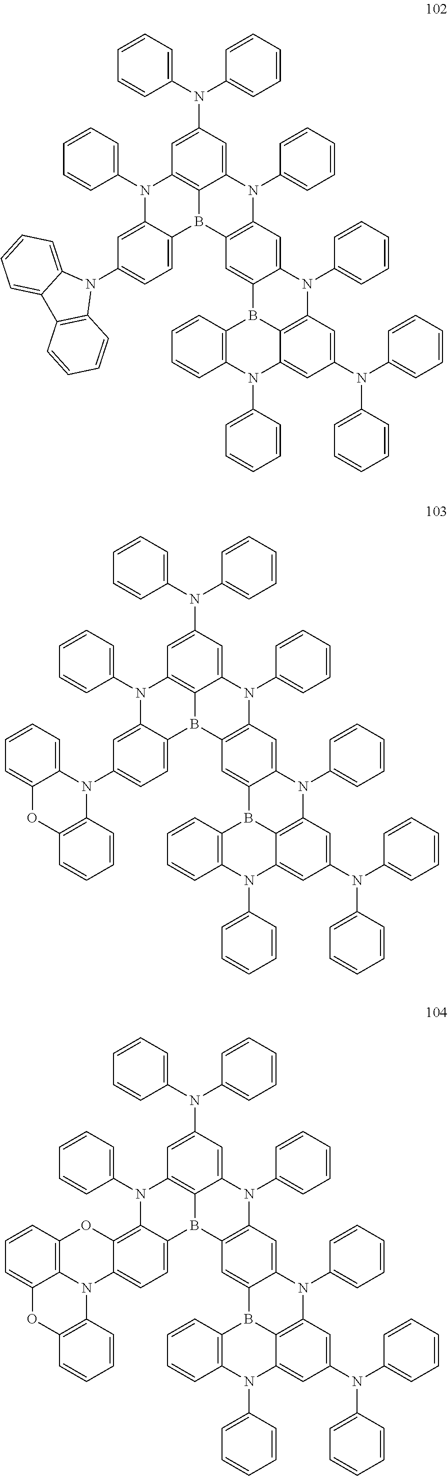 [SMILES: c1ccc(N(c2ccccc2)c2cc3c4c(c2)N(c2ccccc2)c2cc5c(cc2B4c2ccccc2N3c2ccccc2)B2c3ccc(-n4c6ccccc6c6ccccc64)cc3N(c3ccccc3)c3cc(N(c4ccccc4)c4ccccc4)cc(c32)N5c2ccccc2)cc1 ; c1ccc(N(c2ccccc2)c2cc3c4c(c2)N(c2ccccc2)c2cc5c(cc2B4c2ccccc2N3c2ccccc2)B2c3ccc(N4c6ccccc6Oc6ccccc64)cc3N(c3ccccc3)c3cc(N(c4ccccc4)c4ccccc4)cc(c32)N5c2ccccc2)cc1 ; c1ccc(N(c2ccccc2)c2cc3c4c(c2)N(c2ccccc2)c2cc5c(cc2B4c2ccccc2N3c2ccccc2)B2c3ccc4c(c3N(c3ccccc3)c3cc(N(c6ccccc6)c6ccccc6)cc(c32)N5c2ccccc2)Oc2cccc3c2N4c2ccccc2O3)cc1]

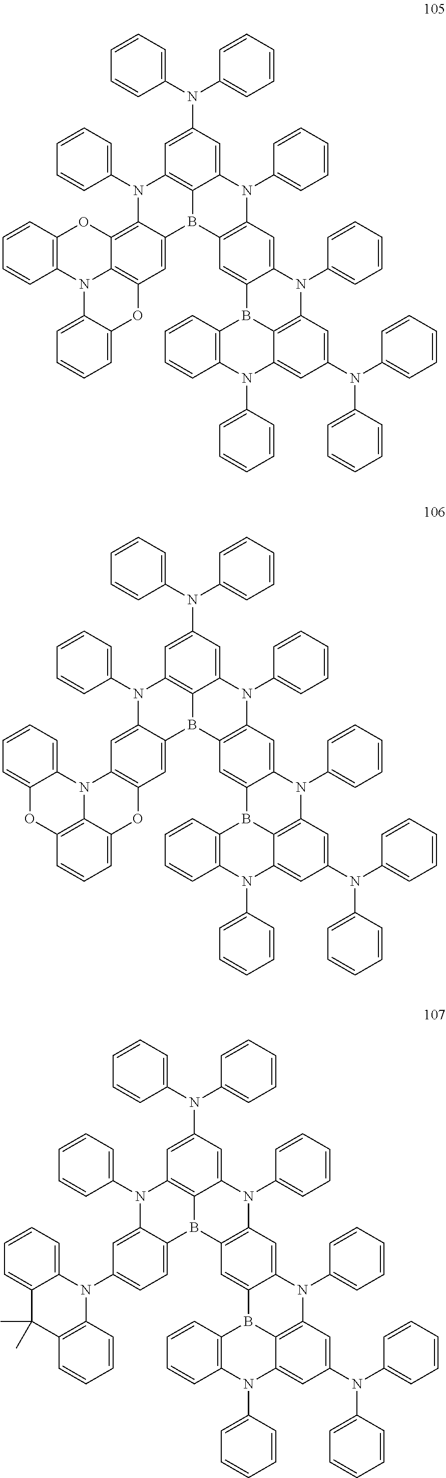 [SMILES: c1ccc(N(c2ccccc2)c2cc3c4c(c2)N(c2ccccc2)c2cc5c(cc2B4c2ccccc2N3c2ccccc2)B2c3cc4c6c(c3N(c3ccccc3)c3cc(N(c7ccccc7)c7ccccc7)cc(c32)N5c2ccccc2)Oc2ccccc2N6c2ccccc2O4)cc1 ; c1ccc(N(c2ccccc2)c2cc3c4c(c2)N(c2ccccc2)c2cc5c(cc2B4c2ccccc2N3c2ccccc2)B2c3cc4c(cc3N(c3ccccc3)c3cc(N(c6ccccc6)c6ccccc6)cc(c32)N5c2ccccc2)N2c3ccccc3Oc3cccc(c32)O4)cc1 ; CC1(C)c2ccccc2N(c2ccc3c(c2)N(c2ccccc2)c2cc(N(c4ccccc4)c4ccccc4)cc4c2B3c2cc3c(cc2N4c2ccccc2)N(c2ccccc2)c2cc(N(c4ccccc4)c4ccccc4)cc4c2B3c2ccccc2N4c2ccccc2)c2ccccc21]

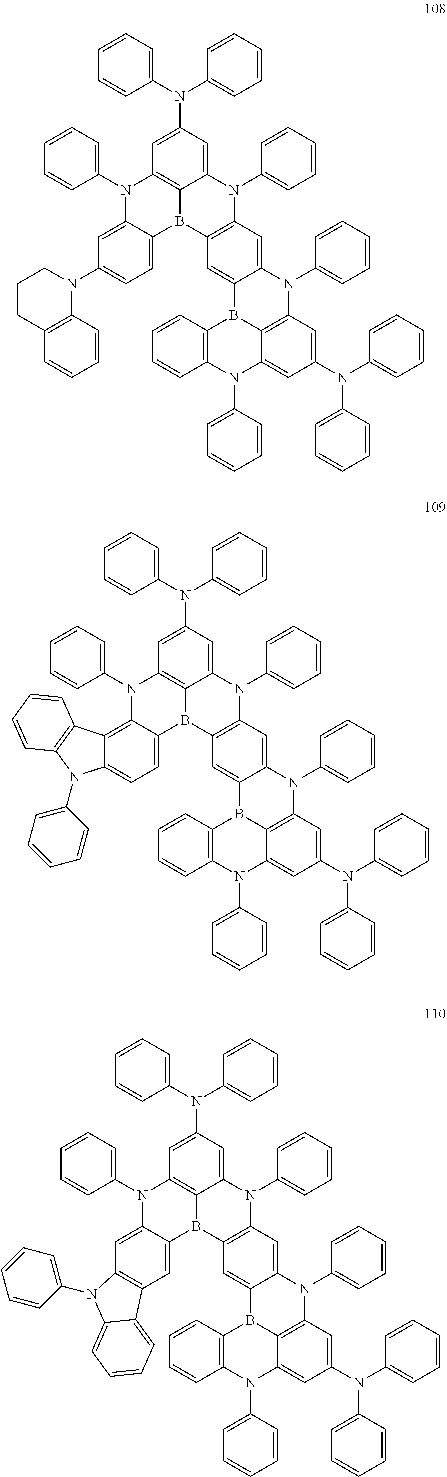 [SMILES: c1ccc(N(c2ccccc2)c2cc3c4c(c2)N(c2ccccc2)c2cc5c(cc2B4c2ccccc2N3c2ccccc2)B2c3ccc(N4CCCc6ccccc64)cc3N(c3ccccc3)c3cc(N(c4ccccc4)c4ccccc4)cc(c32)N5c2ccccc2)cc1 ; c1ccc(N(c2ccccc2)c2cc3c4c(c2)N(c2ccccc2)c2cc5c(cc2B4c2ccccc2N3c2ccccc2)B2c3ccc4c(c3N(c3ccccc3)c3cc(N(c6ccccc6)c6ccccc6)cc(c32)N5c2ccccc2)c2ccccc2n4-c2ccccc2)cc1 ; c1ccc(N(c2ccccc2)c2cc3c4c(c2)N(c2ccccc2)c2cc5c(cc2B4c2ccccc2N3c2ccccc2)B2c3cc4c6ccccc6n(-c6ccccc6)c4cc3N(c3ccccc3)c3cc(N(c4ccccc4)c4ccccc4)cc(c32)N5c2ccccc2)cc1]

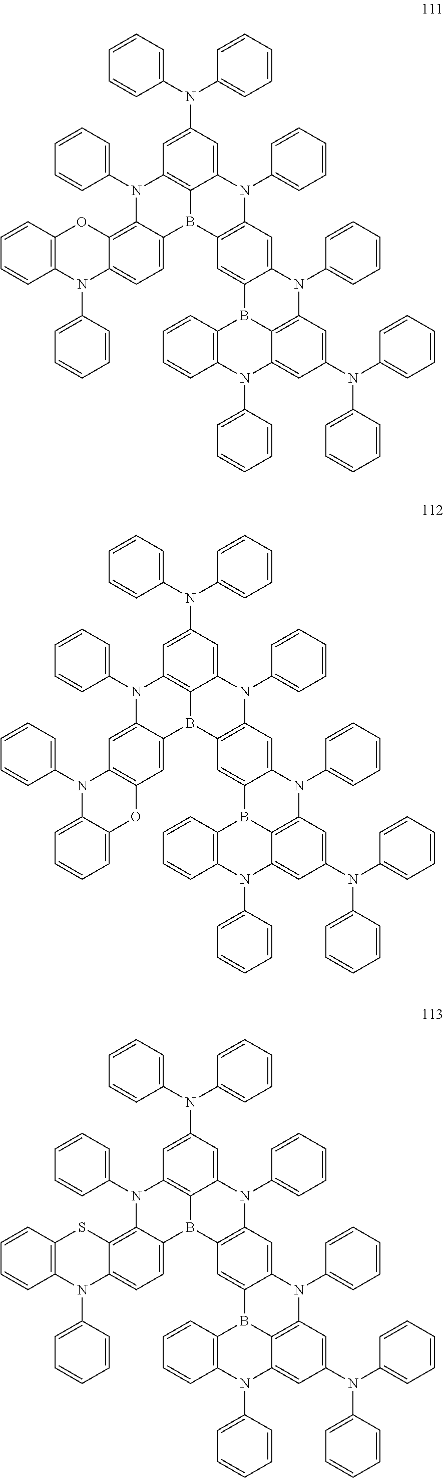 [SMILES: c1ccc(N(c2ccccc2)c2cc3c4c(c2)N(c2ccccc2)c2cc5c(cc2B4c2ccccc2N3c2ccccc2)B2c3ccc4c(c3N(c3ccccc3)c3cc(N(c6ccccc6)c6ccccc6)cc(c32)N5c2ccccc2)Oc2ccccc2N4c2ccccc2)cc1 ; c1ccc(N(c2ccccc2)c2cc3c4c(c2)N(c2ccccc2)c2cc5c(cc2B4c2ccccc2N3c2ccccc2)B2c3cc4c(cc3N(c3ccccc3)c3cc(N(c6ccccc6)c6ccccc6)cc(c32)N5c2ccccc2)N(c2ccccc2)c2ccccc2O4)cc1 ; c1ccc(N(c2ccccc2)c2cc3c4c(c2)N(c2ccccc2)c2cc5c(cc2B4c2ccccc2N3c2ccccc2)B2c3ccc4c(c3N(c3ccccc3)c3cc(N(c6ccccc6)c6ccccc6)cc(c32)N5c2ccccc2)Sc2ccccc2N4c2ccccc2)cc1]

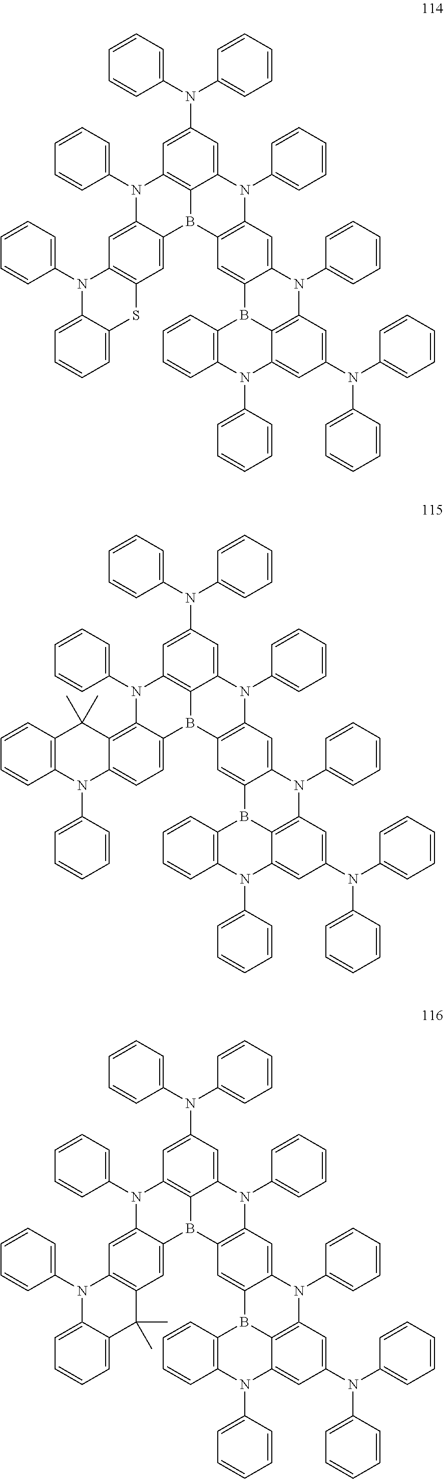 [SMILES: c1ccc(N(c2ccccc2)c2cc3c4c(c2)N(c2ccccc2)c2cc5c(cc2B4c2ccccc2N3c2ccccc2)B2c3cc4c(cc3N(c3ccccc3)c3cc(N(c6ccccc6)c6ccccc6)cc(c32)N5c2ccccc2)N(c2ccccc2)c2ccccc2S4)cc1 ; CC1(C)c2ccccc2N(c2ccccc2)c2ccc3c(c21)N(c1ccccc1)c1cc(N(c2ccccc2)c2ccccc2)cc2c1B3c1cc3c(cc1N2c1ccccc1)N(c1ccccc1)c1cc(N(c2ccccc2)c2ccccc2)cc2c1B3c1ccccc1N2c1ccccc1 ; CC1(C)c2ccccc2N(c2ccccc2)c2cc3c(cc21)B1c2cc4c(cc2N(c2ccccc2)c2cc(N(c5ccccc5)c5ccccc5)cc(c21)N3c1ccccc1)N(c1ccccc1)c1cc(N(c2ccccc2)c2ccccc2)cc2c1B4c1ccccc1N2c1ccccc1]

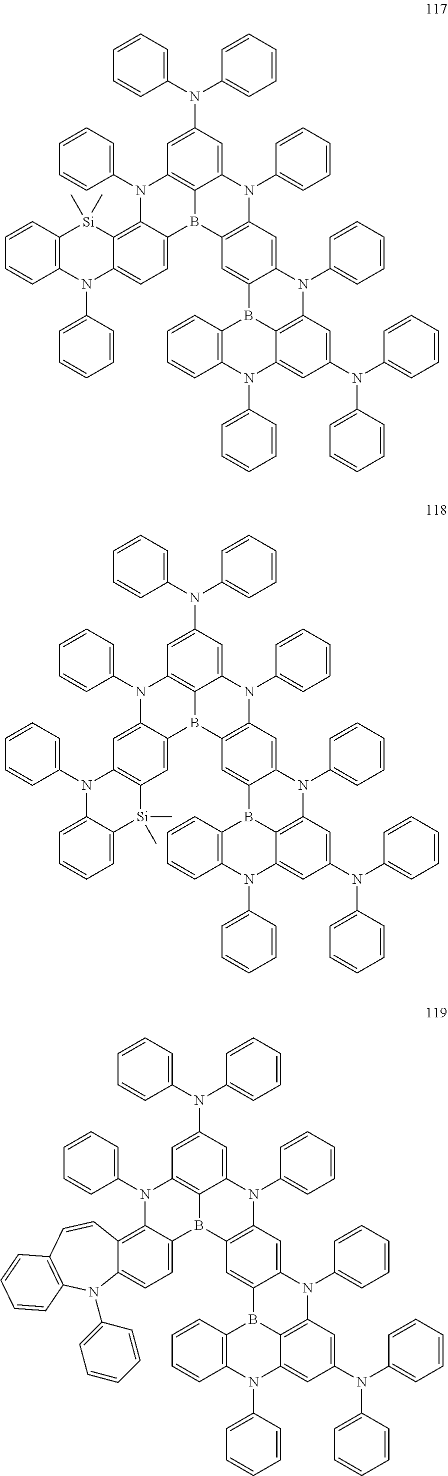 [SMILES: C[Si]1(C)c2ccccc2N(c2ccccc2)c2ccc3c(c21)N(c1ccccc1)c1cc(N(c2ccccc2)c2ccccc2)cc2c1B3c1cc3c(cc1N2c1ccccc1)N(c1ccccc1)c1cc(N(c2ccccc2)c2ccccc2)cc2c1B3c1ccccc1N2c1ccccc1 ; C[Si]1(C)c2ccccc2N(c2ccccc2)c2cc3c(cc21)B1c2cc4c(cc2N(c2ccccc2)c2cc(N(c5ccccc5)c5ccccc5)cc(c21)N3c1ccccc1)N(c1ccccc1)c1cc(N(c2ccccc2)c2ccccc2)cc2c1B4c1ccccc1N2c1ccccc1 ; C1=Cc2c(ccc3c2N(c2ccccc2)c2cc(N(c4ccccc4)c4ccccc4)cc4c2B3c2cc3c(cc2N4c2ccccc2)N(c2ccccc2)c2cc(N(c4ccccc4)c4ccccc4)cc4c2B3c2ccccc2N4c2ccccc2)N(c2ccccc2)c2ccccc21]

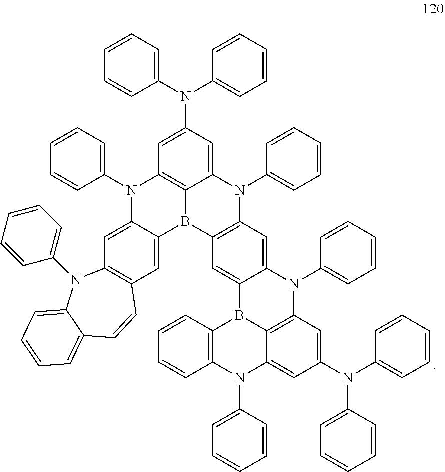 [SMILES: C1=Cc2cc3c(cc2N(c2ccccc2)c2ccccc21)N(c1ccccc1)c1cc(N(c2ccccc2)c2ccccc2)cc2c1B3c1cc3c(cc1N2c1ccccc1)N(c1ccccc1)c1cc(N(c2ccccc2)c2ccccc2)cc2c1B3c1ccccc1N2c1ccccc1]

The fused polycyclic compound represented by Formula 1 of an embodiment may be a thermally activated delayed fluorescence emitting material. Furthermore, the fused polycyclic compound represented by Formula 1 of an embodiment may be a thermally activated delayed fluorescence dopant having a difference (ΔE_{ST}) between a lowest triplet exciton energy level (T1 energy level) and a lowest singlet exciton energy level (S1 energy level) of about 0.13 eV or less. For example, ΔE_{ST} of the fused polycyclic compound represented by Formula 1 of an embodiment may be about 0.13 eV.

The fused polycyclic compound represented by Formula 1 of an embodiment may be a luminescence material having a luminescence center wavelength in a wavelength region in a range of about 430 nm to about 490 nm. For example, the fused polycyclic compound represented by Formula 1 of an embodiment may be a blue thermally activated delayed fluorescence (TADF) dopant. However, embodiments of the present disclosure are not limited thereto, when the fused polycyclic compound of an embodiment is used as a luminescence material, the fused polycyclic compound may be used as a dopant material which emits light of various suitable wavelength regions, such as a red luminescence dopant, and a green luminescence dopant.

The emission layer EML in the organic electroluminescence device 10 of an embodiment may emit a delayed fluorescence. For example, the emission layer EML may emit a thermally activated delayed fluorescence (TADF).

In addition, the emission layer EML of the organic electroluminescence device 10 may emit blue light. For example, the emission layer EML of the organic electroluminescence device 10 of an embodiment may emit deep blue light in a region of about 450 nm or less. However, embodiments of the present disclosure are not limited thereto, and the emission layer EML may emit green light or red light.

In some embodiments, the organic electroluminescence device 10 may include a plurality of emission layers. The plurality of emission layers may be sequentially laminated, for example, the organic electroluminescence device 10 including the plurality of emission layers may emit white light. The organic electroluminescence device including a plurality of emission layers may be an organic electroluminescence device having a tandem structure. When the organic electroluminescence device 10 includes a plurality of emission layers, at least one emission layer EML may include the fused polycyclic compound of an embodiment as described above.

In an embodiment, the emission layer EML includes a host and a dopant, and may include the above-described fused polycyclic compound as a dopant. For example, the emission layer EML in the organic electroluminescence device 10 of an embodiment may include the host to emit a delayed fluorescence and a dopant to emit a delayed fluorescence, and may include the above-described fused polycyclic compound as a dopant to emit a delayed fluorescence. The emission layer EML may include at least one selected from among the fused polycyclic compounds represented by Compound Group 1 as described above as a thermally activated delayed fluorescence dopant.

In an embodiment, the emission layer EML may include, as a host, at least any one selected from among the compound represented by Formula A below and the compound represented by Formula B below:

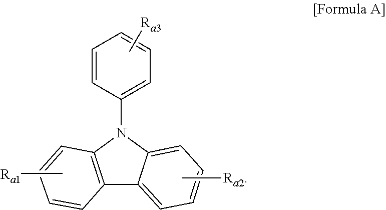

In Formula A above, Rₐ₁ to Rₐ₃ may each independently be a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. For example, Rₐ₁ to Rₐ₃ may each independently be a substituted or unsubstituted aryl group having 6 to 30 ring-forming carbon atoms, or a substituted or unsubstituted heteroaryl group having 2 to 30 ring-forming carbon atoms.

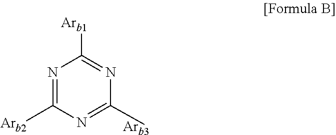

In Formula B above, Ar_{b1} to Ar_{b3} may each independently be a substituted or unsubstituted aryl group having 6 to 30 ring-forming carbon atoms, or a substituted or unsubstituted heteroaryl group having 2 to 30 ring-forming carbon atoms.

In some embodiments, as the host materials of the emission layer EML, any suitable materials generally used in the art may be used, and one selected from among fluoranthene derivatives, pyrene derivatives, arylacetylene derivatives, anthracene derivatives, fluorene derivatives, perylene derivatives, chrysene derivatives, etc. may be used, without specific limitation. In some embodiments, the host materials may include pyrene derivatives, perylene derivatives, and/or anthracene derivatives. For example, as the host materials of the emission layer EML, anthracene derivatives represented by Formula AN below may be used.

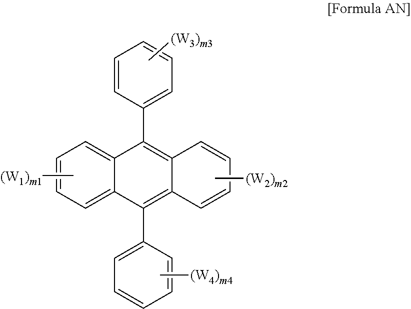

In Formula AN, W₁ to W₄ may each independently be a hydrogen atom, a deuterium atom, a halogen atom, a substituted or unsubstituted silyl group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or may be bonded to an adjacent group to form a ring, m1 and m2 are each independently an integer in a range of 0 to 4, and m3 and m4 are each independently an integer in a range of 0 to 5.

If m1 is 1, W₁ may not be a hydrogen atom, if m2 is 1, W₂ may not be a hydrogen atom, if m3 is 1, W₃ may not be a hydrogen atom, and if m4 is 1, W₄ may not be a hydrogen atom.

If m1 is 2 or more, a plurality of W₁'s are the same or different. If m2 is 2 or more, a plurality of W₂'s are the same or different. If m3 is 2 or more, a plurality of W₃'s are the same or different. If m4 is 2 or more, a plurality of W₄'s are the same or different.

The compound represented by Formula AN above may include, for example, compounds represented by the structural formulae below. However, the compound represented by Formula AN above is not limited thereto.

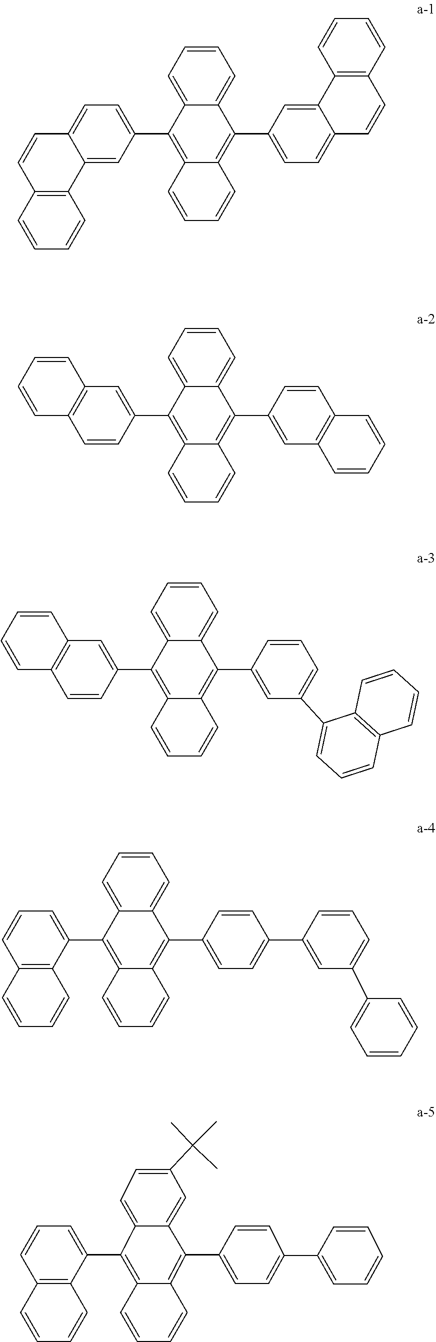

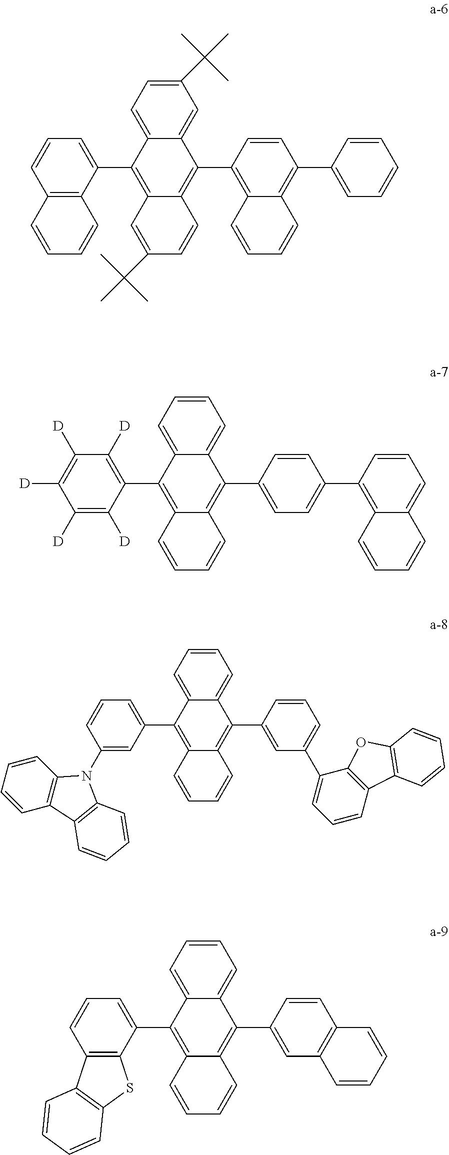

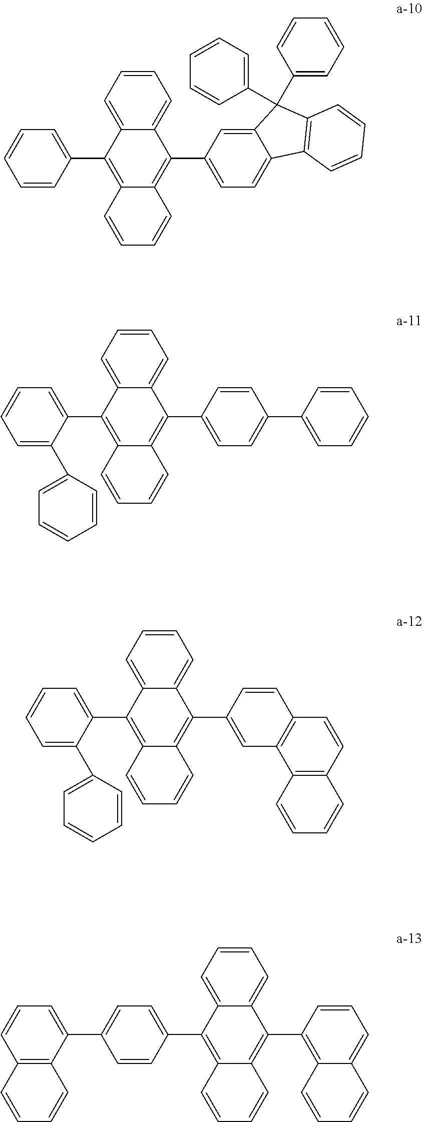

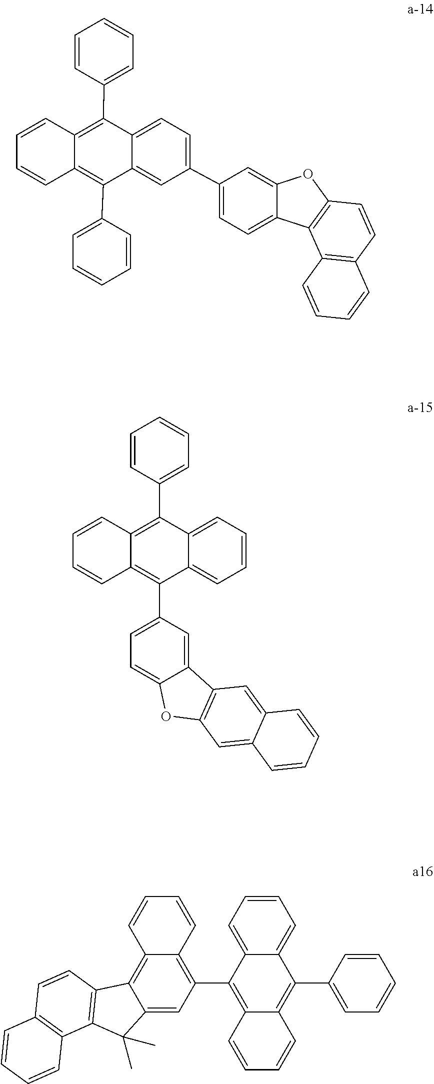

The emission layer EML may further include any suitable material generally used in the art as a host material. In some embodiments, the emission layer EML may include, as a host material, at least one of bis[2-(diphenylphosphino)phenyl] ether oxide (DPEPO), 4,4′-bis(carbazol-9-yl)biphenyl (CBP), 1,3-bis(carbazol-9-yl)benzene (mCP), 2,8-bis(diphenylphosphoryl)dibenzo[b,d]furan (PPF), 4,4′,4″-tris(carbazol-9-yl)-triphenylamine (TCTA), and/or 1,3,5-tris(1-phenyl-1H-benzo[d]imidazole-2-yl)benzene (TPBi). However, embodiments of the present disclosure are not limited thereto, for example, tris(8-hydroxyquinolino)aluminum (Alq₃), poly(N-vinylcarbazole (PVK), 9,10-di(naphthalene-2-yl)anthracene (ADN), 3-tert-butyl-9,10-di(naphth-2-yl)anthracene (TBADN), distyrylarylene (DSA), 4,4′-bis(9-carbazolyl)-2,2′-dimethyl-biphenyl (CDBP), 2-methyl-9,10-bis(naphthalen-2-yl)anthracene (MADN), hexaphenyl cyclotriphosphazene (CP1), 1,4-bis(triphenylsilyl)benzene (UGH2), hexaphenylcyclotrisiloxane (DPSiO₃), octaphenylcyclotetra siloxane (DPSiO₄), etc. may be used as a host material.

In an embodiment, the emission layer EML may further include any suitable dopant material generally used in the art. In some embodiments, the emission layer EML may further include styryl derivatives (e.g., 1,4-bis[2-(3-N-ethylcarbazoryl)vinyl]benzene (BCzVB), 4-(di-p-tolylamino)-4′-[(di-p-tolylamino)styryl]stilbene (DPAVB), and N-(4-((E)-2-(6-((E)-4-(diphenylamino)styryl)naphthalen-2-yl)vinyl)phenyl)-N-phenylbenz enamine (N-BDAVBi)), perylene and the derivatives thereof (e.g., 2,5,8,11-tetra-t-butylperylene (TBPe)), pyrene and the derivatives thereof (e.g., 1,1-dipyrene, 1,4-dipyrenylbenzene, 1,4-bis(N,N-diphenylamino)pyrene), etc.

The emission layer EML may include any suitable phosphorescence dopant material generally used in the art. In some embodiments, a metal complex including iridium (Ir), platinum (Pt), osmium (Os), aurum (Au), titanium (Ti), zirconium (Zr), hafnium (Hf), europium (Eu), terbium (Tb), and/or thulium (Tm) may be used as a phosphorescence dopant. For example, iridium(III) bis(4,6-difluorophenylpyridinato-N, C2′)picolinate) (Flrpic), bis(2,4-difluorophenylpyridinato) (Fir6), and/or platinum octaethyl porphyrin (PtOEP) may be used as a phosphorescence dopant. However, embodiments of the present disclosure are not limited thereto.

In some embodiments, the emission layer EML may include two dopant materials which have a different lowest triplet exciton energy level (T1 energy level). The emission layer EML of the organic electroluminescence device 10 of an embodiment may include a host having a first lowest triplet exciton energy level, a first dopant having a second lowest triplet exciton energy level lower than the first lowest triplet exciton energy level, and a second dopant having a third lowest triplet exciton energy level lower than the second lowest triplet exciton energy level. In an embodiment, the emission layer EML may include the above-described fused polycyclic compound of an embodiment as the first dopant.

In some embodiments, the emission layer EML may further include any suitable phosphorescence host material generally used in the art. In some embodiments, the emission layer EML may include bis(4-(9H-carbazol-9-yl)phenyl)diphenylsilane (BCPDS).

In the organic electroluminescence device 10 of an embodiment shown in FIGS. 1 to 4, the electron transport region ETR is on the emission layer EML. The electron transport region ETR may include, but is not limited to, at least one of the hole blocking layer, the electron transport layer ETL, and/or the electron injection layer EIL.

The electron transport region ETR may have a single layer formed of a single material, a single layer formed of a plurality of different materials, or a multilayer structure including a plurality of layers formed of a plurality of different materials.

For example, the electron transport region ETR may have a single layer structure of an electron injection layer EIL or an electron transport layer ETL, and may have a single layer structure formed of an electron injection material and an electron transport material. In addition, the electron transport region ETR may have a single layer structure formed of materials different from each other, or a structure of an electron transport layer ETL/an electron injection layer EIL, a hole blocking layer/an electron transport layer ETL/an electron injection layer (EIL) which are sequentially laminated from the emission layer EML, but embodiments of the present disclosure are not limited thereto. The thickness of the electron transport region ETR may be, for example, in a range from about 1,000 Å to about 1,500 Å.

The electron transport region ETR may be formed using various suitable methods such as a vacuum deposition method, a spin coating method, a cast method, a Langmuir-Blodgett (LB) method, an inkjet printing method, a laser printing method, a laser induced thermal imaging (LITI) method, etc.

When the electron transport region ETR includes the electron transport layer ETL, the electron transport region ETR may include an anthracene-based compound. However, embodiments of the present disclosure are not limited thereto, and the electron transport region may include, for example, tris(8-hydroxyquinolinato)aluminum (Alq₃), 1,3,5-tri[(3-pyridyl)-phen-3-yl]benzene, 2,4,6-tris(3′-(pyridin-3-yl)biphenyl-3-yl)-1,3,5-triazine, 2-(4-(N-phenylbenzoimidazolyl-1-ylphenyl)-9,10-dinaphthylanthracene, 1,3,5-tri(1-phenyl-1H-benzo[d]imidazol-2-yl)phenyl (TPBi), 2,9-dimethyl-4,7-diphenyl-1,10-phenanthroline (BCP), 4,7-diphenyl-1,10-phenanthroline (Bphen), 3-(4-biphenylyl)-4-phenyl-5-tert-butylphenyl-1,2,4-triazole (TAZ), 4-(naphthalen-1-yl)-3,5-diphenyl-4H-1,2,4-triazole (NTAZ), 2-(4-biphenylyl)-5-(4-tert-butylphenyl)-1,3,4-oxadiazole (tBu-PBD), bis(2-methyl-8-quinolinolato-N1,O8)-(1,1′-biphenyl-4-olato)aluminum (BAlq), berylliumbis(benzoquinolin-10-olate) (Bebq2), 9,10-di(naphthalene-2-yl)anthracene (ADN), 1,3-Bis[3,5-di(pyridin-3-yl)phenyl]benzene (BmPyPhB), or a mixture thereof. The thickness of the electron transport layers ETL may be in a range from about 100 Å to about 1,000 Å, for example, from about 150 Å to about 500 Å. If the thickness of the electron transport layers ETL satisfies the above-described ranges, suitable or satisfactory electron transport characteristics may be obtained without a substantial increase in driving voltage.

If the electron transport region ETR includes the electron injection layer EIL, the electron transport region ETR may be formed using a metal halide such as LiF, NaCl, CsF, RbCl, RbI, and/or CuI, a lanthanide metal such as Yb, a metal oxide such as Li₂O and/or BaO, and/or 8-hydroxyl-lithium quinolate (Liq), etc., but embodiments of the present disclosure are not limited thereto. The electron injection layer EIL may also be formed of a mixture material of an electron transport material and an insulating organometallic salt. The insulating organometallic salt may be a material having an energy band gap of about 4 eV or more. In some embodiments, the organometallic salt may include, for example, metal acetates, metal benzoates, metal acetoacetates, metal acetylacetonates, and/or metal stearates. The thickness of the electron injection layers EIL may be in a range from about 1 Å to about 500 Å, and in a range from about 3 Å to about 300 Å. If the thickness of the electron injection layers EIL satisfies the above-described range, suitable or satisfactory electron injection properties may be obtained without a substantial increase in driving voltage.

The electron transport region ETR may include a hole blocking layer HBL as described above. The hole blocking layer HBL may include, for example, at least one of 2,9-dimethyl-4,7-diphenyl-1,10-phenanthroline (BCP), and/or 4,7-diphenyl-1,10-phenanthroline (Bphen), but embodiments of the present disclosure are not limited thereto.

The second electrode EL2 is on the electron transport region ETR. The second electrode EL2 may be a common electrode. The second electrode EL2 may be an anode or cathode, but embodiments of the present disclosure are not limited thereto. If the first electrode EL1 is an anode, the second electrode EL2 may be a cathode. If the first electrode EU is a cathode, the second electrode EL2 may be an anode.

The second electrode EL2 may be a transmissive electrode, a transflective electrode, or a reflective electrode. When the second electrode EL2 is the transmissive electrode, the second electrode EL2 may include a transparent metal oxide, for example, indium tin oxide (ITO), indium zinc oxide (IZO), zinc oxide (ZnO), indium tin zinc oxide (ITZO), etc.

When the second electrode EL2 is the transflective electrode or the reflective electrode, the second electrode EL2 may include Ag, Mg, Cu, Al, Pt, Pd, Au, Ni, Nd, Ir, Cr, Li, Ca, LiF/Ca, LiF/Al, Mo, Ti, Yb, or a compound or mixture thereof (e.g., AgMg, AgYb, MgAg, and/or the like). In some embodiments, the first electrode EL1 may have a multilayer structure including a reflective layer or a transflective layer formed of the above-described materials, and a transparent conductive layer formed of ITO, IZO, ZnO, ITZO, etc.

In some embodiments, the second electrode EL2 may be coupled with an auxiliary electrode. If the second electrode EL2 is coupled with the auxiliary electrode, the resistance of the second electrode EL2 may decrease.

In some embodiments, a capping layer CPL may be further on the second electrode EL2 of the organic electroluminescence device 10 according to an embodiment. The capping layer CPL may include, for example, α-NPD, NPB, TPD, m-MTDATA, Alq₃, CuPc, N4,N4,N4′,N4′-tetra(biphenyl-4-yl)biphenyl-4,4′-diamine (TPD15), 4,4′,4″-tris(carbazol sol-9-yl)triphenylamine (TCTA), etc.

The organic electroluminescence device 10 according to an embodiment of the present disclosure may include the above-described fused polycyclic compound of an embodiment in the emission layer EML between the first electrode EL1 and the second electrode EL2 to exhibit excellent luminous efficiency in a blue wavelength region.

The above-described fused polycyclic compound of an embodiment includes two boron atoms and a nitrogen atom substituted at the para-position of at least one boron atom, compared to an existing polycyclic compound including a nitrogen atom and a boron atom at the core thereof. Accordingly, the fused polycyclic compound of an embodiment may have a decreased difference between a lowest triplet exciton energy level (T1 energy level) and a lowest singlet exciton energy level (S1 energy level) by the increase in the multiple resonance effects of the fused polycyclic compound, and if the fused polycyclic compound is used as the luminescent material of the organic electroluminescence device, high efficiency of the organic electroluminescence device may be achieved.

Hereinafter, with reference to Examples and Comparative Examples, the fused polycyclic compound according to an embodiment of the present disclosure and the organic electroluminescence device of an embodiment will be explained in more detail. The examples are only illustrations for assisting the understanding of the subject matter of the present disclosure, and the scope of the present disclosure is not limited thereto.

### 1. Synthesis of Fused Polycyclic Compound

A synthetic method of a fused polycyclic compound according to the present embodiment will be described in more detail by illustrating the synthetic method of compounds 1, 11, 29, 61, 69, and 101. In addition, in the following descriptions, a synthetic method of the fused polycyclic compound is provided as an example, but the synthetic method according to embodiments of the present disclosure is not limited to the following examples.

### (1) Synthesis of Compound 1

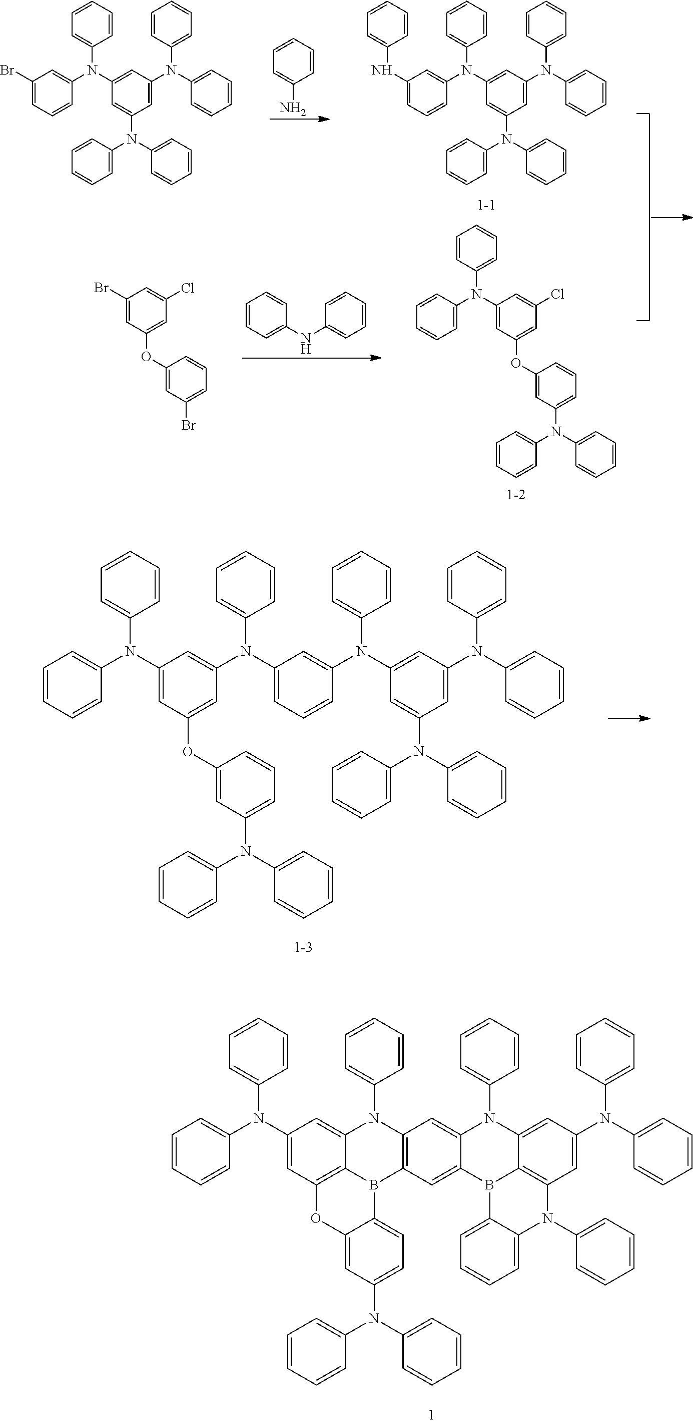

### 1-1) Synthesis of Intermediate 1-1

N1-(3-bromophenyl)-N1,N3,N3,N5,N5-pentaphenylbenzene-1,3,5-triamine (1 eq), aniline (1.5 eq), tris(dibenzylideneacetone)dipalladium(0) (0.05 eq), tri-tert-butylphosphine (0.1 eq), and sodium tert-butoxide (3 eq) were dissolved in toluene and then the resultant mixture was stirred at 100° C. for 12 hours. After cooling, the resultant product was washed three times with ethyl acetate and water, and then separated to obtain an organic layer. The obtained organic layer was dried with MgSO₄, and then dried at reduced pressure. Intermediate 1-1 was obtained by column chromatography (yield: 73%).

### 1-2) Synthesis of Intermediate 1-2

1-bromo-3-(3-bromophenoxy)-5-chlorobenzene (1 eq), diphenylamine (2 eq), tris(dibenzylideneacetone)dipalladium(0) (0.05 eq), BINAP (0.1 eq), and sodium tert-butoxide (3 eq) were dissolved in toluene and then the resultant mixture was stirred at 90° C. for 12 hours. After cooling, the resultant product was washed three times with ethyl acetate and water, and then separated to obtain an organic layer. The obtained organic layer was dried with MgSO₄, and then dried at reduced pressure. Intermediate 1-2 was obtained by column chromatography (yield: 55%).

### 1-3) Synthesis of Intermediate 1-3

Intermediate 1-1 (1 eq), Intermediate 1-2 (1 eq), tris(dibenzylideneacetone)dipalladium(0) (0.05 eq), tri-tert-butylphosphine (0.1 eq), and sodium tert-butoxide (3 eq) were dissolved in o-xylene and then the resultant mixture was stirred at 140° C. for 12 hours. After cooling, the solvent was dried at reduced pressure, the resultant product was washed three times with ethyl acetate and water, and then subjected to liquid separation to obtain an organic layer. The obtained organic layer was dried with MgSO₄, and then dried at reduced pressure. Intermediate 1-3 was obtained by column chromatography (yield: 70%).

### 1-4) Synthesis of Compound 1

Intermediate 1-3 (1 eq) was dissolved in ortho dichlorobenzene, and the resultant mixture was cooled to 0° C., and then BBr₃ (5 eq) was slowly injected thereto in a nitrogen atmosphere. After the injection of BBr₃ was completed, the temperature was elevated to 150° C., and the mixture was stirred for 24 hours. After cooling, the reaction was quenched by slowly adding triethylamine dropwise in the flask containing the resultant product, and then ethyl alcohol was added to the mixture to extract the product. The extracted product was obtained by filtration. The obtained solids were purified by column chromatography to obtain Compound 1 (yield: 9%).

### (2) Synthesis of Compound 11

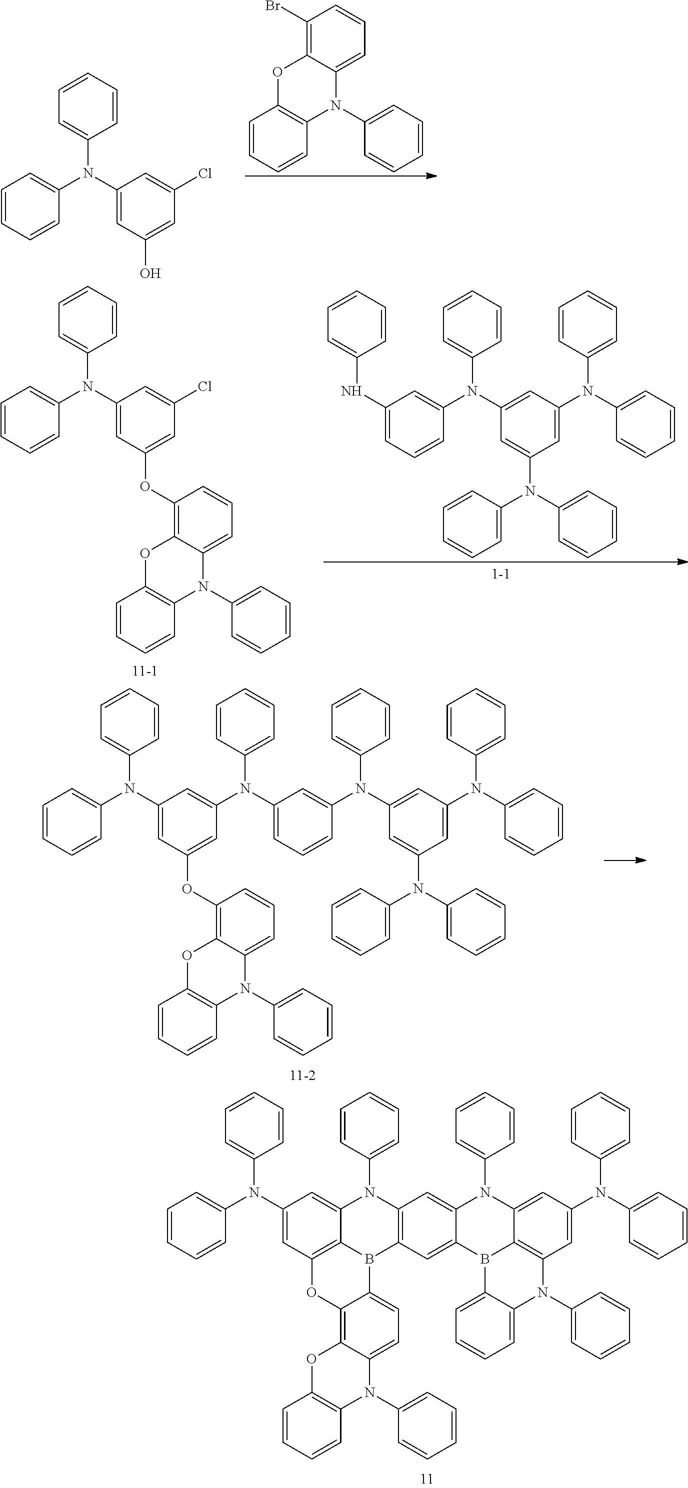

### 2-1) Synthesis of Intermediate 11-1

3-chloro-5-(diphenylamino)phenol (1 eq), 4-bromo-10-phenyl-10H-phenoxazine (1 eq), CuI (0.1 eq), 1,10-phenanthroline (0.2 eq), and K₂CO₃ (3 eq) were dissolved in DMF and then the resultant mixture was stirred at 160° C. for 12 hours. After cooling, the solvent was removed at reduced pressure, and the resultant product was washed three times with ethyl acetate and water, and then subjected to liquid separation to obtain an organic layer. The obtained organic layer was dried with MgSO₄, and then dried at reduced pressure. Intermediate 11-1 was obtained by column chromatography (yield: 66%).

### 2-2) Synthesis of Intermediate 11-2

Intermediate 11-2 was synthesized in substantially the same manner as the synthesis of Intermediate 1-3 by using Intermediate 11-1 and Intermediate 1-1 (yield: 62%).

### 2-3) Synthesis of Compound 11

Compound 11 was synthesized in substantially the same manner as the synthesis of Compound 1 by using Intermediate 11-2 instead of Intermediate 1-3 (yield: 10%).

### (3) Synthesis of Compound 29

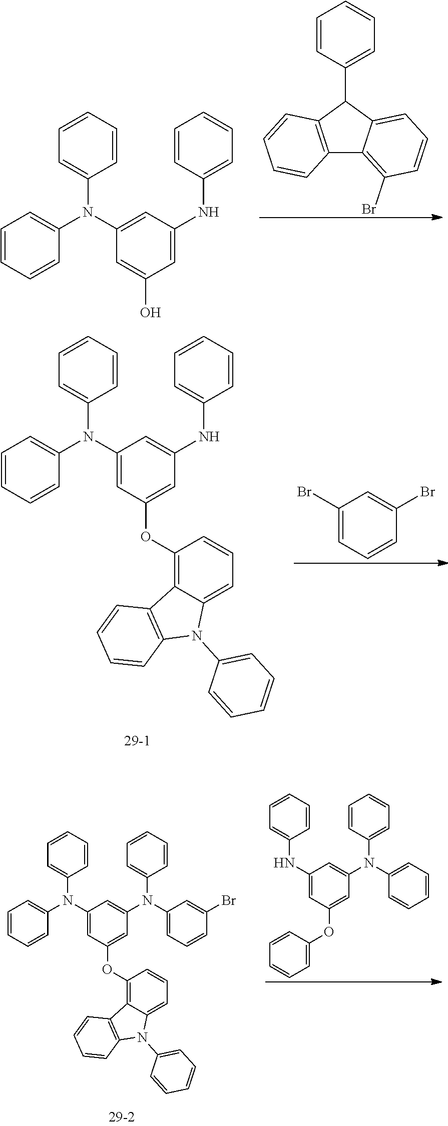

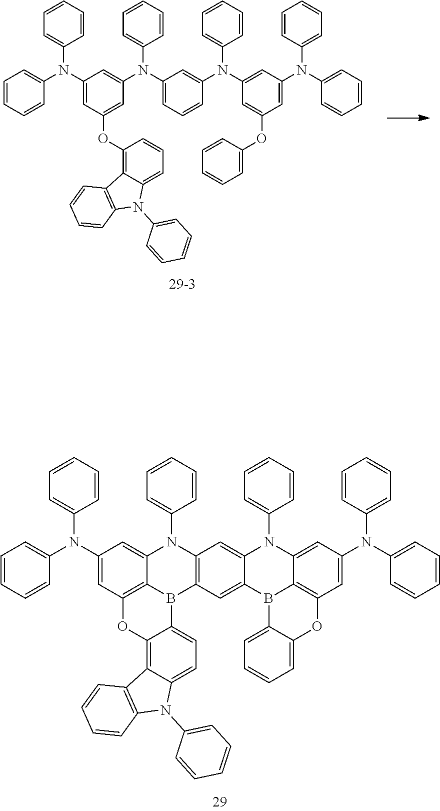 [SMILES: c1ccc(Oc2cc(N(c3ccccc3)c3ccccc3)cc(N(c3ccccc3)c3cccc(N(c4ccccc4)c4cc(Oc5cccc6c5c5ccccc5n6-c5ccccc5)cc(N(c5ccccc5)c5ccccc5)c4)c3)c2)cc1 ; c1ccc(N(c2ccccc2)c2cc3c4c(c2)N(c2ccccc2)c2cc5c(cc2B4c2ccccc2O3)B2c3ccc4c(c3Oc3cc(N(c6ccccc6)c6ccccc6)cc(c32)N5c2ccccc2)c2ccccc2n4-c2ccccc2)cc1]

### 3-1) Synthesis of Intermediate 29-1

Intermediate 29-1 was synthesized in substantially the same manner as the synthesis of Intermediate 11-1 by using 3-(diphenylamino)-5-(phenylamino)phenol and 4-bromo-9-phenyl-9H-carbazole (yield: 58%).

### 3-2) Synthesis of Intermediate 29-2

Intermediate 29-1 (1 eq), 1,3-dibromobenzene (1.5 eq), tris(dibenzylideneacetone)dipalladium(0) (0.05 eq), BINAP (0.1 eq), and sodium tert-butoxide (3 eq) were dissolved in toluene and then the resultant mixture was stirred at 90° C. for 12 hours. After cooling, the resultant product was washed three times with ethyl acetate and water, and then separated to obtain an organic layer. The obtained organic layer was dried with MgSO₄, and then dried at reduced pressure. Intermediate 29-2 was obtained by column chromatography (yield: 50%).

### 3-3) Synthesis of Intermediate 29-3

Intermediate 29-2 (1 eq), 5-phenoxy-N1,N1,N3-triphenylbenzene-1,3-diamine (1 eq), tris(dibenzylideneacetone)dipalladium(0) (0.05 eq), tri-tert-butylphosphine (0.1 eq), and sodium tert-butoxide (3 eq) were dissolved in toluene and then the resultant mixture was stirred at 100° C. for 12 hours. After cooling, the resultant product was washed three times with ethyl acetate and water, and then separated to obtain an organic layer. The obtained organic layer was dried with MgSO₄, and then dried at reduced pressure. Intermediate 29-3 was obtained by column chromatography (yield: 76%).

### 3-4) Synthesis of Compound 29

Compound 29 was synthesized in substantially the same manner as the synthesis of Compound 1 by using Intermediate 29-3 instead of Intermediate 1-3 (yield: 7%)_{.}

### (4) Synthesis of Compound 61

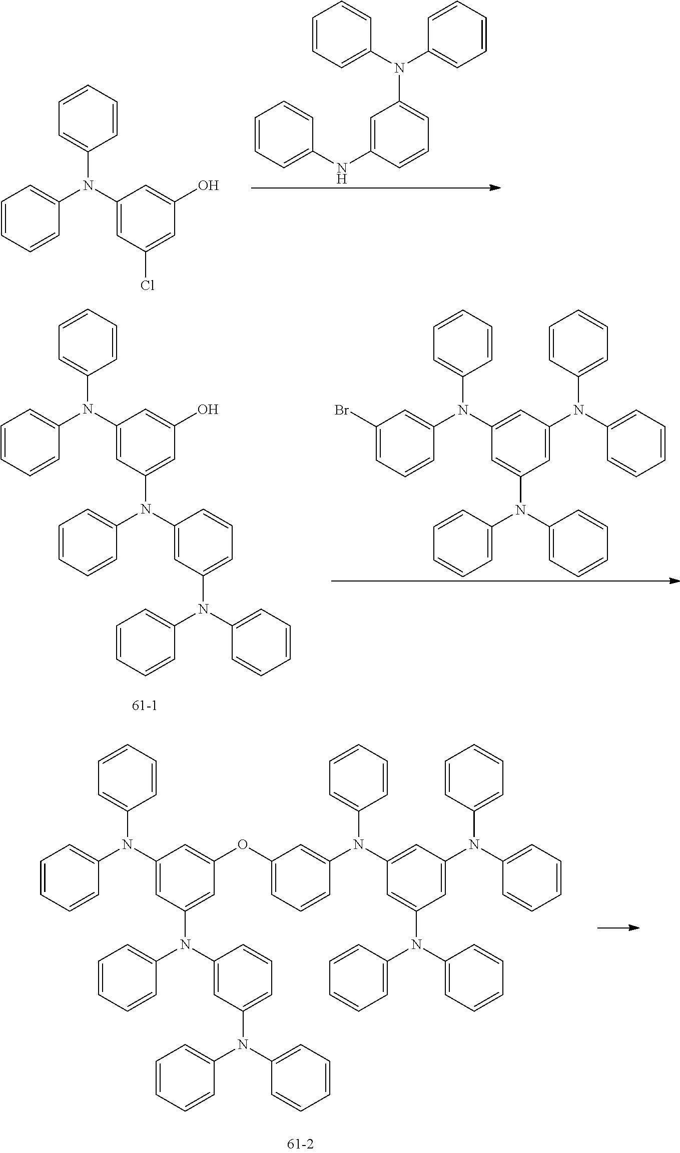 [SMILES: Oc1cc(Cl)cc(N(c2ccccc2)c2ccccc2)c1 ; c1ccc(Nc2cccc(N(c3ccccc3)c3ccccc3)c2)cc1 ; Oc1cc(N(c2ccccc2)c2ccccc2)cc(N(c2ccccc2)c2cccc(N(c3ccccc3)c3ccccc3)c2)c1 ; Brc1cccc(N(c2ccccc2)c2cc(N(c3ccccc3)c3ccccc3)cc(N(c3ccccc3)c3ccccc3)c2)c1 ; c1ccc(N(c2ccccc2)c2cccc(N(c3ccccc3)c3cc(Oc4cccc(N(c5ccccc5)c5cc(N(c6ccccc6)c6ccccc6)cc(N(c6ccccc6)c6ccccc6)c5)c4)cc(N(c4ccccc4)c4ccccc4)c3)c2)cc1]

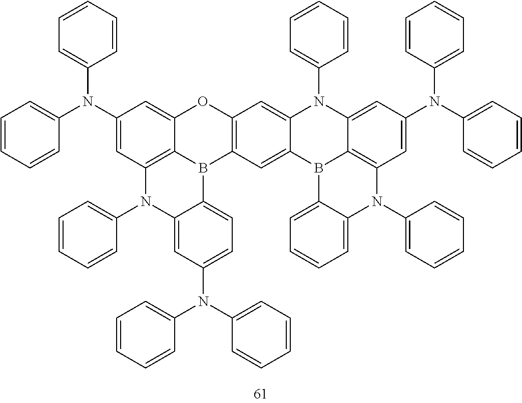 [SMILES: c1ccc(N(c2ccccc2)c2ccc3c(c2)N(c2ccccc2)c2cc(N(c4ccccc4)c4ccccc4)cc4c2B3c2cc3c(cc2O4)N(c2ccccc2)c2cc(N(c4ccccc4)c4ccccc4)cc4c2B3c2ccccc2N4c2ccccc2)cc1]

### 4-1) Synthesis of Intermediate 61-1

Intermediate 61-1 was synthesized in substantially the same manner as the synthesis of Intermediate 1-2 by using 3-chloro-5-(diphenylamino)phenol and N1,N1,N3-triphenylbenzene-1,3-diamine (yield: 72%).

### 4-2) Synthesis of Intermediate 61-2

Intermediate 61-2 was synthesized in substantially the same manner as the synthesis of Intermediate 1-3 by using Intermediate 61-1 and N1-(3-bromophenyl)-N1,N3, N3,N5, N5-pentaphenylbenzene-1,3,5-triam ine (yield: 43%).

### 4-3) Synthesis of Compound 61

Compound 61 was synthesized in substantially the same manner as the synthesis of Compound 1 by using Intermediate 61-2 instead of Intermediate 1-3 (yield: 6%).

### (5) Synthesis of Compound 69

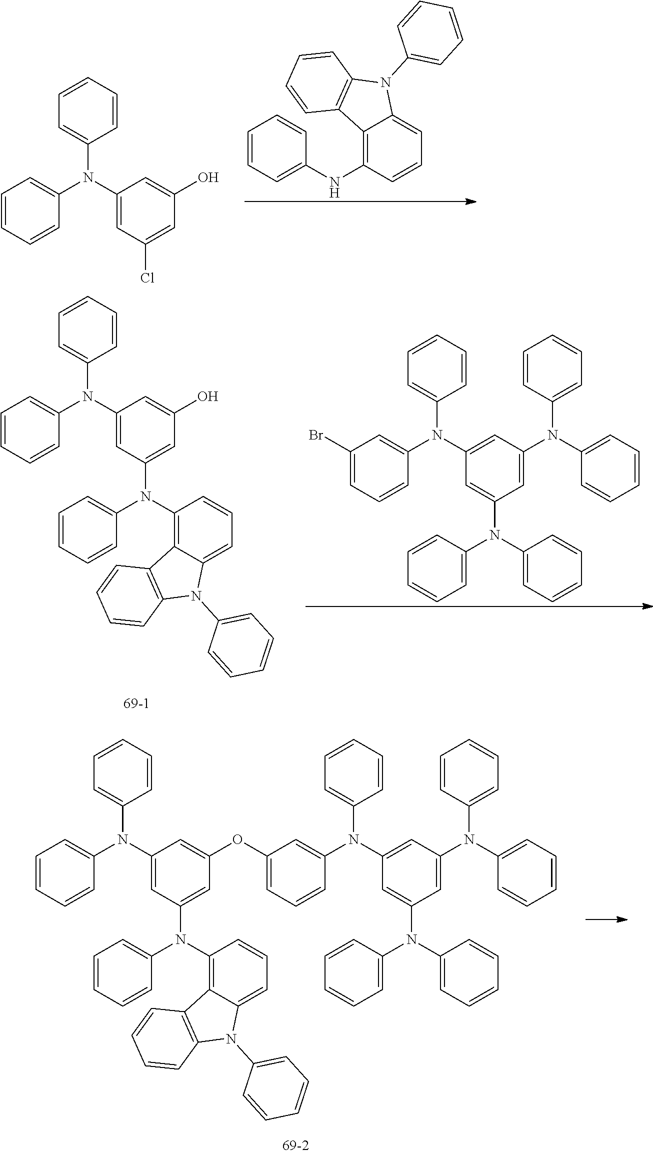

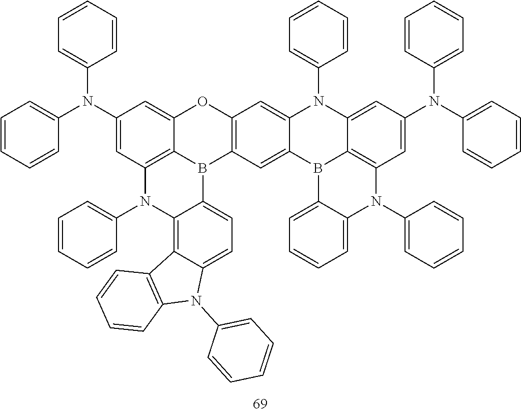 [SMILES: c1ccc(N(c2ccccc2)c2cc3c4c(c2)N(c2ccccc2)c2c(ccc5c2c2ccccc2n5-c2ccccc2)B4c2cc4c(cc2O3)N(c2ccccc2)c2cc(N(c3ccccc3)c3ccccc3)cc3c2B4c2ccccc2N3c2ccccc2)cc1]

### 5-1) Synthesis of Intermediate 69-1

Intermediate 69-1 was synthesized in substantially the same manner as the synthesis of Intermediate 61-1 by using N,9-diphenyl-9H-carbazol-4-amine instead of N1,N1,N3-triphenylbenzene-1,3-diamine (yield: 62%).

### 5-2) Synthesis of Intermediate 69-2

Intermediate 69-2 was synthesized in substantially the same manner as the synthesis of Intermediate 61-2 by using Intermediate 69-1 and N1-(3-bromophenyl)-N1,N3, N3,N5, N5-pentaphenylbenzene-1,3,5-triamine (yield: 55%).

### 5-3) Synthesis of Compound 69

Compound 69 was synthesized in substantially the same manner as the synthesis of Compound 1 by using Intermediate 69-2 instead of Intermediate 1-3 (yield: 8%).

### (6) Synthesis of Compound 101

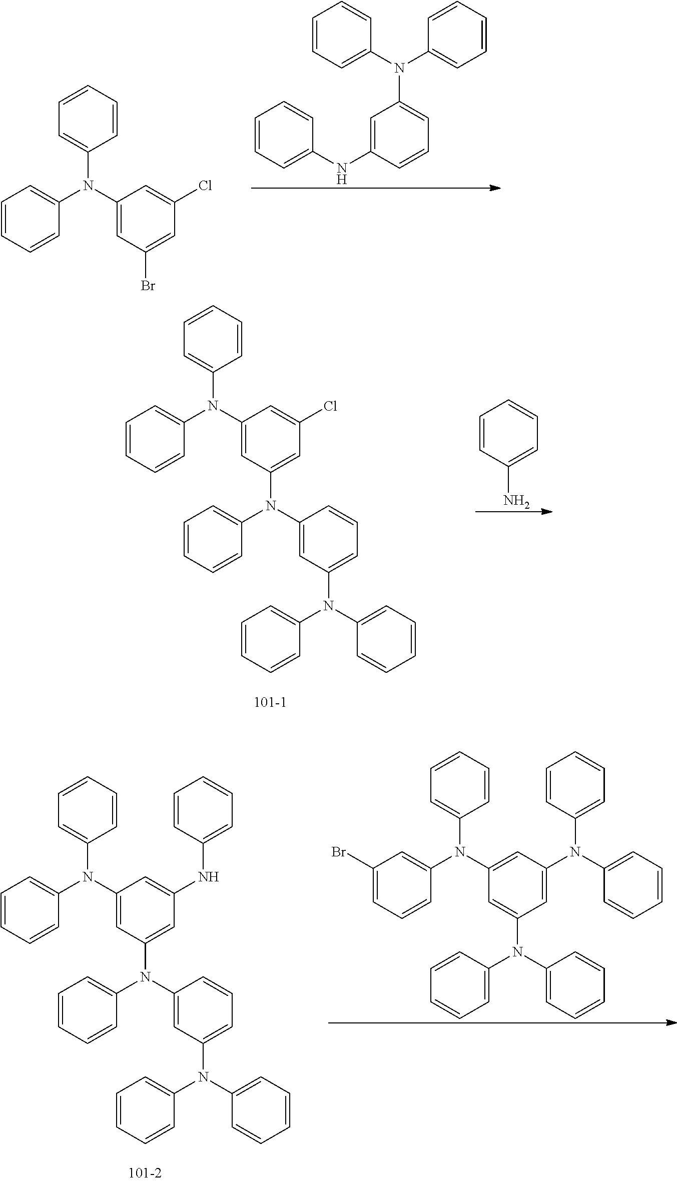 [SMILES: Clc1cc(Br)cc(N(c2ccccc2)c2ccccc2)c1 ; c1ccc(Nc2cccc(N(c3ccccc3)c3ccccc3)c2)cc1 ; Clc1cc(N(c2ccccc2)c2ccccc2)cc(N(c2ccccc2)c2cccc(N(c3ccccc3)c3ccccc3)c2)c1 ; Nc1ccccc1 ; c1ccc(Nc2cc(N(c3ccccc3)c3ccccc3)cc(N(c3ccccc3)c3cccc(N(c4ccccc4)c4ccccc4)c3)c2)cc1 ; Brc1cccc(N(c2ccccc2)c2cc(N(c3ccccc3)c3ccccc3)cc(N(c3ccccc3)c3ccccc3)c2)c1]

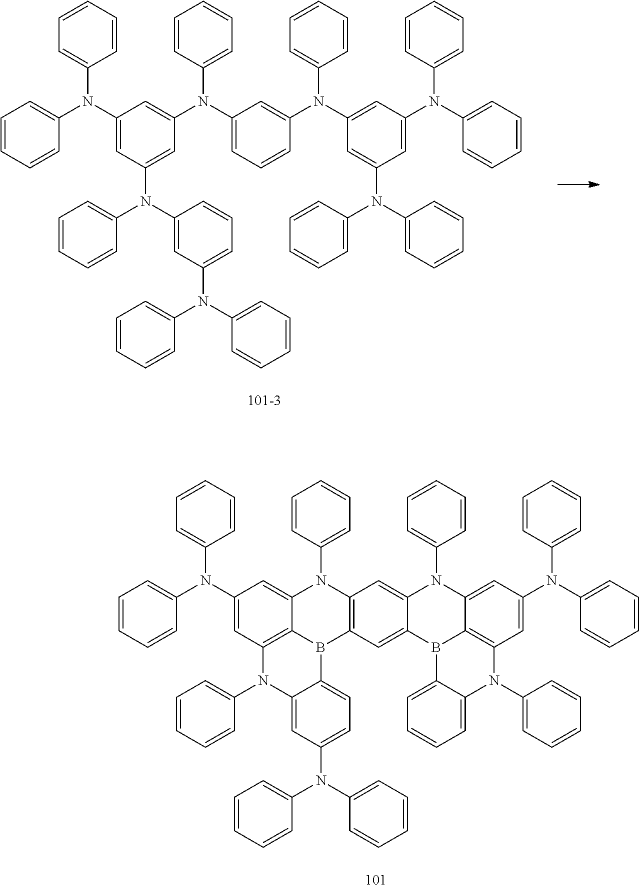 [SMILES: c1ccc(N(c2ccccc2)c2cccc(N(c3ccccc3)c3cc(N(c4ccccc4)c4ccccc4)cc(N(c4ccccc4)c4cccc(N(c5ccccc5)c5cc(N(c6ccccc6)c6ccccc6)cc(N(c6ccccc6)c6ccccc6)c5)c4)c3)c2)cc1 ; c1ccc(N(c2ccccc2)c2ccc3c(c2)N(c2ccccc2)c2cc(N(c4ccccc4)c4ccccc4)cc4c2B3c2cc3c(cc2N4c2ccccc2)N(c2ccccc2)c2cc(N(c4ccccc4)c4ccccc4)cc4c2B3c2ccccc2N4c2ccccc2)cc1]

### 6-1) Synthesis of Intermediate 101-1

3-bromo-5-chloro-N,N-diphenylaniline (1 eq), N1,N1,N3-triphenylbenzene-1,3-diamine (1 eq), tris(dibenzylideneacetone)dipalladium(0) (0.05 eq), tri-tert-butylphosphine (0.1 eq), and sodium tert-butoxide (3 eq) were dissolved in toluene and then the resultant mixture was stirred at 90° C. for 12 hours. After cooling, the resultant product was washed three times with ethyl acetate and water, and then separated to obtain an organic layer. The obtained organic layer was dried with MgSO₄, and then dried at reduced pressure. Intermediate 101-1 was obtained by column chromatography (yield: 75%).

### 6-2) Synthesis of Intermediate 101-2

Intermediate 101-1 (1 eq), aniline (1.5 eq), tris(dibenzylideneacetone)dipalladium(0) (0.05 eq), tri-tert-butylphosphine (0.1 eq), and sodium tert-butoxide (3 eq) were dissolved in o-xylene and then the resultant mixture was stirred at 140° C. for 12 hours. After cooling, the solvent was dried at reduced pressure, the resultant product was washed three times with ethyl acetate and water, and then subjected to liquid separation to obtain an organic layer. The obtained organic layer was dried with MgSO₄, and then dried at reduced pressure. Intermediate 101-2 was obtained by column chromatography (yield: 70%).

### 6-3) Synthesis of Intermediate 101-3

Intermediate 101-3 was synthesized in substantially the same manner as the synthesis of Intermediate 29-3 by using Intermediate 101-2 and N1-(3-bromophenyl)-N1,N3, N3,N5, N5-pentaphenylbenzene-1,3,5-triamine (yield: 72%)

### 6-4) Synthesis of Compound 101

Compound 101 was synthesized in substantially the same manner as the synthesis of Compound 1 by using Intermediate 101-3 instead of Intermediate 1-3 (yield: 11%)

NMR and MS/FAB values of Compounds 1, 11, 29, 61, 69, and 101 are listed in Table 1 below:

TABLE 1

| | | MS/FAB | |
|---|---|---|---|
| Compound | H NMR (δ) | Calc | Found |
| 1 | 10.5 (1H, s), 9.31 (1H, d), 9.30 (1H, d), | 1189.05 | 1189.04 |
| | 7.47-7.38(5H, m), 7.34-7.28(3H, m), 7.19-7.12 | | |
| | (18H, m), | | |
| | 7.03 (4H, m), 6.94-6.83 (20H, m), 5.91-5.73(5H, | | |
| | m) | | |
| 11 | 10.4 (1H, s), 9.32 (1H, d), 9.28 (1H, d), | 1203.03 | 1203.02 |
| | 7.47-7.38(5H, m), 7.30-7.25(3H, m), 7.22-7.11 | | |
| | (18H, m), | | |
| | 7.04 (3H, m), 6.92-6.81 (19H, m), 5.90-5.72(5H, | | |
| | m) | | |
| 29 | 10.5 (1H, s), 9.36 (1H, d), 9.34 (1H, d), | 1111.92 | 1111.91 |
| | 8.11-8.09(1H, m), 7.32-7.25(3H, m), 7.21-7.12 | | |
| | (17H, m), | | |
| | 7.02 (4H, m), 6.93-6.83 (18H, m), 5.91-5.73(5H, | | |
| | m) | | |
| 61 | 10.5 (1H, s), 9.30(1H, d), 9.25 (1H, d), | 1189.05 | 1189.04 |
| | 7.47-7.38(10H, m), 7.34-7.21(3H, m), 7.17-7.10 | | |
| | (16H, m), | | |
| | 7.05 (10H, m), 6.93-6.83 (11H, | | |
| | m), 5.89-5.73(5H, m) | | |
| 69 | 10.5 (1H, s), 9.30(1H, d), 9.26 (1H, d), 8.10 (1H, | 1187.03 | 1187.02 |
| | m), 7.47-7.38(10H, m), 7.32-7.21(3H, m), | | |
| | 7.21-7.12 (15H, m), 7.07 (9H, m), 6.95-6.86 | | |
| | (10H, m), 5.89-5.73(5H, m) | | |
| 101 | 10.4 (1H, s), 9.29 (1H, d), 9.22 (1H, | 1264.16 | 1264.15 |
| | d), 7.47-7.38(10H, m), 7.31-7.20(3H, | | |
| | m), 7.19-7.12 (18H, m), | | |
| | 7.06 (4H, m), 6.98-6.84 (20H, m), 5.86-5.71(5H, | | |
| | m) | | |

### 2. Manufacture and Evaluation of Organic Electroluminescence Device Including Fused Polycyclic Compound

The evaluation of emission characteristics of the fused polycyclic compound of an embodiment and the organic electroluminescence device of an embodiment including the fused polycyclic compound of an embodiment in the emission layer were conducted as follows. The compounds used in the evaluation are shown in below.

### Example Compounds

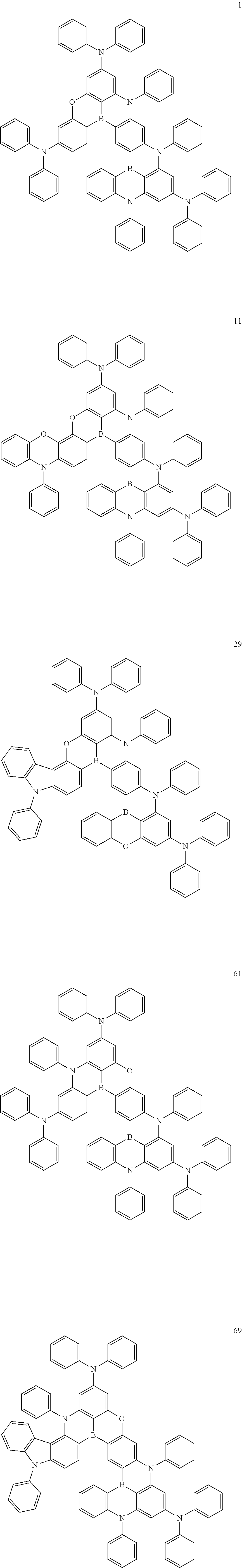

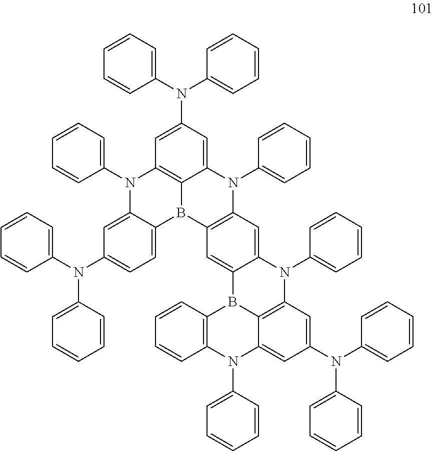 [SMILES: c1ccc(N(c2ccccc2)c2ccc3c(c2)N(c2ccccc2)c2cc(N(c4ccccc4)c4ccccc4)cc4c2B3c2cc3c(cc2N4c2ccccc2)N(c2ccccc2)c2cc(N(c4ccccc4)c4ccccc4)cc4c2B3c2ccccc2N4c2ccccc2)cc1]

### Comparative Example Compounds

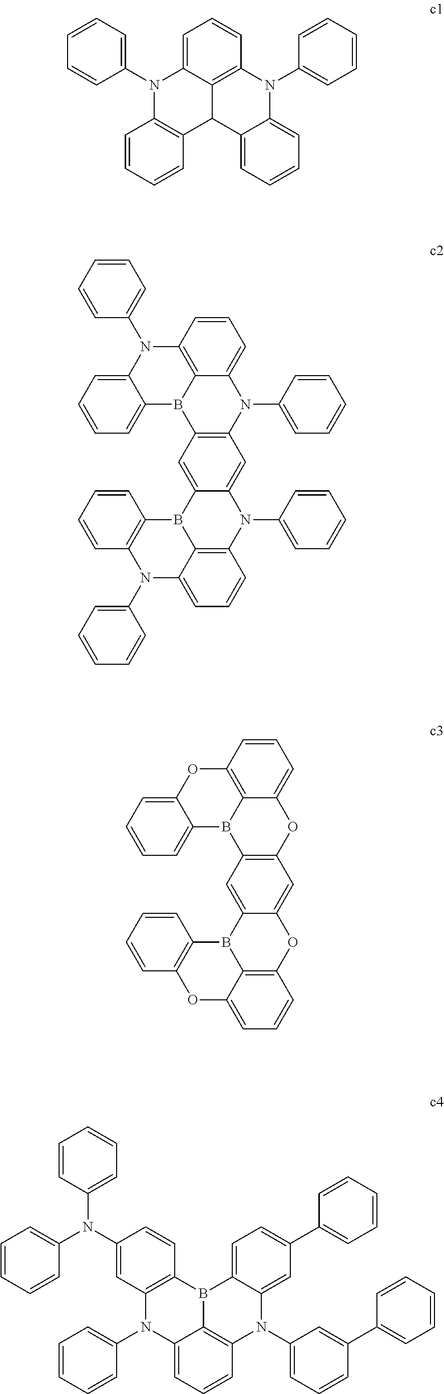 [SMILES: c1ccc(N2c3ccccc3C3c4ccccc4N(c4ccccc4)c4cccc2c43)cc1 ; c1ccc(N2c3ccccc3B3c4cc5c(cc4N(c4ccccc4)c4cccc2c43)N(c2ccccc2)c2cccc3c2B5c2ccccc2N3c2ccccc2)cc1 ; c1ccc2c(c1)Oc1cccc3c1B2c1cc2c(cc1O3)Oc1cccc3c1B2c1ccccc1O3 ; c1ccc(-c2cccc(N3c4cc(-c5ccccc5)ccc4B4c5ccc(N(c6ccccc6)c6ccccc6)cc5N(c5ccccc5)c5cccc3c54)c2)cc1]

Examples 1 to 6 correspond to the organic electroluminescence devices manufactured by using Compounds 1, 11, 29, 61, 69, and 101 as described above as a luminescent material, respectively.

Comparative Examples 1 to 4 correspond to the organic electroluminescence devices manufactured by using Comparative Example Compounds c1, c2, c3, and c4 as a luminescent material, respectively.

The method for manufacturing the organic electroluminescence device for the evaluation of the device is described below.

### Manufacture of Organic Electroluminescence Device

An ITO glass substrate of about 15 Ω/cm² (about 1,200 Å) made by Corning Co. was cut to a size of 50 mm×50 mm×0.7 mm, cleansed by ultrasonic waves using isopropyl alcohol and pure water for about 10 minutes, and then irradiated with ultraviolet rays for about 10 minutes and exposed to ozone and cleansed. The glass substrate was installed on a vacuum deposition apparatus.

On the glass substrate, an existing compound, NPD, was deposited in vacuum to form a 300 Å-thick hole injection layer, and then TCTA as a hole transporting compound was deposited in vacuum to form a 200 Å-thick hole transport layer. Then, CzSi as a hole transport layer compound was deposited in vacuum to a thickness of about 100 Å to form a hole transport region.

On the layer, Host A and Host B were co-deposited to a weight ratio of about 5:5, and at substantially the same time Example Compounds or Comparative Example Compounds were co-deposited to form a 200 Å-thick emission layer so that the weight ratio of Host A and Host B to Example Compounds or Comparative Example Compounds was about 99:1. That is, in Examples 1 to 6, Host A and Host B, and Example Compounds were co-deposited to a weight ratio of about 99:1 to form an emission layer, and in Comparative Examples 1 to 4, Host A and Host B, and Comparative Example Compounds were co-deposited to a weight ratio of about 99:1 to form an emission layer. Host A has a structure including a carbazole skeleton, and Host B has a structure including a triazine skeleton.

The emission layer was formed by using Compound 1, Compound 11, Compound 29, Compound 61, Compound 69, and Compound 101, which are Example Compounds, in Example 1 to Example 6, respectively, and by using Comparative Example Compound c1, Comparative Example Compound c2, Comparative Example Compound c3, and Comparative Example Compound c4 in Comparative Example 1 to Comparative Example 4, respectively.

On the emission layer, TSPO1 as an electron transport layer compound was formed to a thickness of about 200 Å, and then TPBI as an electron injection layer compound was deposited to a thickness of about 300 Å. LiF, which is an alkaline metal halide, was deposited on the upper portion of the electron transport layer to form a 10 Å-thick electron injection layer, and Al was deposited in vacuum to form a 3,000 Å-thick LiF/Al electrode (negative electrode), thereby manufacturing an organic electroluminescence device.

Compounds used in the manufacture of the organic electroluminescence devices are as follows.

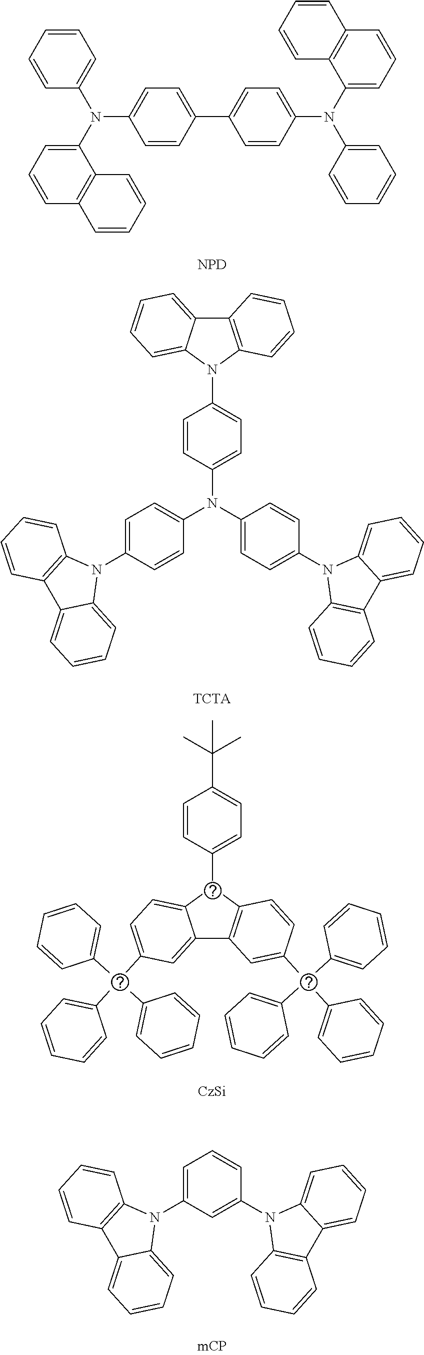

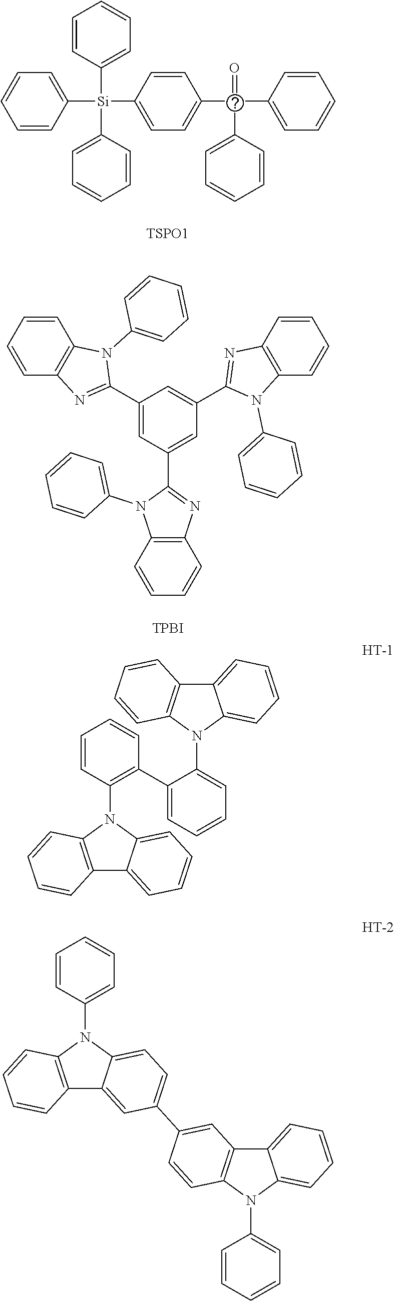

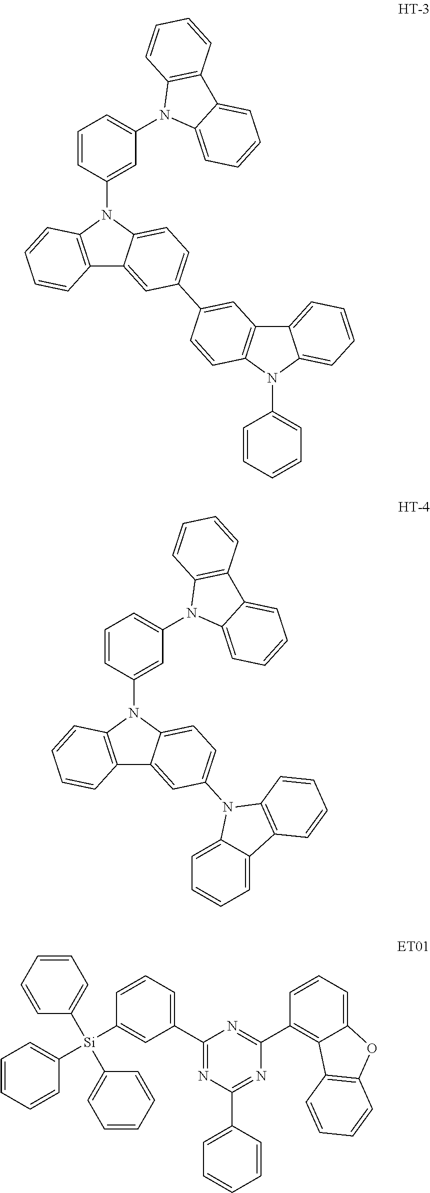 [SMILES: c1ccc(-n2c3ccccc3c3cc(-c4ccc5c(c4)c4ccccc4n5-c4cccc(-n5c6ccccc6c6ccccc65)c4)ccc32)cc1 ; c1cc(-n2c3ccccc3c3ccccc32)cc(-n2c3ccccc3c3cc(-n4c5ccccc5c5ccccc54)ccc32)c1 ; c1ccc(-c2nc(-c3cccc([Si](c4ccccc4)(c4ccccc4)c4ccccc4)c3)nc(-c3cccc4oc5ccccc5c34)n2)cc1]

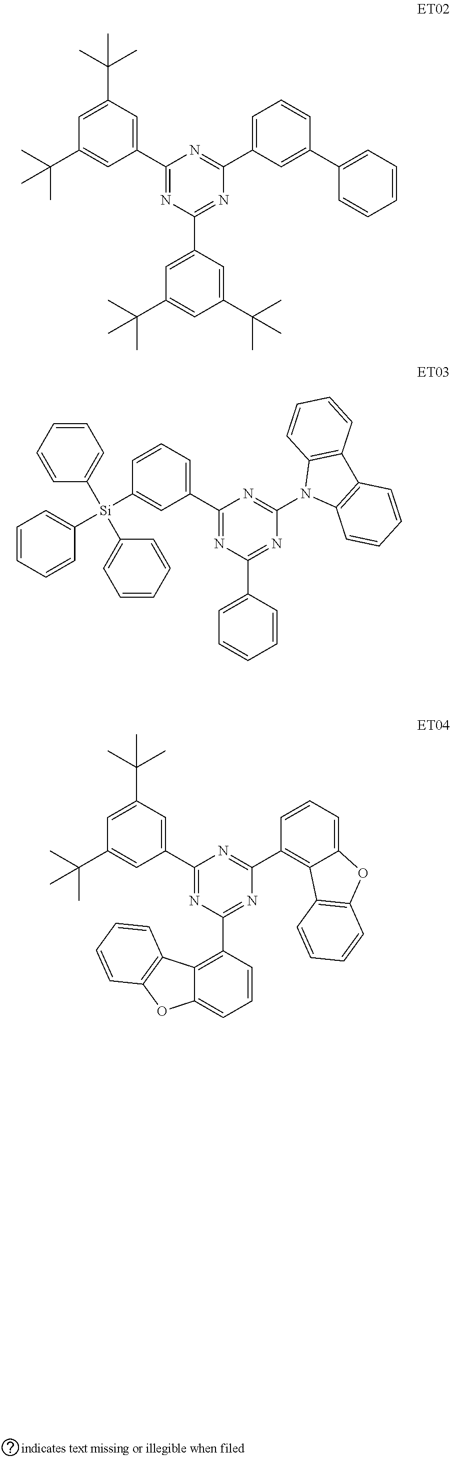 [SMILES: CC(C)(C)c1cc(-c2nc(-c3cccc(-c4ccccc4)c3)nc(-c3cc(C(C)(C)C)cc(C(C)(C)C)c3)n2)cc(C(C)(C)C)c1 ; c1ccc(-c2nc(-c3cccc([Si](c4ccccc4)(c4ccccc4)c4ccccc4)c3)nc(-n3c4ccccc4c4ccccc43)n2)cc1 ; CC(C)(C)c1cc(-c2nc(-c3cccc4oc5ccccc5c34)nc(-c3cccc4oc5ccccc5c34)n2)cc(C(C)(C)C)c1]

### Evaluation of Energy Level of Compounds

Table 2 shows a lowest triplet exciton energy level (T1 energy level), a lowest singlet exciton energy level (S1 energy level), and an energy difference (ΔE_{ST}) between an S1 energy level and a T1 energy level with respect to the compounds of Examples 1 to 6 and Comparative Examples 1 to 4 below:

TABLE 2

| | Dopant | T1 energy | S1 energy | |
|---|---|---|---|---|
| Division | Material | level | level | ΔE_{ST} |
| Example 1 | Example | 2.62 | 2.70 | 0.08 |
| | Compound 1 | | | |
| Example 2 | Example | 2.60 | 2.68 | 0.08 |
| | Compound 11 | | | |
| Example 3 | Example | 2.63 | 2.71 | 0.08 |
| | Compound 29 | | | |
| Example 4 | Example | 2. 65 | 2.69 | 0.04 |
| | Compound 61 | | | |
| Example 5 | Example | 2.62 | 2.68 | 0.06 |
| | Compound 69 | | | |
| Example 6 | Example | 2.63 | 2.70 | 0.07 |
| | Compound 101 | | | |
| Comparative | Comparative | 2.55 | 2.73 | 0.18 |
| Example 1 | Example | | | |
| | Compound c1 | | | |
| Comparative | Comparative | 2.48 | 2.62 | 0.14 |
| Example 2 | Example | | | |
| | Compound c2 | | | |
| Comparative | Comparative | 2.70 | 2.90 | 0.2 |
| Example 3 | Example | | | |
| | Compound c3 | | | |
| Comparative | Comparative | 2.47 | 2.64 | 0.17 |
| Example 4 | Example | | | |
| | Compound c4 | | | |

Referring to the results of Table 2, the compounds of Examples 1 to 6 have a higher average value of a T1 energy level than that of the compounds of Comparative Examples 1 to 4.

The compounds of Examples 1 to 6 have a LEST value of about 0.8 eV or less, and the compounds of Comparative Examples 1 to 4 have a LEST value of about 0.14 eV to about 0.2 eV. From this, it is believed that the compounds of Examples 1 to 6 and Comparative Examples 1 to 4 may be used as a thermally activated delayed fluorescence dopant.

In addition, it can be seen that the compounds of Examples 1 to 6 have a higher T1 energy level and a lower LEST value than the compounds of Comparative Examples 1 to 4, and thus, if applied to the emission layer, may exhibit higher luminous efficiency than the compounds of Comparative Examples 1 to 4.

### Evaluation Example of Organic Electroluminescence Device

The luminous efficiency of the organic electroluminescence devices manufactured with the above-described Example Compounds, i.e., Compound 1, Compound 11, Compound 29, Compound 61, Compound 69, and Compound 101, and Comparative Example Compounds, i.e., Comparative Example Compound c1, Comparative Example Compound c2, Comparative Example Compound c3, and Comparative Example Compound c4, was evaluated. The evaluation results are shown in Tables 3 and Table 4 below.

In Table 3, Host A and Host B were used as hosts of the emission layer in the organic electroluminescence devices of Examples A to F and Comparative Examples A to D.

In the organic electroluminescence devices of Examples A to F, the respective Example Compound, i.e., Compound 1, Compound 11, Compound 29, Compound 61, Compound 69, or Compound 101 was used as a dopant of the emission layer.

In the organic electroluminescence devices of Comparative Examples A to D, the respective Comparative Example Compound, i.e., Comparative Example Compound c1, Comparative Example Compound c2, Comparative Example Compound c3, or Comparative Example Compound c4 was used as a dopant of the emission layer.

TABLE 3

| | | | | | | Maximum | |
|---|---|---|---|---|---|---|---|
| | | | | Driving | | quantum | Luminous |
| | | | | voltage | Efficiency | efficiency | wavelength |
| Division | Host A | Host B | Dopant | (V) | (Cd/A) | (%) | (nm) |
| Example A | HT-1 | ET01 | Compound 1 | 4.3 | 24.2 | 22.6 | 462 |
| Example B | HT-1 | ET02 | Compound 11 | 4.4 | 24.8 | 22.2 | 464 |
| Example C | HT-2 | ET01 | Compound 29 | 4.5 | 25.0 | 23.1 | 464 |
| Example D | HT-2 | ET02 | Compound 61 | 4.3 | 23.3 | 22.8 | 461 |
| Example E | HT-1 | ET02 | Compound 69 | 4.4 | 24.9 | 23.2 | 465 |
| Example F | HT-2 | ET01 | Compound 101 | 4.3 | 25.1 | 23.3 | 461 |
| Comparative | HT-1 | ET01 | Comparative | 5.4 | 14.2 | 14.1 | 461 |
| Example A | | | Example | | | | |
| | | | Compound c1 | | | | |
| Comparative | HT-2 | ET01 | Comparative | 5.3 | 19.3 | 19.0 | 462 |
| Example B | | | Example | | | | |
| | | | Compound c2 | | | | |
| Comparative | HT-1 | ET02 | Comparative | 5.6 | 19.2 | 18.9 | 463 |
| Example C | | | Example | | | | |
| | | | Compound c3 | | | | |
| Comparative | HT-2 | ET01 | Comparative | 5.5 | 18.6 | 18.6 | 461 |
| Example D | | | Example | | | | |
| | | | Compound c4 | | | | |

Referring to the results of Table 3, it can be seen that the organic electroluminescence devices of Examples A to F emit light in a blue wavelength region in a range of about 460 nm to about 465 nm, and have a driving voltage of about 4.5 V or less, efficiency of about 23.3 Cd/A or more, and a maximum quantum efficiency of about 22.2% to about 23.3%. The organic electroluminescence devices of Comparative Examples A to D emit light in a blue wavelength region in a range of about 460 nm to about 465 nm, and have a driving voltage of about 5.3 V or more, efficiency of about 19.3 Cd/A or less, and a maximum quantum efficiency of about 14.1% to about 19.0%. That is, compared to the organic electroluminescence devices of Examples, the organic electroluminescence devices of Comparative Examples A to D have higher driving voltage, lower efficiency, and lower maximum quantum efficiency values.

The organic electroluminescence devices of the present disclosure may have lower driving voltage, higher luminous efficiency, and higher maximum quantum efficiency compared to Comparative Example compounds by including Example Compounds in the emission layer.

In Table 4, either Host A or Host B was used as a host of the emission layer in the organic electroluminescence devices of Examples A-1 to E-1 and Comparative Examples A-1 to E-1.

In the organic electroluminescence devices of Examples A-1 to E-1, the respective Example Compound, i.e., Compound 1, Compound 11, Compound 29, Compound 61, or Compound 101 was used as a dopant of the emission layer.

In the organic electroluminescence devices of Comparative Examples A-1 to E-1, the respective Comparative Example Compound, i.e., Comparative Example Compound c1, Comparative Example Compound c2, Comparative Example Compound c3, or Comparative Example Compound c4 was used as a dopant of the emission layer.

In the organic electroluminescence device of Comparative Example F-1, Comparative Example Compound CBP below was used as a host of the emission layer and Example Compound 1 was used as a dopant of the emission layer.

TABLE 4

| | | | | | | Maximum | |
|---|---|---|---|---|---|---|---|
| | | | | Driving | | quantum | Luminous |
| | | | | voltage | Efficiency | efficiency | wavelength |
| Division | Host A | Host B | Dopant | (V) | (cd/A) | (%) | (nm) |
| Example A-1 | HT-1 | — | Compound 1 | 5.0 | 16.6 | 15.5 | 463 |
| Example B-1 | — | ET01 | Compound 11 | 5.1 | 16.5 | 14.8 | 464 |
| Example C-1 | HT-2 | — | Compound 29 | 5.1 | 16.1 | 15.0 | 462 |
| Example D-1 | — | ET02 | Compound 61 | 5.0 | 15.7 | 15.1 | 463 |
| Example E-1 | HT-1 | — | Compound 101 | 5.2 | 15.4 | 14.4 | 464 |
| Comparative | HT-1 | — | Comparative | 5.8 | 12.2 | 10.6 | 462 |
| Example A-1 | | | Example | | | | |
| | | | Compound c1 | | | | |
| Comparative | — | ET01 | Comparative | 5.7 | 14.4 | 12.8 | 468 |
| Example B-1 | | | Example | | | | |
| | | | Compound c2 | | | | |
| Comparative | HT-2 | — | Comparative | 5.8 | 14.6 | 12.9 | 467 |
| Example C-1 | | | Example | | | | |
| | | | Compound c3 | | | | |
| Comparative | — | ET02 | Comparative | 5.7 | 14.1 | 11.9 | 468 |
| Example D-1 | | | Example | | | | |
| | | | Compound c2 | | | | |
| Comparative | HT-1 | — | Comparative | 5.8 | 13.2 | 12.4 | 464 |
| Example E-1 | | | Example | | | | |
| | | | Compound c4 | | | | |

| | | | | | | |
|---|---|---|---|---|---|---|
| Comparative | CBP | Compound 1 | 5.9 | 10.9 | 9.2 | 462 |
| Example F-1 | | | | | | |

Comparative Example Compound CBP, which was used as a host in Comparative Example F-1 of Table 4, is as follows.

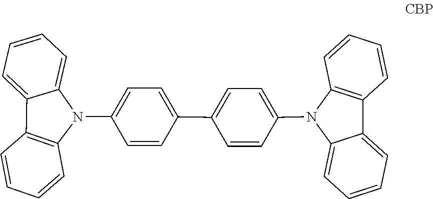 [SMILES: c1ccc2c(c1)c1ccccc1n2-c1ccc(-c2ccc(-n3c4ccccc4c4ccccc43)cc2)cc1]

Referring to the results of Table 4, it can be seen that the organic electroluminescence devices of Examples A-1 to E-1 emit light in a blue wavelength region in a range of about 460 nm to about 464 nm, and have a driving voltage of about 5.2 V or less, efficiency of about 15.4 Cd/A or more, and maximum quantum efficiency of about 14.4% to about 15.5%.

The organic electroluminescence devices of Comparative Examples A-1 to E-1 emit light in a blue wavelength region in a range of about 462 nm to about 468 nm, and have a driving voltage of about 5.7 V or more, efficiency of about 14.6 Cd/A or less, and maximum quantum efficiency in a range of about 10.6% to about 12.9%.

The organic electroluminescence devices of Comparative Examples A-1 to E-1 may have higher driving voltage, lower efficiency, and lower maximum quantum efficiency values compared to the organic electroluminescence devices of the Examples by including the Comparative Example Compounds as a dopant of the emission layer.

The organic electroluminescence device of Comparative Example F-1 emits light in a blue wavelength region of about 462 nm, and has a driving voltage of about 5.9 V, efficiency of about 10.9 Cd/A, and a maximum quantum efficiency of about 9.2%.

The organic electroluminescence devices of Comparative Examples F-1 may have higher driving voltage, lower efficiency, and lower maximum quantum efficiency values compared to the organic electroluminescence devices of the Examples by including the Example Compounds as a dopant of the emission layer but including CBP as a host of the emission layer.

The organic electroluminescence devices of the present disclosure may have lower driving voltage, higher luminous efficiency, and higher maximum quantum efficiency values compared to existing compounds by including the Example Compounds in the emission layer.

The organic electroluminescence device of an embodiment may have improved efficiency.

The fused polycyclic compounds of an embodiment may be included in the emission layer of the organic electroluminescence device to contribute to the high efficiency of the organic electroluminescence device.

Although the subject matter of the present disclosure has been described with reference to example embodiments of the present disclosure, it will be understood that the present disclosure should not be limited to the disclosed embodiments but various changes and modifications can be made by those skilled in the art without departing from the spirit and scope of the present disclosure.

Accordingly, the technical scope of the present disclosure is not intended to be limited to the contents set forth in the detailed description of the specification, but is intended to be defined by the appended claims, and equivalents thereof.

1. An organic electroluminescence device comprising:
a first electrode;
a second electrode facing the first electrode; and
a plurality of organic layers between the first electrode and the second electrode,
wherein at least one organic layer selected from among the organic layers comprises a fused polycyclic compound represented by Formula 1 below, and at least any one of a compound represented by Formula A and a compound represented by Formula B below: 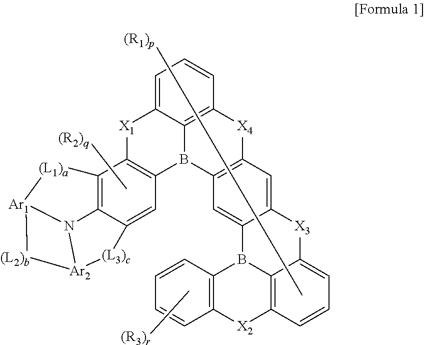
wherein, in Formula 1 above,
X₁, X₂, X₃, and X₄ are each independently NAr₃, O, or S,
Ar₁ to Ar₃ are each independently a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or are bonded to an adjacent group to form a ring,
R₁ to R₃ are each independently a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms,
p is an integer in a range of 0 to 8,
q is 0 or 1,
r is an integer in a range of 0 to 4,
L₁ to L₃ are each independently a direct linkage, *—O—*, *—S—*, *—Si(R₁₁R₁₂)—*, *—CR₁₃R₁₄—*, or *—(CR₁₅)(CR₁₆)—*,
R₁₁ to R₁₆ are each independently a deuterium atom, a halogen atom, a cyano group, a substituted or unsubstituted alkyl group having 1 to 20 carbon atoms,
a, b, and c are each independently 0 or 1, 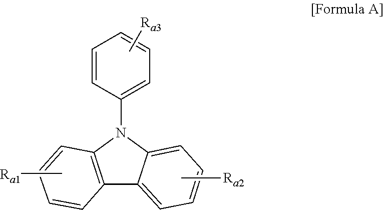
wherein, in Formula A above, Rₐ₁ to Rₐ₃ are each independently a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and 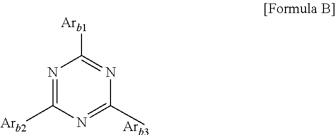
wherein, in Formula B above, Ar_{b1} to Ar_{b3} are each independently a substituted or unsubstituted aryl group having 6 to 30 ring-forming carbon atoms, or a substituted or unsubstituted heteroaryl group having 2 to 30 ring-forming carbon atoms.

2. The organic electroluminescence device of claim 1, wherein the fused polycyclic compound represented by Formula 1 above is represented by any one selected from among Formula 1-1 to Formula 1-3 below: 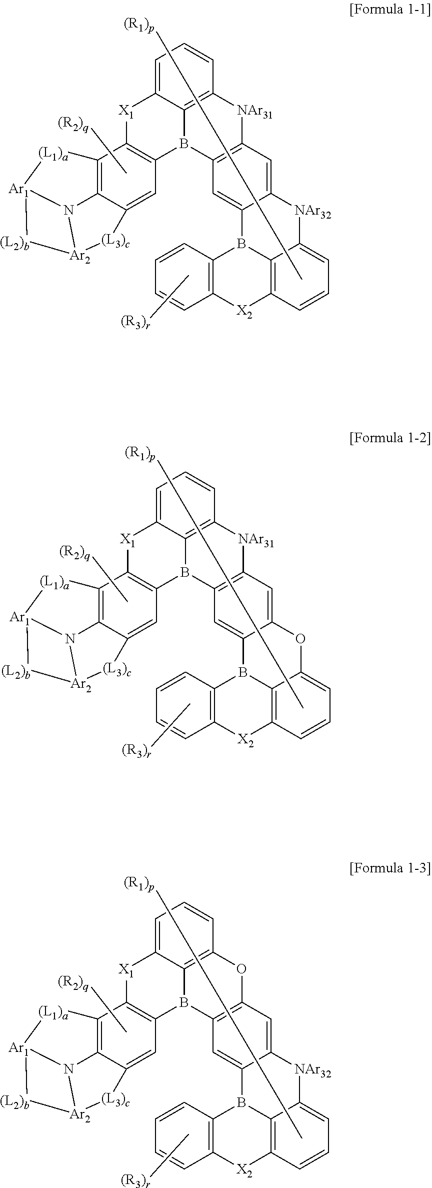
wherein, in Formula 1-1 to Formula 1-3 above,
Ar₃₁ and Ar₃₂ are each independently a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or are bonded to an adjacent group to form a ring,
X₁, X₂, Ar₁, Ar₂, L₁ to L₃, R₁ to R₃, a, b, c, p, q, and r above are the same as defined with respect to Formula 1.

3. The organic electroluminescence device of claim 1, wherein the fused polycyclic compound represented by Formula 1 above is represented by Formula 2-1 or Formula 2-2 below: 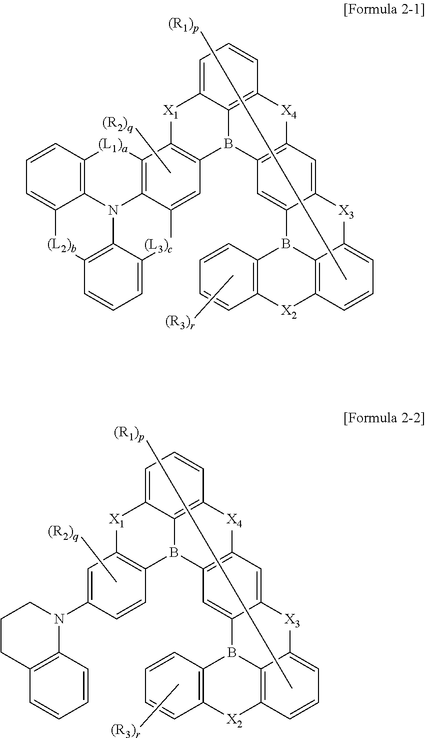
wherein, in Formula 2-1 and Formula 2-2 above,
X₁ to X₄, L₁ to L₃, R₁ to R₃, a, b, c, p, q, and r above are the same as defined with respect to Formula 1.

4. The organic electroluminescence device of claim 1, wherein the fused polycyclic compound represented by Formula 1 above is represented by Formula 3 below: 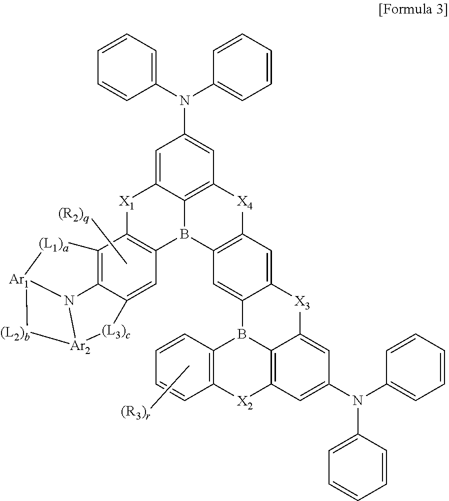
wherein, in Formula 3 above,
X₁ to X₄, Ar₁, Ar₂, L₁ to L₃, R₂, R₃, a, b, c, q, and r above are the same as defined with respect to Formula 1.

5. The organic electroluminescence device of claim 1, wherein X₁ to X₄ above are each independently NAr₃ or O.

6. The organic electroluminescence device of claim 1, wherein R₂ and R₃ are each independently a hydrogen atom or a deuterium atom.

7. The organic electroluminescence device of claim 1, wherein:
the organic layers comprise a hole transport region, an emission layer, and an electron transport region which are sequentially on the first electrode; and
the emission layer comprises the fused polycyclic compound.

8. The organic electroluminescence device of claim 7, wherein the emission layer emits delayed fluorescence.

9. The organic electroluminescence device of claim 1, wherein at least one organic layer selected from among the organic layers comprises the fused polycyclic compound represented by Formula 1 above, the compound represented by Formula A above, and the compound represented by Formula B above.

10. The organic electroluminescence device of claim 7, wherein the emission layer emits light in a blue wavelength region.

11. The organic electroluminescence device of claim 1, wherein a difference (ΔE_{ST}) value between a lowest triplet exciton energy level (T1 energy level) and a lowest singlet exciton energy level (S1 energy level) of the fused polycyclic compound is about 0.13 eV or less.

12. The organic electroluminescence device of claim 1, wherein the fused polycyclic compound comprises at least one selected from among the compounds represented in Compound Group 1 below:

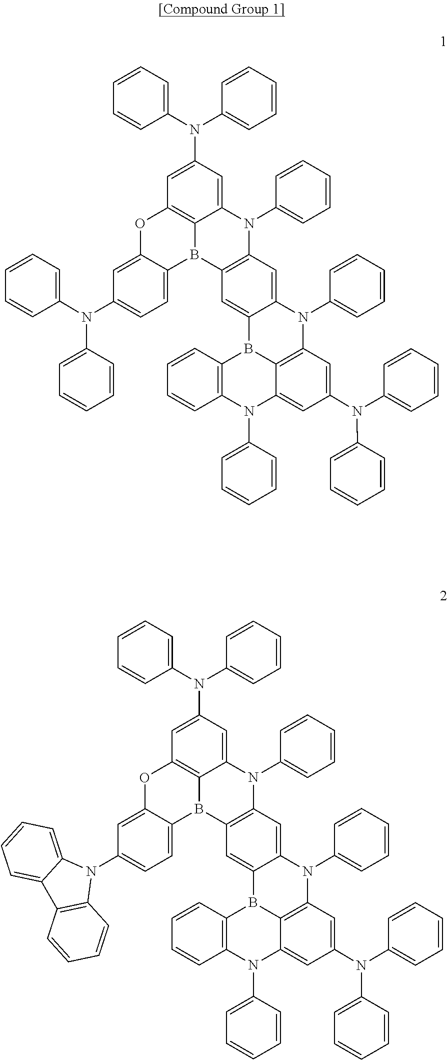 [SMILES: c1ccc(N(c2ccccc2)c2ccc3c(c2)Oc2cc(N(c4ccccc4)c4ccccc4)cc4c2B3c2cc3c(cc2N4c2ccccc2)N(c2ccccc2)c2cc(N(c4ccccc4)c4ccccc4)cc4c2B3c2ccccc2N4c2ccccc2)cc1 ; c1ccc(N(c2ccccc2)c2cc3c4c(c2)N(c2ccccc2)c2cc5c(cc2B4c2ccc(-n4c6ccccc6c6ccccc64)cc2O3)B2c3ccccc3N(c3ccccc3)c3cc(N(c4ccccc4)c4ccccc4)cc(c32)N5c2ccccc2)cc1]

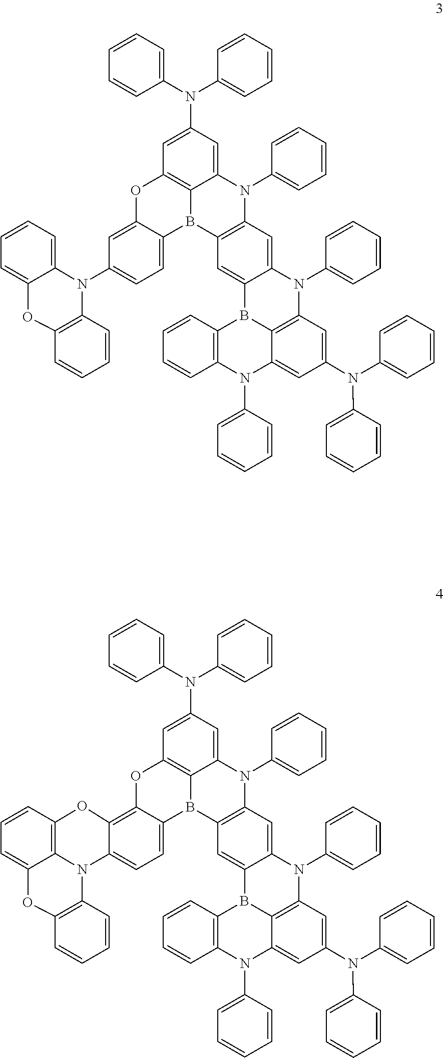 [SMILES: c1ccc(N(c2ccccc2)c2cc3c4c(c2)N(c2ccccc2)c2cc5c(cc2B4c2ccc(N4c6ccccc6Oc6ccccc64)cc2O3)B2c3ccccc3N(c3ccccc3)c3cc(N(c4ccccc4)c4ccccc4)cc(c32)N5c2ccccc2)cc1 ; c1ccc(N(c2ccccc2)c2cc3c4c(c2)N(c2ccccc2)c2cc5c(cc2B4c2ccc4c(c2O3)Oc2cccc3c2N4c2ccccc2O3)B2c3ccccc3N(c3ccccc3)c3cc(N(c4ccccc4)c4ccccc4)cc(c32)N5c2ccccc2)cc1]

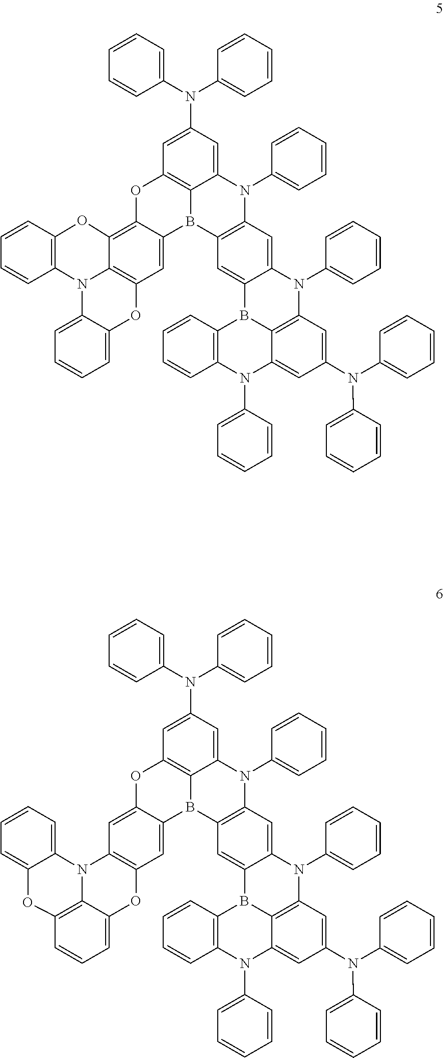 [SMILES: c1ccc(N(c2ccccc2)c2cc3c4c(c2)N(c2ccccc2)c2cc5c(cc2B4c2cc4c6c(c2O3)Oc2ccccc2N6c2ccccc2O4)B2c3ccccc3N(c3ccccc3)c3cc(N(c4ccccc4)c4ccccc4)cc(c32)N5c2ccccc2)cc1 ; c1ccc(N(c2ccccc2)c2cc3c4c(c2)N(c2ccccc2)c2cc5c(cc2B4c2cc4c(cc2O3)N2c3ccccc3Oc3cccc(c32)O4)B2c3ccccc3N(c3ccccc3)c3cc(N(c4ccccc4)c4ccccc4)cc(c32)N5c2ccccc2)cc1]

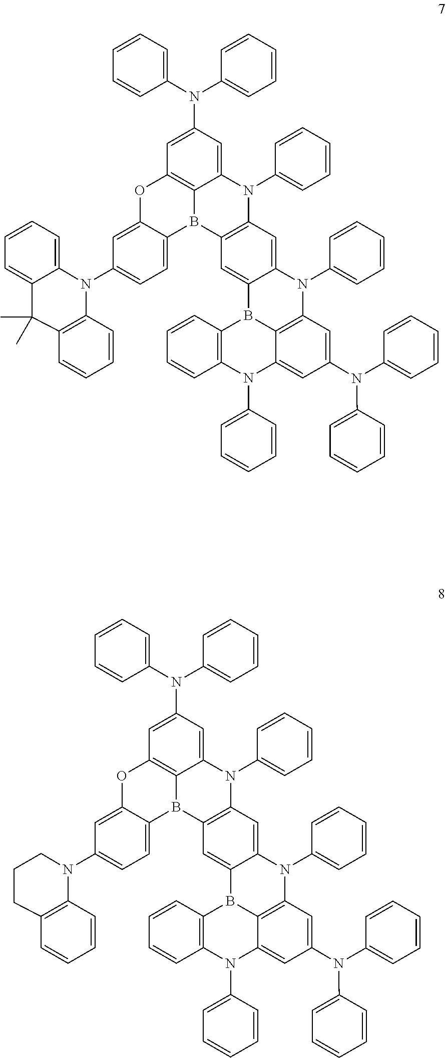 [SMILES: CC1(C)c2ccccc2N(c2ccc3c(c2)Oc2cc(N(c4ccccc4)c4ccccc4)cc4c2B3c2cc3c(cc2N4c2ccccc2)N(c2ccccc2)c2cc(N(c4ccccc4)c4ccccc4)cc4c2B3c2ccccc2N4c2ccccc2)c2ccccc21 ; c1ccc(N(c2ccccc2)c2cc3c4c(c2)N(c2ccccc2)c2cc5c(cc2B4c2ccc(N4CCCc6ccccc64)cc2O3)B2c3ccccc3N(c3ccccc3)c3cc(N(c4ccccc4)c4ccccc4)cc(c32)N5c2ccccc2)cc1]

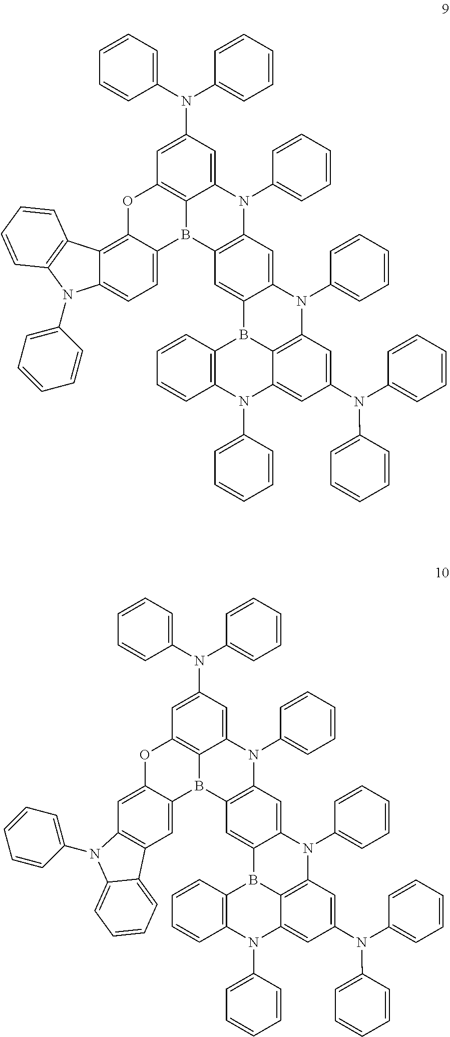 [SMILES: c1ccc(N(c2ccccc2)c2cc3c4c(c2)N(c2ccccc2)c2cc5c(cc2B4c2ccc4c(c2O3)c2ccccc2n4-c2ccccc2)B2c3ccccc3N(c3ccccc3)c3cc(N(c4ccccc4)c4ccccc4)cc(c32)N5c2ccccc2)cc1 ; c1ccc(N(c2ccccc2)c2cc3c4c(c2)N(c2ccccc2)c2cc5c(cc2B4c2cc4c6ccccc6n(-c6ccccc6)c4cc2O3)B2c3ccccc3N(c3ccccc3)c3cc(N(c4ccccc4)c4ccccc4)cc(c32)N5c2ccccc2)cc1]

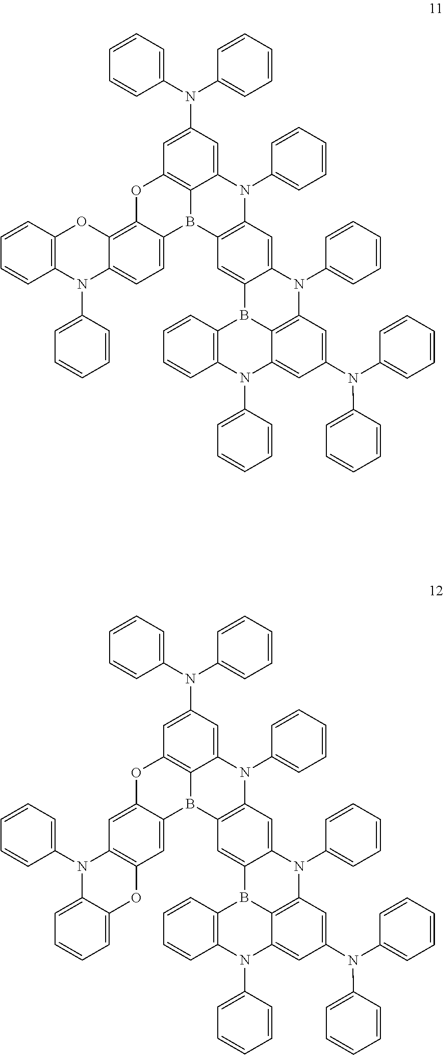 [SMILES: c1ccc(N(c2ccccc2)c2cc3c4c(c2)N(c2ccccc2)c2cc5c(cc2B4c2ccc4c(c2O3)Oc2ccccc2N4c2ccccc2)B2c3ccccc3N(c3ccccc3)c3cc(N(c4ccccc4)c4ccccc4)cc(c32)N5c2ccccc2)cc1 ; c1ccc(N(c2ccccc2)c2cc3c4c(c2)N(c2ccccc2)c2cc5c(cc2B4c2cc4c(cc2O3)N(c2ccccc2)c2ccccc2O4)B2c3ccccc3N(c3ccccc3)c3cc(N(c4ccccc4)c4ccccc4)cc(c32)N5c2ccccc2)cc1]

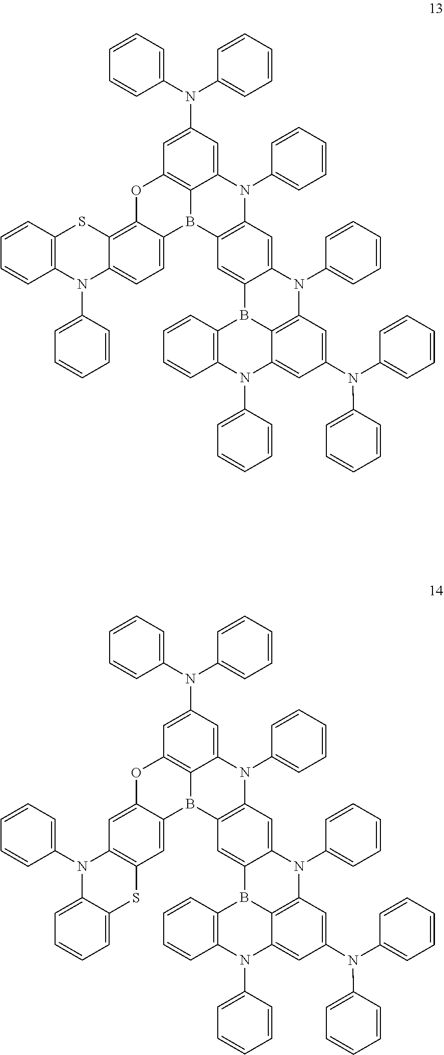 [SMILES: c1ccc(N(c2ccccc2)c2cc3c4c(c2)N(c2ccccc2)c2cc5c(cc2B4c2ccc4c(c2O3)Sc2ccccc2N4c2ccccc2)B2c3ccccc3N(c3ccccc3)c3cc(N(c4ccccc4)c4ccccc4)cc(c32)N5c2ccccc2)cc1 ; c1ccc(N(c2ccccc2)c2cc3c4c(c2)N(c2ccccc2)c2cc5c(cc2B4c2cc4c(cc2O3)N(c2ccccc2)c2ccccc2S4)B2c3ccccc3N(c3ccccc3)c3cc(N(c4ccccc4)c4ccccc4)cc(c32)N5c2ccccc2)cc1]

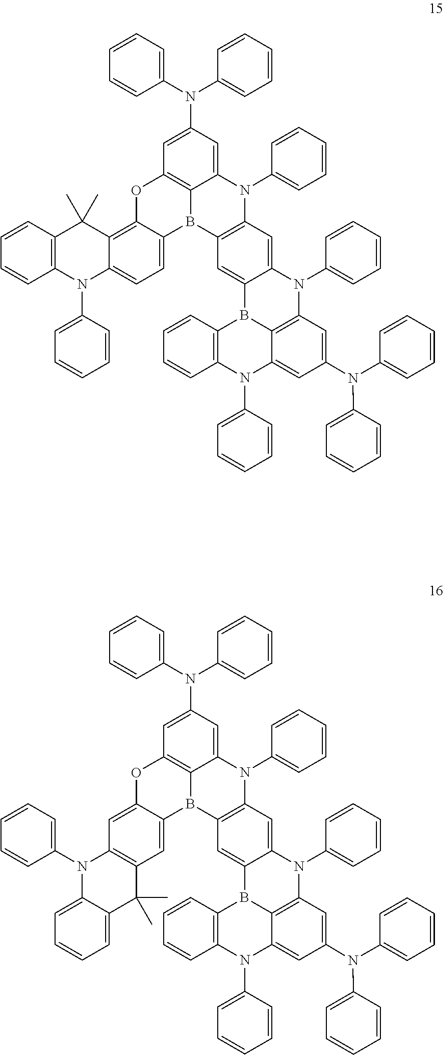 [SMILES: CC1(C)c2ccccc2N(c2ccccc2)c2ccc3c(c21)Oc1cc(N(c2ccccc2)c2ccccc2)cc2c1B3c1cc3c(cc1N2c1ccccc1)N(c1ccccc1)c1cc(N(c2ccccc2)c2ccccc2)cc2c1B3c1ccccc1N2c1ccccc1 ; CC1(C)c2ccccc2N(c2ccccc2)c2cc3c(cc21)B1c2cc4c(cc2N(c2ccccc2)c2cc(N(c5ccccc5)c5ccccc5)cc(c21)O3)N(c1ccccc1)c1cc(N(c2ccccc2)c2ccccc2)cc2c1B4c1ccccc1N2c1ccccc1]

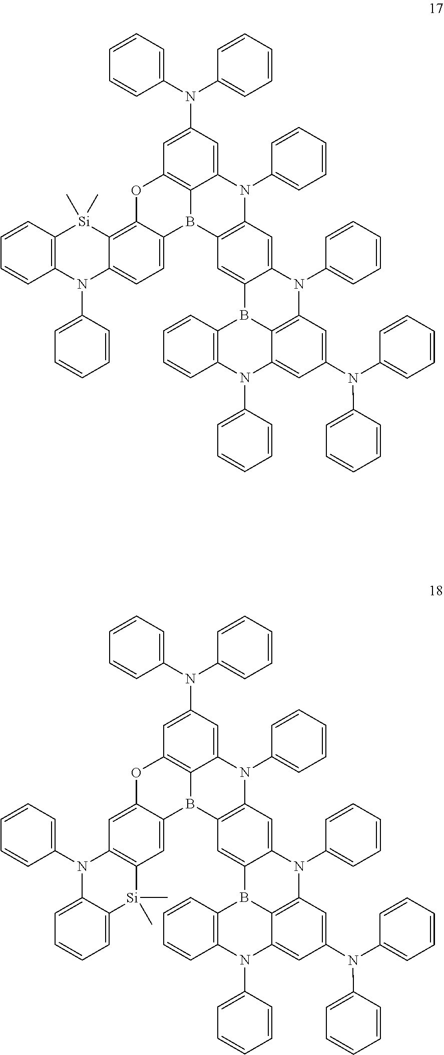 [SMILES: C[Si]1(C)c2ccccc2N(c2ccccc2)c2ccc3c(c21)Oc1cc(N(c2ccccc2)c2ccccc2)cc2c1B3c1cc3c(cc1N2c1ccccc1)N(c1ccccc1)c1cc(N(c2ccccc2)c2ccccc2)cc2c1B3c1ccccc1N2c1ccccc1 ; C[Si]1(C)c2ccccc2N(c2ccccc2)c2cc3c(cc21)B1c2cc4c(cc2N(c2ccccc2)c2cc(N(c5ccccc5)c5ccccc5)cc(c21)O3)N(c1ccccc1)c1cc(N(c2ccccc2)c2ccccc2)cc2c1B4c1ccccc1N2c1ccccc1]

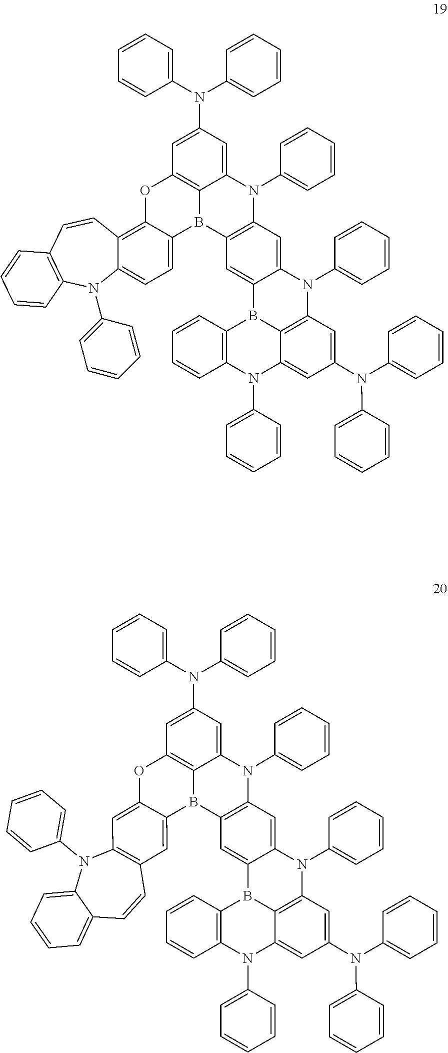 [SMILES: C1=Cc2c(ccc3c2Oc2cc(N(c4ccccc4)c4ccccc4)cc4c2B3c2cc3c(cc2N4c2ccccc2)N(c2ccccc2)c2cc(N(c4ccccc4)c4ccccc4)cc4c2B3c2ccccc2N4c2ccccc2)N(c2ccccc2)c2ccccc21 ; C1=Cc2cc3c(cc2N(c2ccccc2)c2ccccc21)Oc1cc(N(c2ccccc2)c2ccccc2)cc2c1B3c1cc3c(cc1N2c1ccccc1)N(c1ccccc1)c1cc(N(c2ccccc2)c2ccccc2)cc2c1B3c1ccccc1N2c1ccccc1]

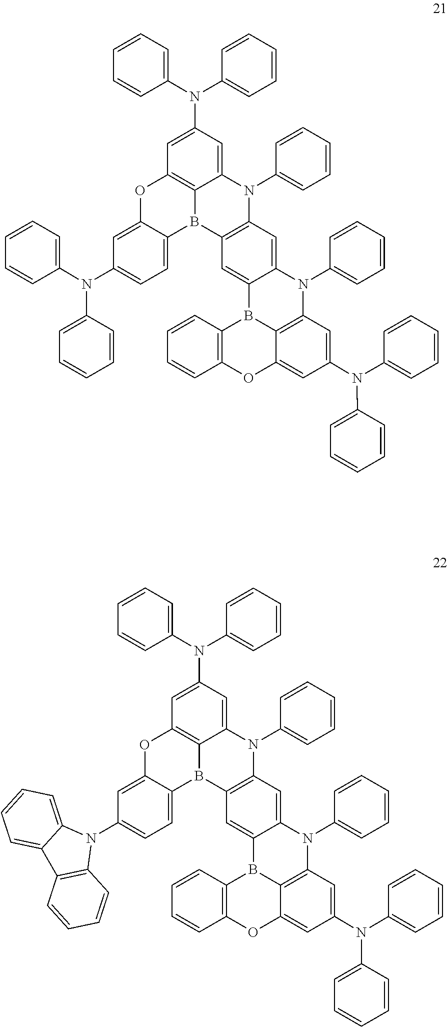 [SMILES: c1ccc(N(c2ccccc2)c2ccc3c(c2)Oc2cc(N(c4ccccc4)c4ccccc4)cc4c2B3c2cc3c(cc2N4c2ccccc2)N(c2ccccc2)c2cc(N(c4ccccc4)c4ccccc4)cc4c2B3c2ccccc2O4)cc1 ; c1ccc(N(c2ccccc2)c2cc3c4c(c2)N(c2ccccc2)c2cc5c(cc2B4c2ccccc2O3)B2c3ccc(-n4c6ccccc6c6ccccc64)cc3Oc3cc(N(c4ccccc4)c4ccccc4)cc(c32)N5c2ccccc2)cc1]

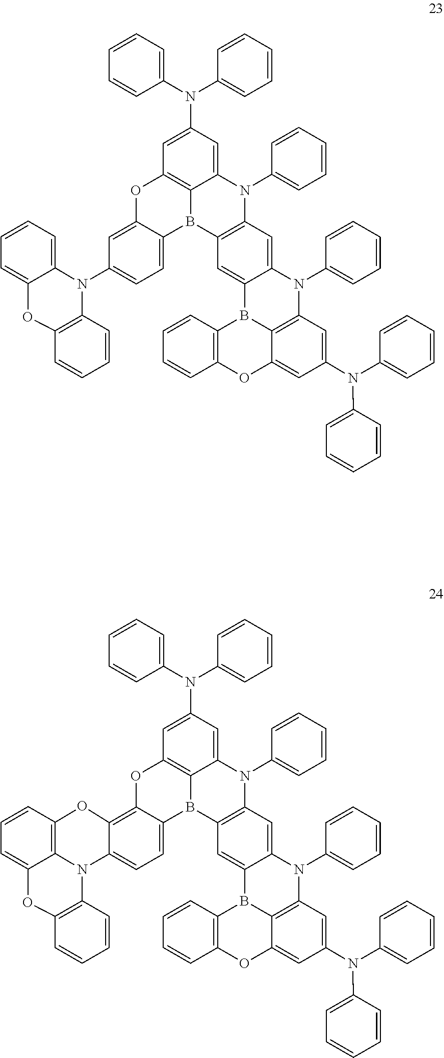 [SMILES: c1ccc(N(c2ccccc2)c2cc3c4c(c2)N(c2ccccc2)c2cc5c(cc2B4c2ccccc2O3)B2c3ccc(N4c6ccccc6Oc6ccccc64)cc3Oc3cc(N(c4ccccc4)c4ccccc4)cc(c32)N5c2ccccc2)cc1 ; c1ccc(N(c2ccccc2)c2cc3c4c(c2)N(c2ccccc2)c2cc5c(cc2B4c2ccccc2O3)B2c3ccc4c(c3Oc3cc(N(c6ccccc6)c6ccccc6)cc(c32)N5c2ccccc2)Oc2cccc3c2N4c2ccccc2O3)cc1]

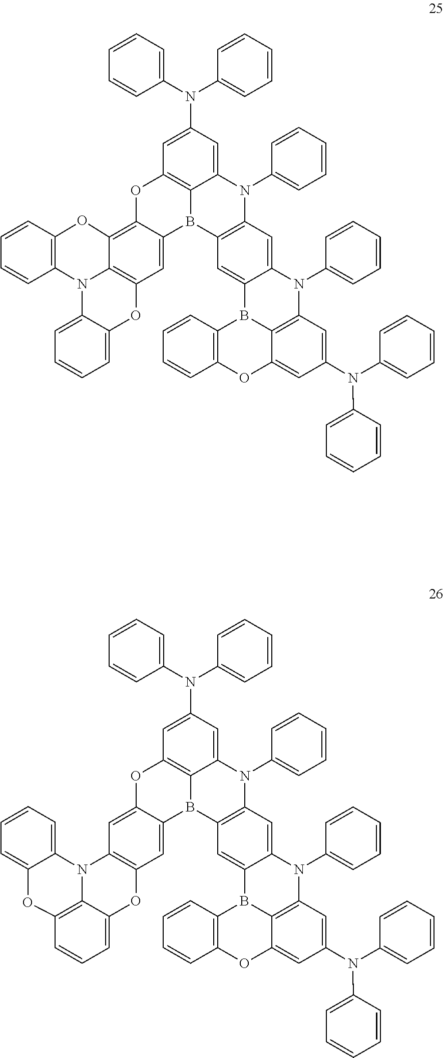 [SMILES: c1ccc(N(c2ccccc2)c2cc3c4c(c2)N(c2ccccc2)c2cc5c(cc2B4c2ccccc2O3)B2c3cc4c6c(c3Oc3cc(N(c7ccccc7)c7ccccc7)cc(c32)N5c2ccccc2)Oc2ccccc2N6c2ccccc2O4)cc1 ; c1ccc(N(c2ccccc2)c2cc3c4c(c2)N(c2ccccc2)c2cc5c(cc2B4c2ccccc2O3)B2c3cc4c(cc3Oc3cc(N(c6ccccc6)c6ccccc6)cc(c32)N5c2ccccc2)N2c3ccccc3Oc3cccc(c32)O4)cc1]

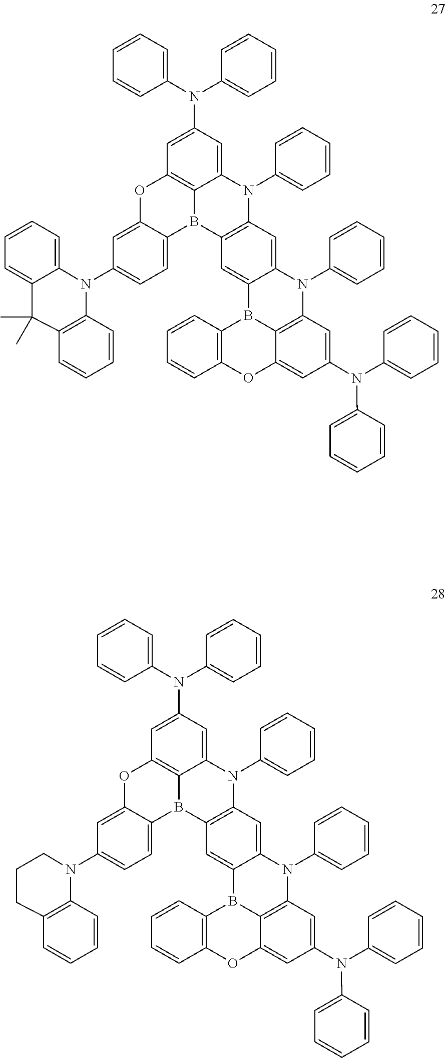 [SMILES: CC1(C)c2ccccc2N(c2ccc3c(c2)Oc2cc(N(c4ccccc4)c4ccccc4)cc4c2B3c2cc3c(cc2N4c2ccccc2)N(c2ccccc2)c2cc(N(c4ccccc4)c4ccccc4)cc4c2B3c2ccccc2O4)c2ccccc21 ; c1ccc(N(c2ccccc2)c2cc3c4c(c2)N(c2ccccc2)c2cc5c(cc2B4c2ccccc2O3)B2c3ccc(N4CCCc6ccccc64)cc3Oc3cc(N(c4ccccc4)c4ccccc4)cc(c32)N5c2ccccc2)cc1]

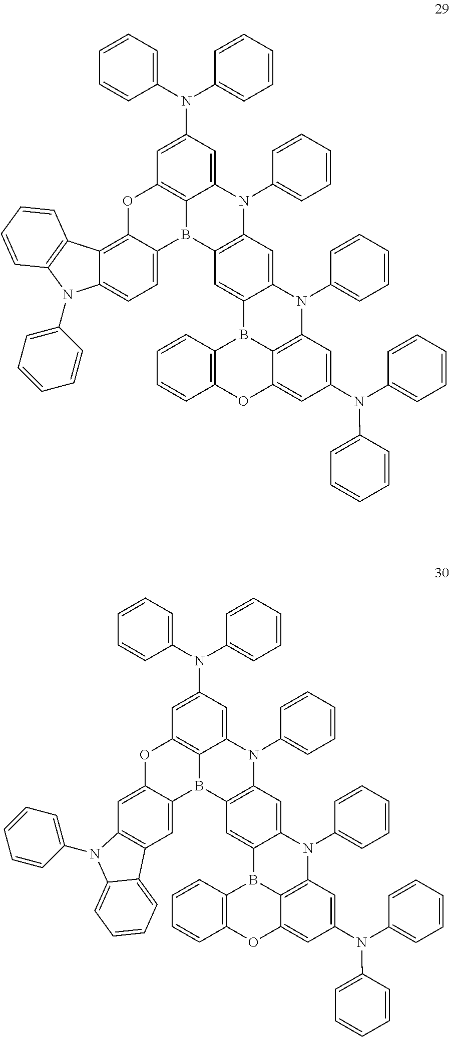 [SMILES: c1ccc(N(c2ccccc2)c2cc3c4c(c2)N(c2ccccc2)c2cc5c(cc2B4c2ccccc2O3)B2c3ccc4c(c3Oc3cc(N(c6ccccc6)c6ccccc6)cc(c32)N5c2ccccc2)c2ccccc2n4-c2ccccc2)cc1 ; c1ccc(N(c2ccccc2)c2cc3c4c(c2)N(c2ccccc2)c2cc5c(cc2B4c2ccccc2O3)B2c3cc4c6ccccc6n(-c6ccccc6)c4cc3Oc3cc(N(c4ccccc4)c4ccccc4)cc(c32)N5c2ccccc2)cc1]

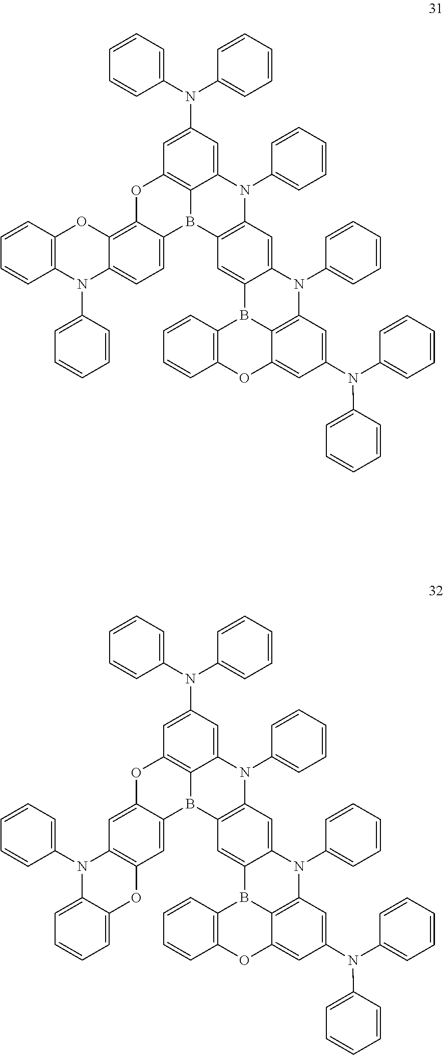 [SMILES: c1ccc(N(c2ccccc2)c2cc3c4c(c2)N(c2ccccc2)c2cc5c(cc2B4c2ccccc2O3)B2c3ccc4c(c3Oc3cc(N(c6ccccc6)c6ccccc6)cc(c32)N5c2ccccc2)Oc2ccccc2N4c2ccccc2)cc1 ; c1ccc(N(c2ccccc2)c2cc3c4c(c2)N(c2ccccc2)c2cc5c(cc2B4c2ccccc2O3)B2c3cc4c(cc3Oc3cc(N(c6ccccc6)c6ccccc6)cc(c32)N5c2ccccc2)N(c2ccccc2)c2ccccc2O4)cc1]

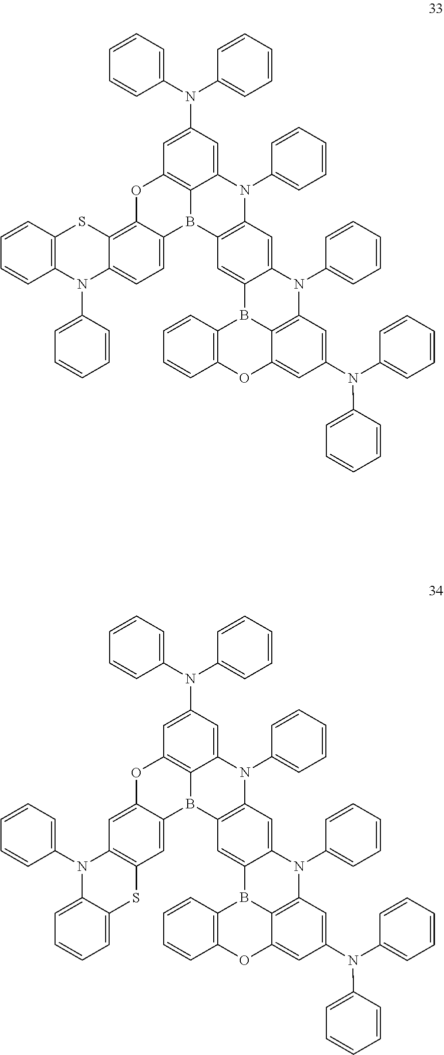 [SMILES: c1ccc(N(c2ccccc2)c2cc3c4c(c2)N(c2ccccc2)c2cc5c(cc2B4c2ccccc2O3)B2c3ccc4c(c3Oc3cc(N(c6ccccc6)c6ccccc6)cc(c32)N5c2ccccc2)Sc2ccccc2N4c2ccccc2)cc1 ; c1ccc(N(c2ccccc2)c2cc3c4c(c2)N(c2ccccc2)c2cc5c(cc2B4c2ccccc2O3)B2c3cc4c(cc3Oc3cc(N(c6ccccc6)c6ccccc6)cc(c32)N5c2ccccc2)N(c2ccccc2)c2ccccc2S4)cc1]

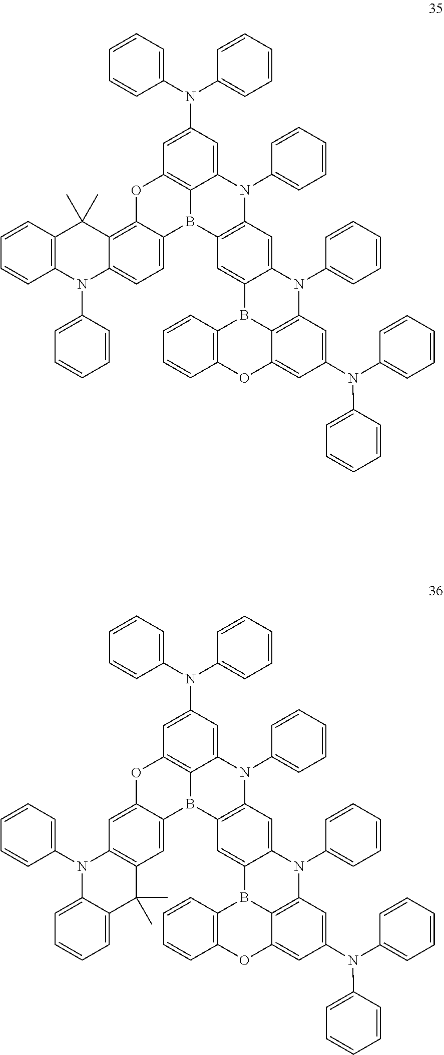 [SMILES: CC1(C)c2ccccc2N(c2ccccc2)c2ccc3c(c21)Oc1cc(N(c2ccccc2)c2ccccc2)cc2c1B3c1cc3c(cc1N2c1ccccc1)N(c1ccccc1)c1cc(N(c2ccccc2)c2ccccc2)cc2c1B3c1ccccc1O2 ; CC1(C)c2ccccc2N(c2ccccc2)c2cc3c(cc21)B1c2cc4c(cc2N(c2ccccc2)c2cc(N(c5ccccc5)c5ccccc5)cc(c21)O3)N(c1ccccc1)c1cc(N(c2ccccc2)c2ccccc2)cc2c1B4c1ccccc1O2]

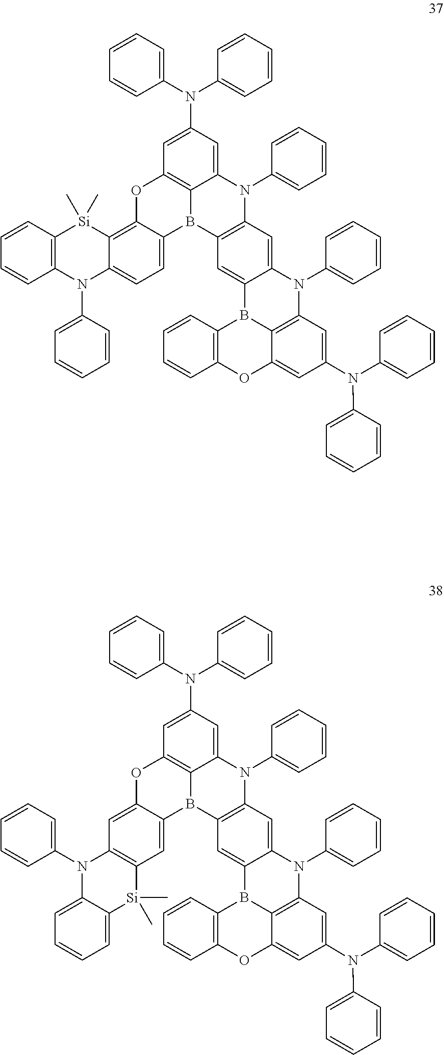 [SMILES: C[Si]1(C)c2ccccc2N(c2ccccc2)c2ccc3c(c21)Oc1cc(N(c2ccccc2)c2ccccc2)cc2c1B3c1cc3c(cc1N2c1ccccc1)N(c1ccccc1)c1cc(N(c2ccccc2)c2ccccc2)cc2c1B3c1ccccc1O2 ; C[Si]1(C)c2ccccc2N(c2ccccc2)c2cc3c(cc21)B1c2cc4c(cc2N(c2ccccc2)c2cc(N(c5ccccc5)c5ccccc5)cc(c21)O3)N(c1ccccc1)c1cc(N(c2ccccc2)c2ccccc2)cc2c1B4c1ccccc1O2]

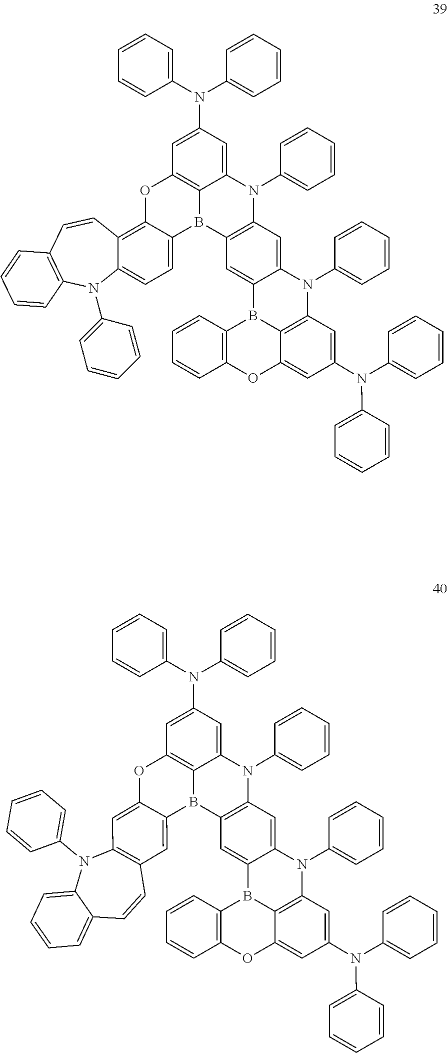 [SMILES: C1=Cc2c(ccc3c2Oc2cc(N(c4ccccc4)c4ccccc4)cc4c2B3c2cc3c(cc2N4c2ccccc2)N(c2ccccc2)c2cc(N(c4ccccc4)c4ccccc4)cc4c2B3c2ccccc2O4)N(c2ccccc2)c2ccccc21 ; C1=Cc2cc3c(cc2N(c2ccccc2)c2ccccc21)Oc1cc(N(c2ccccc2)c2ccccc2)cc2c1B3c1cc3c(cc1N2c1ccccc1)N(c1ccccc1)c1cc(N(c2ccccc2)c2ccccc2)cc2c1B3c1ccccc1O2]

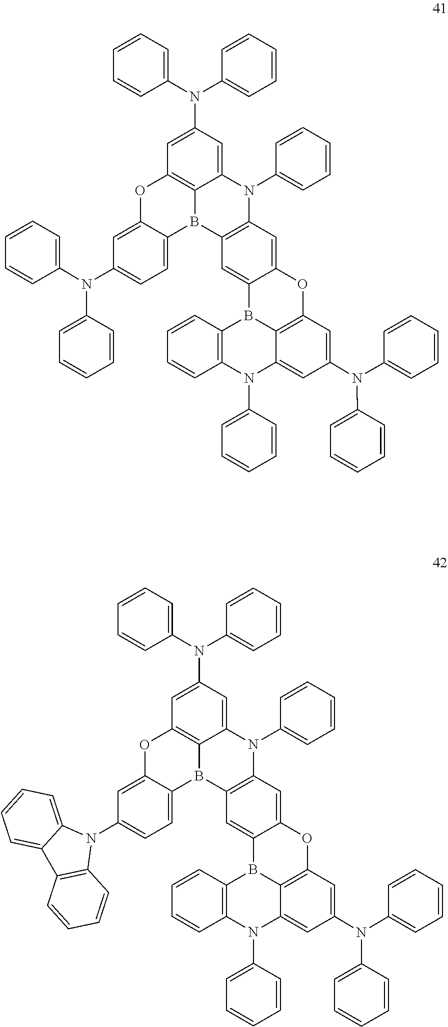 [SMILES: c1ccc(N(c2ccccc2)c2ccc3c(c2)Oc2cc(N(c4ccccc4)c4ccccc4)cc4c2B3c2cc3c(cc2N4c2ccccc2)Oc2cc(N(c4ccccc4)c4ccccc4)cc4c2B3c2ccccc2N4c2ccccc2)cc1 ; c1ccc(N(c2ccccc2)c2cc3c4c(c2)N(c2ccccc2)c2ccccc2B4c2cc4c(cc2O3)N(c2ccccc2)c2cc(N(c3ccccc3)c3ccccc3)cc3c2B4c2ccc(-n4c5ccccc5c5ccccc54)cc2O3)cc1]

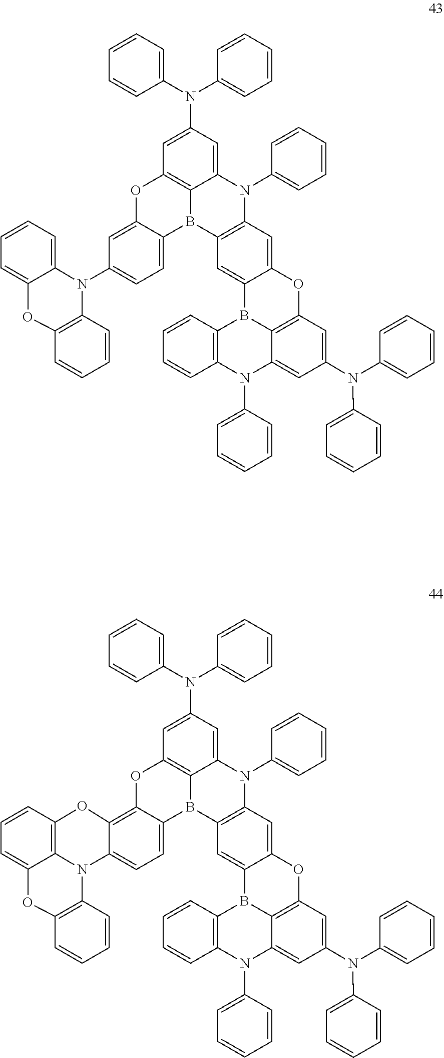 [SMILES: c1ccc(N(c2ccccc2)c2cc3c4c(c2)N(c2ccccc2)c2ccccc2B4c2cc4c(cc2O3)N(c2ccccc2)c2cc(N(c3ccccc3)c3ccccc3)cc3c2B4c2ccc(N4c5ccccc5Oc5ccccc54)cc2O3)cc1 ; c1ccc(N(c2ccccc2)c2cc3c4c(c2)N(c2ccccc2)c2ccccc2B4c2cc4c(cc2O3)N(c2ccccc2)c2cc(N(c3ccccc3)c3ccccc3)cc3c2B4c2ccc4c(c2O3)Oc2cccc3c2N4c2ccccc2O3)cc1]

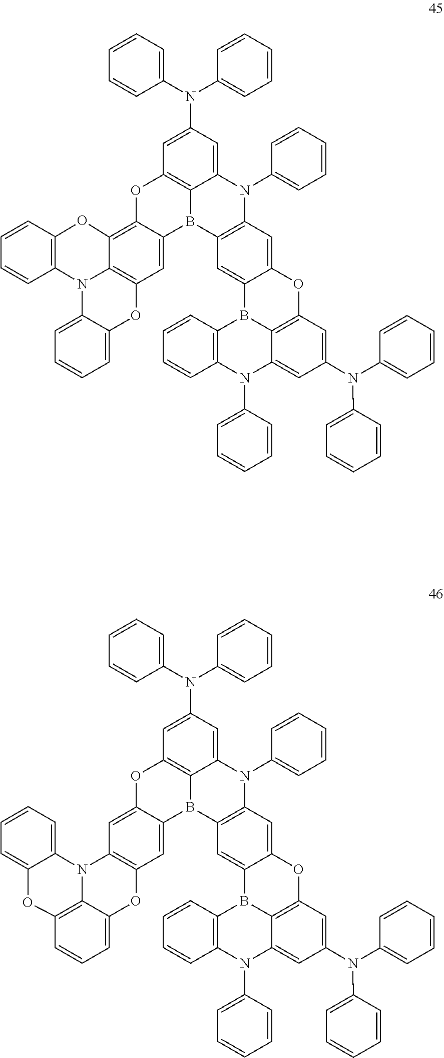 [SMILES: c1ccc(N(c2ccccc2)c2cc3c4c(c2)N(c2ccccc2)c2ccccc2B4c2cc4c(cc2O3)N(c2ccccc2)c2cc(N(c3ccccc3)c3ccccc3)cc3c2B4c2cc4c5c(c2O3)Oc2ccccc2N5c2ccccc2O4)cc1 ; c1ccc(N(c2ccccc2)c2cc3c4c(c2)N(c2ccccc2)c2ccccc2B4c2cc4c(cc2O3)N(c2ccccc2)c2cc(N(c3ccccc3)c3ccccc3)cc3c2B4c2cc4c(cc2O3)N2c3ccccc3Oc3cccc(c32)O4)cc1]

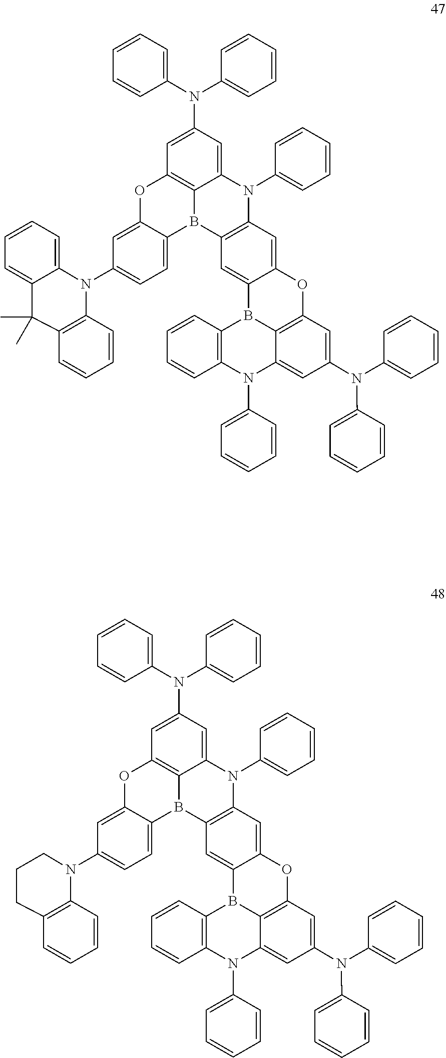 [SMILES: CC1(C)c2ccccc2N(c2ccc3c(c2)Oc2cc(N(c4ccccc4)c4ccccc4)cc4c2B3c2cc3c(cc2N4c2ccccc2)Oc2cc(N(c4ccccc4)c4ccccc4)cc4c2B3c2ccccc2N4c2ccccc2)c2ccccc21 ; c1ccc(N(c2ccccc2)c2cc3c4c(c2)N(c2ccccc2)c2ccccc2B4c2cc4c(cc2O3)N(c2ccccc2)c2cc(N(c3ccccc3)c3ccccc3)cc3c2B4c2ccc(N4CCCc5ccccc54)cc2O3)cc1]

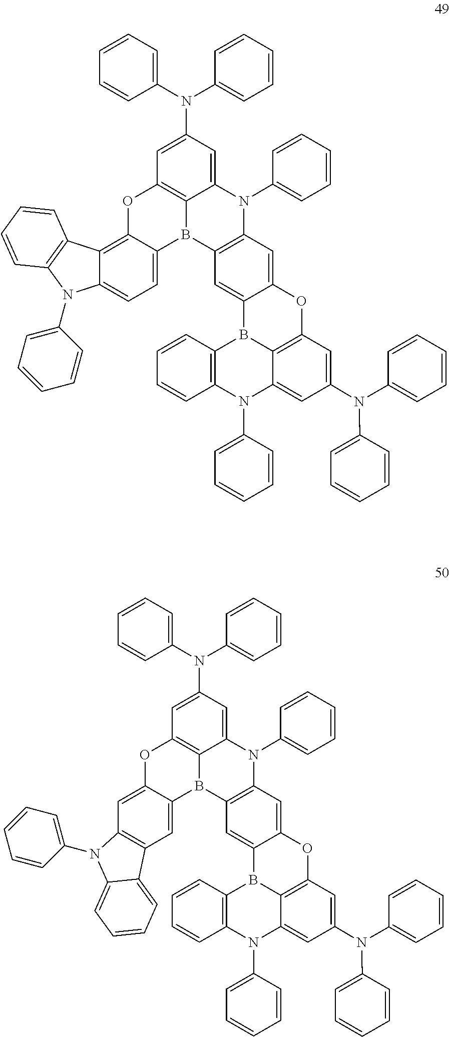 [SMILES: c1ccc(N(c2ccccc2)c2cc3c4c(c2)N(c2ccccc2)c2ccccc2B4c2cc4c(cc2O3)N(c2ccccc2)c2cc(N(c3ccccc3)c3ccccc3)cc3c2B4c2ccc4c(c2O3)c2ccccc2n4-c2ccccc2)cc1 ; c1ccc(N(c2ccccc2)c2cc3c4c(c2)N(c2ccccc2)c2ccccc2B4c2cc4c(cc2O3)N(c2ccccc2)c2cc(N(c3ccccc3)c3ccccc3)cc3c2B4c2cc4c5ccccc5n(-c5ccccc5)c4cc2O3)cc1]

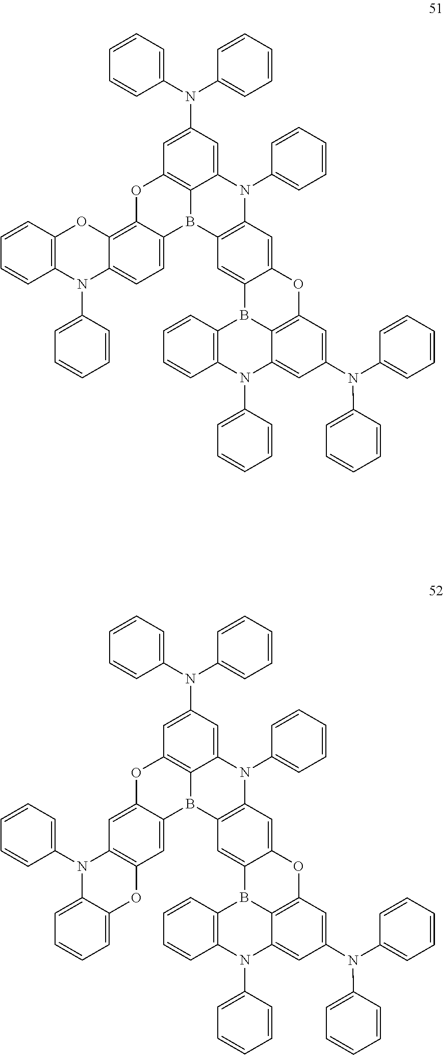 [SMILES: c1ccc(N(c2ccccc2)c2cc3c4c(c2)N(c2ccccc2)c2ccccc2B4c2cc4c(cc2O3)N(c2ccccc2)c2cc(N(c3ccccc3)c3ccccc3)cc3c2B4c2ccc4c(c2O3)Oc2ccccc2N4c2ccccc2)cc1 ; c1ccc(N(c2ccccc2)c2cc3c4c(c2)N(c2ccccc2)c2ccccc2B4c2cc4c(cc2O3)N(c2ccccc2)c2cc(N(c3ccccc3)c3ccccc3)cc3c2B4c2cc4c(cc2O3)N(c2ccccc2)c2ccccc2O4)cc1]

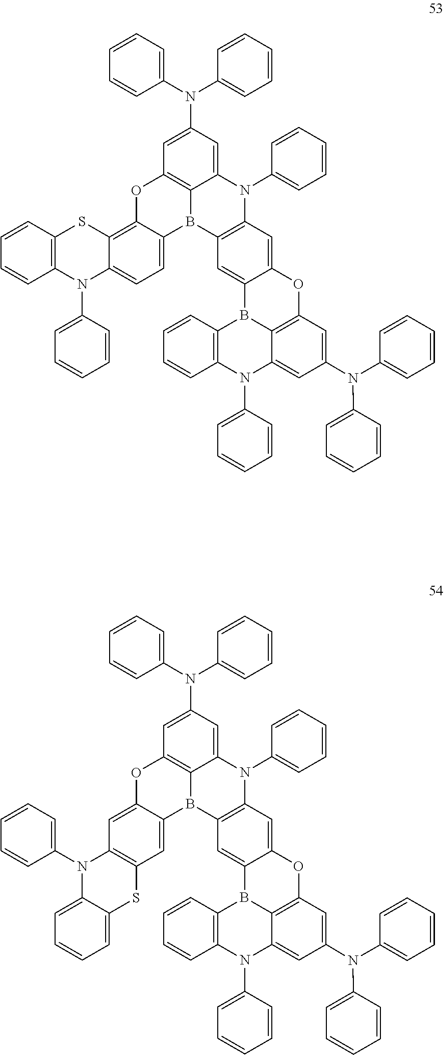 [SMILES: c1ccc(N(c2ccccc2)c2cc3c4c(c2)N(c2ccccc2)c2ccccc2B4c2cc4c(cc2O3)N(c2ccccc2)c2cc(N(c3ccccc3)c3ccccc3)cc3c2B4c2ccc4c(c2O3)Sc2ccccc2N4c2ccccc2)cc1 ; c1ccc(N(c2ccccc2)c2cc3c4c(c2)N(c2ccccc2)c2ccccc2B4c2cc4c(cc2O3)N(c2ccccc2)c2cc(N(c3ccccc3)c3ccccc3)cc3c2B4c2cc4c(cc2O3)N(c2ccccc2)c2ccccc2S4)cc1]

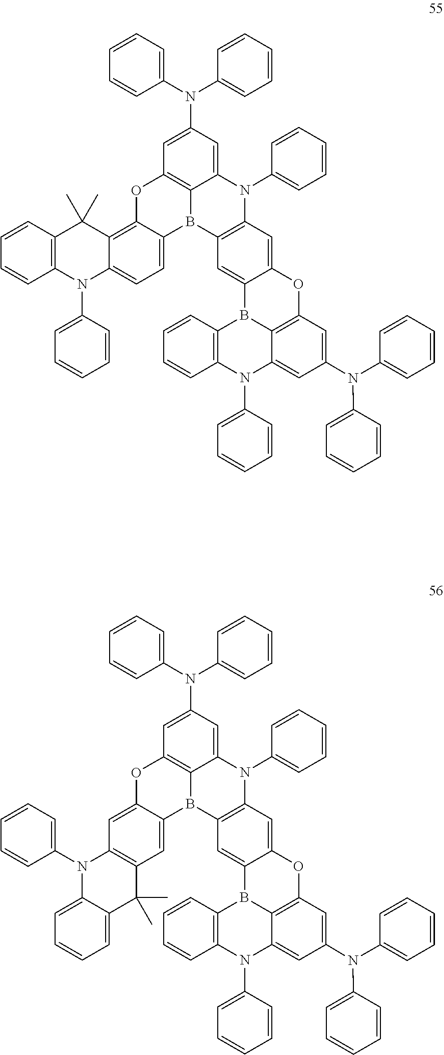 [SMILES: CC1(C)c2ccccc2N(c2ccccc2)c2ccc3c(c21)Oc1cc(N(c2ccccc2)c2ccccc2)cc2c1B3c1cc3c(cc1N2c1ccccc1)Oc1cc(N(c2ccccc2)c2ccccc2)cc2c1B3c1ccccc1N2c1ccccc1 ; CC1(C)c2ccccc2N(c2ccccc2)c2cc3c(cc21)B1c2cc4c(cc2N(c2ccccc2)c2cc(N(c5ccccc5)c5ccccc5)cc(c21)O3)Oc1cc(N(c2ccccc2)c2ccccc2)cc2c1B4c1ccccc1N2c1ccccc1]

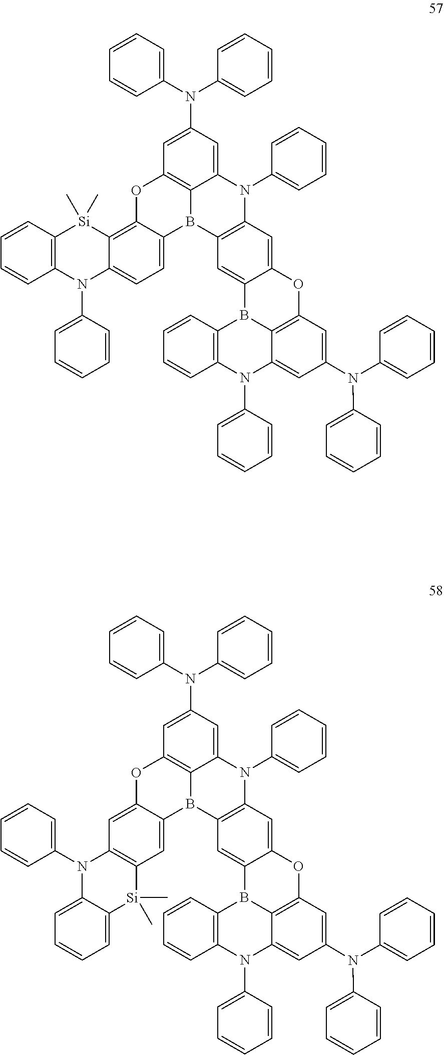 [SMILES: C[Si]1(C)c2ccccc2N(c2ccccc2)c2ccc3c(c21)Oc1cc(N(c2ccccc2)c2ccccc2)cc2c1B3c1cc3c(cc1N2c1ccccc1)Oc1cc(N(c2ccccc2)c2ccccc2)cc2c1B3c1ccccc1N2c1ccccc1 ; C[Si]1(C)c2ccccc2N(c2ccccc2)c2cc3c(cc21)B1c2cc4c(cc2N(c2ccccc2)c2cc(N(c5ccccc5)c5ccccc5)cc(c21)O3)Oc1cc(N(c2ccccc2)c2ccccc2)cc2c1B4c1ccccc1N2c1ccccc1]

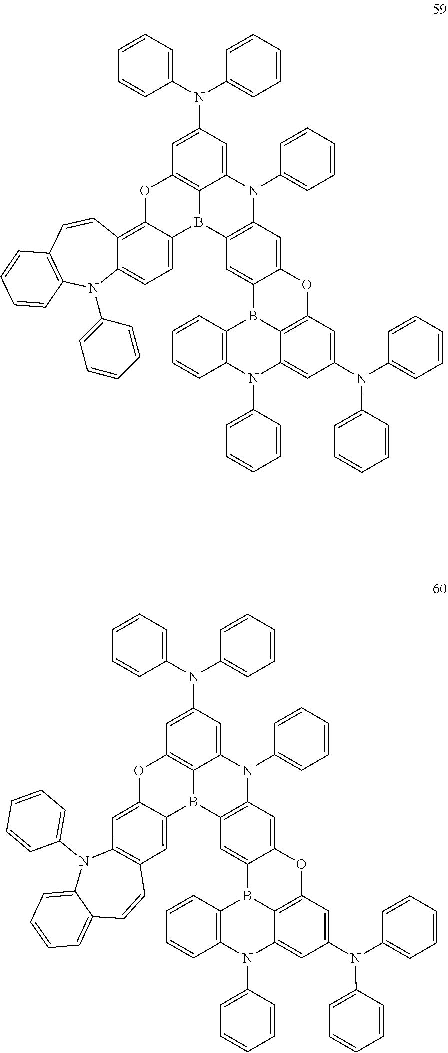 [SMILES: C1=Cc2c(ccc3c2Oc2cc(N(c4ccccc4)c4ccccc4)cc4c2B3c2cc3c(cc2N4c2ccccc2)Oc2cc(N(c4ccccc4)c4ccccc4)cc4c2B3c2ccccc2N4c2ccccc2)N(c2ccccc2)c2ccccc21 ; C1=Cc2cc3c(cc2N(c2ccccc2)c2ccccc21)Oc1cc(N(c2ccccc2)c2ccccc2)cc2c1B3c1cc3c(cc1N2c1ccccc1)Oc1cc(N(c2ccccc2)c2ccccc2)cc2c1B3c1ccccc1N2c1ccccc1]

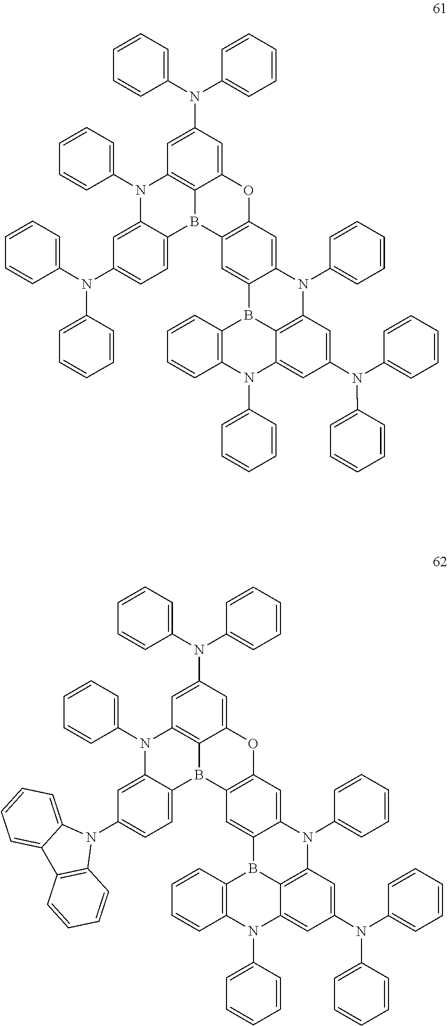 [SMILES: c1ccc(N(c2ccccc2)c2ccc3c(c2)N(c2ccccc2)c2cc(N(c4ccccc4)c4ccccc4)cc4c2B3c2cc3c(cc2O4)N(c2ccccc2)c2cc(N(c4ccccc4)c4ccccc4)cc4c2B3c2ccccc2N4c2ccccc2)cc1 ; c1ccc(N(c2ccccc2)c2cc3c4c(c2)N(c2ccccc2)c2cc(-n5c6ccccc6c6ccccc65)ccc2B4c2cc4c(cc2O3)N(c2ccccc2)c2cc(N(c3ccccc3)c3ccccc3)cc3c2B4c2ccccc2N3c2ccccc2)cc1]

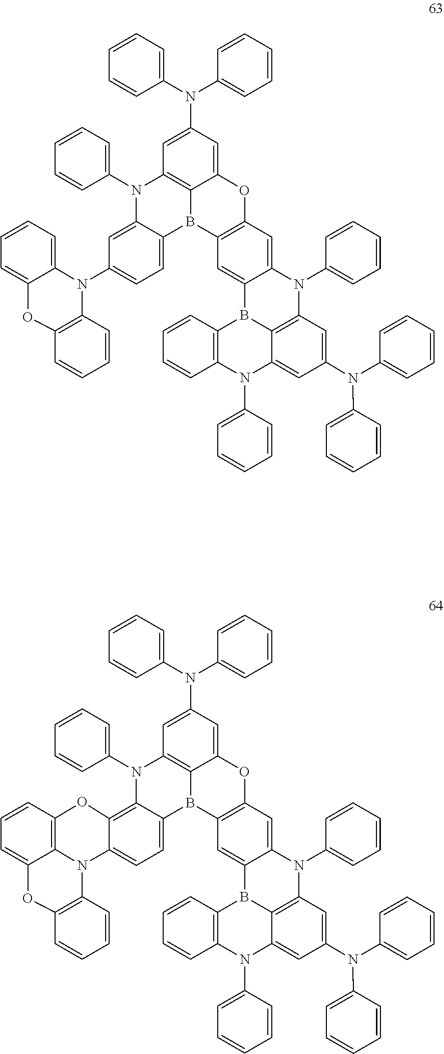 [SMILES: c1ccc(N(c2ccccc2)c2cc3c4c(c2)N(c2ccccc2)c2cc(N5c6ccccc6Oc6ccccc65)ccc2B4c2cc4c(cc2O3)N(c2ccccc2)c2cc(N(c3ccccc3)c3ccccc3)cc3c2B4c2ccccc2N3c2ccccc2)cc1 ; c1ccc(N(c2ccccc2)c2cc3c4c(c2)N(c2ccccc2)c2c(ccc5c2Oc2cccc6c2N5c2ccccc2O6)B4c2cc4c(cc2O3)N(c2ccccc2)c2cc(N(c3ccccc3)c3ccccc3)cc3c2B4c2ccccc2N3c2ccccc2)cc1]

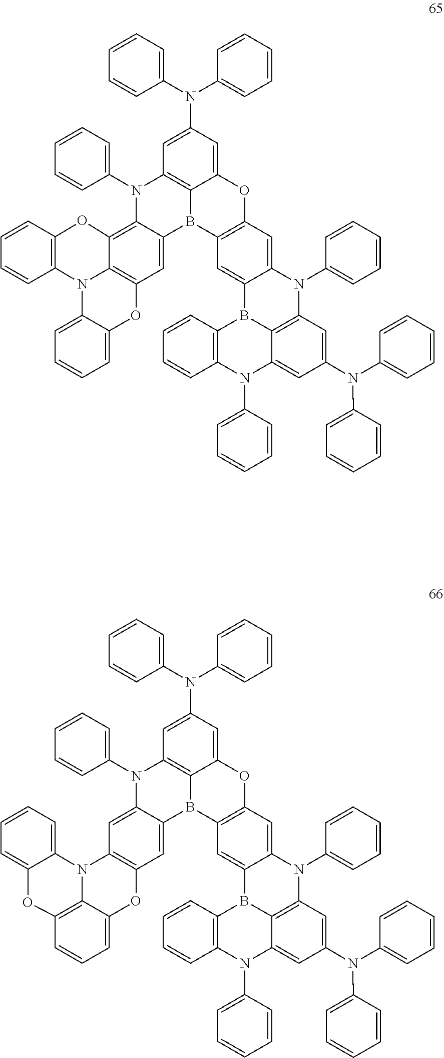 [SMILES: c1ccc(N(c2ccccc2)c2cc3c4c(c2)N(c2ccccc2)c2c(cc5c6c2Oc2ccccc2N6c2ccccc2O5)B4c2cc4c(cc2O3)N(c2ccccc2)c2cc(N(c3ccccc3)c3ccccc3)cc3c2B4c2ccccc2N3c2ccccc2)cc1 ; c1ccc(N(c2ccccc2)c2cc3c4c(c2)N(c2ccccc2)c2cc5c(cc2B4c2cc4c(cc2O3)N(c2ccccc2)c2cc(N(c3ccccc3)c3ccccc3)cc3c2B4c2ccccc2N3c2ccccc2)Oc2cccc3c2N5c2ccccc2O3)cc1]

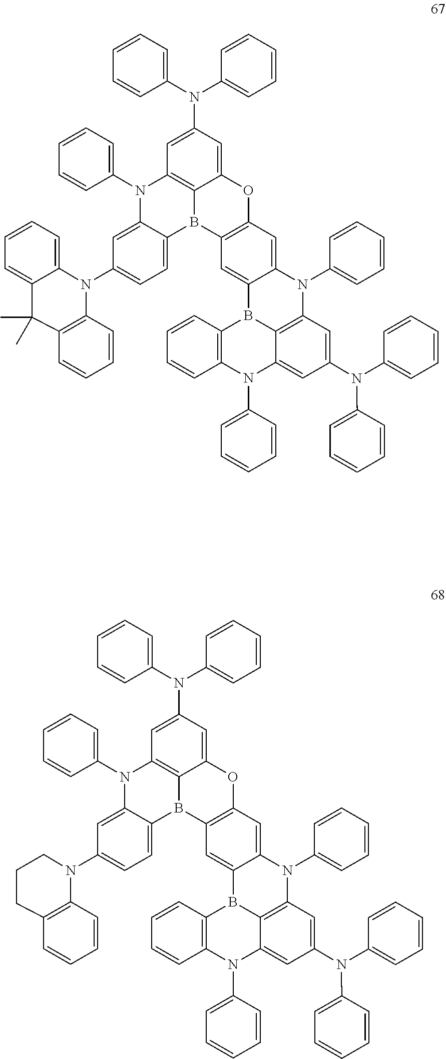 [SMILES: CC1(C)c2ccccc2N(c2ccc3c(c2)N(c2ccccc2)c2cc(N(c4ccccc4)c4ccccc4)cc4c2B3c2cc3c(cc2O4)N(c2ccccc2)c2cc(N(c4ccccc4)c4ccccc4)cc4c2B3c2ccccc2N4c2ccccc2)c2ccccc21 ; c1ccc(N(c2ccccc2)c2cc3c4c(c2)N(c2ccccc2)c2cc(N5CCCc6ccccc65)ccc2B4c2cc4c(cc2O3)N(c2ccccc2)c2cc(N(c3ccccc3)c3ccccc3)cc3c2B4c2ccccc2N3c2ccccc2)cc1]

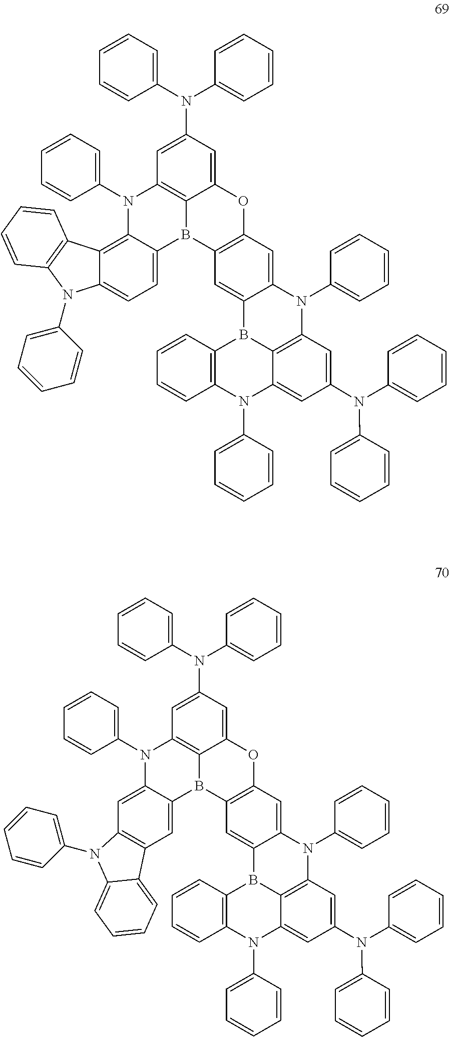 [SMILES: c1ccc(N(c2ccccc2)c2cc3c4c(c2)N(c2ccccc2)c2c(ccc5c2c2ccccc2n5-c2ccccc2)B4c2cc4c(cc2O3)N(c2ccccc2)c2cc(N(c3ccccc3)c3ccccc3)cc3c2B4c2ccccc2N3c2ccccc2)cc1 ; c1ccc(N(c2ccccc2)c2cc3c4c(c2)N(c2ccccc2)c2cc5c(cc2B4c2cc4c(cc2O3)N(c2ccccc2)c2cc(N(c3ccccc3)c3ccccc3)cc3c2B4c2ccccc2N3c2ccccc2)c2ccccc2n5-c2ccccc2)cc1]

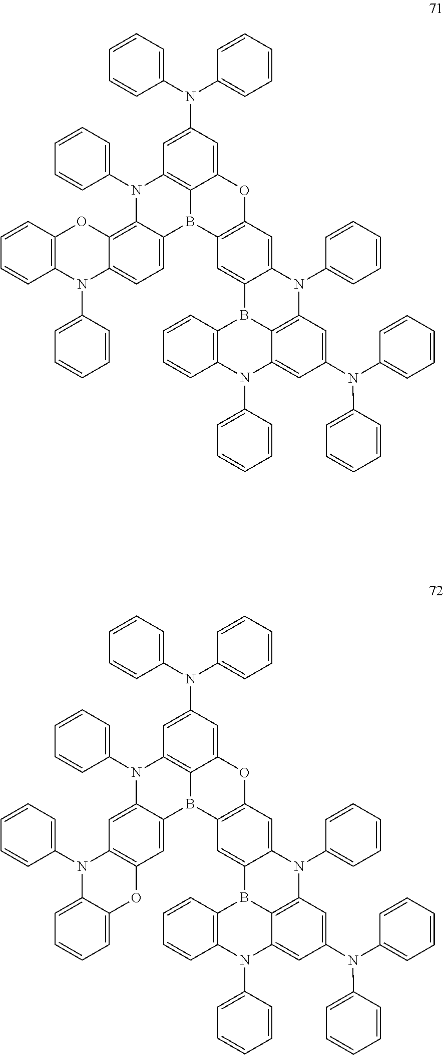 [SMILES: c1ccc(N(c2ccccc2)c2cc3c4c(c2)N(c2ccccc2)c2c(ccc5c2Oc2ccccc2N5c2ccccc2)B4c2cc4c(cc2O3)N(c2ccccc2)c2cc(N(c3ccccc3)c3ccccc3)cc3c2B4c2ccccc2N3c2ccccc2)cc1 ; c1ccc(N(c2ccccc2)c2cc3c4c(c2)N(c2ccccc2)c2cc5c(cc2B4c2cc4c(cc2O3)N(c2ccccc2)c2cc(N(c3ccccc3)c3ccccc3)cc3c2B4c2ccccc2N3c2ccccc2)Oc2ccccc2N5c2ccccc2)cc1]

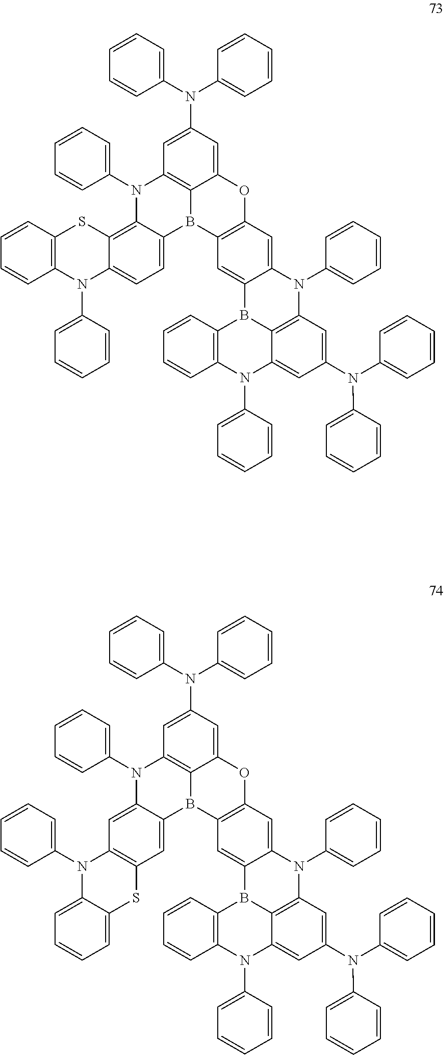 [SMILES: c1ccc(N(c2ccccc2)c2cc3c4c(c2)N(c2ccccc2)c2c(ccc5c2Sc2ccccc2N5c2ccccc2)B4c2cc4c(cc2O3)N(c2ccccc2)c2cc(N(c3ccccc3)c3ccccc3)cc3c2B4c2ccccc2N3c2ccccc2)cc1 ; c1ccc(N(c2ccccc2)c2cc3c4c(c2)N(c2ccccc2)c2cc5c(cc2B4c2cc4c(cc2O3)N(c2ccccc2)c2cc(N(c3ccccc3)c3ccccc3)cc3c2B4c2ccccc2N3c2ccccc2)Sc2ccccc2N5c2ccccc2)cc1]

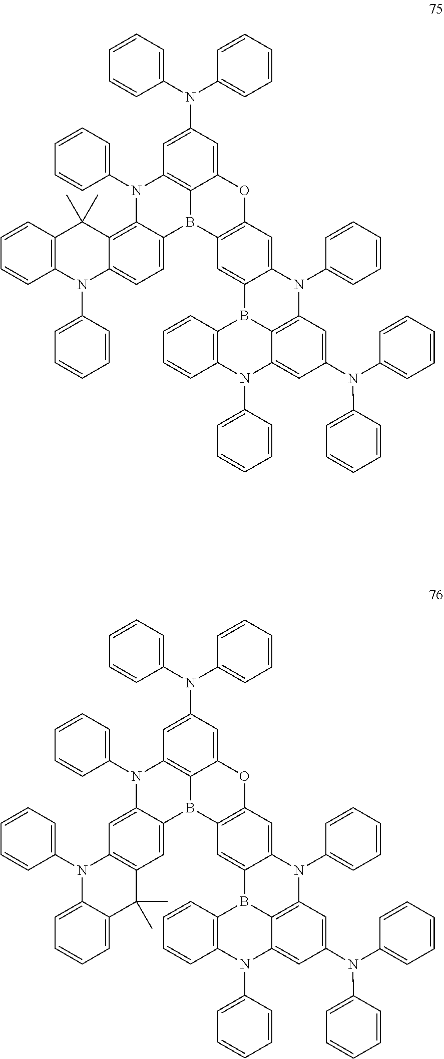 [SMILES: CC1(C)c2ccccc2N(c2ccccc2)c2ccc3c(c21)N(c1ccccc1)c1cc(N(c2ccccc2)c2ccccc2)cc2c1B3c1cc3c(cc1O2)N(c1ccccc1)c1cc(N(c2ccccc2)c2ccccc2)cc2c1B3c1ccccc1N2c1ccccc1 ; CC1(C)c2ccccc2N(c2ccccc2)c2cc3c(cc21)B1c2cc4c(cc2Oc2cc(N(c5ccccc5)c5ccccc5)cc(c21)N3c1ccccc1)N(c1ccccc1)c1cc(N(c2ccccc2)c2ccccc2)cc2c1B4c1ccccc1N2c1ccccc1]

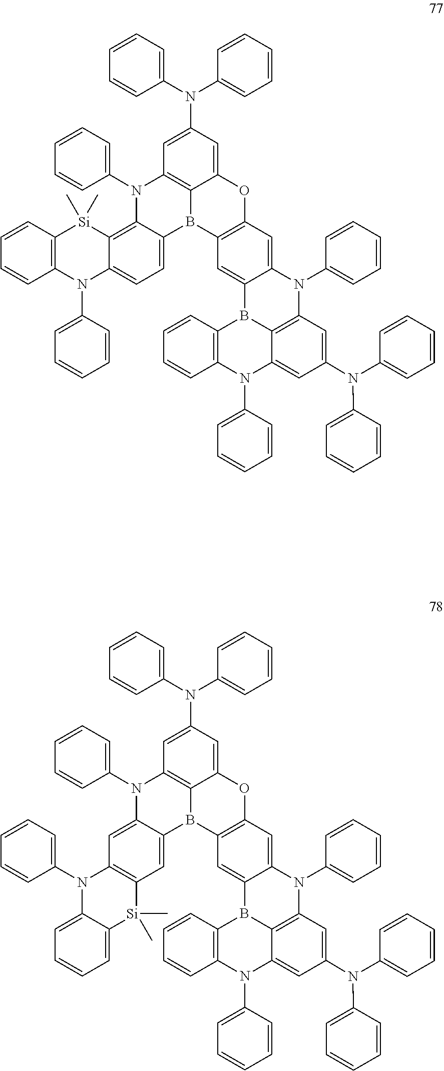 [SMILES: C[Si]1(C)c2ccccc2N(c2ccccc2)c2ccc3c(c21)N(c1ccccc1)c1cc(N(c2ccccc2)c2ccccc2)cc2c1B3c1cc3c(cc1O2)N(c1ccccc1)c1cc(N(c2ccccc2)c2ccccc2)cc2c1B3c1ccccc1N2c1ccccc1 ; C[Si]1(C)c2ccccc2N(c2ccccc2)c2cc3c(cc21)B1c2cc4c(cc2Oc2cc(N(c5ccccc5)c5ccccc5)cc(c21)N3c1ccccc1)N(c1ccccc1)c1cc(N(c2ccccc2)c2ccccc2)cc2c1B4c1ccccc1N2c1ccccc1]

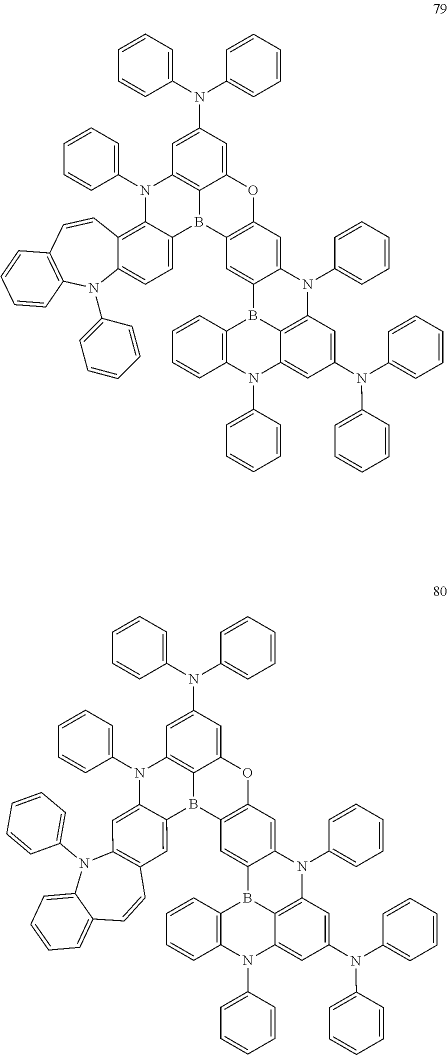 [SMILES: C1=Cc2c(ccc3c2N(c2ccccc2)c2cc(N(c4ccccc4)c4ccccc4)cc4c2B3c2cc3c(cc2O4)N(c2ccccc2)c2cc(N(c4ccccc4)c4ccccc4)cc4c2B3c2ccccc2N4c2ccccc2)N(c2ccccc2)c2ccccc21 ; C1=Cc2cc3c(cc2N(c2ccccc2)c2ccccc21)N(c1ccccc1)c1cc(N(c2ccccc2)c2ccccc2)cc2c1B3c1cc3c(cc1O2)N(c1ccccc1)c1cc(N(c2ccccc2)c2ccccc2)cc2c1B3c1ccccc1N2c1ccccc1]

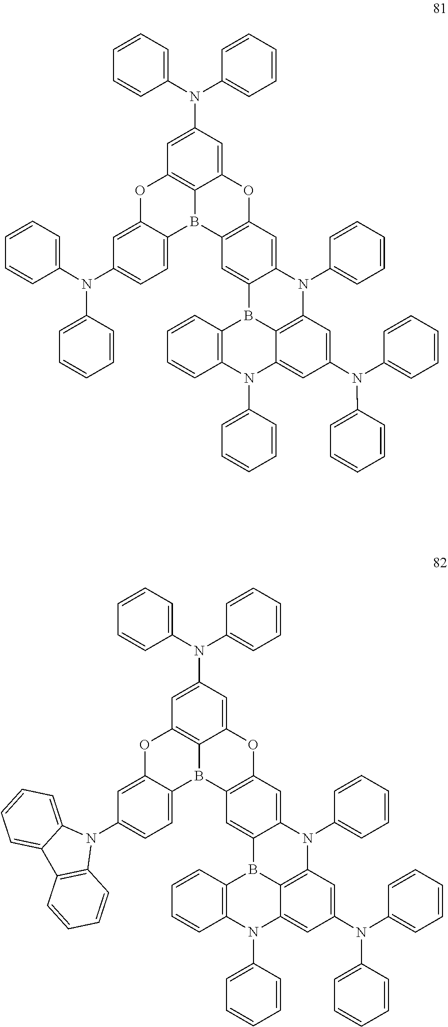 [SMILES: c1ccc(N(c2ccccc2)c2ccc3c(c2)Oc2cc(N(c4ccccc4)c4ccccc4)cc4c2B3c2cc3c(cc2O4)N(c2ccccc2)c2cc(N(c4ccccc4)c4ccccc4)cc4c2B3c2ccccc2N4c2ccccc2)cc1 ; c1ccc(N(c2ccccc2)c2cc3c4c(c2)Oc2cc5c(cc2B4c2ccc(-n4c6ccccc6c6ccccc64)cc2O3)B2c3ccccc3N(c3ccccc3)c3cc(N(c4ccccc4)c4ccccc4)cc(c32)N5c2ccccc2)cc1]

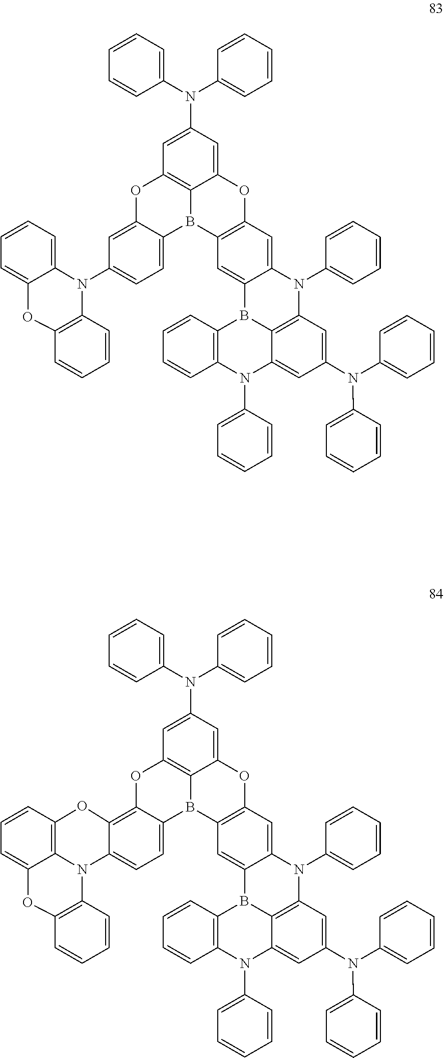 [SMILES: c1ccc(N(c2ccccc2)c2cc3c4c(c2)Oc2cc5c(cc2B4c2ccc(N4c6ccccc6Oc6ccccc64)cc2O3)B2c3ccccc3N(c3ccccc3)c3cc(N(c4ccccc4)c4ccccc4)cc(c32)N5c2ccccc2)cc1 ; c1ccc(N(c2ccccc2)c2cc3c4c(c2)Oc2c(ccc5c2Oc2cccc6c2N5c2ccccc2O6)B4c2cc4c(cc2O3)N(c2ccccc2)c2cc(N(c3ccccc3)c3ccccc3)cc3c2B4c2ccccc2N3c2ccccc2)cc1]

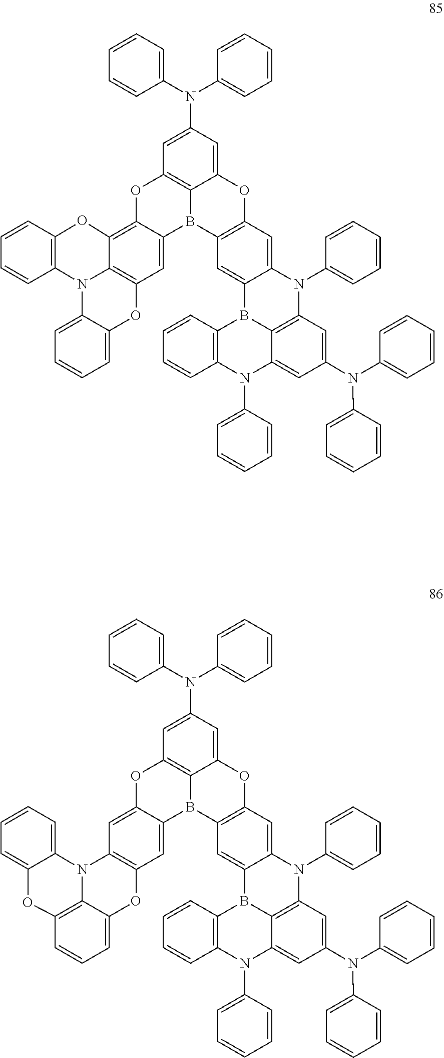 [SMILES: c1ccc(N(c2ccccc2)c2cc3c4c(c2)Oc2c(cc5c6c2Oc2ccccc2N6c2ccccc2O5)B4c2cc4c(cc2O3)N(c2ccccc2)c2cc(N(c3ccccc3)c3ccccc3)cc3c2B4c2ccccc2N3c2ccccc2)cc1 ; c1ccc(N(c2ccccc2)c2cc3c4c(c2)Oc2cc5c(cc2B4c2cc4c(cc2O3)N2c3ccccc3Oc3cccc(c32)O4)B2c3ccccc3N(c3ccccc3)c3cc(N(c4ccccc4)c4ccccc4)cc(c32)N5c2ccccc2)cc1]

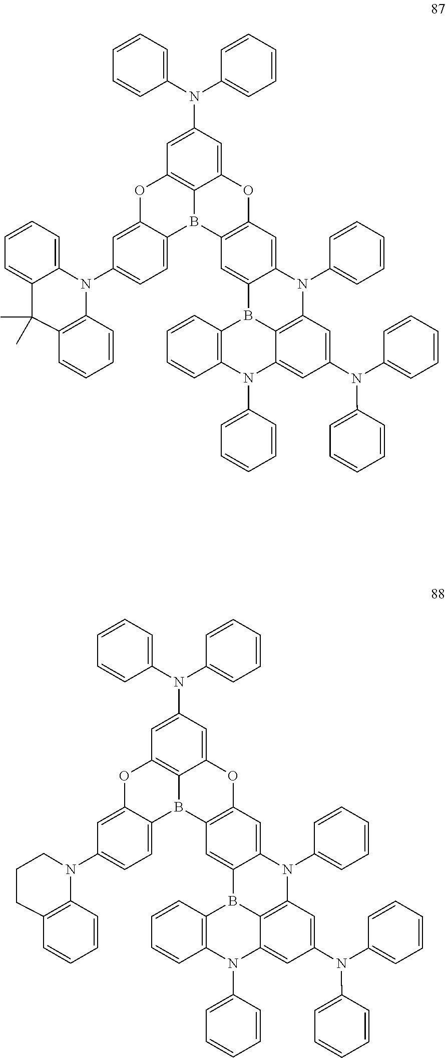 [SMILES: CC1(C)c2ccccc2N(c2ccc3c(c2)Oc2cc(N(c4ccccc4)c4ccccc4)cc4c2B3c2cc3c(cc2O4)N(c2ccccc2)c2cc(N(c4ccccc4)c4ccccc4)cc4c2B3c2ccccc2N4c2ccccc2)c2ccccc21 ; c1ccc(N(c2ccccc2)c2cc3c4c(c2)Oc2cc5c(cc2B4c2ccc(N4CCCc6ccccc64)cc2O3)B2c3ccccc3N(c3ccccc3)c3cc(N(c4ccccc4)c4ccccc4)cc(c32)N5c2ccccc2)cc1]

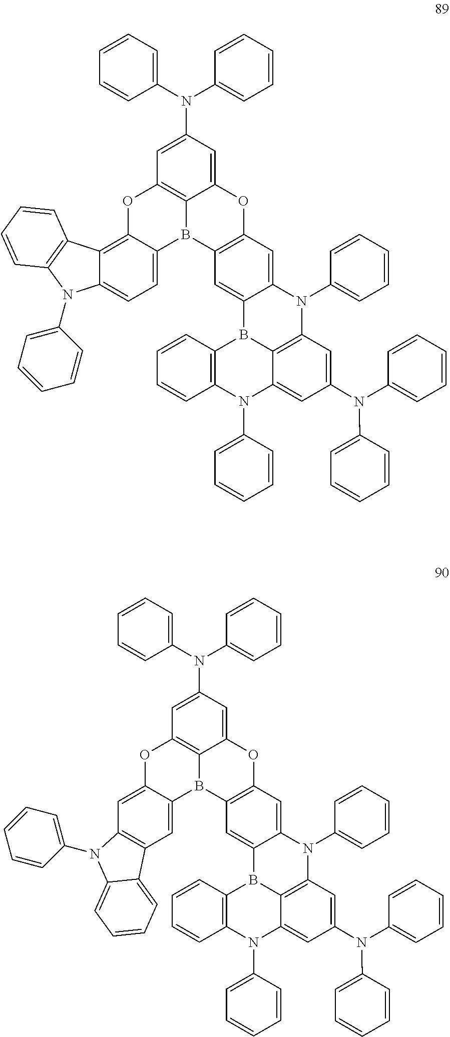 [SMILES: c1ccc(N(c2ccccc2)c2cc3c4c(c2)Oc2c(ccc5c2c2ccccc2n5-c2ccccc2)B4c2cc4c(cc2O3)N(c2ccccc2)c2cc(N(c3ccccc3)c3ccccc3)cc3c2B4c2ccccc2N3c2ccccc2)cc1 ; c1ccc(N(c2ccccc2)c2cc3c4c(c2)Oc2cc5c(cc2B4c2cc4c(cc2O3)N(c2ccccc2)c2cc(N(c3ccccc3)c3ccccc3)cc3c2B4c2ccccc2N3c2ccccc2)c2ccccc2n5-c2ccccc2)cc1]

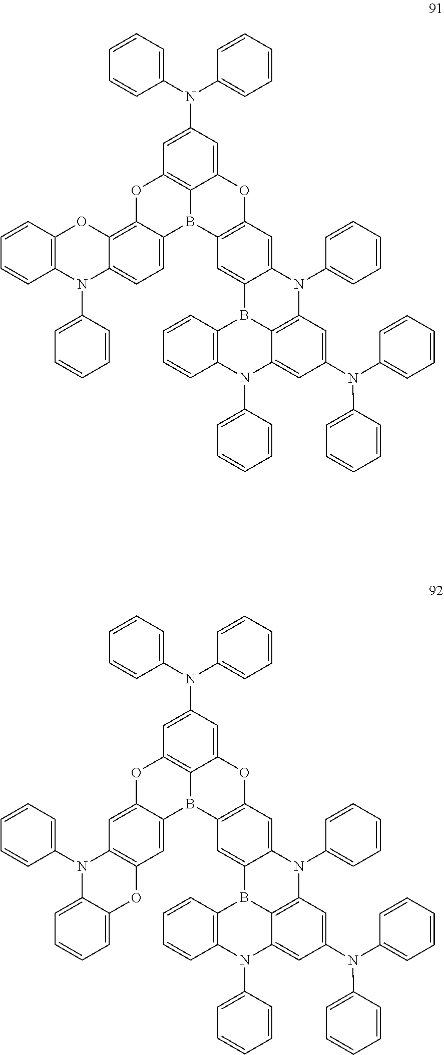 [SMILES: c1ccc(N(c2ccccc2)c2cc3c4c(c2)Oc2c(ccc5c2Oc2ccccc2N5c2ccccc2)B4c2cc4c(cc2O3)N(c2ccccc2)c2cc(N(c3ccccc3)c3ccccc3)cc3c2B4c2ccccc2N3c2ccccc2)cc1 ; c1ccc(N(c2ccccc2)c2cc3c4c(c2)Oc2cc5c(cc2B4c2cc4c(cc2O3)N(c2ccccc2)c2ccccc2O4)B2c3ccccc3N(c3ccccc3)c3cc(N(c4ccccc4)c4ccccc4)cc(c32)N5c2ccccc2)cc1]

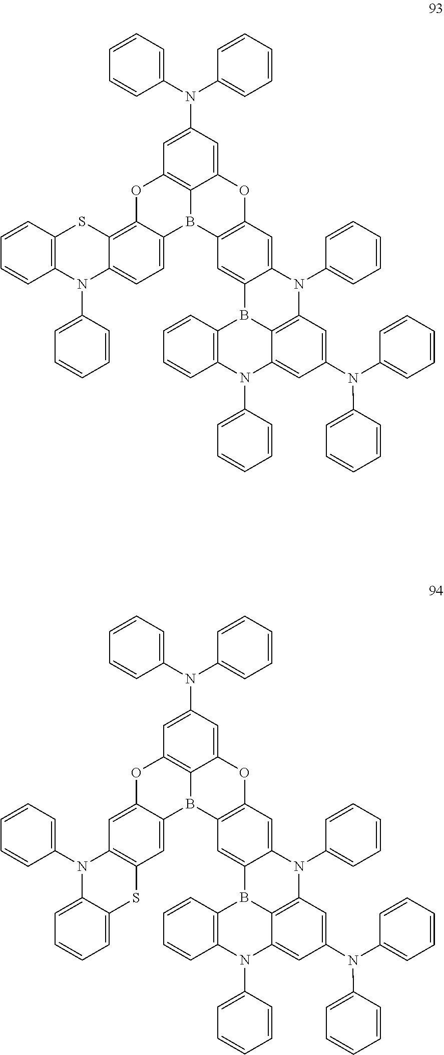 [SMILES: c1ccc(N(c2ccccc2)c2cc3c4c(c2)Oc2c(ccc5c2Sc2ccccc2N5c2ccccc2)B4c2cc4c(cc2O3)N(c2ccccc2)c2cc(N(c3ccccc3)c3ccccc3)cc3c2B4c2ccccc2N3c2ccccc2)cc1 ; c1ccc(N(c2ccccc2)c2cc3c4c(c2)Oc2cc5c(cc2B4c2cc4c(cc2O3)N(c2ccccc2)c2ccccc2S4)B2c3ccccc3N(c3ccccc3)c3cc(N(c4ccccc4)c4ccccc4)cc(c32)N5c2ccccc2)cc1]

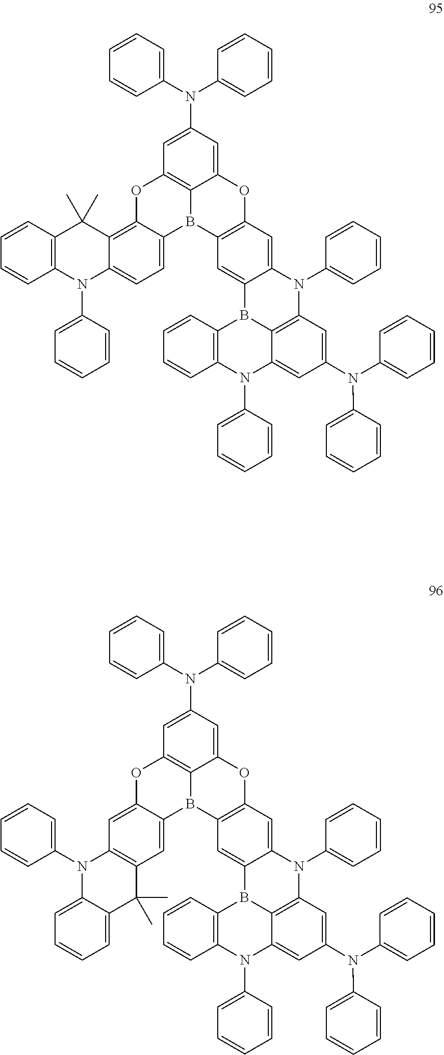 [SMILES: CC1(C)c2ccccc2N(c2ccccc2)c2ccc3c(c21)Oc1cc(N(c2ccccc2)c2ccccc2)cc2c1B3c1cc3c(cc1O2)N(c1ccccc1)c1cc(N(c2ccccc2)c2ccccc2)cc2c1B3c1ccccc1N2c1ccccc1 ; CC1(C)c2ccccc2N(c2ccccc2)c2cc3c(cc21)B1c2cc4c(cc2Oc2cc(N(c5ccccc5)c5ccccc5)cc(c21)O3)N(c1ccccc1)c1cc(N(c2ccccc2)c2ccccc2)cc2c1B4c1ccccc1N2c1ccccc1]

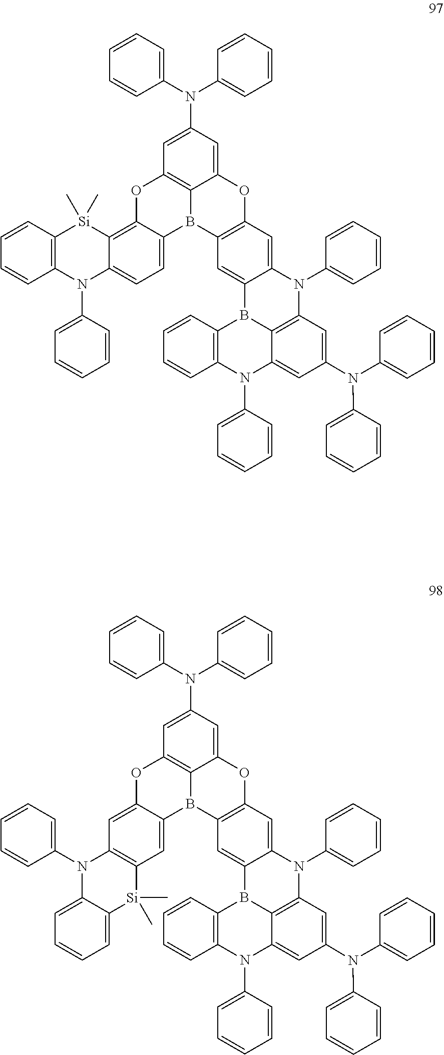 [SMILES: C[Si]1(C)c2ccccc2N(c2ccccc2)c2ccc3c(c21)Oc1cc(N(c2ccccc2)c2ccccc2)cc2c1B3c1cc3c(cc1O2)N(c1ccccc1)c1cc(N(c2ccccc2)c2ccccc2)cc2c1B3c1ccccc1N2c1ccccc1 ; C[Si]1(C)c2ccccc2N(c2ccccc2)c2cc3c(cc21)B1c2cc4c(cc2Oc2cc(N(c5ccccc5)c5ccccc5)cc(c21)O3)N(c1ccccc1)c1cc(N(c2ccccc2)c2ccccc2)cc2c1B4c1ccccc1N2c1ccccc1]

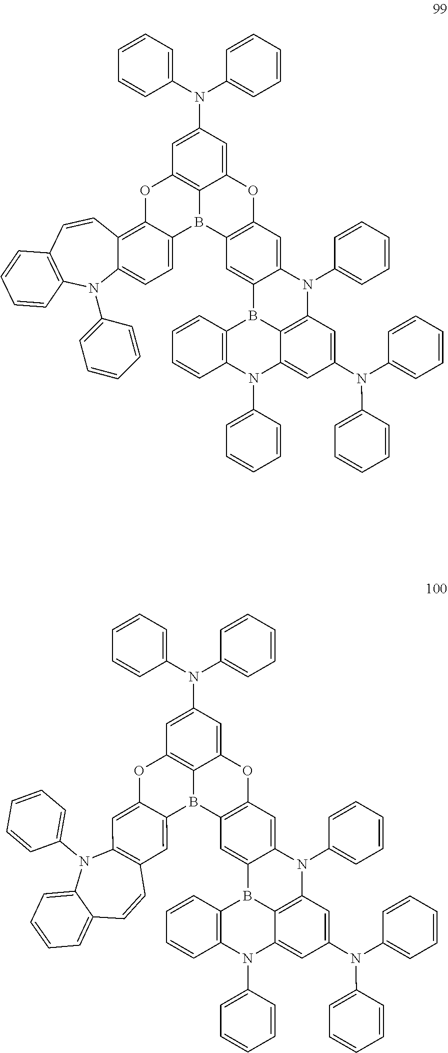 [SMILES: C1=Cc2c(ccc3c2Oc2cc(N(c4ccccc4)c4ccccc4)cc4c2B3c2cc3c(cc2O4)N(c2ccccc2)c2cc(N(c4ccccc4)c4ccccc4)cc4c2B3c2ccccc2N4c2ccccc2)N(c2ccccc2)c2ccccc21 ; C1=Cc2cc3c(cc2N(c2ccccc2)c2ccccc21)Oc1cc(N(c2ccccc2)c2ccccc2)cc2c1B3c1cc3c(cc1O2)N(c1ccccc1)c1cc(N(c2ccccc2)c2ccccc2)cc2c1B3c1ccccc1N2c1ccccc1]

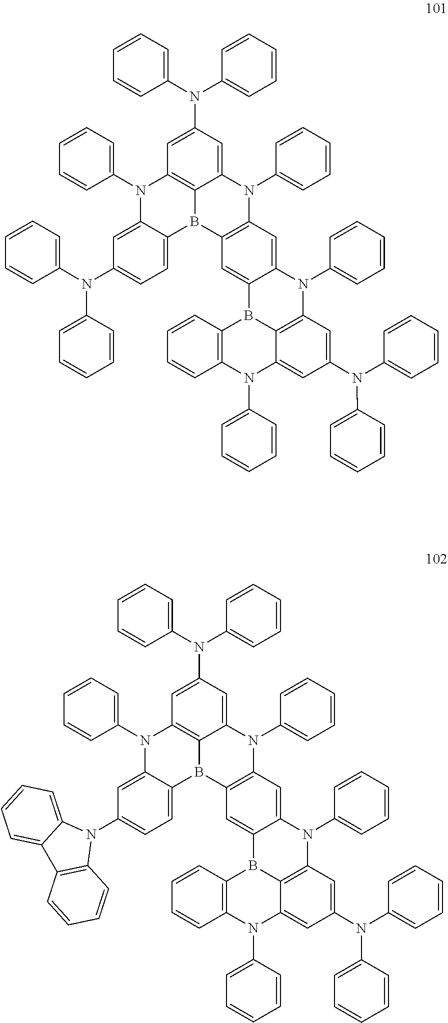 [SMILES: c1ccc(N(c2ccccc2)c2ccc3c(c2)N(c2ccccc2)c2cc(N(c4ccccc4)c4ccccc4)cc4c2B3c2cc3c(cc2N4c2ccccc2)N(c2ccccc2)c2cc(N(c4ccccc4)c4ccccc4)cc4c2B3c2ccccc2N4c2ccccc2)cc1 ; c1ccc(N(c2ccccc2)c2cc3c4c(c2)N(c2ccccc2)c2cc5c(cc2B4c2ccccc2N3c2ccccc2)B2c3ccc(-n4c6ccccc6c6ccccc64)cc3N(c3ccccc3)c3cc(N(c4ccccc4)c4ccccc4)cc(c32)N5c2ccccc2)cc1]

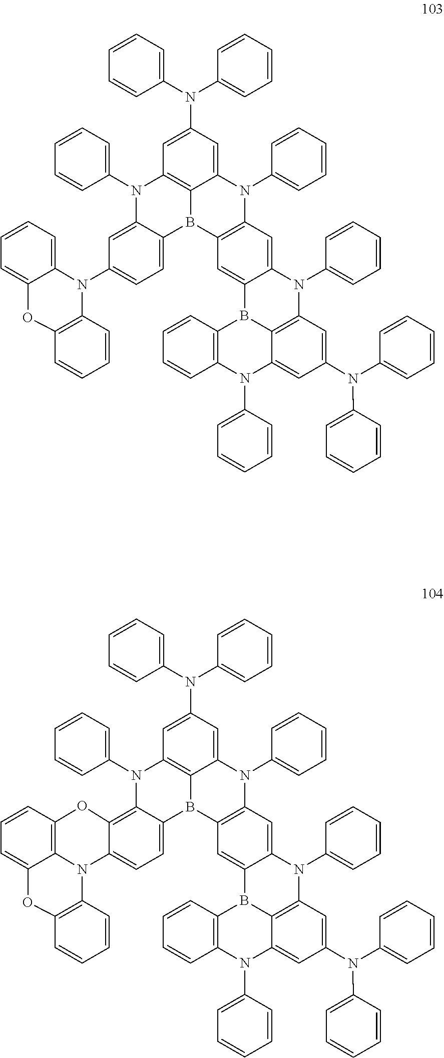 [SMILES: c1ccc(N(c2ccccc2)c2cc3c4c(c2)N(c2ccccc2)c2cc5c(cc2B4c2ccccc2N3c2ccccc2)B2c3ccc(N4c6ccccc6Oc6ccccc64)cc3N(c3ccccc3)c3cc(N(c4ccccc4)c4ccccc4)cc(c32)N5c2ccccc2)cc1 ; c1ccc(N(c2ccccc2)c2cc3c4c(c2)N(c2ccccc2)c2cc5c(cc2B4c2ccccc2N3c2ccccc2)B2c3ccc4c(c3N(c3ccccc3)c3cc(N(c6ccccc6)c6ccccc6)cc(c32)N5c2ccccc2)Oc2cccc3c2N4c2ccccc2O3)cc1]

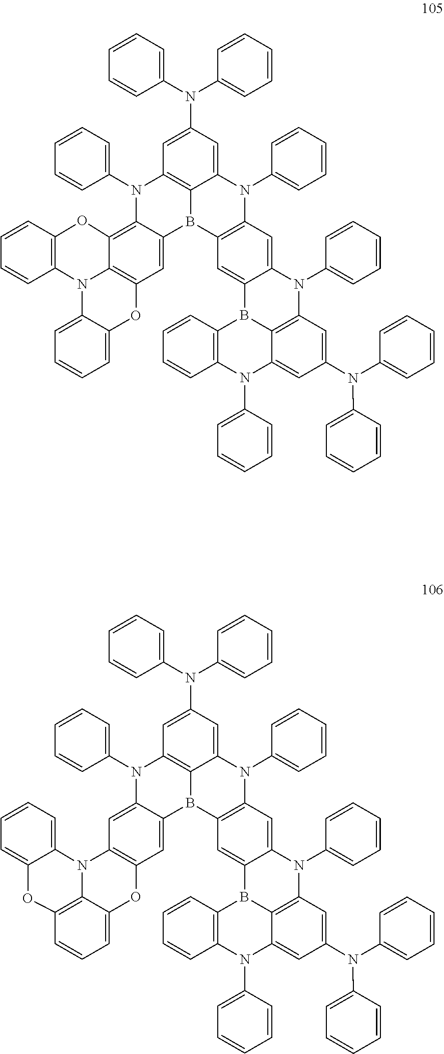 [SMILES: c1ccc(N(c2ccccc2)c2cc3c4c(c2)N(c2ccccc2)c2cc5c(cc2B4c2ccccc2N3c2ccccc2)B2c3cc4c6c(c3N(c3ccccc3)c3cc(N(c7ccccc7)c7ccccc7)cc(c32)N5c2ccccc2)Oc2ccccc2N6c2ccccc2O4)cc1 ; c1ccc(N(c2ccccc2)c2cc3c4c(c2)N(c2ccccc2)c2cc5c(cc2B4c2ccccc2N3c2ccccc2)B2c3cc4c(cc3N(c3ccccc3)c3cc(N(c6ccccc6)c6ccccc6)cc(c32)N5c2ccccc2)N2c3ccccc3Oc3cccc(c32)O4)cc1]

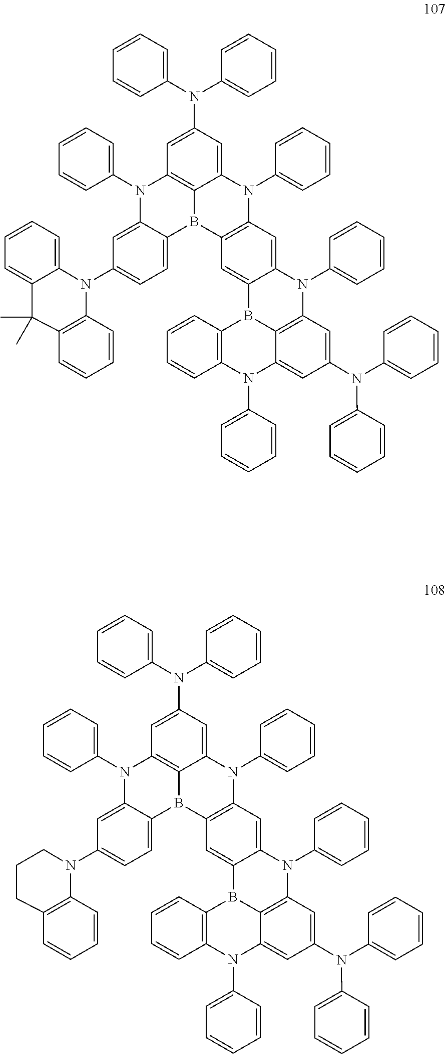 [SMILES: CC1(C)c2ccccc2N(c2ccc3c(c2)N(c2ccccc2)c2cc(N(c4ccccc4)c4ccccc4)cc4c2B3c2cc3c(cc2N4c2ccccc2)N(c2ccccc2)c2cc(N(c4ccccc4)c4ccccc4)cc4c2B3c2ccccc2N4c2ccccc2)c2ccccc21 ; c1ccc(N(c2ccccc2)c2cc3c4c(c2)N(c2ccccc2)c2cc5c(cc2B4c2ccccc2N3c2ccccc2)B2c3ccc(N4CCCc6ccccc64)cc3N(c3ccccc3)c3cc(N(c4ccccc4)c4ccccc4)cc(c32)N5c2ccccc2)cc1]

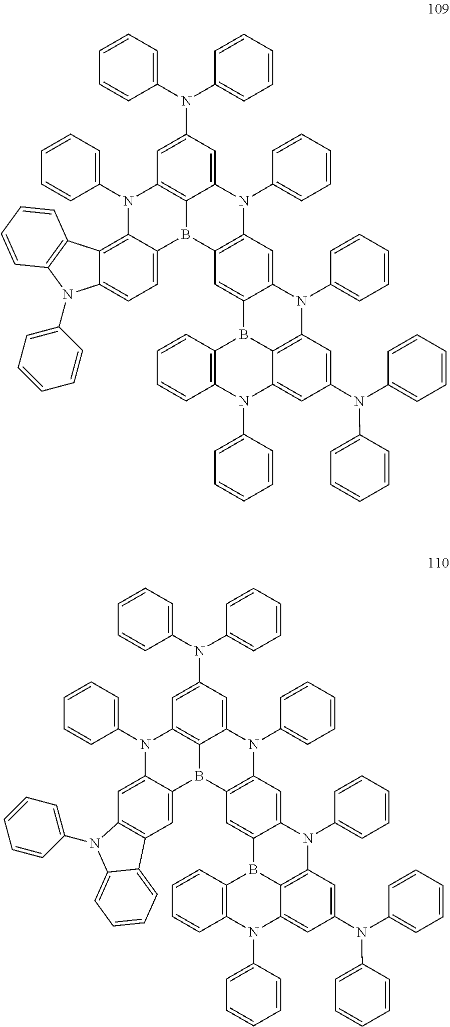 [SMILES: c1ccc(N(c2ccccc2)c2cc3c4c(c2)N(c2ccccc2)c2cc5c(cc2B4c2ccccc2N3c2ccccc2)B2c3ccc4c(c3N(c3ccccc3)c3cc(N(c6ccccc6)c6ccccc6)cc(c32)N5c2ccccc2)c2ccccc2n4-c2ccccc2)cc1 ; c1ccc(N(c2ccccc2)c2cc3c4c(c2)N(c2ccccc2)c2cc5c(cc2B4c2ccccc2N3c2ccccc2)B2c3cc4c6ccccc6n(-c6ccccc6)c4cc3N(c3ccccc3)c3cc(N(c4ccccc4)c4ccccc4)cc(c32)N5c2ccccc2)cc1]

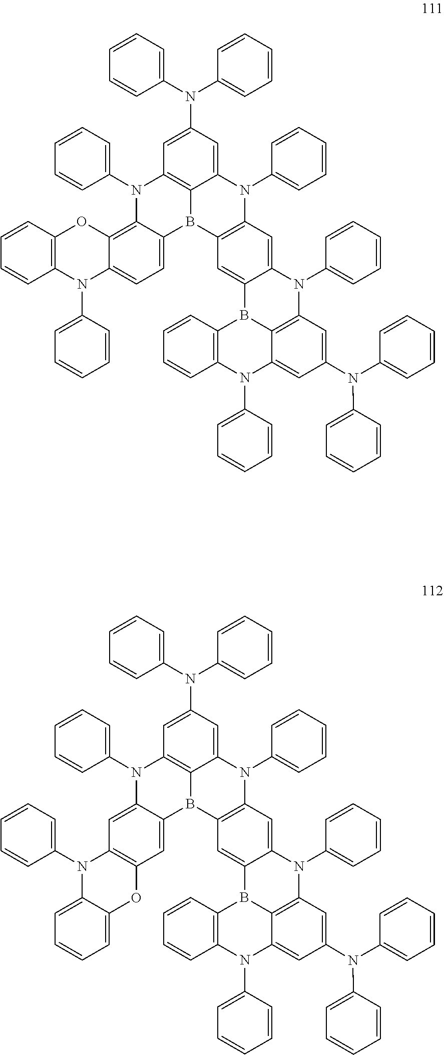 [SMILES: c1ccc(N(c2ccccc2)c2cc3c4c(c2)N(c2ccccc2)c2cc5c(cc2B4c2ccccc2N3c2ccccc2)B2c3ccc4c(c3N(c3ccccc3)c3cc(N(c6ccccc6)c6ccccc6)cc(c32)N5c2ccccc2)Oc2ccccc2N4c2ccccc2)cc1 ; c1ccc(N(c2ccccc2)c2cc3c4c(c2)N(c2ccccc2)c2cc5c(cc2B4c2ccccc2N3c2ccccc2)B2c3cc4c(cc3N(c3ccccc3)c3cc(N(c6ccccc6)c6ccccc6)cc(c32)N5c2ccccc2)N(c2ccccc2)c2ccccc2O4)cc1]

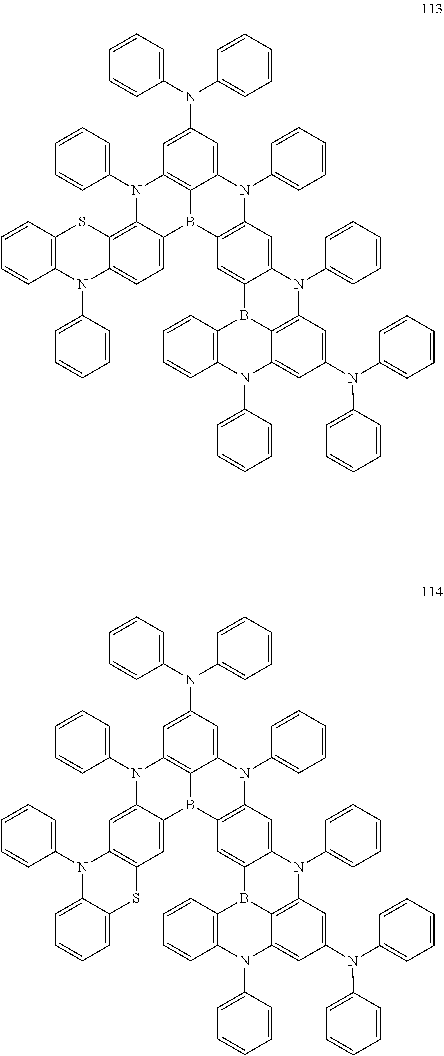 [SMILES: c1ccc(N(c2ccccc2)c2cc3c4c(c2)N(c2ccccc2)c2cc5c(cc2B4c2ccccc2N3c2ccccc2)B2c3ccc4c(c3N(c3ccccc3)c3cc(N(c6ccccc6)c6ccccc6)cc(c32)N5c2ccccc2)Sc2ccccc2N4c2ccccc2)cc1 ; c1ccc(N(c2ccccc2)c2cc3c4c(c2)N(c2ccccc2)c2cc5c(cc2B4c2ccccc2N3c2ccccc2)B2c3cc4c(cc3N(c3ccccc3)c3cc(N(c6ccccc6)c6ccccc6)cc(c32)N5c2ccccc2)N(c2ccccc2)c2ccccc2S4)cc1]

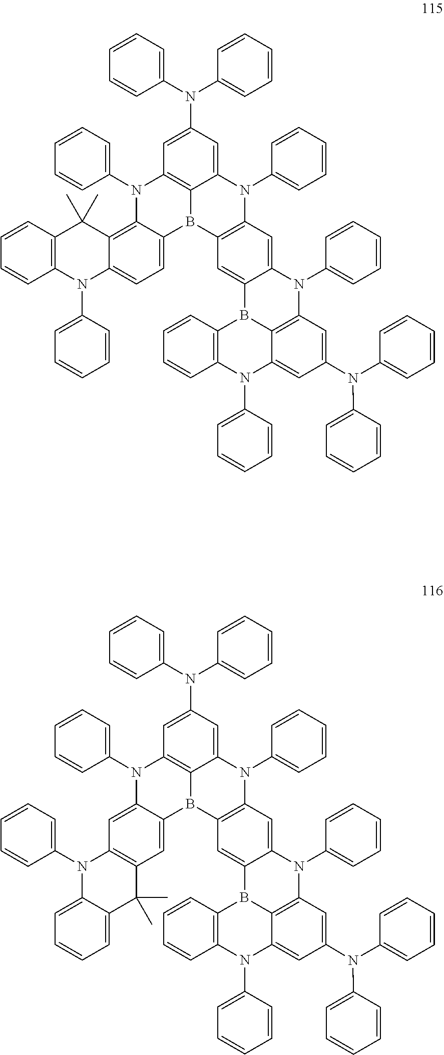 [SMILES: CC1(C)c2ccccc2N(c2ccccc2)c2ccc3c(c21)N(c1ccccc1)c1cc(N(c2ccccc2)c2ccccc2)cc2c1B3c1cc3c(cc1N2c1ccccc1)N(c1ccccc1)c1cc(N(c2ccccc2)c2ccccc2)cc2c1B3c1ccccc1N2c1ccccc1 ; CC1(C)c2ccccc2N(c2ccccc2)c2cc3c(cc21)B1c2cc4c(cc2N(c2ccccc2)c2cc(N(c5ccccc5)c5ccccc5)cc(c21)N3c1ccccc1)N(c1ccccc1)c1cc(N(c2ccccc2)c2ccccc2)cc2c1B4c1ccccc1N2c1ccccc1]

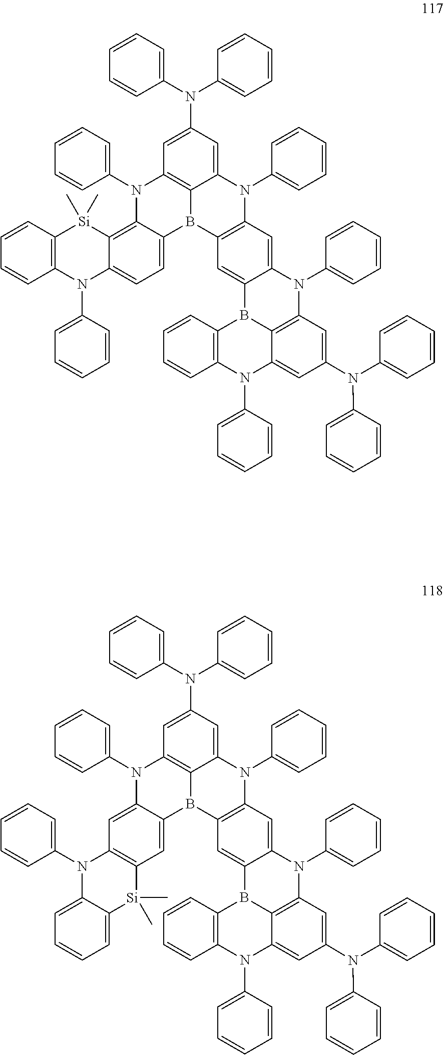 [SMILES: C[Si]1(C)c2ccccc2N(c2ccccc2)c2ccc3c(c21)N(c1ccccc1)c1cc(N(c2ccccc2)c2ccccc2)cc2c1B3c1cc3c(cc1N2c1ccccc1)N(c1ccccc1)c1cc(N(c2ccccc2)c2ccccc2)cc2c1B3c1ccccc1N2c1ccccc1 ; C[Si]1(C)c2ccccc2N(c2ccccc2)c2cc3c(cc21)B1c2cc4c(cc2N(c2ccccc2)c2cc(N(c5ccccc5)c5ccccc5)cc(c21)N3c1ccccc1)N(c1ccccc1)c1cc(N(c2ccccc2)c2ccccc2)cc2c1B4c1ccccc1N2c1ccccc1]

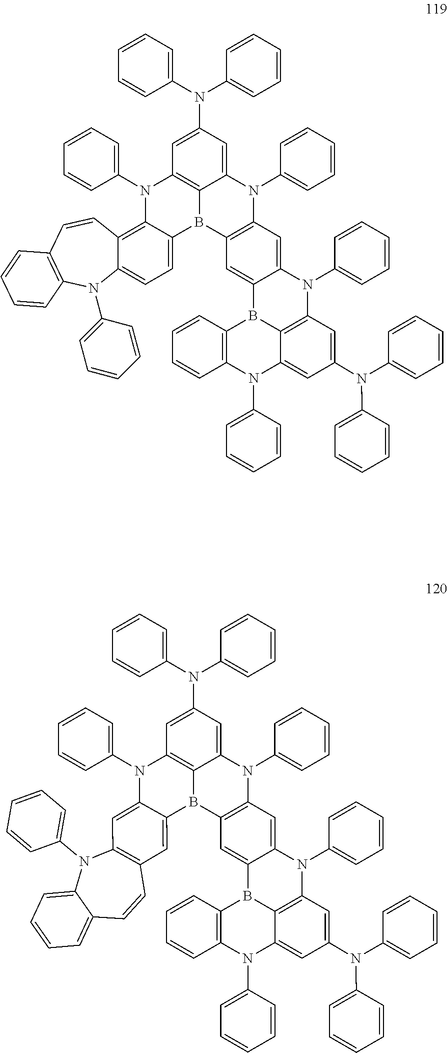 [SMILES: C1=Cc2c(ccc3c2N(c2ccccc2)c2cc(N(c4ccccc4)c4ccccc4)cc4c2B3c2cc3c(cc2N4c2ccccc2)N(c2ccccc2)c2cc(N(c4ccccc4)c4ccccc4)cc4c2B3c2ccccc2N4c2ccccc2)N(c2ccccc2)c2ccccc21 ; C1=Cc2cc3c(cc2N(c2ccccc2)c2ccccc21)N(c1ccccc1)c1cc(N(c2ccccc2)c2ccccc2)cc2c1B3c1cc3c(cc1N2c1ccccc1)N(c1ccccc1)c1cc(N(c2ccccc2)c2ccccc2)cc2c1B3c1ccccc1N2c1ccccc1]

13. A fused polycyclic compound represented by Formula 1 below: 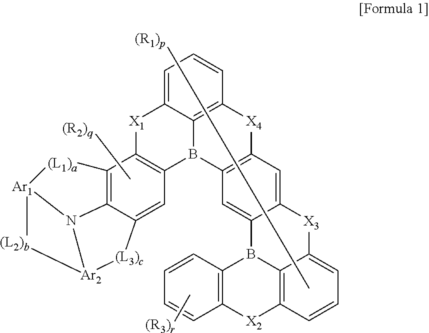
wherein, in Formula 1 above,
X₁, X₂, X₃, and X₄ are each independently NAr₃, O, or S,
Ar₁ to Ar₃ are each independently a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or are bonded to an adjacent group to form a ring,
R₁ to R₃ are each independently a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms,
p is an integer in a range of 0 to 8,
q is 0 or 1,
r is an integer in a range of 0 to 4,
L₁ to L₃ are each independently a direct linkage, *—O—*, *—S—*, *—Si(R₁₁R₁₂)—*, *—CR₁₃R₁₄—*, or *—(CR₁₅)(CR₁₆)—*,
R₁₁ to R₁₆ are each independently a deuterium atom, a halogen atom, a cyano group, a substituted or unsubstituted alkyl group having 1 to 20 carbon atoms, and
a, b, and c are each independently 0 or 1.

14. The fused polycyclic compound of claim 13, wherein the fused polycyclic compound represented by Formula 1 above is represented by any one selected from among Formula 1-1 to Formula 1-3 below: 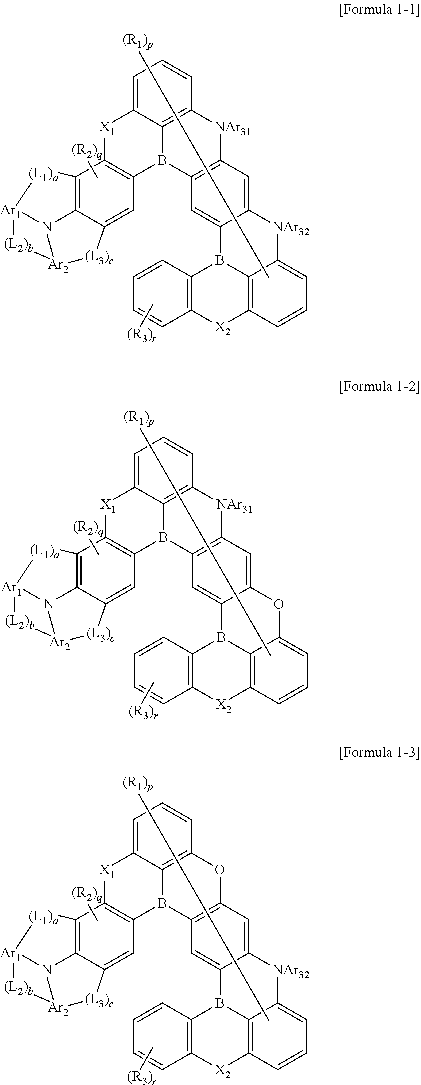
wherein, in Formula 1-1 to Formula 1-3 above,
Ar₃₁ and Ar₃₂ are each independently a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or are bonded to an adjacent group to form a ring,
X₂, Ar₁, Ar₂, L₁ to L₃, R₁ to R₃, a, b, c, p, q, and r above are the same as defined with respect to Formula 1.

15. The fused polycyclic compound of claim 13, wherein the fused polycyclic compound represented by Formula 1 above is represented by Formula 2-1 or Formula 2-2 below: 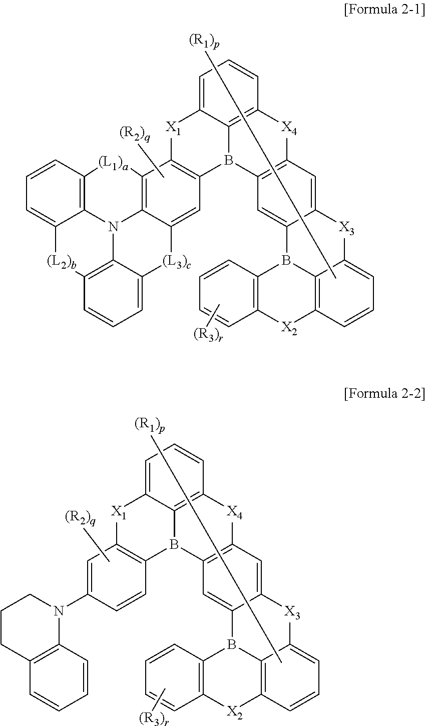
wherein, in Formula 2-1 and Formula 2-2 above,
X₁ to X₄, L₁ to L₃, R₁ to R₃, a, b, c, p, q, and r above are the same as defined with respect to Formula 1.

16. The fused polycyclic compound of claim 13, wherein the fused polycyclic compound represented by Formula 1 above is represented by Formula 3 below: 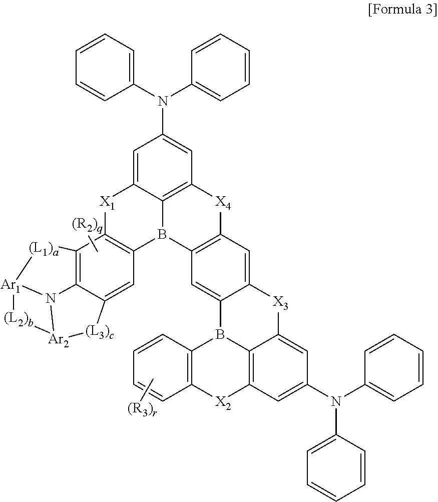
wherein, in Formula 3 above,
X₁ to X₄, Ar₁, Ar₂, L₁ to L₃, R₂, R₃, a, b, c, q, and r above are the same as defined with respect to Formula 1.

17. The fused polycyclic compound of claim 13, wherein X₁ to X₄ above are each independently NAr₃ or O.

18. The fused polycyclic compound of claim 13, wherein R₂ and R₃ are each independently a hydrogen atom or a deuterium atom.

19. The fused polycyclic compound of claim 13, wherein a difference (ΔE_{ST}) value between a lowest triplet exciton energy level (T1 energy level) and a lowest singlet exciton energy level (S1 energy level) of the fused polycyclic compound is about 0.13 eV or less.

20. The fused polycyclic compound of claim 13, wherein the fused polycyclic compound is any one selected from among the compounds represented in Compound Group 1 below: 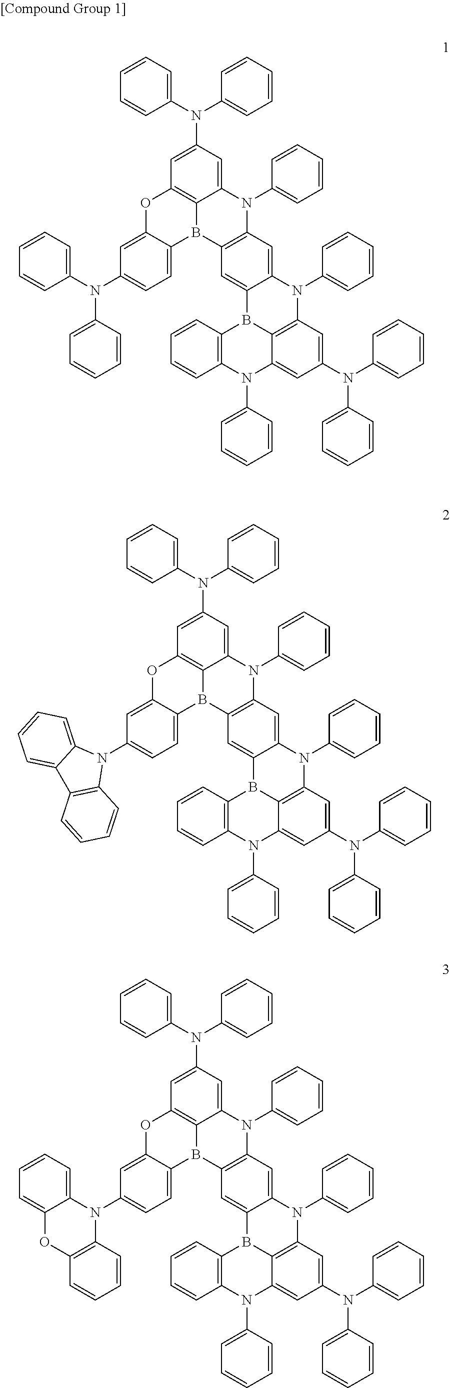 [SMILES: c1ccc(N(c2ccccc2)c2ccc3c(c2)Oc2cc(N(c4ccccc4)c4ccccc4)cc4c2B3c2cc3c(cc2N4c2ccccc2)N(c2ccccc2)c2cc(N(c4ccccc4)c4ccccc4)cc4c2B3c2ccccc2N4c2ccccc2)cc1 ; c1ccc(N(c2ccccc2)c2cc3c4c(c2)N(c2ccccc2)c2cc5c(cc2B4c2ccc(-n4c6ccccc6c6ccccc64)cc2O3)B2c3ccccc3N(c3ccccc3)c3cc(N(c4ccccc4)c4ccccc4)cc(c32)N5c2ccccc2)cc1 ; c1ccc(N(c2ccccc2)c2cc3c4c(c2)N(c2ccccc2)c2cc5c(cc2B4c2ccc(N4c6ccccc6Oc6ccccc64)cc2O3)B2c3ccccc3N(c3ccccc3)c3cc(N(c4ccccc4)c4ccccc4)cc(c32)N5c2ccccc2)cc1] 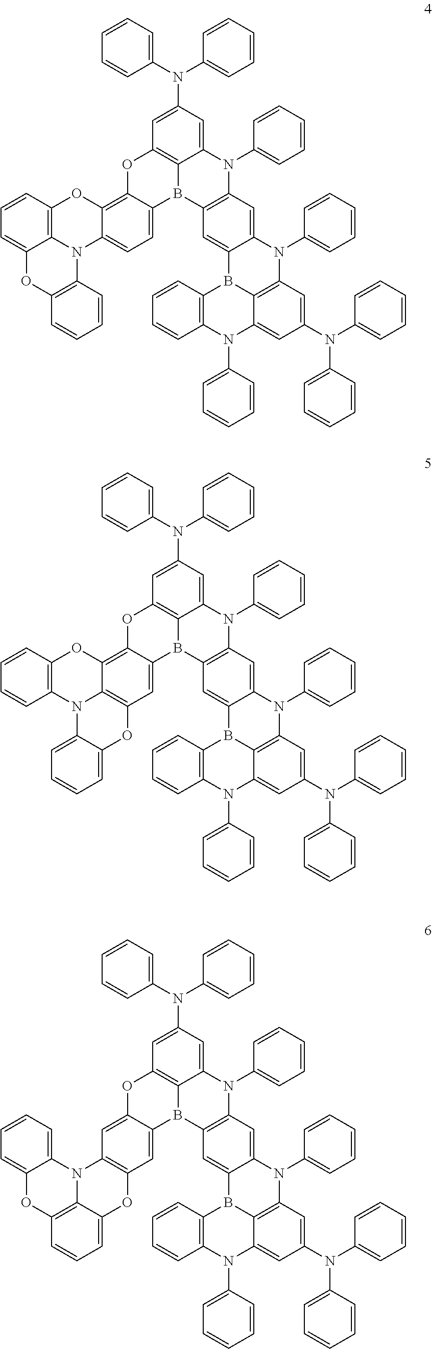 [SMILES: c1ccc(N(c2ccccc2)c2cc3c4c(c2)N(c2ccccc2)c2cc5c(cc2B4c2ccc4c(c2O3)Oc2cccc3c2N4c2ccccc2O3)B2c3ccccc3N(c3ccccc3)c3cc(N(c4ccccc4)c4ccccc4)cc(c32)N5c2ccccc2)cc1 ; c1ccc(N(c2ccccc2)c2cc3c4c(c2)N(c2ccccc2)c2cc5c(cc2B4c2cc4c6c(c2O3)Oc2ccccc2N6c2ccccc2O4)B2c3ccccc3N(c3ccccc3)c3cc(N(c4ccccc4)c4ccccc4)cc(c32)N5c2ccccc2)cc1 ; c1ccc(N(c2ccccc2)c2cc3c4c(c2)N(c2ccccc2)c2cc5c(cc2B4c2cc4c(cc2O3)N2c3ccccc3Oc3cccc(c32)O4)B2c3ccccc3N(c3ccccc3)c3cc(N(c4ccccc4)c4ccccc4)cc(c32)N5c2ccccc2)cc1] 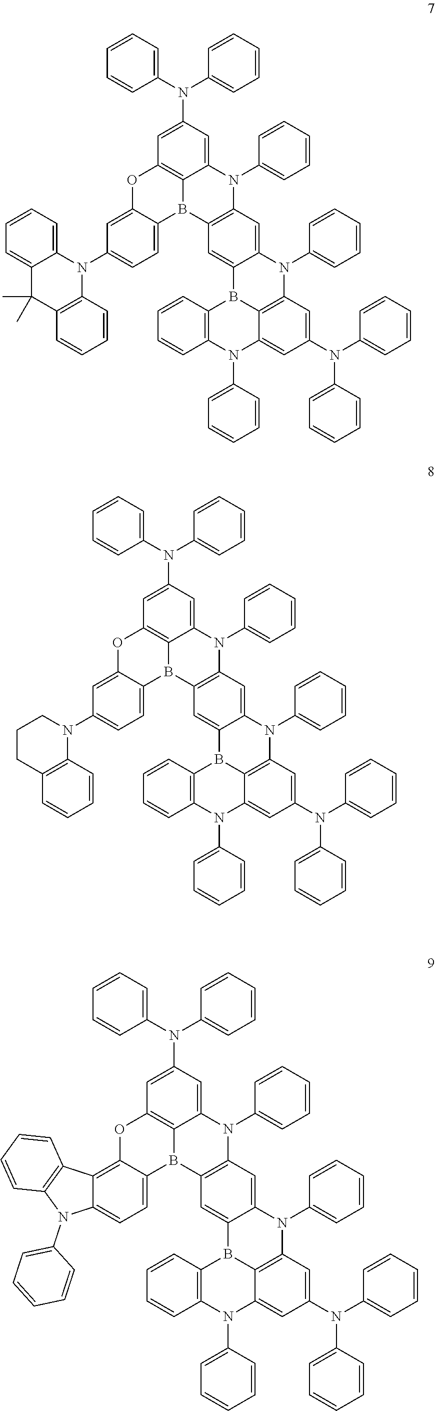 [SMILES: CC1(C)c2ccccc2N(c2ccc3c(c2)Oc2cc(N(c4ccccc4)c4ccccc4)cc4c2B3c2cc3c(cc2N4c2ccccc2)N(c2ccccc2)c2cc(N(c4ccccc4)c4ccccc4)cc4c2B3c2ccccc2N4c2ccccc2)c2ccccc21 ; c1ccc(N(c2ccccc2)c2cc3c4c(c2)N(c2ccccc2)c2cc5c(cc2B4c2ccc(N4CCCc6ccccc64)cc2O3)B2c3ccccc3N(c3ccccc3)c3cc(N(c4ccccc4)c4ccccc4)cc(c32)N5c2ccccc2)cc1 ; c1ccc(N(c2ccccc2)c2cc3c4c(c2)N(c2ccccc2)c2cc5c(cc2B4c2ccc4c(c2O3)c2ccccc2n4-c2ccccc2)B2c3ccccc3N(c3ccccc3)c3cc(N(c4ccccc4)c4ccccc4)cc(c32)N5c2ccccc2)cc1] 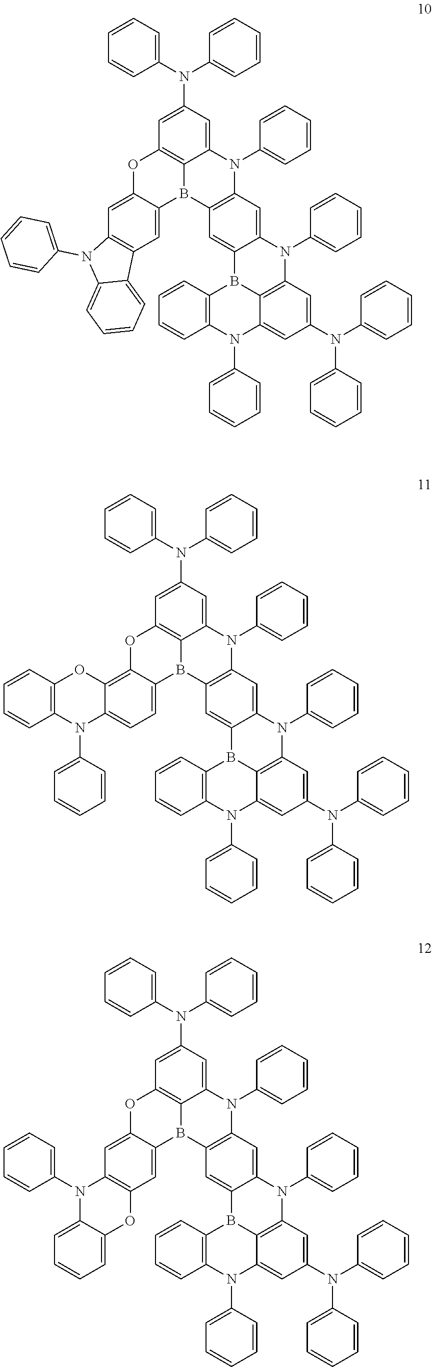 [SMILES: c1ccc(N(c2ccccc2)c2cc3c4c(c2)N(c2ccccc2)c2cc5c(cc2B4c2cc4c6ccccc6n(-c6ccccc6)c4cc2O3)B2c3ccccc3N(c3ccccc3)c3cc(N(c4ccccc4)c4ccccc4)cc(c32)N5c2ccccc2)cc1 ; c1ccc(N(c2ccccc2)c2cc3c4c(c2)N(c2ccccc2)c2cc5c(cc2B4c2ccc4c(c2O3)Oc2ccccc2N4c2ccccc2)B2c3ccccc3N(c3ccccc3)c3cc(N(c4ccccc4)c4ccccc4)cc(c32)N5c2ccccc2)cc1 ; c1ccc(N(c2ccccc2)c2cc3c4c(c2)N(c2ccccc2)c2cc5c(cc2B4c2cc4c(cc2O3)N(c2ccccc2)c2ccccc2O4)B2c3ccccc3N(c3ccccc3)c3cc(N(c4ccccc4)c4ccccc4)cc(c32)N5c2ccccc2)cc1] 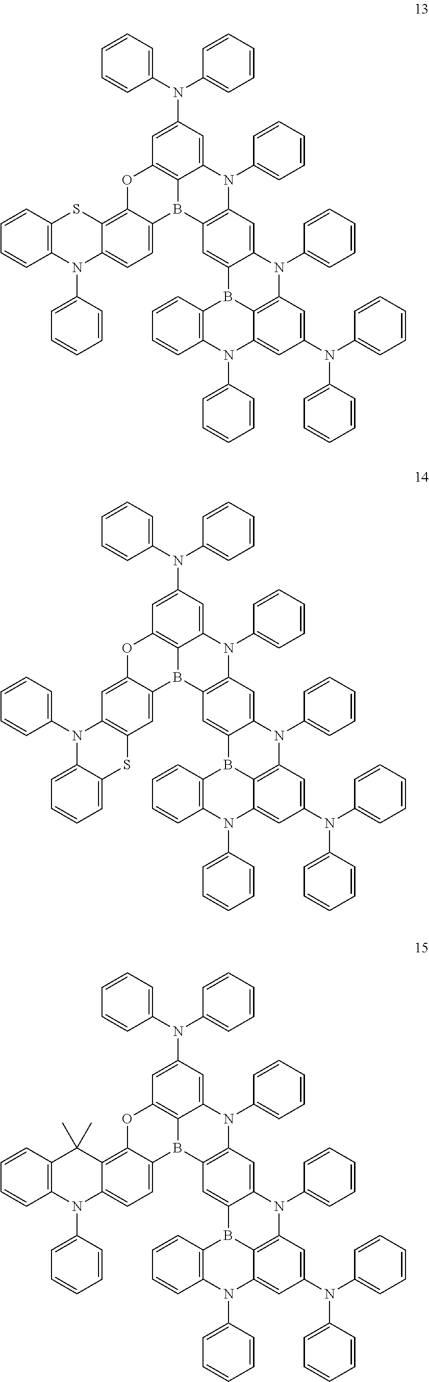 [SMILES: c1ccc(N(c2ccccc2)c2cc3c4c(c2)N(c2ccccc2)c2cc5c(cc2B4c2ccc4c(c2O3)Sc2ccccc2N4c2ccccc2)B2c3ccccc3N(c3ccccc3)c3cc(N(c4ccccc4)c4ccccc4)cc(c32)N5c2ccccc2)cc1 ; c1ccc(N(c2ccccc2)c2cc3c4c(c2)N(c2ccccc2)c2cc5c(cc2B4c2cc4c(cc2O3)N(c2ccccc2)c2ccccc2S4)B2c3ccccc3N(c3ccccc3)c3cc(N(c4ccccc4)c4ccccc4)cc(c32)N5c2ccccc2)cc1 ; CC1(C)c2ccccc2N(c2ccccc2)c2ccc3c(c21)Oc1cc(N(c2ccccc2)c2ccccc2)cc2c1B3c1cc3c(cc1N2c1ccccc1)N(c1ccccc1)c1cc(N(c2ccccc2)c2ccccc2)cc2c1B3c1ccccc1N2c1ccccc1] 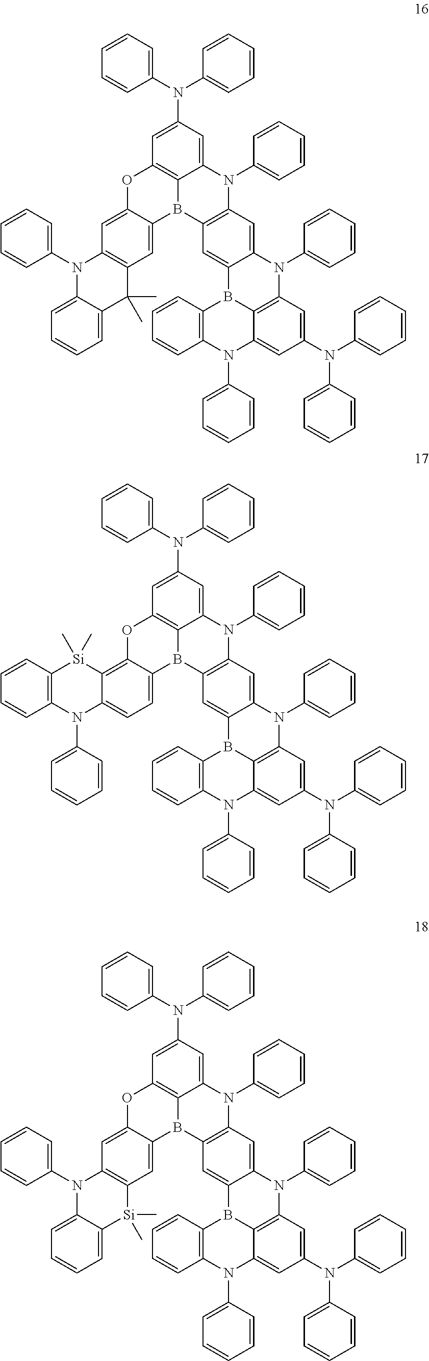 [SMILES: CC1(C)c2ccccc2N(c2ccccc2)c2cc3c(cc21)B1c2cc4c(cc2N(c2ccccc2)c2cc(N(c5ccccc5)c5ccccc5)cc(c21)O3)N(c1ccccc1)c1cc(N(c2ccccc2)c2ccccc2)cc2c1B4c1ccccc1N2c1ccccc1 ; C[Si]1(C)c2ccccc2N(c2ccccc2)c2ccc3c(c21)Oc1cc(N(c2ccccc2)c2ccccc2)cc2c1B3c1cc3c(cc1N2c1ccccc1)N(c1ccccc1)c1cc(N(c2ccccc2)c2ccccc2)cc2c1B3c1ccccc1N2c1ccccc1 ; C[Si]1(C)c2ccccc2N(c2ccccc2)c2cc3c(cc21)B1c2cc4c(cc2N(c2ccccc2)c2cc(N(c5ccccc5)c5ccccc5)cc(c21)O3)N(c1ccccc1)c1cc(N(c2ccccc2)c2ccccc2)cc2c1B4c1ccccc1N2c1ccccc1] 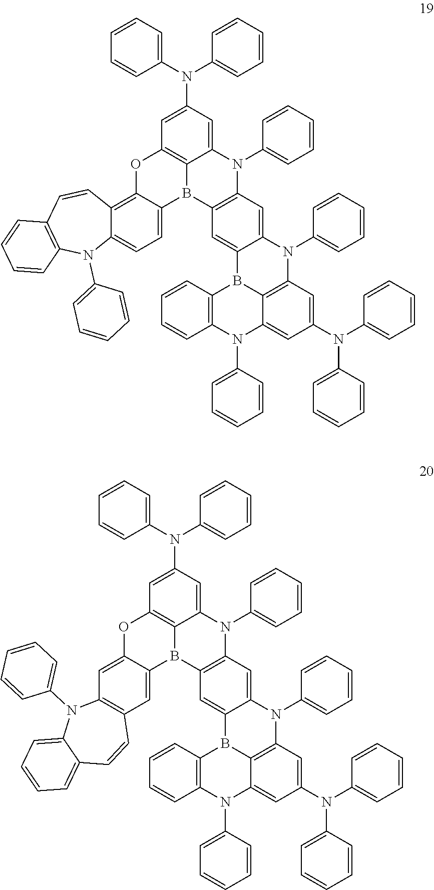 [SMILES: C1=Cc2c(ccc3c2Oc2cc(N(c4ccccc4)c4ccccc4)cc4c2B3c2cc3c(cc2N4c2ccccc2)N(c2ccccc2)c2cc(N(c4ccccc4)c4ccccc4)cc4c2B3c2ccccc2N4c2ccccc2)N(c2ccccc2)c2ccccc21 ; C1=Cc2cc3c(cc2N(c2ccccc2)c2ccccc21)Oc1cc(N(c2ccccc2)c2ccccc2)cc2c1B3c1cc3c(cc1N2c1ccccc1)N(c1ccccc1)c1cc(N(c2ccccc2)c2ccccc2)cc2c1B3c1ccccc1N2c1ccccc1] 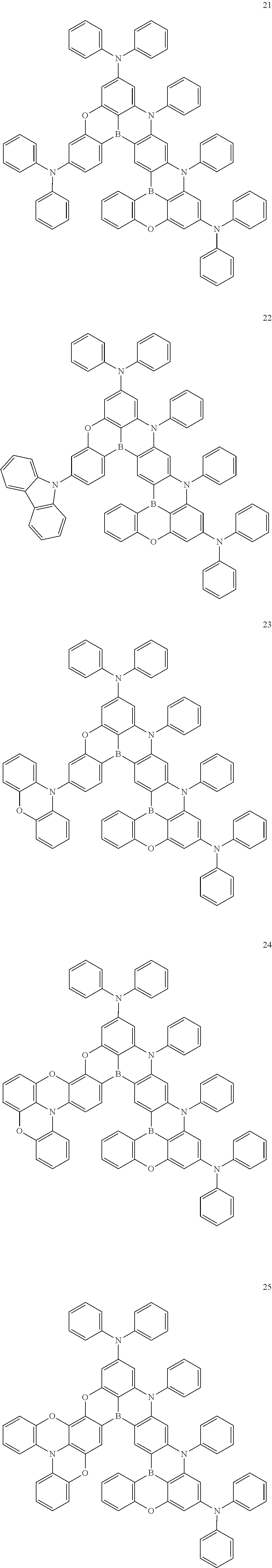 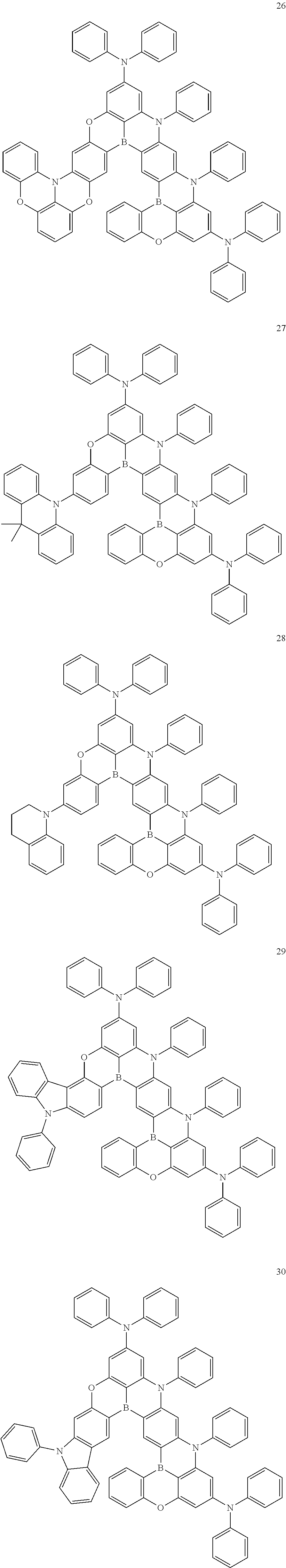 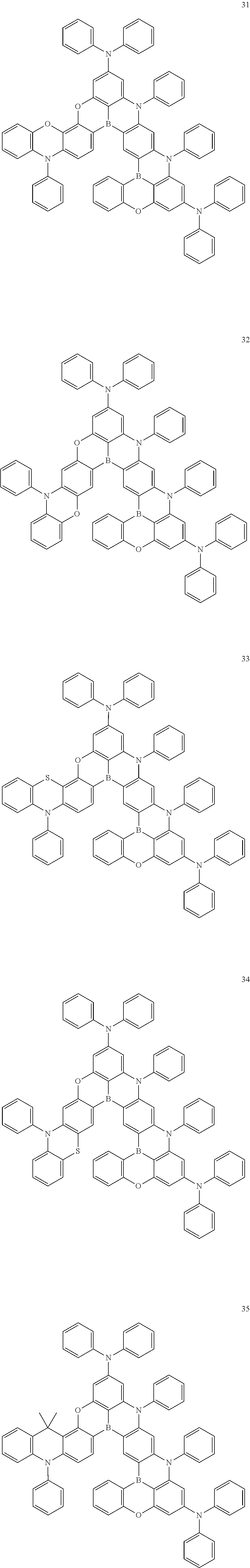 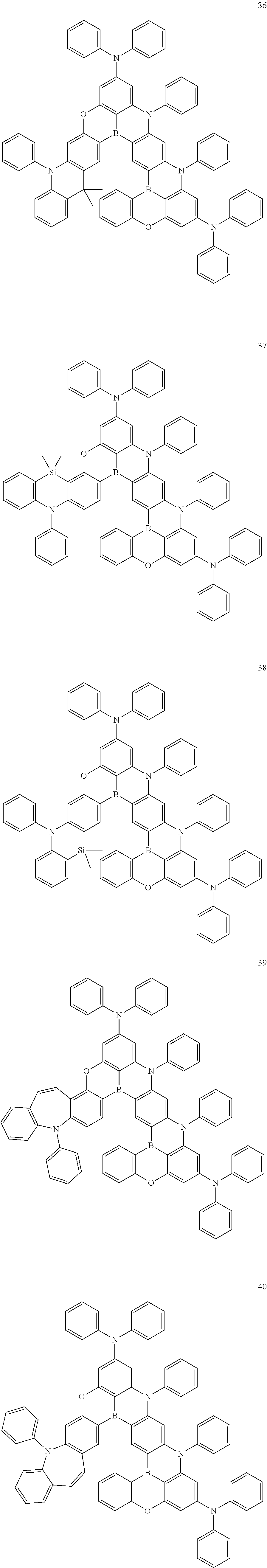 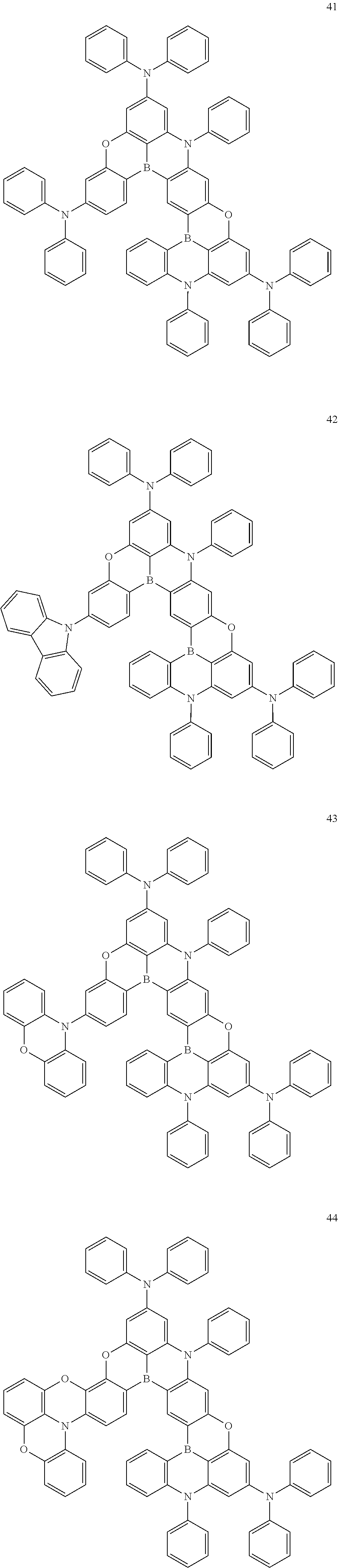 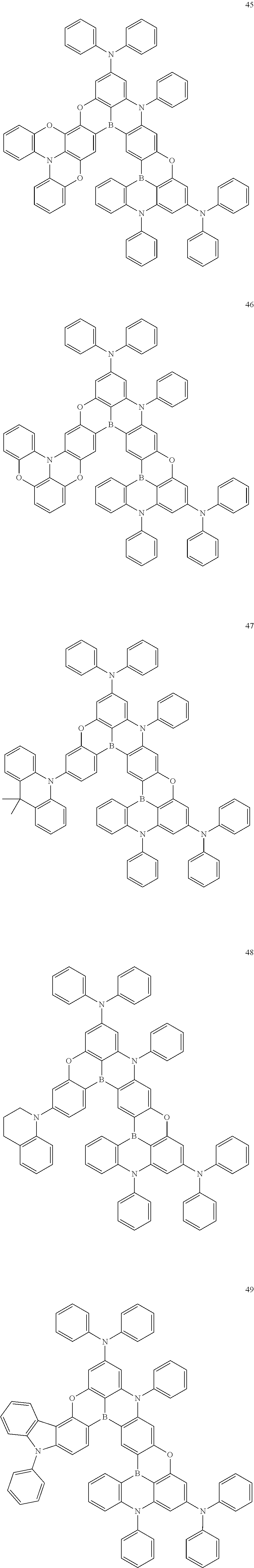 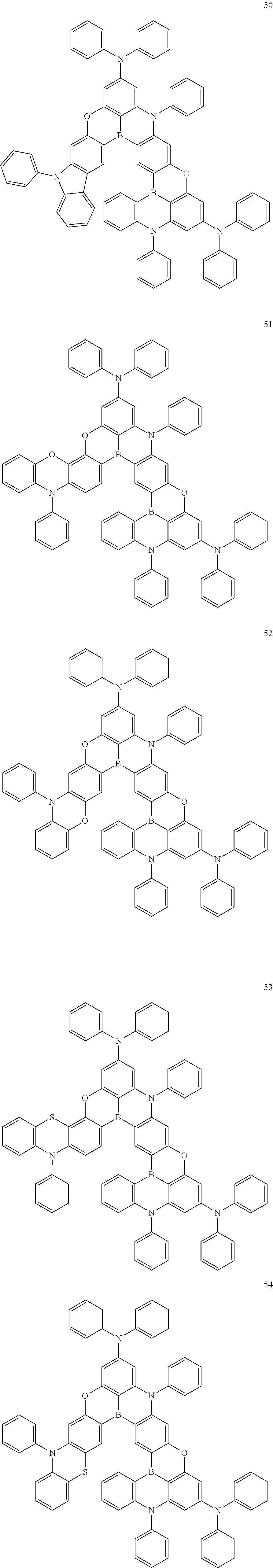 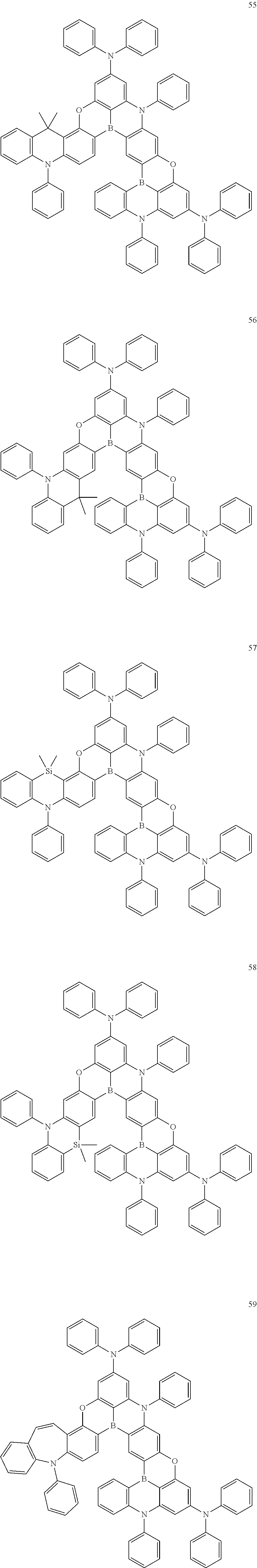 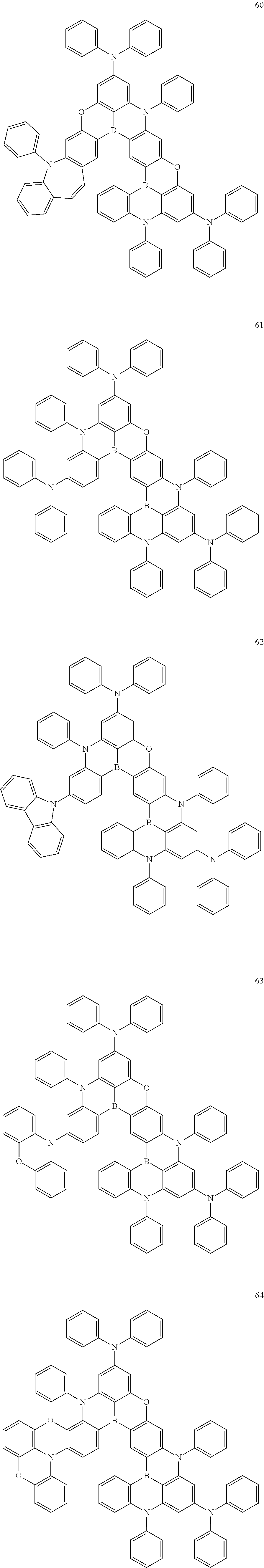 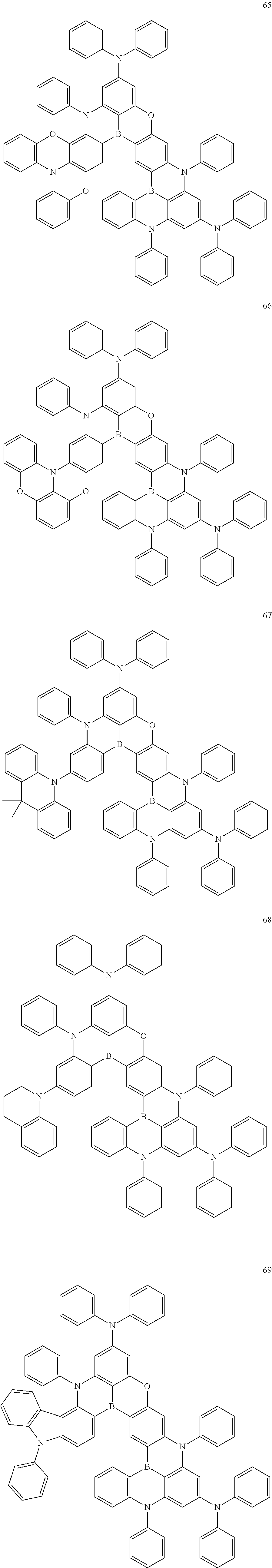 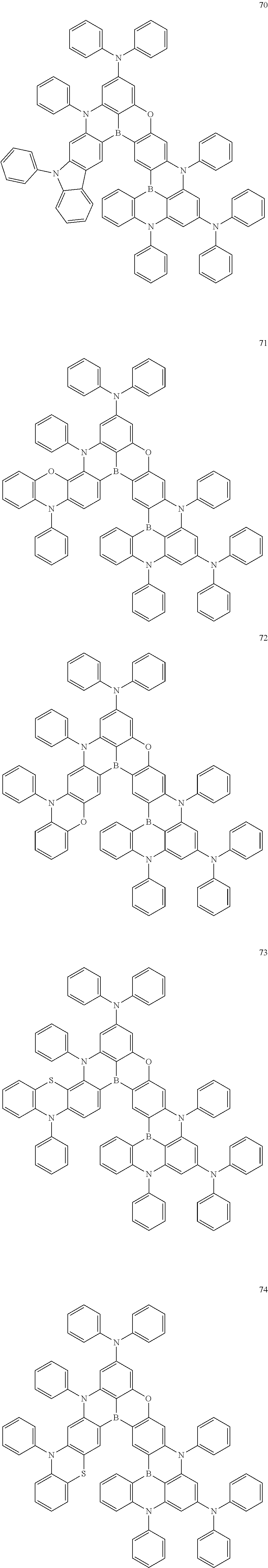 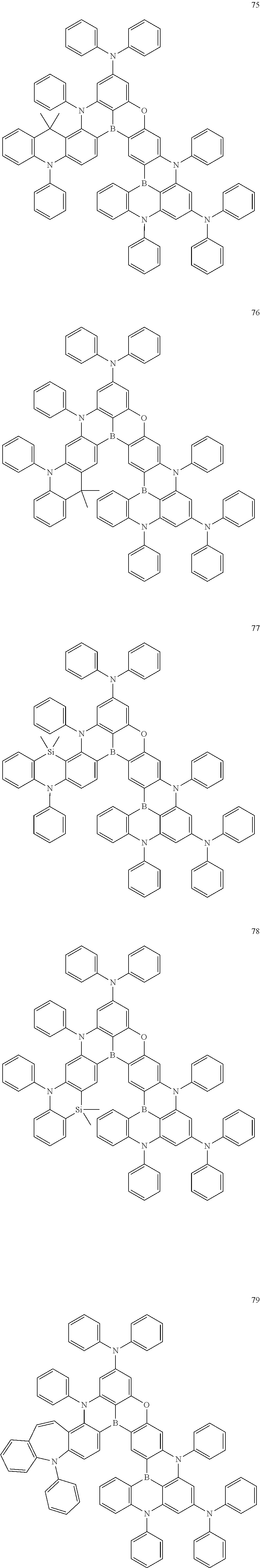 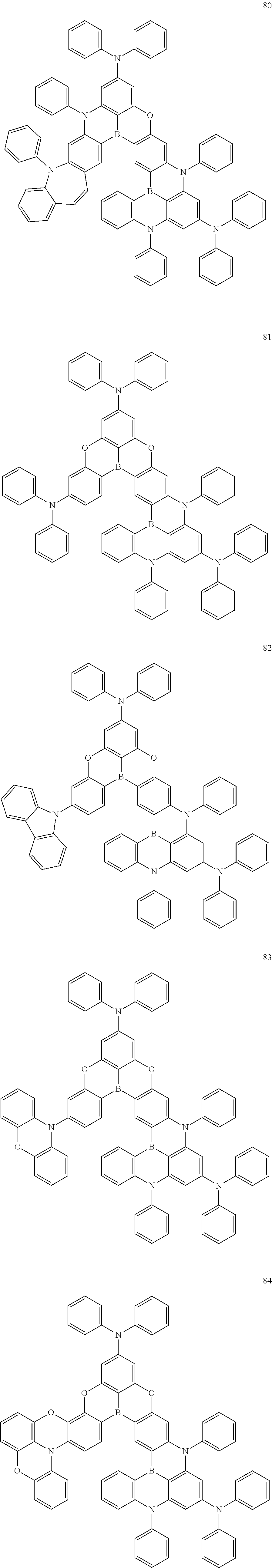 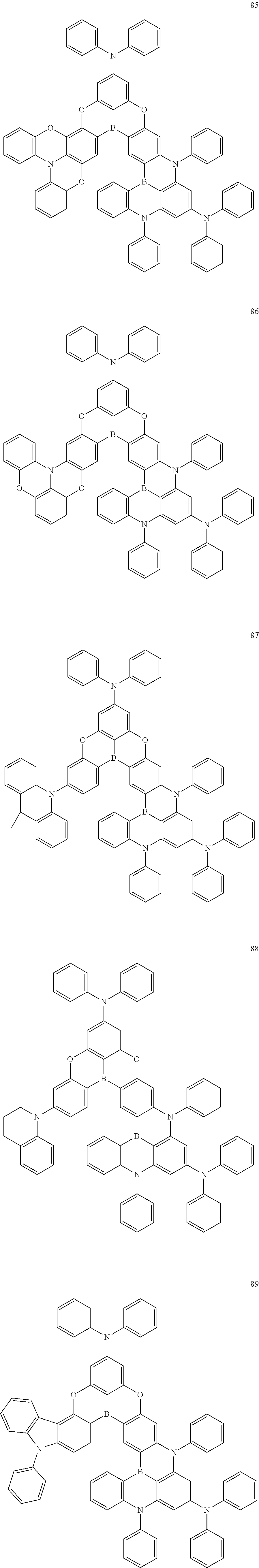 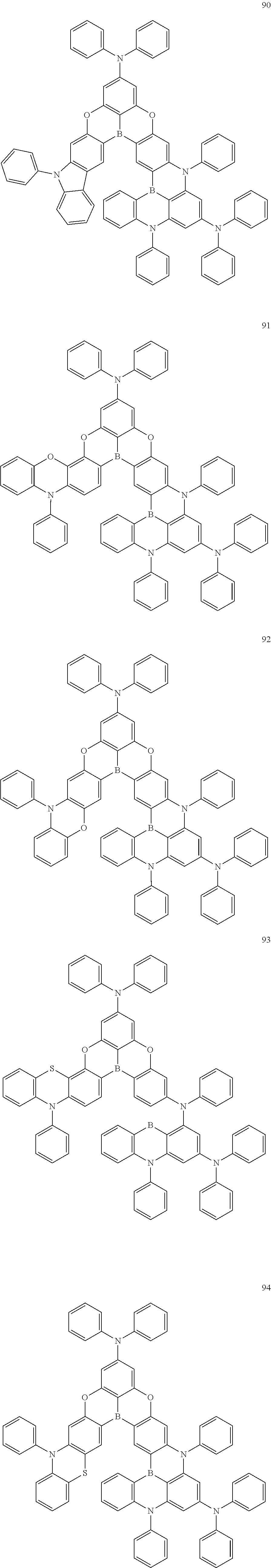 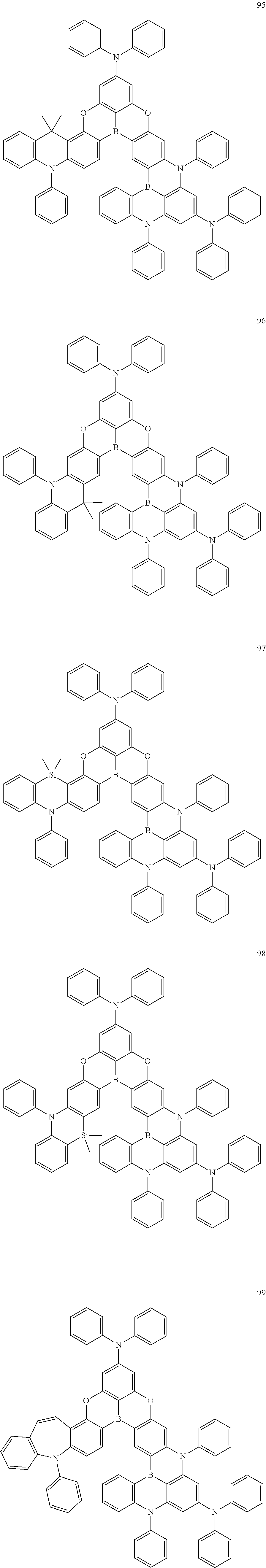 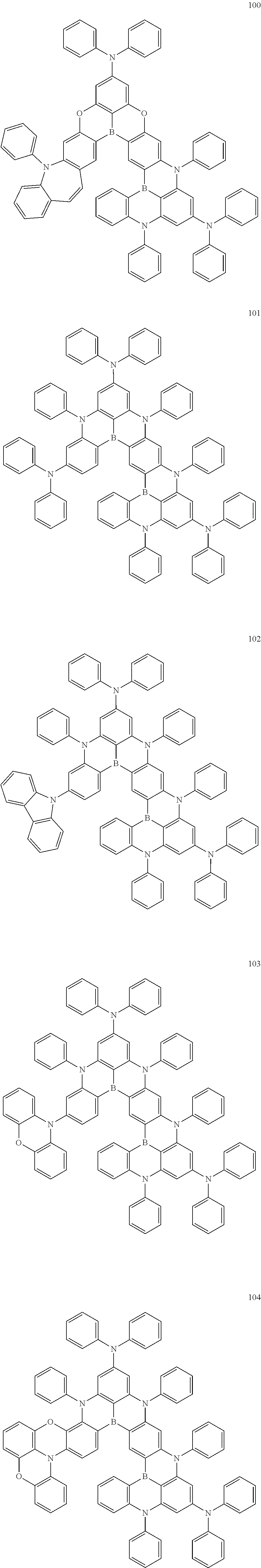 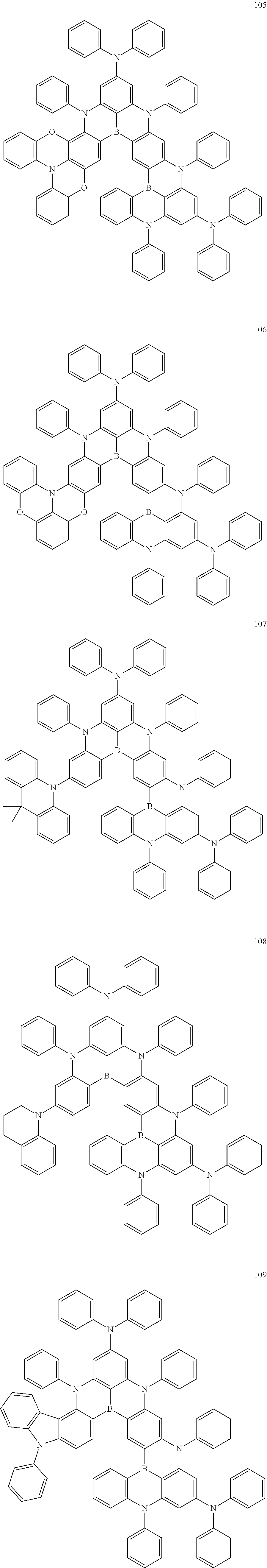 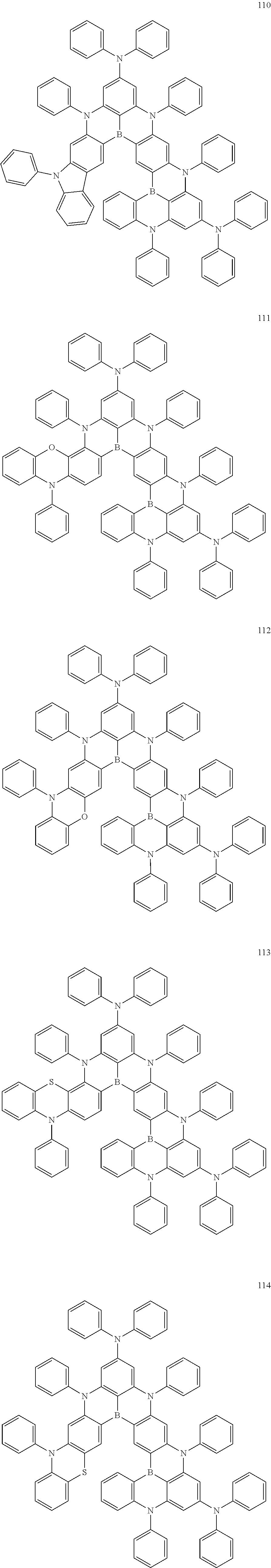 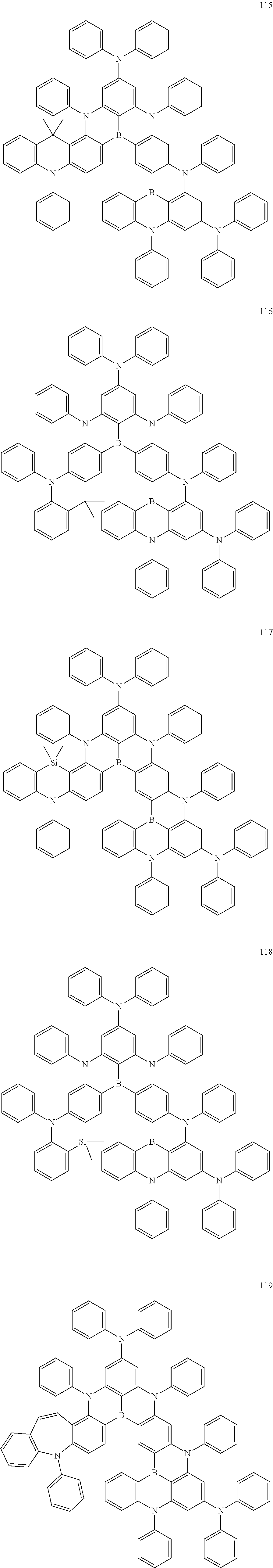 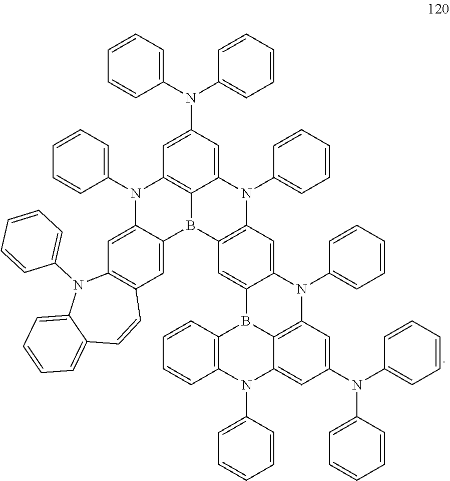 [SMILES: C1=Cc2cc3c(cc2N(c2ccccc2)c2ccccc21)N(c1ccccc1)c1cc(N(c2ccccc2)c2ccccc2)cc2c1B3c1cc3c(cc1N2c1ccccc1)N(c1ccccc1)c1cc(N(c2ccccc2)c2ccccc2)cc2c1B3c1ccccc1N2c1ccccc1]
